(19) United States
(12) Patent Application Publication
(10) Pub. No.: US 2023/0309401 A1
(43) Pub. Date: Sep. 28, 2023

(54) LIGHT EMITTING DEVICE

(71) Applicant: Samsung Display Co., Ltd., Yongin-si (KR)

(72) Inventors: TAEIL KIM, Hwaseong-si (KR); SUN YOUNG PAK, Suwon-si (KR); JUNHA PARK, Gwacheon-si (KR); JANG YEOL BAEK, Yongin-si (KR); Kyoung SUNWOO, Hwaseong-si (KR); MUN-KI SIM, Seoul (KR); CHANSEOK OH, Seoul (KR); MINJUNG JUNG, Hongcheon-gun (KR)

(73) Assignee: Samsung Display Co., Ltd., Yongin-si (KR)

(21) Appl. No.: 18/089,887

(22) Filed: Dec. 28, 2022

(30) Foreign Application Priority Data
Mar. 25, 2022 (KR) 10-2022-0037555

(51) Int. Cl. H10K 85/60; H10K 85/30; C09K 11/06; H10K 85/40

(52) U.S. Cl. CPC H10K 85/658; H10K 85/6572; H10K 85/654; H10K 85/346; C09K 11/06; H10K 85/40; H10K 50/12

(57) ABSTRACT

Embodiments provide a light emitting device that includes a first electrode, a second electrode facing the first electrode, and an emission layer disposed between the first electrode and the second electrode. The emission layer includes: a first compound represented by Formula 1; and at least one of a second compound, a third compound 3, and a fourth compound, thereby showing improved emission efficiency and device life.

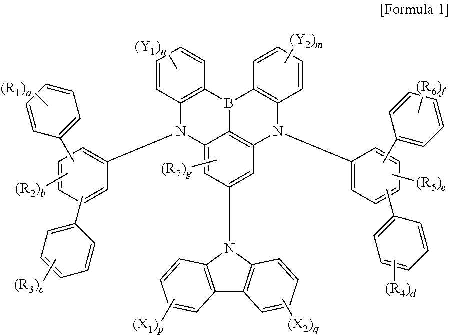

### CROSS-REFERENCE TO RELATED APPLICATION(S)

This application claims priority to and benefits of Korean Patent Application No. 10-2022-0037555 under 35 U.S.C. § 119, filed on Mar. 25, 2022 in the Korean Intellectual Property Office, the entire contents of which are incorporated herein by reference.

### BACKGROUND

### 1. Technical Field

The disclosure relates to a light emitting device including multiple materials as well as a novel fused polycyclic compound in an emission layer as light emitting materials.

### 2. Description of the Related Art

Active development continues for an organic electroluminescence display as an image display. The organic electroluminescence display is different from a liquid crystal display and is a so-called self-luminescent display in which holes and electrons respectively injected from a first electrode and a second electrode recombine in an emission layer so that a light emitting material including an organic compound in the emission layer emits light to achieve display.

In the application of an organic electroluminescence device to a display, there is a demand for an organic electroluminescence device having a low driving voltage, high emission efficiency, and a long service life, and continuous development is required on materials for an organic electroluminescence device which are capable of stably achieving such characteristics.

In order to implement an organic electroluminescence device with high efficiency, techniques pertaining to phosphorescence emission which uses energy in a triplet state or to delayed fluorescence emission which uses the generating phenomenon of singlet excitons by the collision of triplet excitons (triplet-triplet annihilation, TTA) are being developed, and development is currently directed to a thermally activated delayed fluorescence (TADF) material using delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting device having improved emission efficiency and device life.

The disclosure also provides a novel fused polycyclic compound which is capable of improving the emission efficiency and device life of a light emitting device.

An embodiment provides a light emitting device which may include a first electrode, a second electrode facing the first electrode, and an emission layer disposed between the first electrode and the second electrode. The emission layer may include: a first compound represented by Formula 1; and at least one of a second compound represented by Formula 2, a third compound represented by Formula 3, and a fourth compound represented by Formula 4:

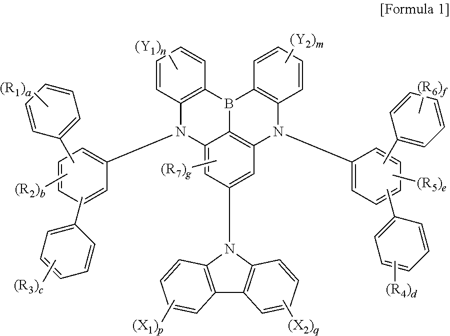

In Formula 1, X₁ and X₂ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring; p and q may each independently be an integer from 0 to 4; Y₁ and Y₂ may each independently be a hydrogen atom, a deuterium atom, a substituted or unsubstituted amine group, a substituted or unsubstituted alkyl group of 1 to 20 carbon atoms, a substituted or unsubstituted oxy group, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring, wherein for Y₁ and Y₂, at least one of Y₁ and Y₂ may each independently be a substituted or unsubstituted aryl group of 6 to 30 ring-forming carbon atoms, or a substituted or unsubstituted heteroaryl group of 2 to 30 ring-forming carbon atoms, or at least one of Y₁ and Y₂ may be combined with an adjacent group to form a substituted or unsubstituted aliphatic heterocycle of 2 to 30 ring-forming carbon atoms, or a substituted or unsubstituted aromatic heterocycle of 2 to 30 ring-forming carbon atoms; n and m may each independently be an integer from 1 to 4; R₁ to R₇ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring; a, c, d, and f may each independently be an integer from 0 to 5; b and e may each independently be an integer from 0 to 3; and g may be an integer from 0 to 2.

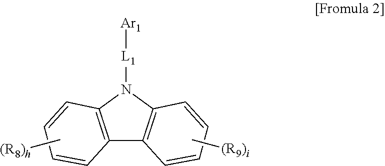

In Formula 2, L₁ may be a direct linkage, a substituted or unsubstituted arylene group of 6 to 30 ring-forming carbon atoms, or a substituted or unsubstituted heteroarylene group of 2 to 30 ring-forming carbon atoms; Ar₁ may be a substituted or unsubstituted aryl group of 6 to 30 ring-forming carbon atoms, or a substituted or unsubstituted heteroaryl group of 2 to 30 ring-forming carbon atoms; R₈ and R₉ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring; and h and i may each independently be an integer from 0 to 4.

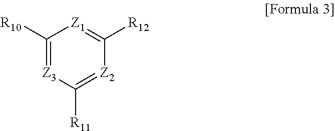

In Formula 3, at least one of Z₁ to Z₃ may each be N; the remainder of Z₁ to Z₃ may each independently be C(R₁₃); and R₁₀ to R₁₃ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, may be combined with an adjacent group to form a ring.

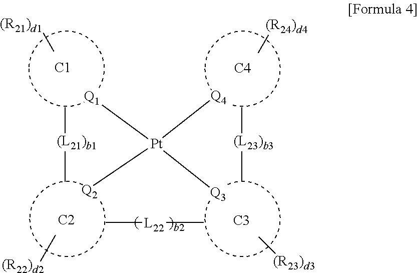

In Formula 4, Q₁ to Q₄ may each independently be C or N; C1 to C4 may each independently be a substituted or unsubstituted hydrocarbon ring of 5 to 30 ring-forming carbon atoms, or a substituted or unsubstituted heterocycle of 2 to 30 ring-forming carbon atoms; L₂₁ to L₂₃ may each independently be a direct linkage,

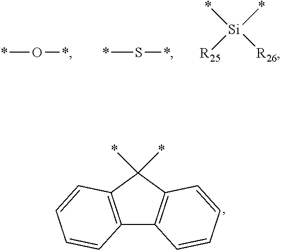

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms; b1 to b3 may each independently be 0 or 1; R₂₁ to R₂₆ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 1 to 30 ring-forming carbon atoms, or may be combined with an adjacent group to form a ring; and d1 to d4 may each independently be an integer from 0 to 4.

In an embodiment, the emission layer may emit delayed fluorescence.

In an embodiment, the emission layer may emit light having a central wavelength in a range of about 430 nm to about 470 nm.

In an embodiment, the emission layer may include the first compound, the second compound, and the third compound.

In an embodiment, the emission layer may include the first compound, the second compound, the third compound, and the fourth compound.

In an embodiment, the first compound represented by Formula 1 may be represented by Formula 1-1:

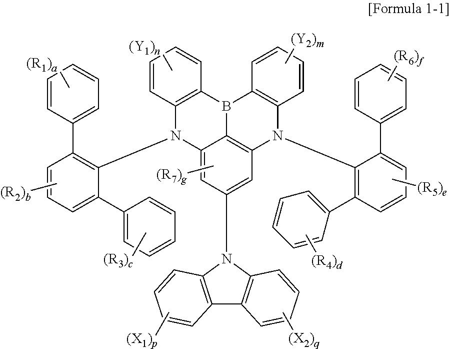

In Formula 1-1, X₁, X₂, Y₁, Y₂, R₁ to R₇, a to g, n, m, p, and q are each the same as defined in Formula 1.

In an embodiment, the first compound represented by Formula 1 may be represented by any one of Formula 1-2-1 to Formula 1-2-7:

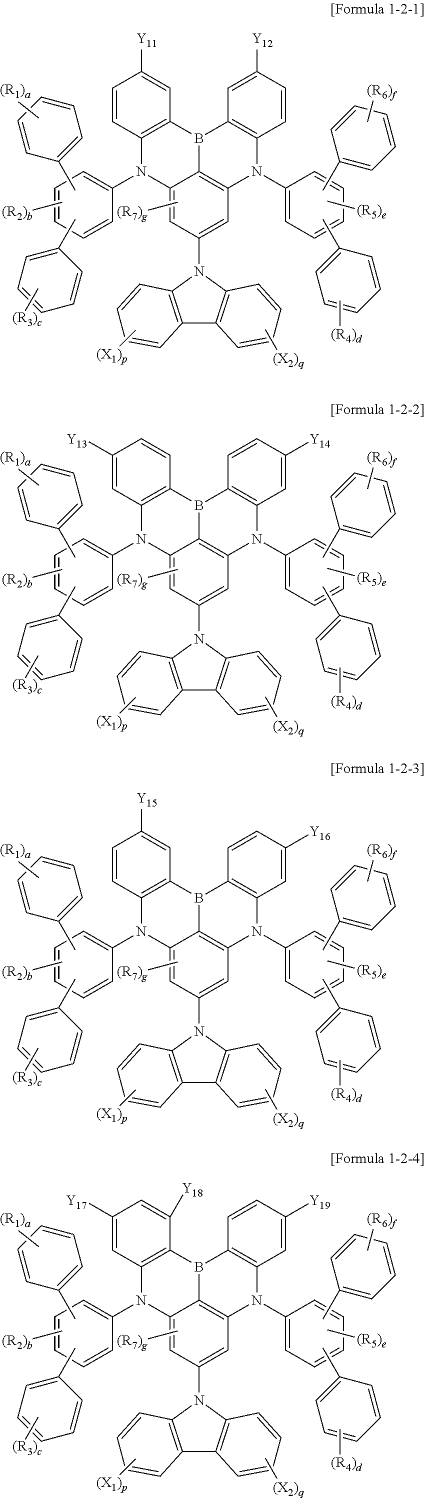

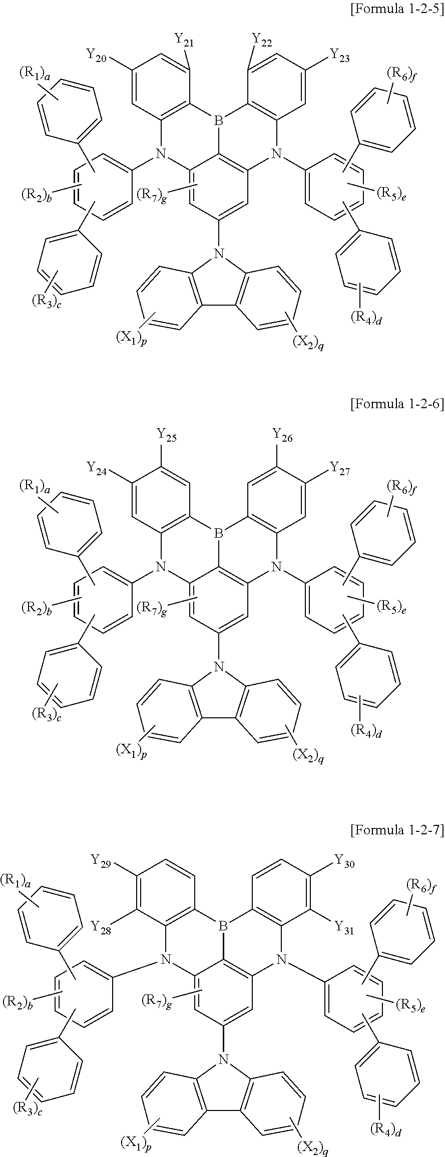

In Formula 1-2-1 to Formula 1-2-7, Y₁₁ to Y₃₁ may each independently be a deuterium atom, a substituted or unsubstituted amine group, a substituted or unsubstituted oxy group, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring, wherein for Y₁₁ to Y₃₁, at least one of Y₁₁ and Y₁₂, at least one of Y₁₃ and Y₁₄, at least one of Y₁₅ and Y₁₆, at least one of Y₁₇ and Y₁₈, at least one of Y₂₀ and Y₂₁, and at least one of Y₂₂ and Y₂₃ may each independently be a substituted or unsubstituted aryl group of 6 to 30 ring-forming carbon atoms, or a substituted or unsubstituted heteroaryl group of 2 to 30 ring-forming carbon atoms, at least one of Y₂₄ and Y₂₅, or Y₂₆ and Y₂₇ may be combined with each other to form a ring, and at least one of Y₂₈ and Y₂₉, or Y₃₀ and Y₃₁ may be combined with each other to form a ring; and X₁, X₂, R₁ to R₇, a to g, p, and q are each the same as defined in Formula 1.

In an embodiment, in Formula 1, Y₁ and Y₂ may each independently be a hydrogen atom, a substituted or unsubstituted t-butyl group, a substituted or unsubstituted diphenyl amine group, a substituted or unsubstituted phenyl group, a substituted or unsubstituted biphenyl group, a substituted or unsubstituted terphenyl group, a substituted or unsubstituted naphthyl group, a substituted or unsubstituted carbazole group, a substituted or unsubstituted pyridine group, or may be combined with an adjacent group to form a ring.

In an embodiment, in Formula 1, Y₁ and Y₂ may each independently include at least one substituent selected from Substituent Group S1:

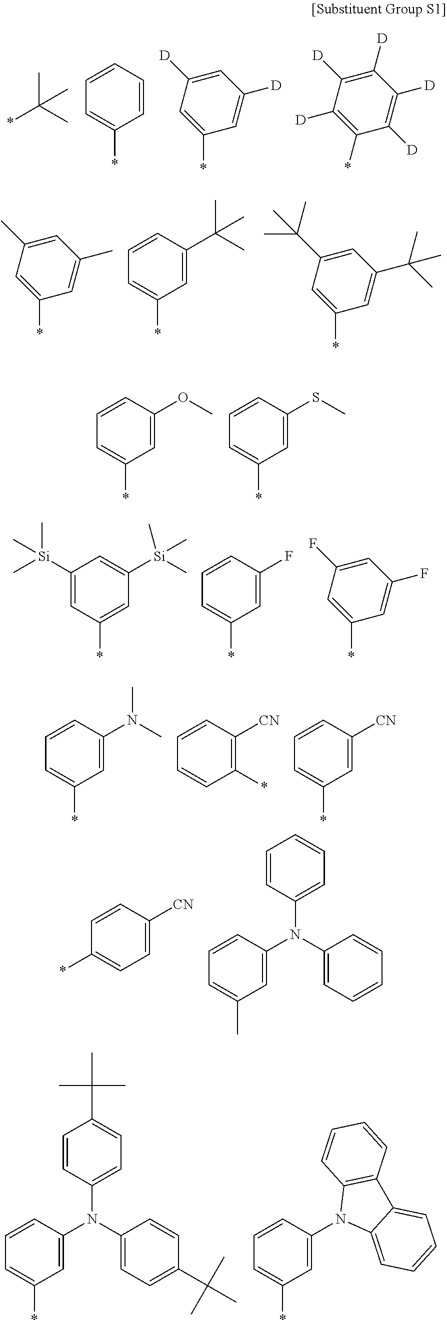

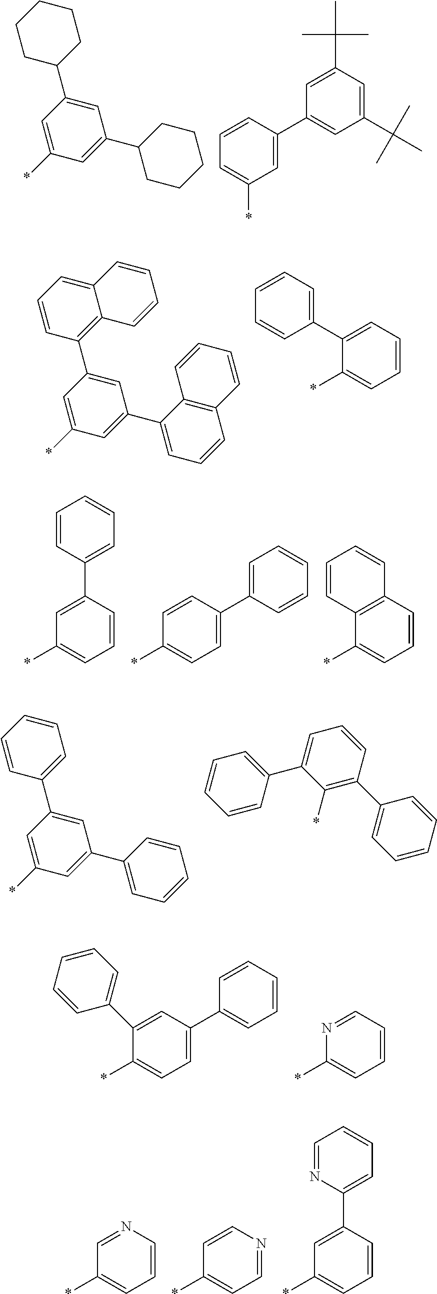

In an embodiment, in Formula 1, a case of forming a ring via a combination of two adjacent Y₁ groups and a case of forming a ring via a combination of two adjacent Y₂ groups may each include at least one substituent selected from Substituent Group S2.

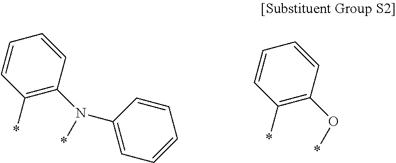 [SMILES: *c1ccccc1N(*)c1ccccc1 ; *Oc1ccccc1*]

In an embodiment, in Formula 1, X₁ and X₂ may be different from each other.

In an embodiment, in Formula 1, X₁ and X₂ may be the same.

In an embodiment, the first compound represented by Formula 1 may be represented by Formula 1-3:

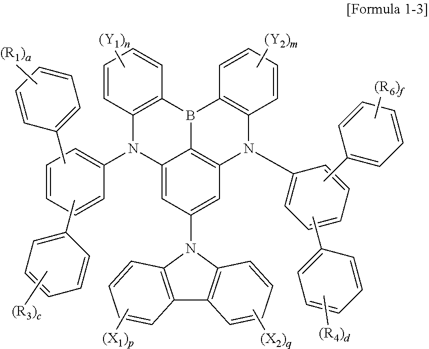

In Formula 1-3, X₁, X₂, R₁, R₃, R₄, R₆, Y₁, Y₂, a, c, d, f, n, m, p, and q are each the same as defined in Formula 1.

In an embodiment, in Formula 1, R₁, R₃, R₄, and R₆ may each independently be a hydrogen atom, a deuterium atom, a fluorine atom, a cyano group, a trimethylsilyl group, a methyl group, an isopropyl group, a cumenyl group, a t-butyl group, a cyclopentyl group, a methoxy group, a phenoxy group, or may be combined with an adjacent group to form a ring.

In an embodiment, the first compound represented by Formula 1 may include at least one compound selected from Compound Group 1, which is explained below.

Embodiments provide a light emitting device which may include a first electrode, a hole transport region disposed on the first electrode, an emission layer disposed on the hole transport region, an electron transport region disposed on the emission layer, and a second electrode disposed on the electron transport region, wherein the emission layer may include a first compound represented by Formula 1, a second compound represented by Formula 2, and a third compound represented by Formula 3:

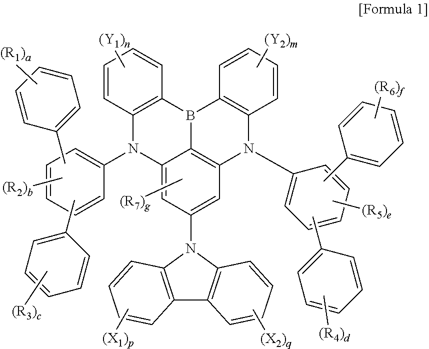

In Formula 1, X₁ and X₂ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring; p and q may each independently be an integer from 0 to 4; Y₁ and Y₂ may each independently be a hydrogen atom, a deuterium atom, a substituted or unsubstituted amine group, a substituted or unsubstituted alkyl group of 1 to 20 carbon atoms, a substituted or unsubstituted oxy group, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring, wherein for Y₁ and Y₂, at least one of Y₁ and Y₂ may be a substituted or unsubstituted aryl group of 6 to 30 ring-forming carbon atoms, or a substituted or unsubstituted heteroaryl group of 2 to 30 ring-forming carbon atoms, or at least one of Y₁ and Y₂ may be combined with an adjacent group to form a substituted or unsubstituted aliphatic heterocycle of 2 to 30 ring-forming carbon atoms, or a substituted or unsubstituted aromatic heterocycle of 2 to 30 ring-forming carbon atoms; n and m may each independently be an integer from 1 to 4; R₁ to R₇ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring; a, c, d, and f may each independently be an integer from 0 to 5; b and e may each independently be an integer from 0 to 3; and g may be an integer from 0 to 2.

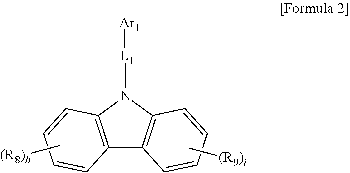

In Formula 2, L₁ may be a direct linkage, a substituted or unsubstituted arylene group of 6 to 30 ring-forming carbon atoms, or a substituted or unsubstituted heteroarylene group of 2 to 30 ring-forming carbon atoms; Ar₁ may be a substituted or unsubstituted aryl group of 6 to 30 ring-forming carbon atoms, or a substituted or unsubstituted heteroaryl group of 2 to 30 ring-forming carbon atoms; R₈ and R₉ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring; and h and i may each independently be an integer from 0 to 4.

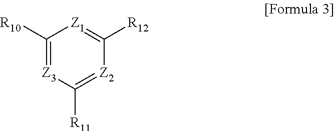

In Formula 3, at least one of Z₁ to Z₃ may each be N; the remainder of Z₁ to Z₃ may each independently be C(R₁₃); and R₁₀ to R₁₃ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring.

In an embodiment, the first compound represented by Formula 1 may be represented by Formula 1-1, which is explained herein.

In an embodiment, the first compound represented by Formula 1 may be represented by any one of Formula 1-2-1 to Formula 1-2-7, which are explained herein.

In an embodiment, the first compound represented by Formula 1 may be represented by Formula 1-3, which is explained herein.

In an embodiment, the first compound represented by Formula 1 may include at least one compound selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a plan view showing a display apparatus according to an embodiment;

FIG. 2 is a schematic cross-sectional view of a display apparatus according to an embodiment;

FIG. 3 is a schematic cross-sectional view of a light emitting device according to an embodiment;

FIG. 4 is a schematic cross-sectional view of a light emitting device according to an embodiment;

FIG. 5 is a schematic cross-sectional view of a light emitting device according to an embodiment;

FIG. 6 is a schematic cross-sectional view of a light emitting device according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view of a display apparatus according to an embodiment; and

FIG. 10 is a schematic cross-sectional view of a display apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thiol group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “combined with an adjacent group to form a ring” may be interpreted as a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed be the combination of adjacent groups may itself be combined with another ring to form a spiro structure.

In the specification, the term “adjacent group” may be interpreted as a substituent that is substituted for an atom which is directly combined with an atom substituted with a corresponding substituent, as another substituent substituted for an atom which is substituted with a corresponding substituent, or as a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. For example, in 4,5-dimethylphenanthrene, two methyl groups may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., without limitation.

In the specification, an alkyl group may be an aryl alkyl group. An aryl alkyl group may be the above-defined alkyl group combined with an aryl group. Examples of an aryl alkyl group may include a toluyl group, a chrysinyl group, a cumenyl group, a mesityl group, a benzyl group, a phenethyl group, a styryl group, etc., without limitation.

In the specification, an alkenyl group may be a hydrocarbon group including one or more carbon-carbon double bonds in the middle or at a terminus of an alkyl group having 2 or more carbon atoms. The alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styrylvinyl group, etc., without limitation.

In the specification, a hydrocarbon ring group may be any functional group or substituent derived from an aliphatic hydrocarbon ring. for example, a hydrocarbon ring group may be a saturated hydrocarbon ring group of 5 to 20 ring-forming carbon atoms.

In the specification, an aryl group may be any functional group or substituent derived from an aromatic hydrocarbon ring. The aryl group may be monocyclic or polycyclic. The number of ring-forming carbon atoms in an aryl group may be 6 to 30, 6 to 20, or 6 to 15. Examples of an aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the specification, a fluorenyl group may be substituted, and two substituents may be combined with each other to form a spiro structure. Examples of substituted fluorenyl groups are as follows, but embodiments are not limited thereto.

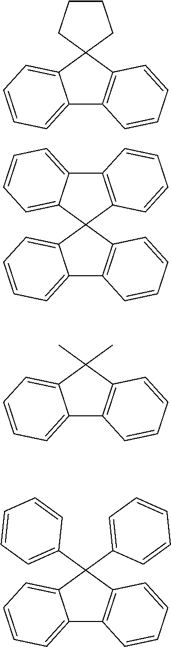

In the specification, a heterocyclic group may be any functional group or substituent derived from a ring including one or more of B, O, N, P, Si, or S as a heteroatom. The heterocyclic group may be an aliphatic heterocyclic group or an aromatic heterocyclic group. An aromatic heterocyclic group may be a heteroaryl group. The aliphatic heterocyclic group and the aromatic heterocyclic group may each independently be monocyclic or polycyclic.

In the specification, a heterocyclic group may include one or more or B, O, N, P, Si, or S as a heteroatom. If the heterocyclic group includes two or more heteroatoms, the two or more heteroatoms may be the same as or different from each other. The heterocyclic group may be monocyclic or polycyclic, and a heterocyclic group may be a heteroaryl group. The number of ring-forming carbon atoms in a heterocyclic group may be 2 to 30, 2 to 20, or 2 to 10.

In the specification, an aliphatic heterocyclic group may include one or more of B, O, N, P, Si, or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the specification, a heteroaryl group may include one or more of B, O, N, P, Si, or S as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include thiophene, furan, pyrrole, imidazole, pyridine, bipyridine, pyridine, triazine, triazole, acridyl, pyridazine, pyrazinyl, quinoline, quinazoline, quinoxaline, phenoxazine, phthalazine, pyrido pyridine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the specification, the above description of the aryl group may be applied to an arylene group, except that the arylene group is a divalent group. The above description of the heteroaryl group may be applied to a heteroarylene group, except that the heteroarylene group is a divalent group.

In the specification, a silyl group may be an alkyl silyl group or an aryl silyl group. Examples of a silyl group may include a trimethylsilyl group, a triethylsilyl group, a t-butyldimethylsilyl group, a triisopropylsilyl group, a vinyldimethylsilyl group, a propyldimethylsilyl group, a triphenylsilyl group, a diphenylsilyl group, a phenylsilyl group, etc., without limitation.

In the specification, a thiol group may be an alkyl thiol group or an aryl thiol group. A thiol group may be a sulfur atom that is bonded to an alkyl group or to an aryl group as defined above. Examples of a thiol group may include a methylthiol group, an ethylthiol group, a propylthiol group, a pentylthiol group, a hexylthiol group, an octylthiol group, a dodecylthiol group, a cyclopentylthiol group, a cyclohexylthiol group, a phenylthiol group, a naphthylthiol group, etc., without limitation.

In the specification, an oxy group may be an oxygen atom that is bonded to an alkyl group or an aryl group as defined above. An oxy group may be an alkoxy group or an aryl oxy group. The alkoxy group may be linear, branched, or cyclic. The number of carbon atoms in an alkoxy group is not specifically limited but may be, for example, 1 to 20 or 1 to 10. The number of carbon atoms in an aryl oxy group is not specifically limited but the number of ring-forming carbon atoms may be, for example, 6 to 30, 6 to 20, or 6 to 15. Examples of an oxy group may include methoxy, ethoxy, n-propoxy, isopropoxy, butoxy, pentyloxy, hexyloxy, octyloxy, nonyloxy, decyloxy, phenoxy, benzyloxy, etc. However, embodiments are not limited thereto.

In the specification, a boron group may be a boron atom that is bonded to an alkyl group or an aryl group as defined above. A boron group may be an alkyl boron group or an aryl boron group. Examples of a boron group may include a trimethylboron group, a triethylboron group, a t-butyldimethylboron group, a triphenylboron group, a diphenylboron group, a phenylboron group, etc., without limitation.

In the specification, the number of carbon atoms in an amine group is not specifically limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., without limitation.

In the specification, alkyl groups in an alkylthiol group, an alkylsulfoxy group, an alkylaryl group, an alkylamino group, an alkyl boron group, an alkyl silyl group, or an alkyl amine group may be the same as the examples of the above-described alkyl group.

In the specification, aryl groups in an aryloxy group, an arylthiol group, an arylsulfoxy group, an arylamino group, an aryl boron group, an aryl silyl group, an aryl amine group, and an aryl alkyl group may be the same as the examples of the above-described aryl group.

In the specification, a direct linkage may be a single bond.

In the specification, the symbols

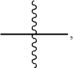

or [symbol] each represent a bonding site to a neighboring atom.

Hereinafter, embodiments will be explained with reference to the drawings.

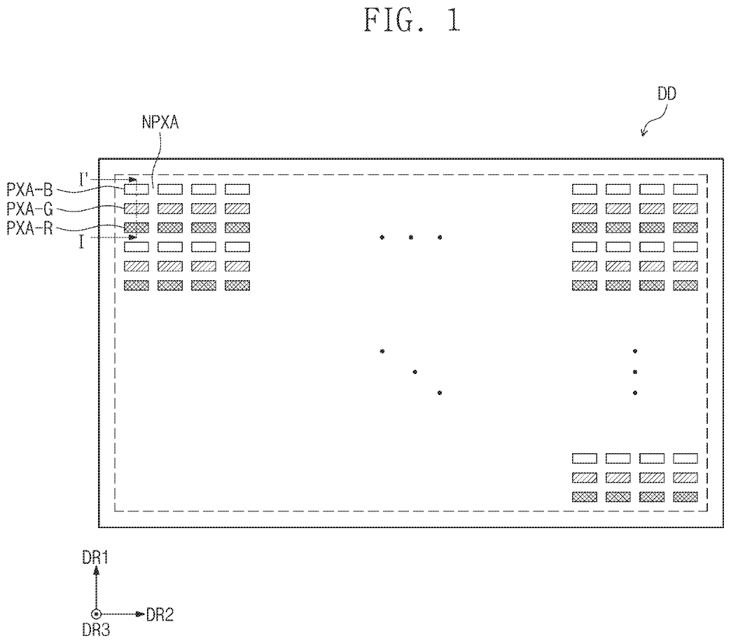

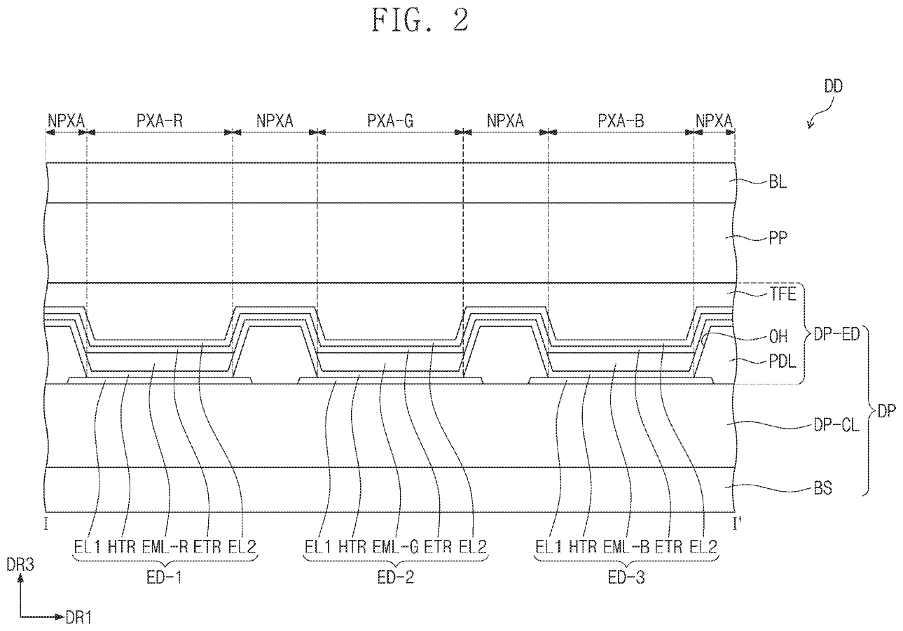

FIG. 1 is a plan view showing an embodiment of a display apparatus DD. FIG. 2 is a schematic cross-sectional view of a display apparatus DD according to an embodiment. FIG. 2 is a schematic cross-sectional view showing a part corresponding to line I-I′ in FIG. 1.

The display apparatus DD may include a display panel DP and an optical layer PP disposed on the display panel DP. The display panel DP includes light emitting devices ED-1, ED-2, and ED-3. The display apparatus DD may include multiples of each of the light emitting devices ED-1, ED-2, and ED-3. The optical layer PP may be disposed on the display panel DP and may control light that is reflected the display panel DP from an external light. The optical layer PP may include, for example, a polarization layer or a color filter layer. Although not shown in the drawings, in an embodiment, the optical layer PP may be omitted from the display apparatus DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a plugging layer (not shown). The plugging layer (not shown) may be disposed between a display device layer DP-ED and a base substrate BL. The plugging layer (not shown) may be an organic layer. The plugging layer (not shown) may include at least one of an acrylic resin, a silicon-based resin, or an epoxy-based resin.

The display panel DP may include a base layer BS, a circuit layer DP-CL provided on the base layer BS, and a display device layer DP-ED. The display device layer DP-ED may include a pixel definition layer PDL, light emitting devices ED-1, ED-2, and ED-3 disposed between portions of the pixel definition layer PDL, and an encapsulating layer TFE disposed on the light emitting devices ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). Each of the transistors (not shown) may include a control electrode, an input electrode, and an output electrode. For example, the circuit layer DP-CL may include switching transistors and driving transistors for driving the light emitting devices ED-1, ED-2, and ED-3 of the display device layer DP-ED.

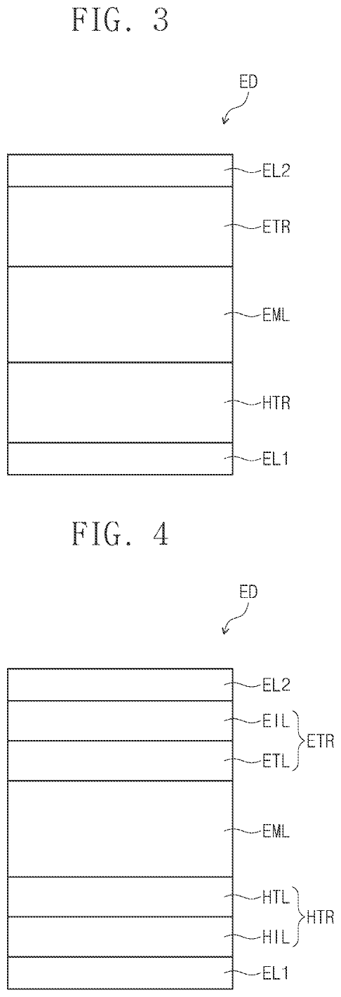

The light emitting devices ED-1, ED-2, and ED-3 may each have a structure of a light emitting device ED of an embodiment according to any of FIG. 3 to FIG. 6, which will be explained later. The light emitting devices ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment where the emission layers EML-R, EML-G, and EML-B of light emitting devices ED-1, ED-2, and ED-3 are disposed in openings OH defined in the pixel definition layer PDL, and a hole transport region HTR, an electron transport region ETR, and a second electrode EL2 are each provided as a common layer for all of the light emitting devices ED-1, ED-2, and ED-3. However, embodiments are not limited thereto. Although not shown in FIG. 2, in an embodiment, the hole transport region HTR and the electron transport region ETR may each be patterned and provided in the openings OH defined in the pixel definition layer PDL. For example, in an embodiment, the hole transport region HTR, the emission layers EML-R, EML-G, and EML-B, and the electron transport region ETR of the light emitting devices ED-1, ED-2, and ED-3 may each be patterned by an ink jet printing method and provided.

An encapsulating layer TFE may cover the light emitting devices ED-1, ED-2, and ED-3. The encapsulating layer TFE may seal the light emitting devices ED-1, ED-2, and ED-3. The encapsulating layer TFE may be a thin film encapsulating layer. The encapsulating layer TFE may be a single layer or multiple layers. The encapsulating layer TFE may include at least one insulating layer. The encapsulating layer TFE according to an embodiment may include at least one inorganic layer (hereinafter, an encapsulating inorganic layer). The encapsulating layer TFE according to an embodiment may include at least one organic layer (hereinafter, an encapsulating organic layer) and at least one encapsulating inorganic layer.

The encapsulating inorganic layer may protect the display device layer DP-ED from moisture and/or oxygen, and the encapsulating organic layer may protect the display device layer DP-ED from foreign materials such as dust particles. The encapsulating inorganic layer may include silicon nitride, silicon oxy nitride, silicon oxide, titanium oxide, or aluminum oxide, without limitation. The encapsulating organic layer may include an acrylic compound, an epoxy-based compound, etc. The encapsulating organic layer may include a photopolymerizable organic material, without limitation.

The encapsulating layer TFE may be disposed on the second electrode EL2 and may be disposed to fill the openings OH.

Referring to FIG. 1 and FIG. 2, the display apparatus DD may include a non-luminous area NPXA and luminous areas PXA-R, PXA-G, and PXA-B. The luminous areas PXA-R, PXA-G, and PXA-B may each be an area emitting light produced from the light emitting devices ED-1, ED-2, and ED-3, respectively. The luminous areas PXA-R, PXA-G, and PXA-B may be separated from each other in a plan view.

The luminous areas PXA-R, PXA-G, and PXA-B may be areas separated by the pixel definition layer PDL. The non-luminous areas NPXA may be areas between neighboring luminous areas PXA-R, PXA-G, and PXA-B and may be areas corresponding to the pixel definition layer PDL. For example, in an embodiment, the luminous areas PXA-R, PXA-G, and PXA-B may each respectively correspond to a pixel. The pixel definition layer PDL may separate the light emitting devices ED-1, ED-2, and ED-3. The emission layers EML-R, EML-G, and EML-B of the light emitting devices ED-1, ED-2, and ED-3 may be disposed in the openings OH defined in the pixel definition layer PDL and separated from each other.

The luminous areas PXA-R, PXA-G, and PXA-B may be arranged into groups according to the color of light produced from the light emitting devices ED-1, ED-2, and ED-3. In the display apparatus DD according to an embodiment shown in FIG. 1 and FIG. 2, three luminous areas PXA-R, PXA-G, and PXA-B which respectively emit red light, green light and blue light are illustrated as an example. For example, the display apparatus DD may include a red luminous area PXA-R, a green luminous area PXA-G, and a blue luminous area PXA-B, which are separated from each other.

In the display apparatus DD according to an embodiment, the light emitting devices ED-1, ED-2, and ED-3 may emit light having wavelength regions that are different from each other. For example, in an embodiment, the display apparatus DD may include a first light emitting device ED-1 emitting red light, a second light emitting device ED-2 emitting green light, and a third light emitting device ED-3 emitting blue light. For example, each of the red luminous area PXA-R, the green luminous area PXA-G, and the blue luminous area PXA-B of the display apparatus DD may respectively correspond to the first light emitting device ED-1, the second light emitting device ED-2, and the third light emitting device ED-3.

However, embodiments are not limited thereto, and the first to third light emitting devices ED-1, ED-2 and ED-3 may emit light in a same wavelength region, or at least one thereof may emit light in a different wavelength region. For example, the first to third light emitting devices ED-1, ED-2 and ED-3 may all emit blue light.

The luminous areas PXA-R, PXA-G, and PXA-B in the display apparatus DD according to an embodiment may be arranged in a stripe configuration. Referring to FIG. 1, the red luminous areas PXA-R, the green luminous areas PXA-G, and the blue luminous areas PXA-B may be arranged along a second direction DR2. In another embodiment, the red luminous area PXA-R, the green luminous area PXA-G, and the blue luminous area PXA-B may be arranged by turns along a first direction DR1.

In FIG. 1 and FIG. 2, the luminous areas PXA-R, PXA-G, and PXA-B are shown as having a similar area to each other, but embodiments are not limited thereto. The areas of the luminous areas PXA-R, PXA-G and PXA-B may be different from each other according to a wavelength region of emitted light. For example, the areas of the luminous areas PXA-R, PXA-G and PXA-B may be areas in a plan view that are defined by the first direction DR1 and the second direction DR2.

An arrangement configuration of the luminous areas PXA-R, PXA-G, and PXA-B is not limited to the configuration shown in FIG. 1, and the arrangement order of the red luminous areas PXA-R, the green luminous areas PXA-G, and the blue luminous areas PXA-B may be provided in various combinations according to the display quality characteristics which are required for the display apparatus DD. For example, the luminous areas PXA-R, PXA-G, and PXA-B may be arranged in a pentile configuration (such as a PENTILE™ configuration), or in a diamond configuration (such as a Diamond Pixel™ configuration).

In, the areas of the luminous areas PXA-R, PXA-G and PXA-B may be different from each other. For example, in an embodiment, the area of the green luminous area PXA-G may be smaller than the area of the blue luminous area PXA-B, but embodiments are not limited thereto.

Hereinafter, FIG. 3 to FIG. 6 are each a schematic cross-sectional view showing a light emitting device according to an embodiment.

Referring to FIG. 3, a light emitting device ED according to an embodiment may include a first electrode EL1, a hole transport region HTR, an emission layer EML, an electron transport region ETR, and a second electrode EL2, stacked in that order.

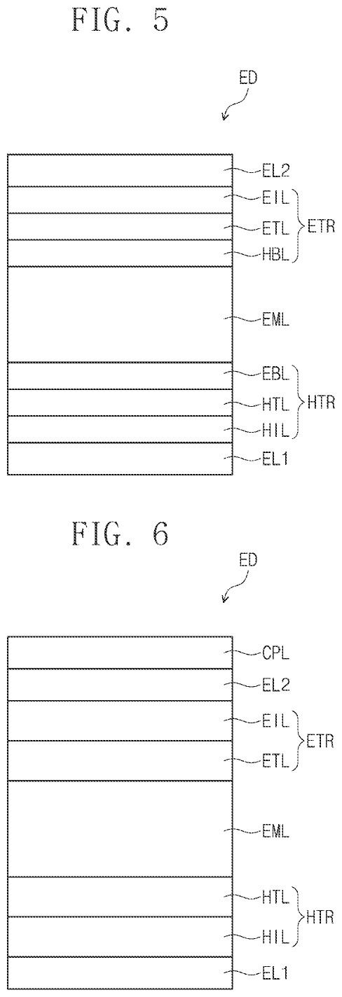

In comparison to FIG. 3, FIG. 4 shows a schematic cross-sectional view of a light emitting device ED, wherein a hole transport region HTR includes a hole injection layer HIL and a hole transport layer HTL, and an electron transport region ETR includes an electron injection layer EIL and an electron transport layer ETL. In comparison to FIG. 3, FIG. 5 shows a schematic cross-sectional view of a light emitting device ED, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 shows a schematic cross-sectional view of a light emitting device ED that includes a capping layer CPL disposed on the second electrode EL2.

In the light emitting device ED, the first electrode EL1 has conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, a compound thereof, or a mixture thereof (for example, a mixture of Ag and Mg). In another embodiment, the first electrode EL1 may have a structure including multiple layers, including a reflective layer or a transflective layer formed of the above materials, and a transmissive conductive layer formed of ITO, IZO, ZnO, or ITZO. For example, the first electrode EL1 may have a three-layer structure of ITO/Ag/ITO. However, embodiments are not limited thereto. The first electrode EL1 may include the above-described metal materials, combinations of two or more metal materials selected from the above-described metal materials, or oxides of the above-described metal materials. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may be a layer formed of a single material, a layer formed of different materials, or a structure including multiple layers formed of different materials.

The hole transport region HTR may include at least one of a hole injection layer HIL, a hole transport layer HTL, a buffer layer (not shown), an emission auxiliary layer (not shown), or an electron blocking layer EBL.

For example, the hole transport region HTR may have a single layer structure of a hole injection layer HIL or a hole transport layer HTL, or may have a single layer structure formed of a hole injection material and a hole transport material. In other embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

A thickness of the hole transport region HTR may be, for example, in a range of about 50 Å to about 15,000 Å.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1:

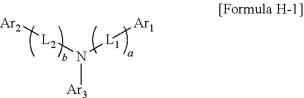

In Formula H-1, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. In Formula H-1, a and b may each independently be an integer from 0 to 10. If a or b is 2 or more, multiple L₁ groups or multiple L₂ groups may each independently be a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. In Formula H-1, Ar₃ may be a substituted or unsubstituted aryl group of 6 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Arₙ includes an amine group as a substituent. In still other embodiments, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H.

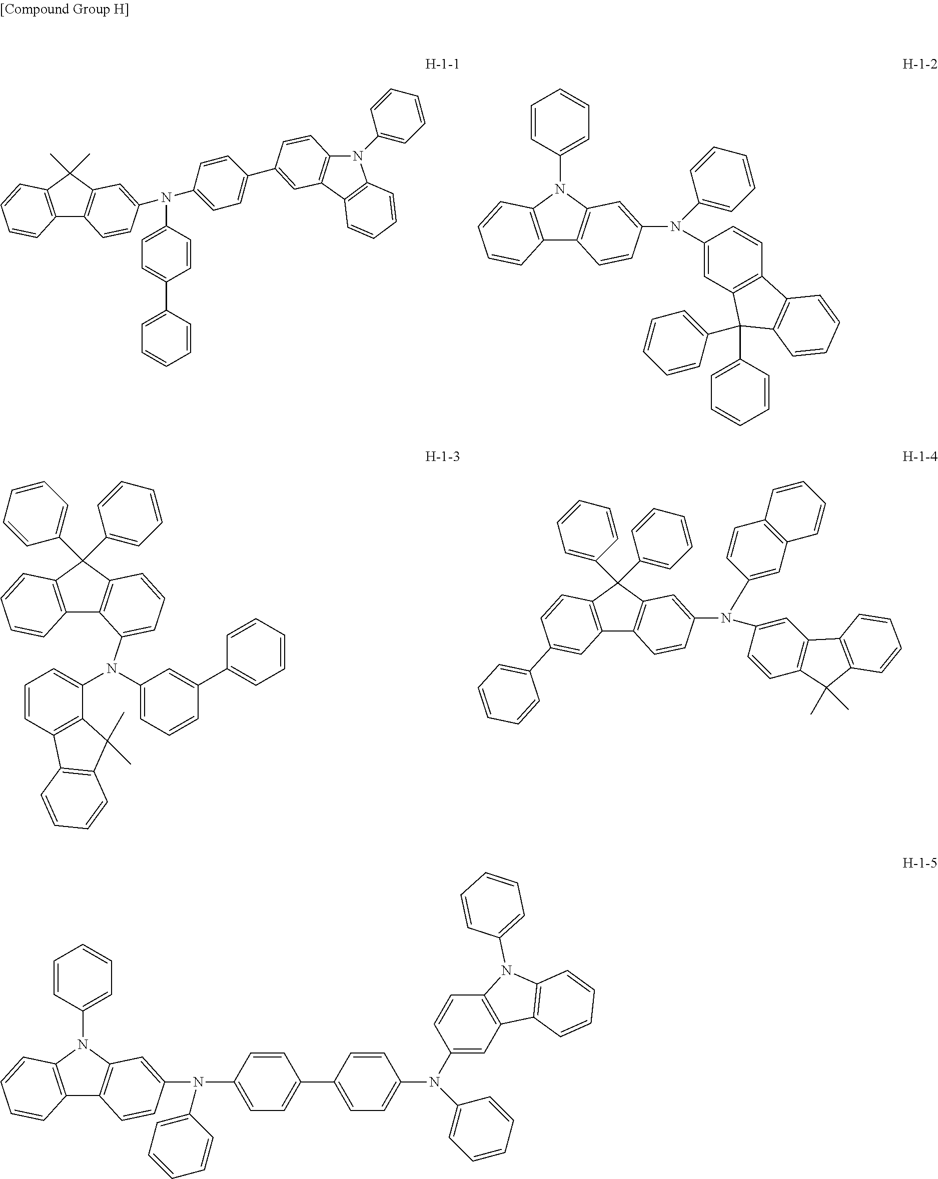 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

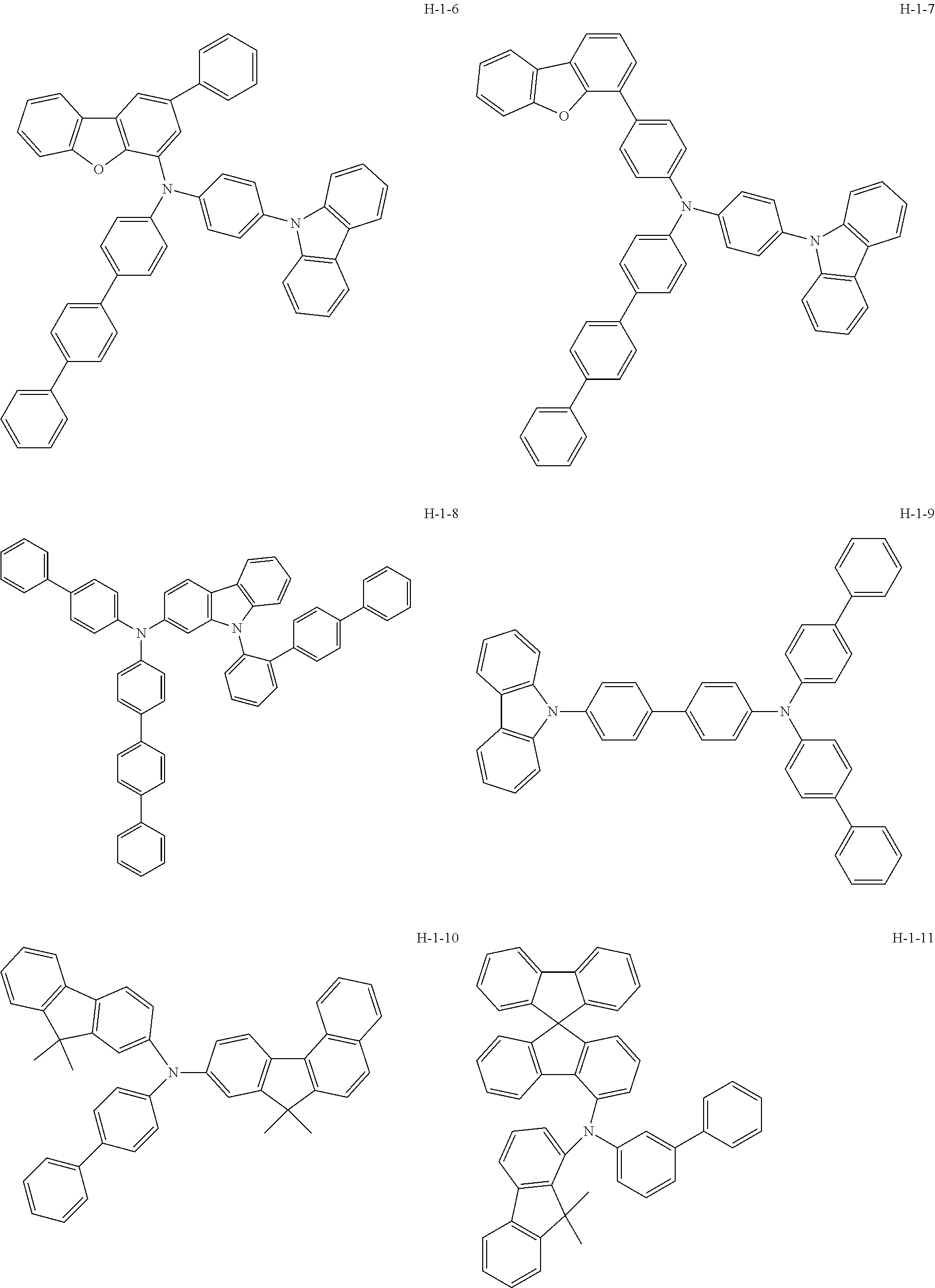

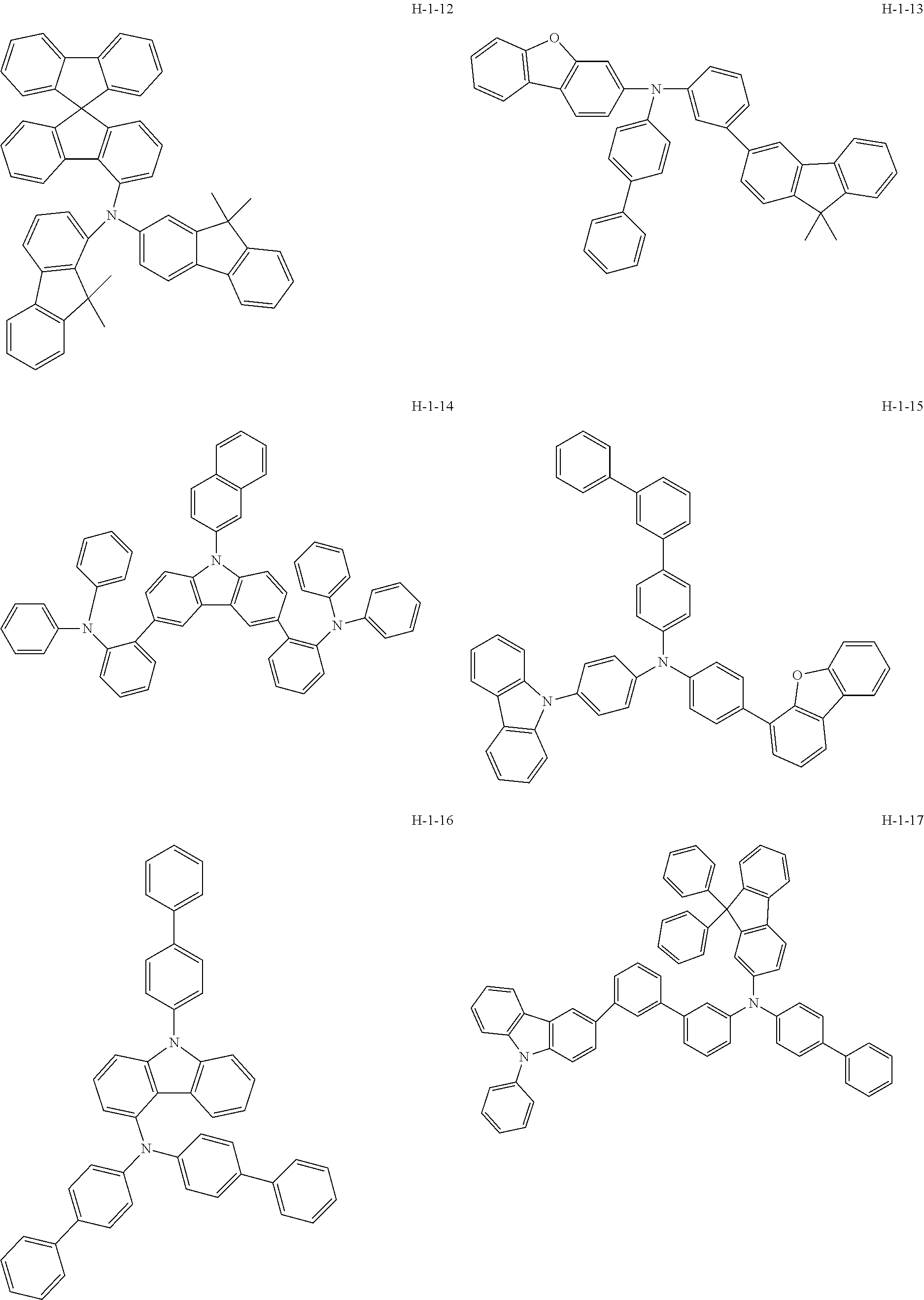

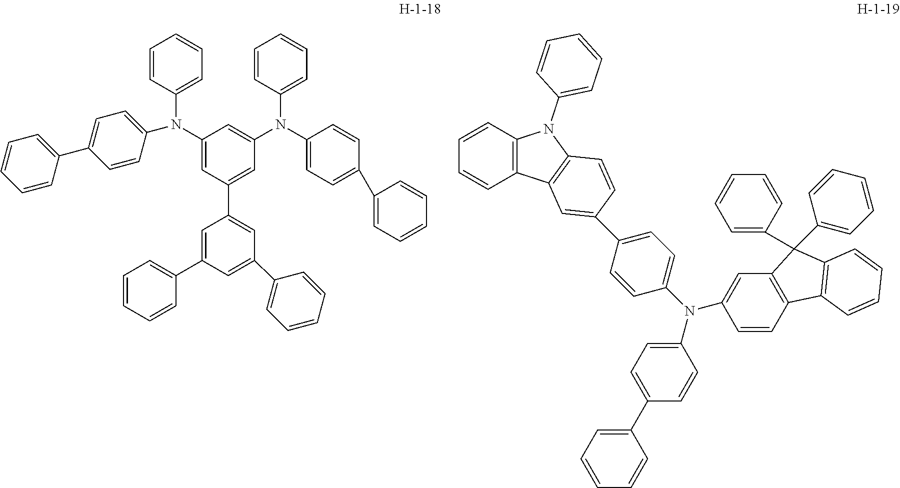

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrene sulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and dipyrazino[2,3-f:2′,3′-h] quinoxaline-2,3,6,7,10,11-hexacarbonitrile (HAT-CN).

The hole transport region HTR may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å.

If the hole transport region HTR includes a hole injection layer HIL, a thickness of the hole injection region HIL may be, for example, in a range of about 30 Å to about 1,000 Å.

If the hole transport region HTR includes a hole transport layer HTL, a thickness of the hole transport layer HTL may be in a range of about 30 Å to about 1,000 Å. If the hole transport region HTR includes an electron blocking layer, a thickness of the electron blocking layer EBL may be in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase of driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of metal halide compounds, quinone derivatives, metal oxides, and cyano group-containing compounds, without limitation. For example, the p-dopant may include metal halide compounds such as CuI and RbI, quinone derivatives such as tetracyanoquinodimethane (TCNQ) and 2,3,5,6-tetrafluoro-7,7′,8,8-tetracyanoquinodimethane (F4-TCNQ), metal oxides such as tungsten oxide and molybdenum oxide, cyano group-containing compounds such as dipyrazino[2,3-f: 2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one of a buffer layer (not shown) or an electron blocking layer EBL, in addition to the hole injection layer HIL and the hole transport layer HTL. The buffer layer (not shown) may compensate for a resonance distance according to a wavelength of light emitted from an emission layer EML and may increase emission efficiency. Materials which may be included in the hole transport region HTR may be included in the buffer layer (not shown). The electron blocking layer EBL may block the injection of electrons from an electron transport region ETR to a hole transport region HTR.

The emission layer EML is provided on the hole transport region HTR. The emission layer EML may have a thickness, for example, in a range of about 100 Å to about 1,000 Å. For example, the emission layer EML may have a thickness in a range of about 100 Å to about 300 Å. The emission layer EML may be a layer formed of a single material, a layer formed of different materials, or a structure having multiple layers formed of different materials.

In the light emitting device ED according to an embodiment, the emission layer EML may include multiple light emitting materials. In the light emitting device ED according to an embodiment, the emission layer EML may include: a first compound; and at least one of a second compound, a third compound, a fourth compound. In the light emitting device ED according to an embodiment, the emission layer EML may include at least one host and at least one dopant. For example, the emission layer EML may include a first dopant, and a first host and a second host, which are different from each other, as the hosts. The emission layer EML may include a first host and a second host that are different from each other, and a first dopant and a second dopant that are different from each other.

In the emission layer EML of the light emitting device ED according to an embodiment, the first compound may be represented by Formula 1:

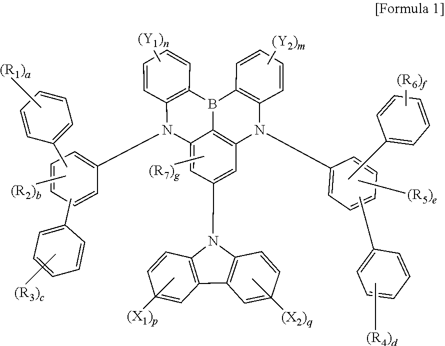

In Formula 1, X₁ and X₂ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring.

In an embodiment, in Formula 1, X₁ and X₂ may each independently be a hydrogen atom, a deuterium atom, a fluorine atom, a cyano group, a trimethylsilyl group, a triisopropylsilyl group, a triphenylsilyl group, a methylthiol group, a methoxy group, a substituted or unsubstituted diphenylamine group, an unsubstituted methyl group, a deuterium-substituted methyl group, a substituted or unsubstituted isopropyl group, a substituted or unsubstituted t-butyl group, a cyclopentyl group, an unsubstituted phenyl group, a substituted or unsubstituted carbazole group, or may be combined with an adjacent group to form a ring. For example, X₁ and X₂ may each independently be combined with an adjacent group to form a benzene ring.

In an embodiment, in Formula 1, X₁ and X₂ may be different from each other. In another embodiment, in Formula 1, X₁ and X₂ may be the same.

In Formula 1, p and q may each independently be an integer from 0 to 4. For example, p and q may each independently be 0, 1, 2, or 4. A case where p is 0 may be the same as a case where p is 1 and X₁ is a hydrogen atom. A case where q is 0 may be the same as a case where q is 1 and X₂ is a hydrogen atom.

If p is 2 or more, multiple X₁ groups may be the same, or at least one may be different from the remainder. If q is 2 or more, multiple X₂ groups may be the same, or at least one may be different from the remainder.

In Formula 1, Y₁ and Y₂ may each independently be a hydrogen atom, a deuterium atom, a substituted or unsubstituted amine group, a substituted or unsubstituted alkyl group of 1 to 20 carbon atoms, a substituted or unsubstituted oxy group, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring. For Y₁ and Y₂, at least one of Y₁ and Y₂ may each independently be a substituted or unsubstituted aryl group of 6 to 30 ring-forming carbon atoms, or a substituted or unsubstituted heteroaryl group of 2 to 30 ring-forming carbon atoms; or at least one of Y₁ and Y₂ may be combined with an adjacent group to form a substituted or unsubstituted aliphatic heterocycle of 2 to 30 ring-forming carbon atoms, or a substituted or unsubstituted aromatic heterocycle of 2 to 30 ring-forming carbon atoms.

In an embodiment, in Formula 1, Y₁ and Y₂ may each independently be a hydrogen atom, a substituted or unsubstituted t-butyl group, a substituted or unsubstituted diphenyl amine group, a substituted or unsubstituted phenyl group, a substituted or unsubstituted biphenyl group, a substituted or unsubstituted terphenyl group, a substituted or unsubstituted naphthyl group, a substituted or unsubstituted carbazole group, a substituted or unsubstituted pyridine group, or may be combined with an adjacent group to form a ring, wherein for Y₁ and Y₂: at least one of Y₁ and Y₂ may be a substituted or unsubstituted aryl group of 6 to 30 ring-forming carbon atoms, or a substituted or unsubstituted heteroaryl group of 2 to 30 ring-forming carbon atoms; or at least one of Y₁ and Y₂ may be combined with an adjacent group to form a substituted or unsubstituted aliphatic heterocycle of 2 to 30 ring-forming carbon atoms, or a substituted or unsubstituted aromatic heterocycle of 2 to 30 ring-forming carbon atoms. For example, any one of Y₁ and Y₂ may be a substituted or unsubstituted aryl group of 6 to 30 ring-forming carbon atoms, or a substituted or unsubstituted heteroaryl group of 2 to 30 ring-forming carbon atoms, and the other of Y₁ and Y₂ may be a hydrogen atom, a deuterium atom, or a substituted or unsubstituted alkyl group of 1 to 20 carbon atoms. As another example, Y₁ and Y₂ may each independently be a substituted or unsubstituted aryl group of 6 to 30 ring-forming carbon atoms, or a substituted or unsubstituted heteroaryl group of 2 to 30 ring-forming carbon atoms. As yet another example, at least one of Y₁ and Y₂ may be combined with an adjacent group to form a substituted or unsubstituted aliphatic heterocycle of 2 to 30 ring-forming carbon atoms, or a substituted or unsubstituted aromatic heterocycle of 2 to 30 ring-forming carbon atoms. However, embodiments are not limited thereto.

In an embodiment, in Formula 1, Y₁ and Y₂ may be different from each other. In another embodiment, in Formula 1, Y₁ and Y₂ may be the same.

In an embodiment, in Formula 1, Y₁ and Y₂ may each independently include at least one substituent selected from Substituent Group S1:

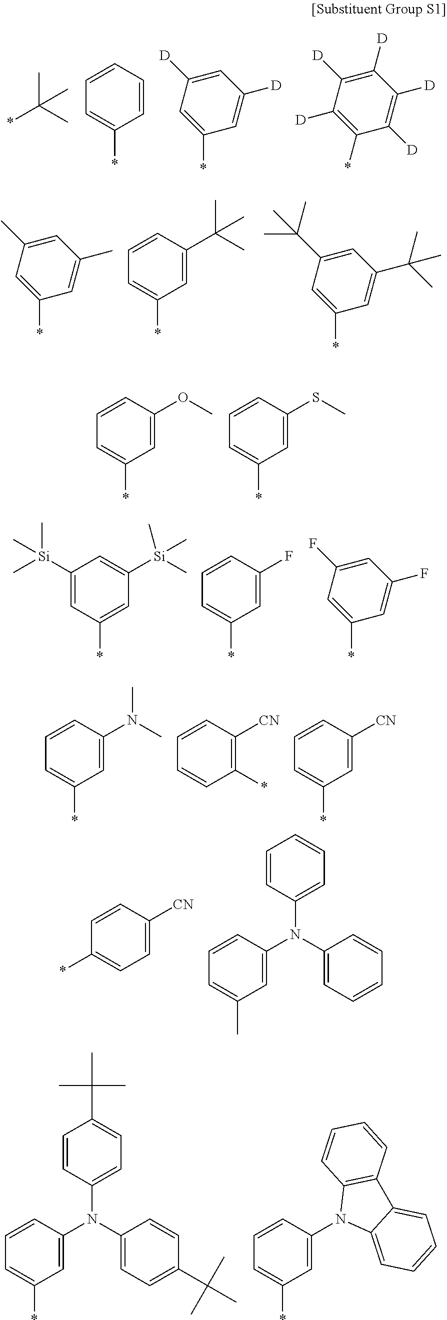

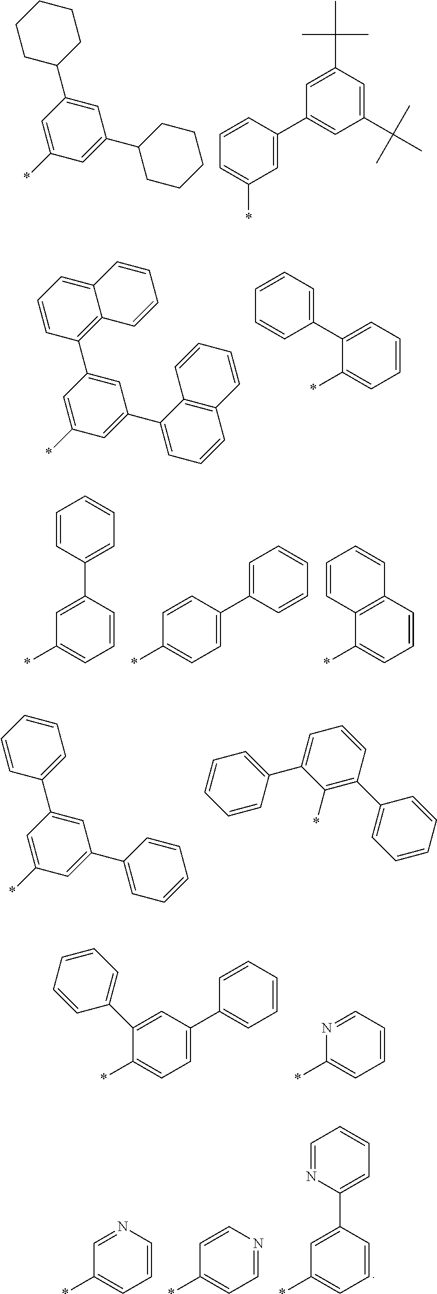

In an embodiment, in Formula 1, a case of forming a ring via a combination of two adjacent Y₁ groups and a case of forming a ring via a combination of two adjacent Y₂ groups may each include at least one substituent selected from Substituent Group S2:

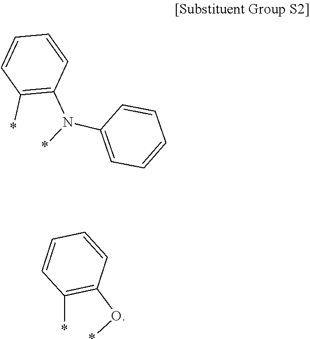 [SMILES: *c1ccccc1N(*)c1ccccc1 ; *Oc1ccccc1*]

In Formula 1, n and m may each independently be an integer from 1 to 4. For example, n and m may each independently be 1 or 2. If n is 2 or more, multiple Y₁ groups may be the same, or at least one may be different from the remainder. If m is 2 or more, multiple Y₂ groups may be the same, or at least one may be different from the remainder.

In Formula 1, R₁ to R₇ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring.

For example, R₂, R₅, and R₇ may each be a hydrogen atom. In an embodiment, R₁, R₃, R₄, and R₆ may each independently be a hydrogen atom, a deuterium atom, a fluorine atom, a cyano group, a trimethylsilyl group, a methyl group, an isopropyl group, a cumenyl group, a t-butyl group, a cyclopentyl group, a methoxy group, or a phenoxy group, or may be combined with an adjacent group to form a ring. For example, R₁, R₃, R₄, and R₆ may each independently be combined with an adjacent group to form a naphthyl group, a dibenzofuran group, or a dibenzothiophene group.

In Formula 1, a, c, d, and f may each independently be an integer from 0 to 5. For example, a, c, d, and f may each independently be 0, 1, 2, 3, or 5. A case where a is 0 may be the same as a case where a is 1 and R₁ is a hydrogen atom. A case where c is 0 may be the same as a case where c is 1 and R₃ is a hydrogen atom. A case where d is 0 may be the same as a case where d is 1 and R₄ is a hydrogen atom. A case where f is 0 may be the same as a case where f is 1 and R₆ is a hydrogen atom.

In Formula 1, b and e may each independently be an integer from 0 to 3. For example, b and e may each be 0. A case where b is 0 may be the same as a case where b is 1 and R₂ is a hydrogen atom. A case where e is 0 may be the same as a case where e is 1 and R₅ is a hydrogen atom.

In Formula 1, g may be an integer from 0 to 2. For example, g may be 0. A case where g is 0 may be the same as a case where g is 1 and R₇ is a hydrogen atom.

The first compound represented by Formula 1 may be represented by Formula 1-1:

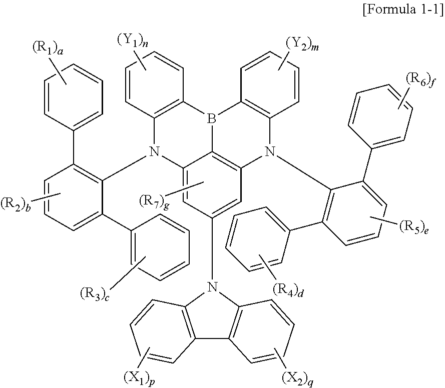

Formula 1-1 represents an embodiment of Formula 1 having a specific bonding structure for a terphenyl group.

In Formula 1-1, X₁, X₂, Y₁, Y₂, R₁ to R₇, a to g, n, m, p, and q are each the same as defined in Formula 1.

The first compound according to an embodiment may include a fused structure of multiple aromatic rings via at least one boron atom and two heteroatoms. The first compound may include a fused structure of multiple aromatic rings via one boron atom and two nitrogen atoms.

The first compound includes an electron donating group bonded at a meta- or a para-position to a benzene ring that is directly bonded to the boron atom, thereby improving material stability, and when the first compound is included in a light emitting device, emission efficiency of the device may be improved.

For example, the first compound may be represented by Formula 1 wherein at least one of Y₁ and Y₂ may be a substituted or unsubstituted aryl group of 6 to 30 ring-forming carbon atoms, or a substituted or unsubstituted heteroaryl group of 2 to 30 ring-forming carbon atoms, which is bonded at a meta- or a para-position with respect to the boron atom, or at least one of Y₁ and Y₂ may be combined with an adjacent group to form a substituted or unsubstituted aliphatic heterocycle of 2 to 30 ring-forming carbon atoms or a substituted or unsubstituted aromatic heterocycle of 2 to 30 ring-forming carbon atoms.

For example, in Formula 1, Y₁ and Y₂ may each independently be a substituted or unsubstituted aryl group of 6 to 30 ring-forming carbon atoms, which is connected at a meta- or a para-position with respect to the boron atom. Thus, the absorbance of the first compound may be largely improved, and the Forster or Fluorescence resonance energy transfer (FRET) efficiency from a host may be improved, and the improvement of the efficiency of the device during manufacturing thereof may be expected. The first compound may include a substituted or unsubstituted aryl group of 6 to 30 ring-forming carbon atoms, which is bonded at a meta- or a para-position with respect to the boron atom, and due to radical stabilizing effects, material stability may be improved.

The first compound may include a substituted or unsubstituted carbazole group bonded at a para-position of a benzene ring directly bonded to the boron atom. Accordingly, the multiple resonance effects of the first compound may be reinforced, and the lifetime (tau) value with respect to a delayed component may be reduced to about 10-30 ms. Due to the electron withdrawing effects of the carbazole group, the highest occupied molecular orbital (HOMO) energy level of the core of the first compound may be markedly reduced, and when a device includes the first compound, the formation of triplet excitons may be suppressed to improve the device life.

The first compound includes the substituted or unsubstituted carbazole group bonded at a para-position with respect to the boron atom, and material stability may be improved.

For example, the carbazole group bonded at a para-position with respect to the boron atom of Formula 1 may include X₁ and X₂ as substituents. If X₁ and X₂ are substituted at the carbazole group at positions 3 and 6 (for example, at a para-position with respect to the nitrogen atom of the carbazole group), and if X₁ and X₂ are each not hydrogen, the highly chemically active position of the carbazole group may be protected, and material stability may be markedly improved.

If X₁ and X₂ are substituted at the carbazole group at positions 2 and 7 (for example, at a meta-position with respect to the nitrogen atom of the carbazole group), and if X₁ and X₂ are substituents that are sterically bulky and may induce steric effects, the reaction of radicals, etc. at positions 3 and 6 of the carbazole group may be prevented, and improved material stability may be shown.

The first compound according to embodiments may include an ortho-type terphenyl group in a multiple resonance plate-type structure including a boron atom, and intermolecular distance may be relatively increased. Accordingly, the intermolecular aggregation phenomenon of the first compound may be prevented, intermolecular interaction may be reduced, and material stability against thermal decomposition, etc., may be improved. For example, the first compound may include an ortho-type terphenyl group, and intermolecular interaction may be suppressed, and accordingly, the defects of increasing sublimation temperature due to the intermolecular interaction during a sublimation purification process may be prevented, and the thermal stability of molecules may be secured.

Since the first compound has relatively little intermolecular interaction, the approach of radicals, excitons, polarons, etc., having high energy to the first compound may be blocked during manufacturing a device including the first compound, and dexter energy transfer from a host or host-Pt sensitizer may be suppressed, and deterioration phenomenon may be reduced, and device life may be improved.

In the first compound, an ortho-type terphenyl group may be bonded to a fused structure including a boron atom, and the boron atom may prevent the occurrence of defects of the deformation of the trigonal bond structure of the boron atom via the bonding of the boron atom with a nucleophile. Accordingly, the first compound of an embodiment may have improved stability, reinforced multiple resonance effects, and improved thermally activated delayed fluorescence (TADF) properties.

The light emitting device according to embodiments includes the first compound in the emission layer, and deterioration of the device may be reduced, the efficiency and lifetime of the device may be improved, and high color purity may be shown.

In an embodiment, the first compound represented by Formula 1 may be represented by any one of Formula 1-2-1 to Formula 1-2-7:

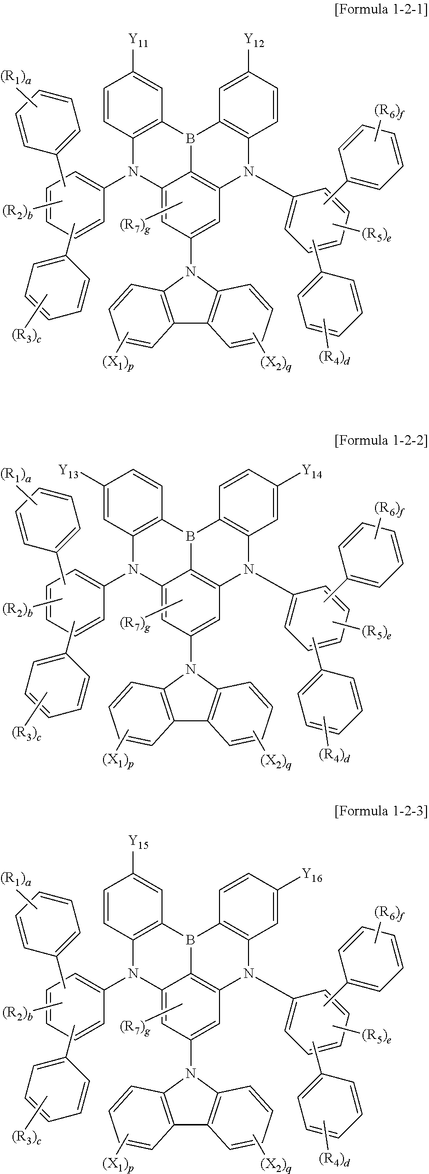

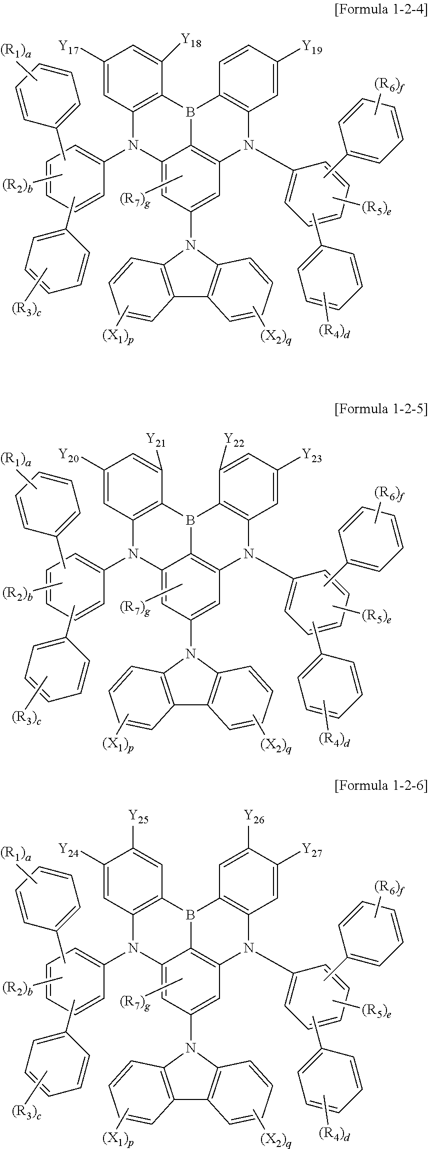

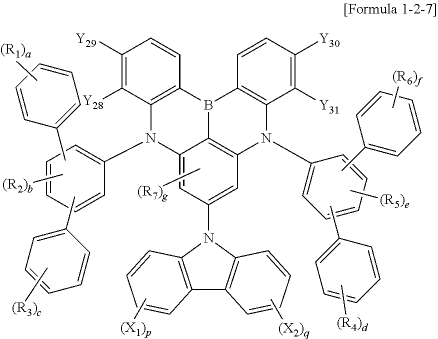

Formula 1-2-1 to Formula 1-2-7 represent embodiments of Formula 1 where Y₁ and Y₂ are specified.

In Formula 1-2-1 to Formula 1-2-7, Y₁₁ to Y₃₁ may each independently be a deuterium atom, a substituted or unsubstituted amine group, a substituted or unsubstituted oxy group, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring, wherein for Y₁₁ to Y₃₁: at least one of Y₁ and Y₁₂, at least one of Y₁₃ and Y₁₄, at least one of Y₁₅ and Y₁₆, at least one of Y₁₇ and Y₁₈, at least one of Y₂₀ and Y₂₁, and at least one of Y₂₂ and Y₂₃ may each independently be a substituted or unsubstituted aryl group of 6 to 30 ring-forming carbon atoms, or a substituted or unsubstituted heteroaryl group of 2 to 30 ring-forming carbon atoms; at least one of Y₂₄ and Y₂₅ or Y₂₆ and Y₂₇ may be combined with each other to form a ring; and at least one of Y₂₈ and Y₂₉ or Y₃₀ and Y₃₁ may be combined with each other to form a ring.

In an embodiment, in Formula 1-2-1 to Formula 1-2-7, Y₁₁ to Y₃₁ may each independently include at least one substituent selected from Substituent Group Si:

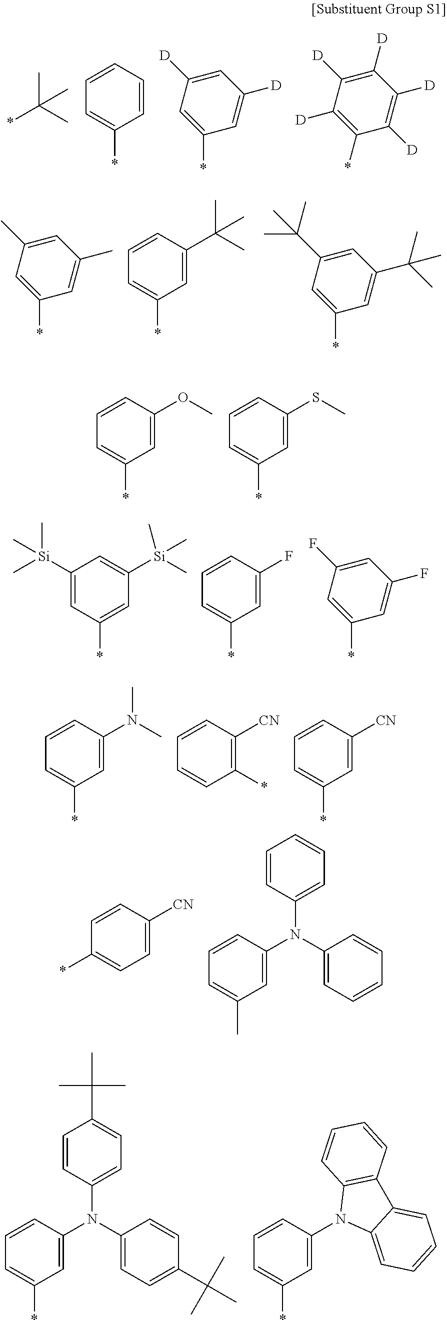

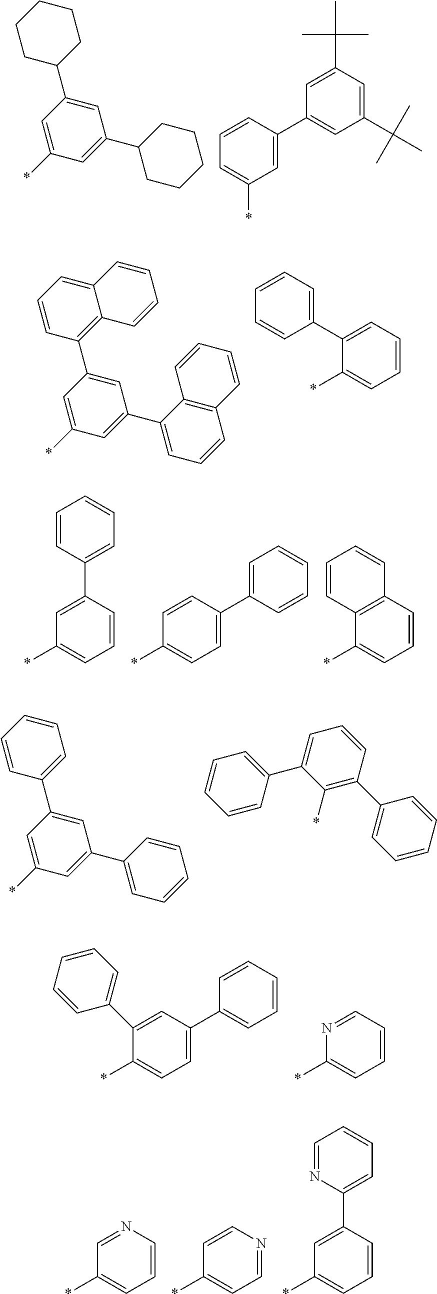

For example, in Formula 1-2-1 to Formula 1-2-7, Y₁₁ to Y₁₈, and Y₂₀ to Y₃₁ may each independently be a substituted or unsubstituted diphenyl amine group, a substituted or unsubstituted phenyl group, a substituted or unsubstituted biphenyl group, a substituted or unsubstituted terphenyl group, a substituted or unsubstituted naphthyl group, a substituted or unsubstituted carbazole group, a substituted or unsubstituted pyridine group, or may be combined with an adjacent group to form a ring.

For example, in Formula 1-2-4, Y₁₉ may be a substituted or unsubstituted t-butyl group. For example, in Formula 1-2-4, Y₁₉ may be an unsubstituted t-butyl group.

For example, in Formula 1-2-6 and Formula 1-2-7, each of Y₂₄ and Y₂₅, Y₂₆ and Y₂₇, Y₂₈ and Y₂₉, and Y₃₀ and Y₃₁ may be combined with each other to form ring.

In an embodiment, in Formula 1-2-6 and Formula 1-2-7, if each of Y₂₄ and Y₂₅, Y₂₆ and Y₂₇, Y₂₈ and Y₂₉, and Y₃₀ and Y₃₁ are each combined with each other, at least one of Y₂₄ and Y₂₅, Y₂₆ and Y₂₇, Y₂₈ and Y₂₉, or Y₃₀ and Y₃₁ may each independently include a substituent selected from Substituent Group S2:

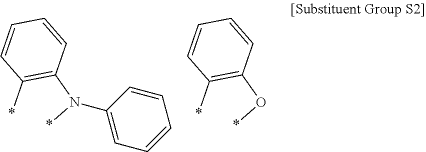

However, the embodiments of Y₁₁ to Y₃₁ in Formula 1-2-1 to Formula 1-2-7 are not limited thereto.

In Formula 1-2-1 to Formula 1-2-7, X₁, X₂, R₁ to R₇, a to g, p, and q are each the same as defined in Formula 1.

In an embodiment, the first compound represented by Formula 1 may be represented by Formula 1-3:

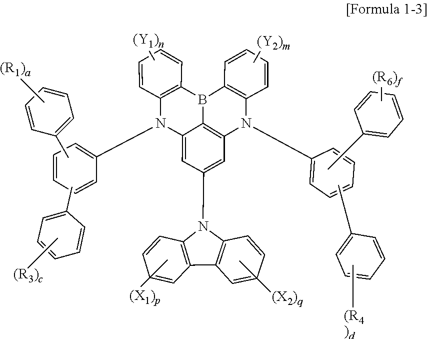

Formula 1-3 represents an embodiment of Formula 1 where R₂, R₅, R₇, b, e, and g are specified. Formula 1-3 corresponds to Formula 1 where R₂, R₅, and R₇ are all hydrogen atoms. Formula 1-3 corresponds to Formula 1 where b, e, and g are each 0.

In Formula 1-3, X₁, X₂, R₁, R₃, R₄, R₆, Y₁, Y₂, a, c, d, f, n, m, p, and q are each the same as defined in Formula 1.

In an embodiment, the first compound represented by Formula 1-3 may be represented by Formula 1-4:

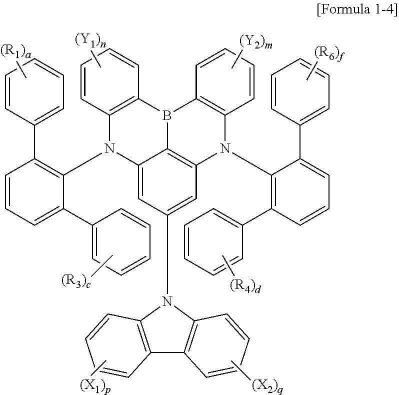

Formula 1-4 represents an embodiment of Formula 1-3 having a specific bonding structure for a terphenyl group.

In Formula 1-4, X₁, X₂, R₁, R₃, R₄, R₆, Y₁, Y₂, a, c, d, f, n, m, p, and q are each the same as defined in Formula 1.

The first compound according to an embodiment includes an ortho-type terphenyl group in a multiple resonance plate-type structure including a boron atom, and intermolecular distance may be relatively increased, intermolecular aggregation phenomenon may be prevented, and material stability may be improved. The first compound includes a terphenyl group, and the molecular bond structure of the boron atom may be stabilized. Accordingly, the multiple resonance structure of the first compound may be reinforced.

In an embodiment, the first compound represented by Formula 1-4 may be represented by Formula 1-5-1 or Formula 1-5-2:

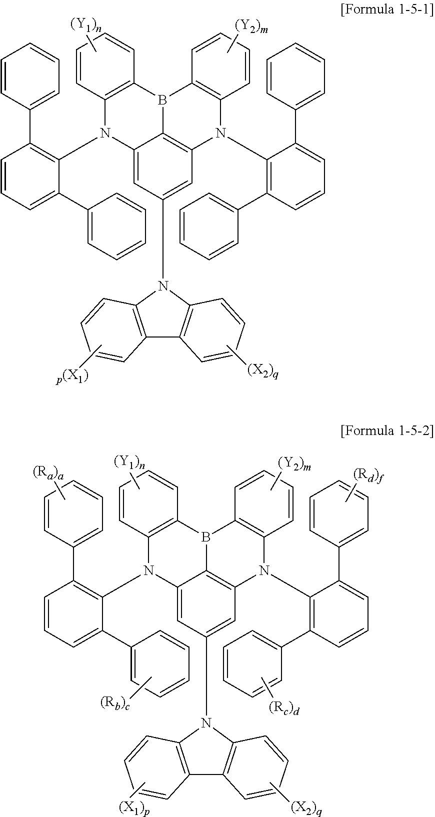

Formula 1-5-1 and Formula 1-5-2 represent embodiments of Formula 1-4 where R₁, R₃, R₄, and R₆ are specified. Formula 1-5-1 corresponds to Formula 1-4 where R₁, R₃, R₄, and R₆ are all hydrogen atoms. Formula 1-5-2 corresponds to Formula 1-4 where R₁, R₃, R₄, and R₆ are specified as Rₐ, R_{b}, R_{c} and R_{d}, respectively.

In Formula 1-5-2, Rₐ, R_{b}, R_{c}, and R_{d} may each independently be a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring.

For example, Rₐ, R_{b}, R_{c}, and R_{d} may each independently be a deuterium atom, a fluorine atom, a cyano group, a trimethylsilyl group, a methyl group, an isopropyl group, a cumenyl group, a t-butyl group, a cyclopentyl group, a methoxy group, or a phenoxy group, or may be combined with an adjacent group to form a ring. For example, Rₐ, R_{b}, R_{c}, and R_{d} may each independently be combined with an adjacent group to form a naphthyl group, a dibenzofuran group, or a dibenzothiophene group.

In Formula 1-5-1 and Formula 1-5-2, X₁, X₂, Y₁, Y₂, a, c, d, f, n, m, p, and q are each the same as defined in Formula 1.

The first compound may be any compound selected from Compound Group 1. In the light emitting device ED according to an embodiment, an emission layer EML may include at least one compound selected from Compound Group 1 as the first compound:

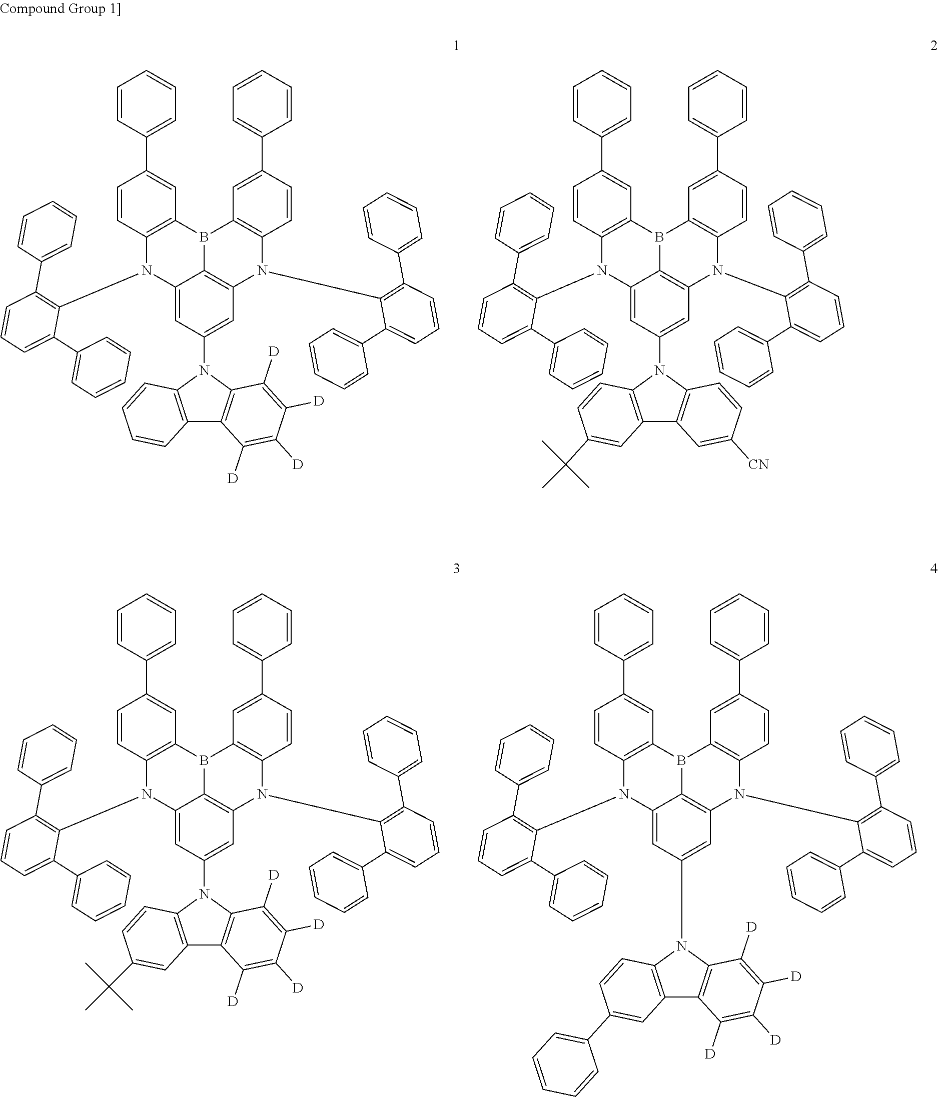

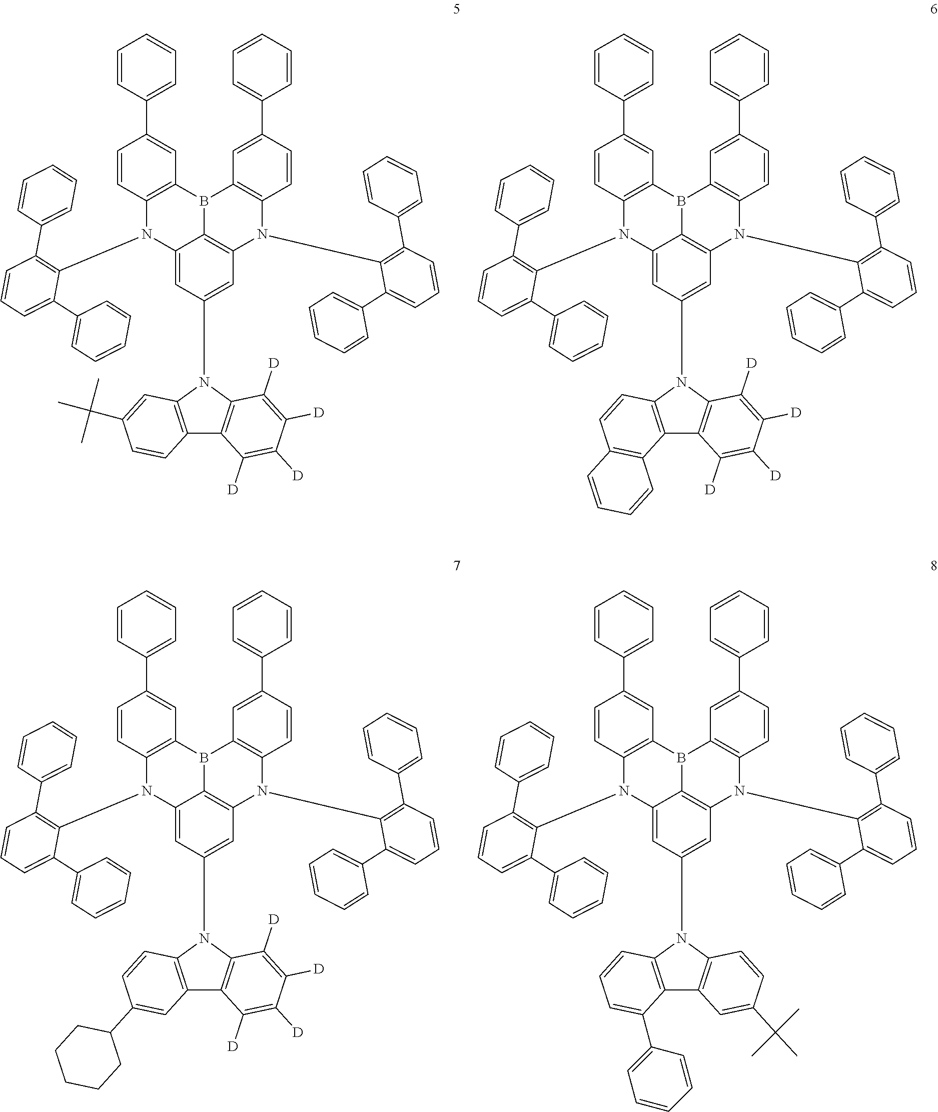

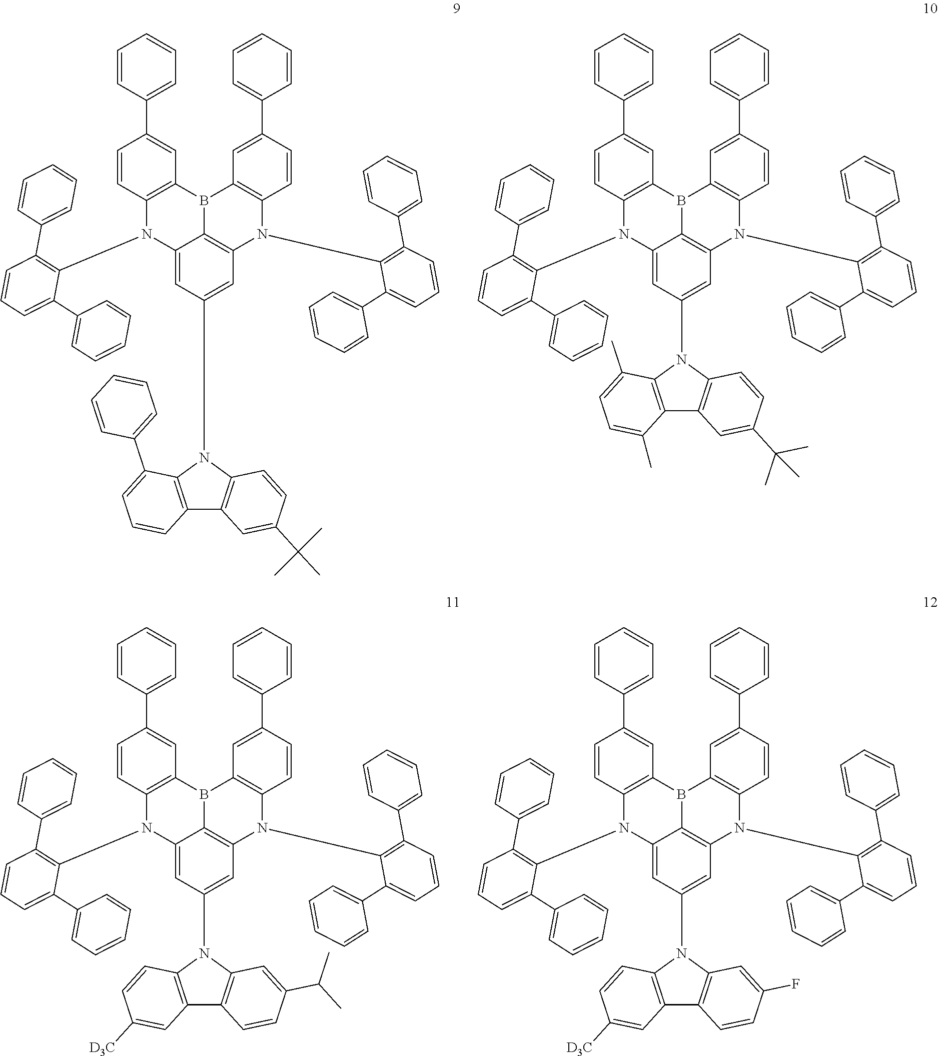

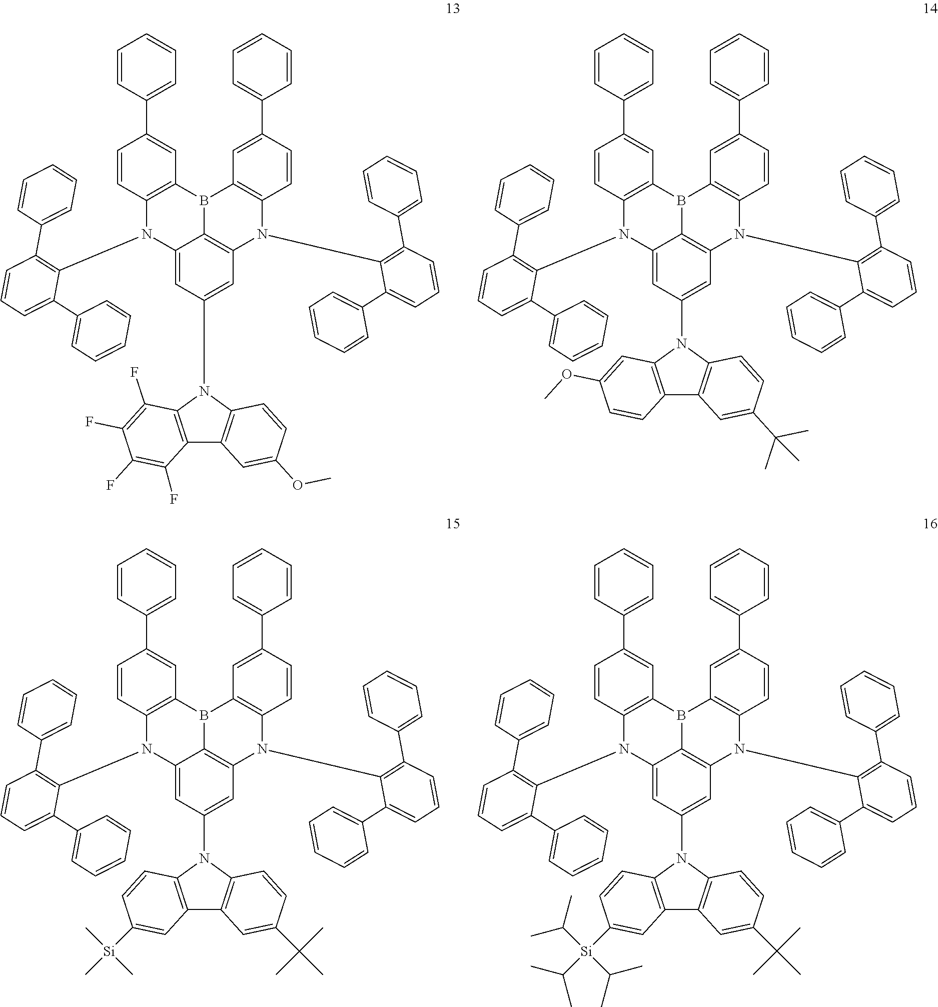

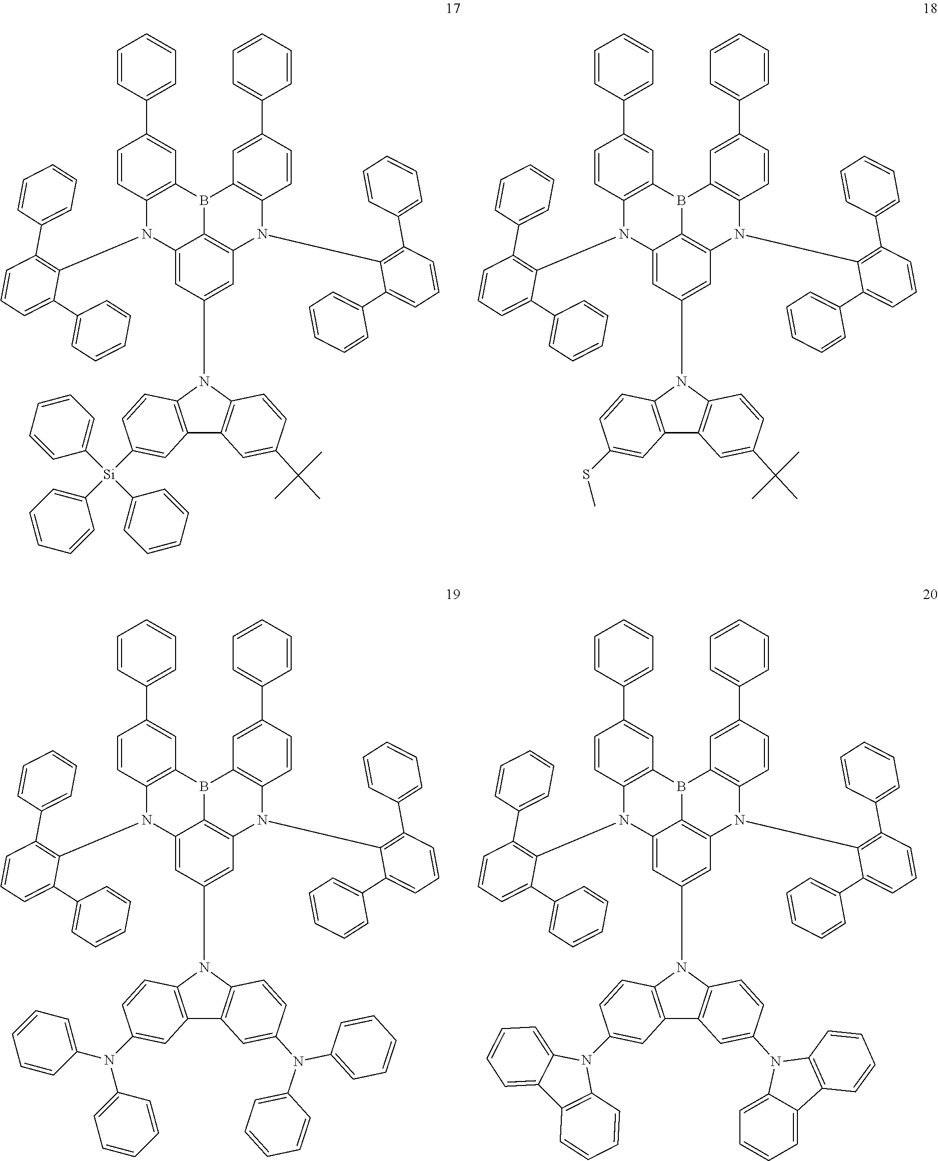

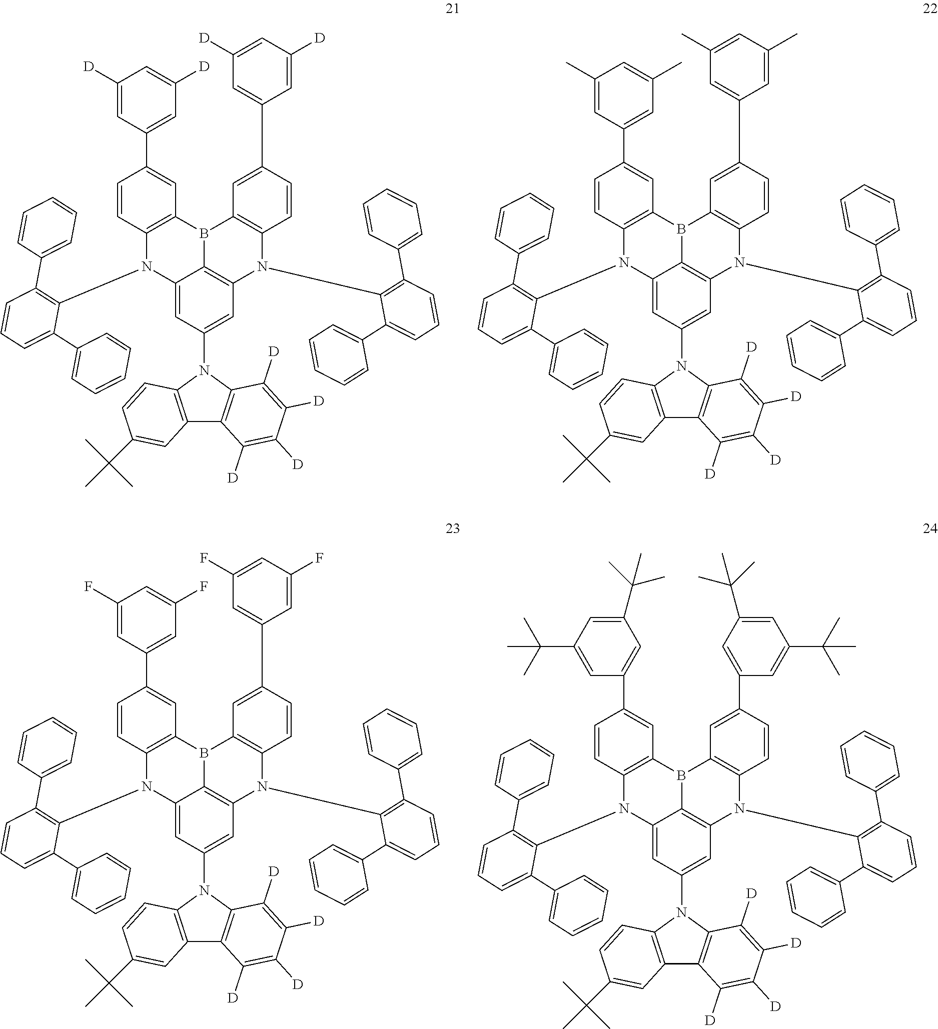

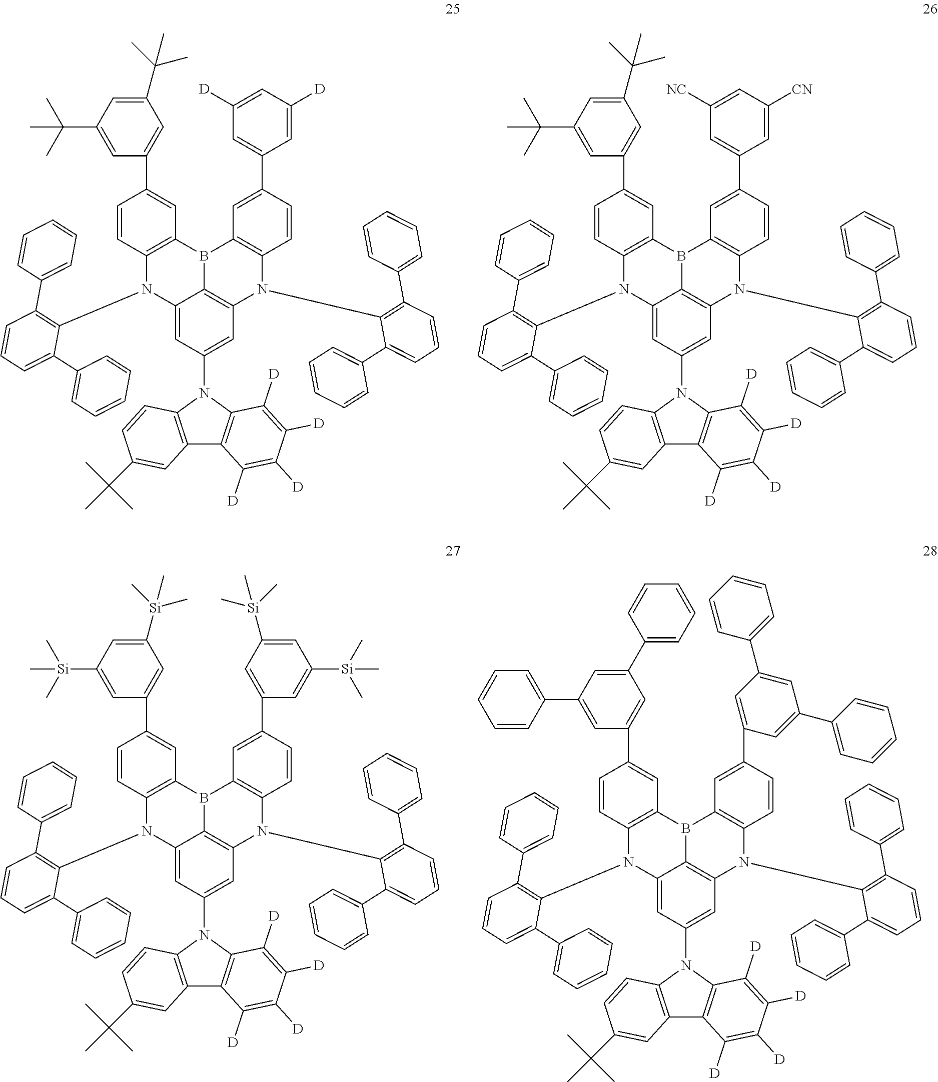

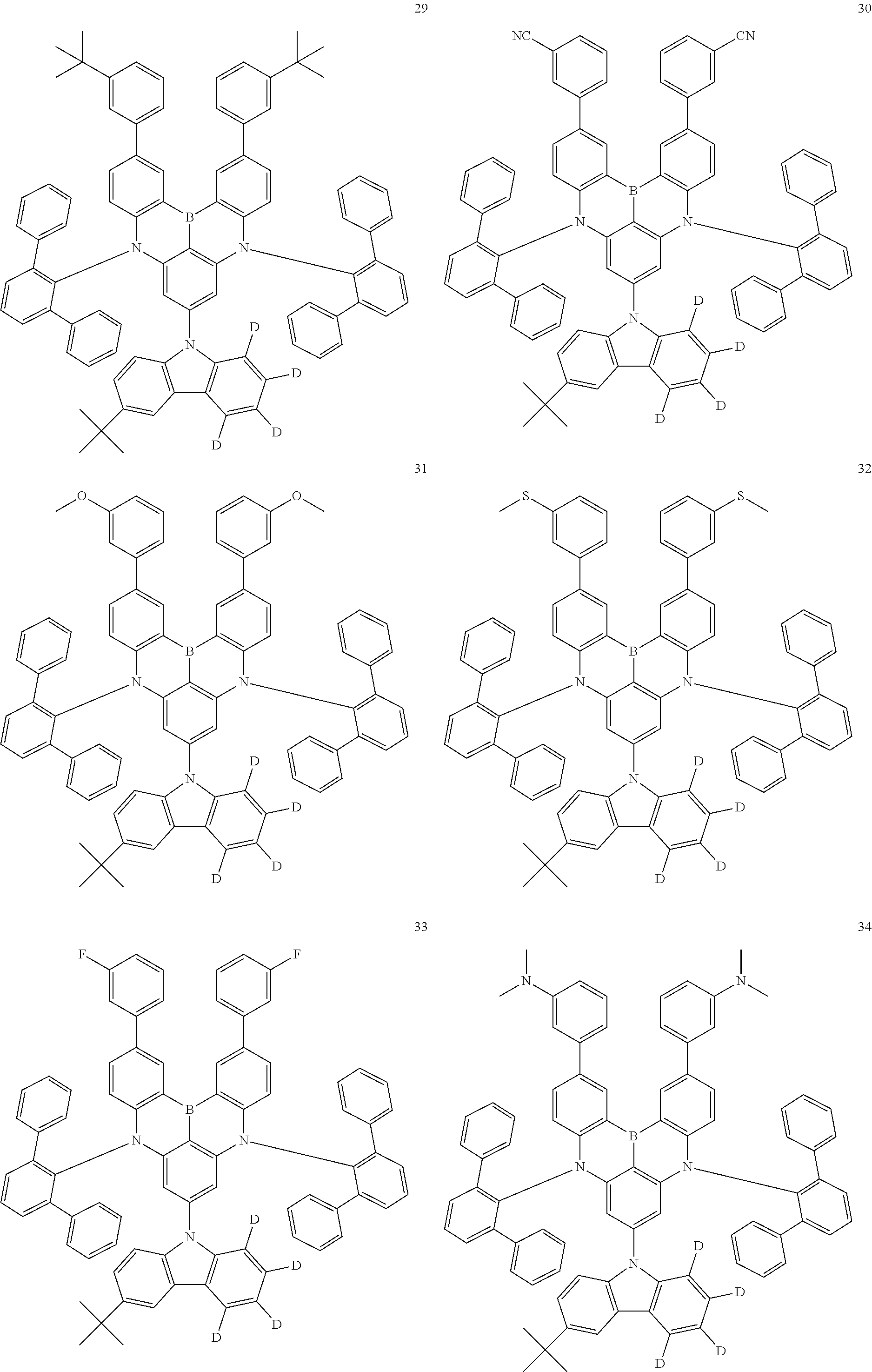

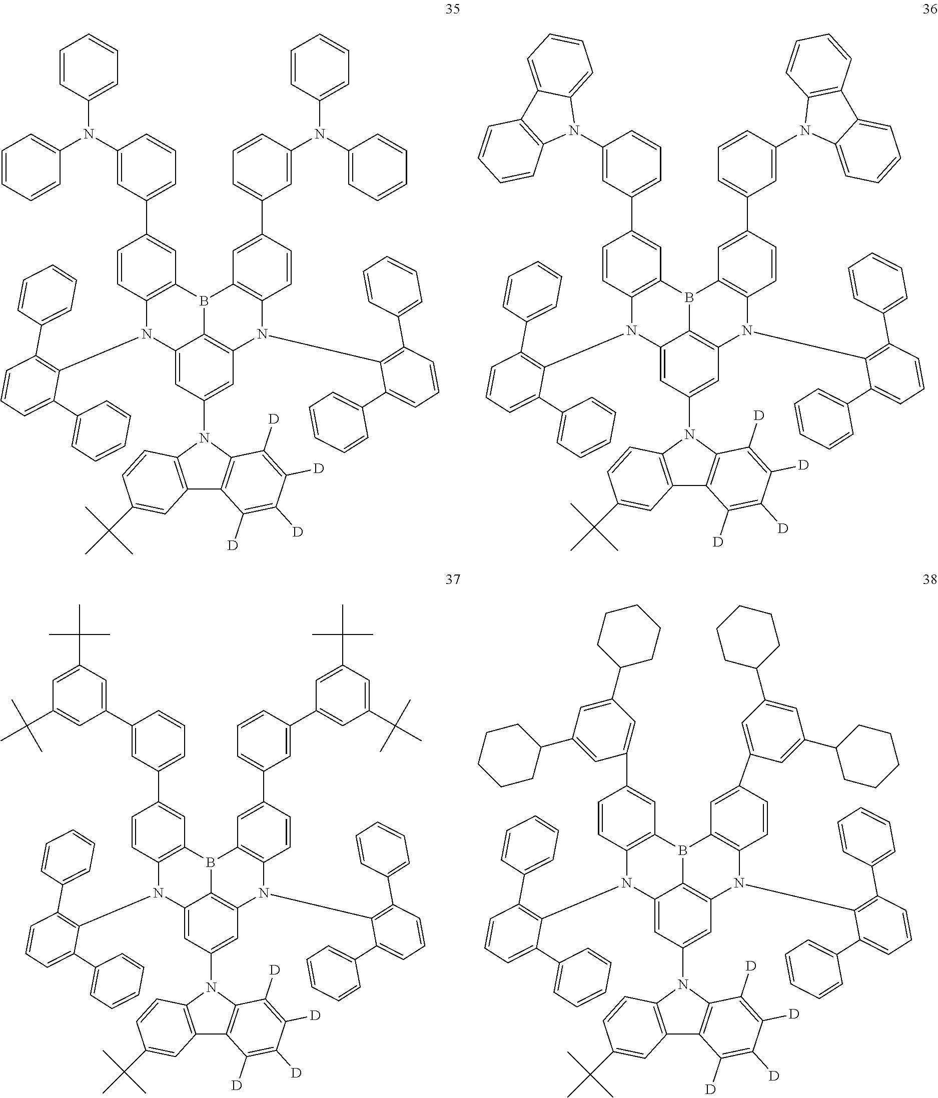

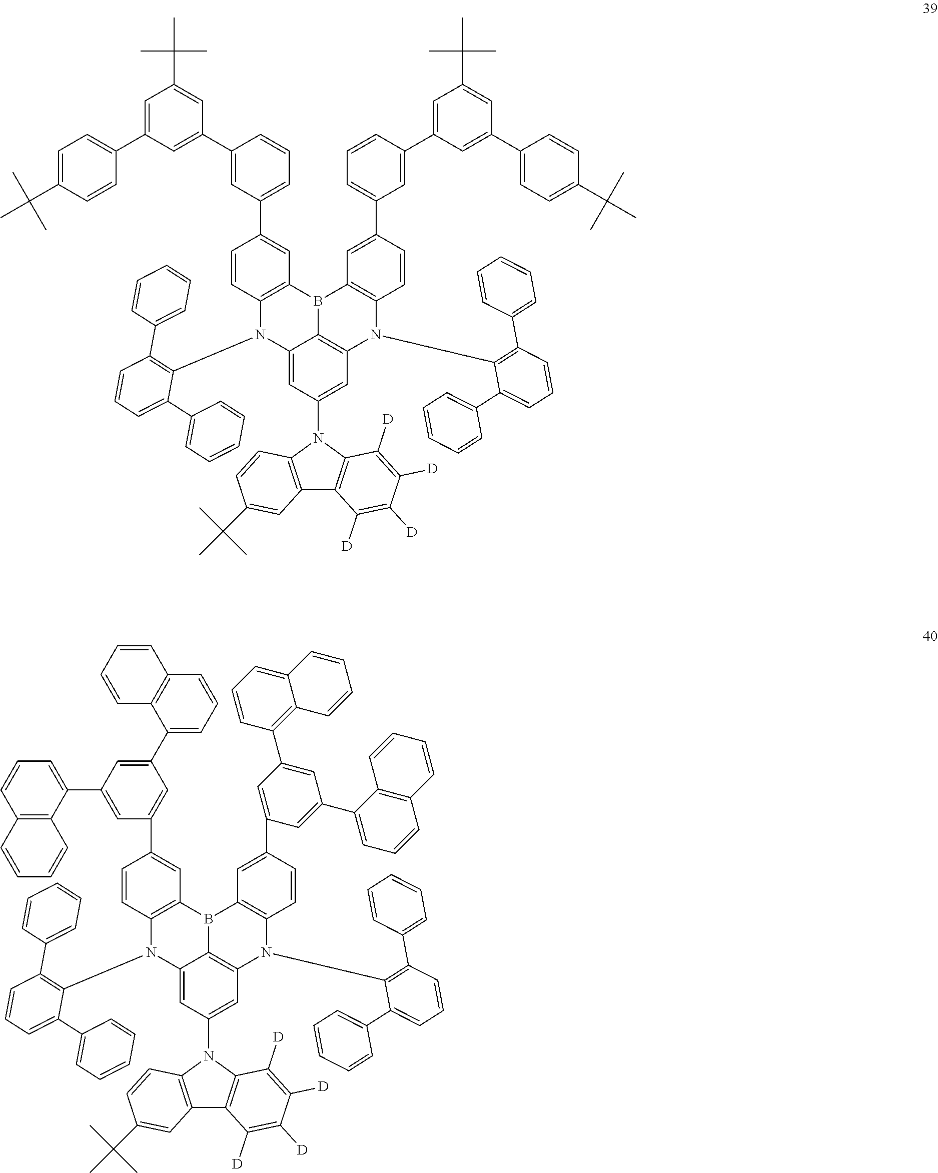 [SMILES: [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4cccc(-c5cc(-c6ccc(C(C)(C)C)cc6)cc(C(C)(C)C)c5)c4)cc1B3c1cc(-c3cccc(-c4cc(-c5ccc(C(C)(C)C)cc5)cc(C(C)(C)C)c4)c3)ccc1N2c1c(-c2ccccc2)cccc1-c1ccccc1 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4cc(-c5cccc6ccccc56)cc(-c5cccc6ccccc56)c4)cc1B3c1cc(-c3cc(-c4cccc5ccccc45)cc(-c4cccc5ccccc45)c3)ccc1N2c1c(-c2ccccc2)cccc1-c1ccccc1]

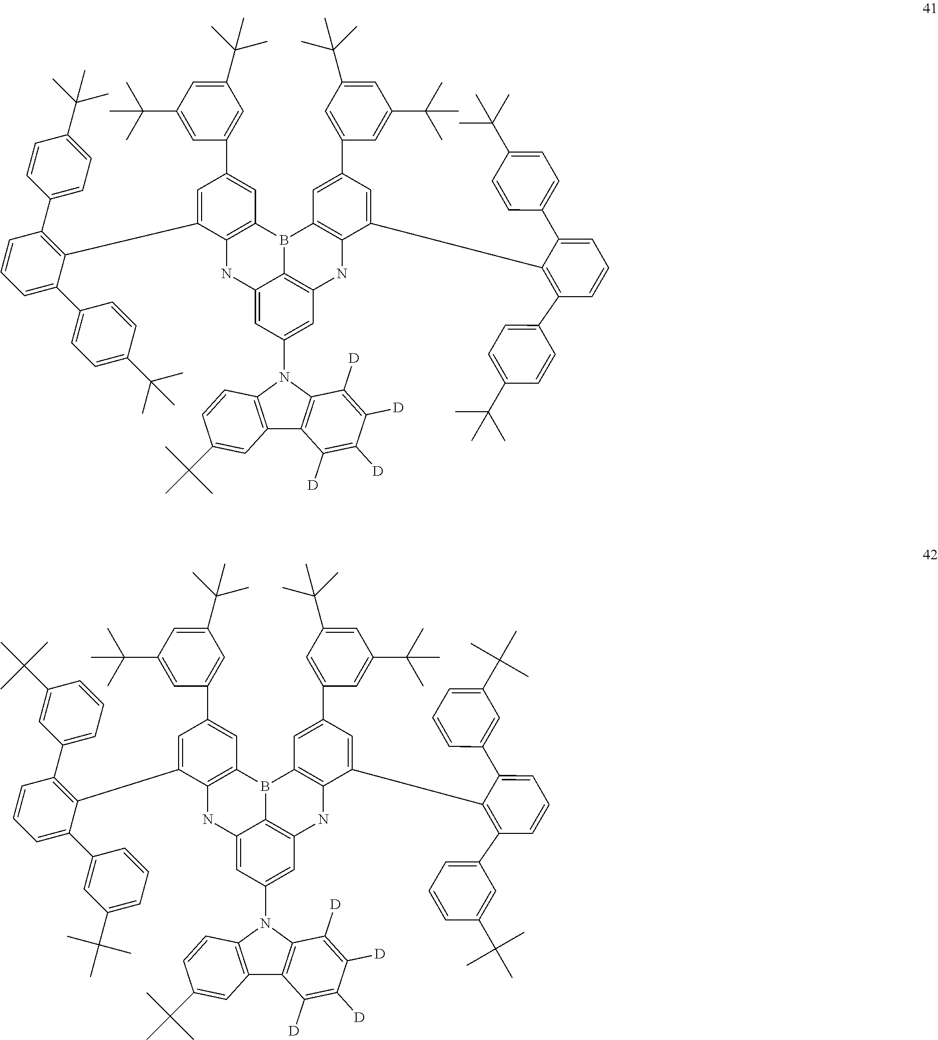

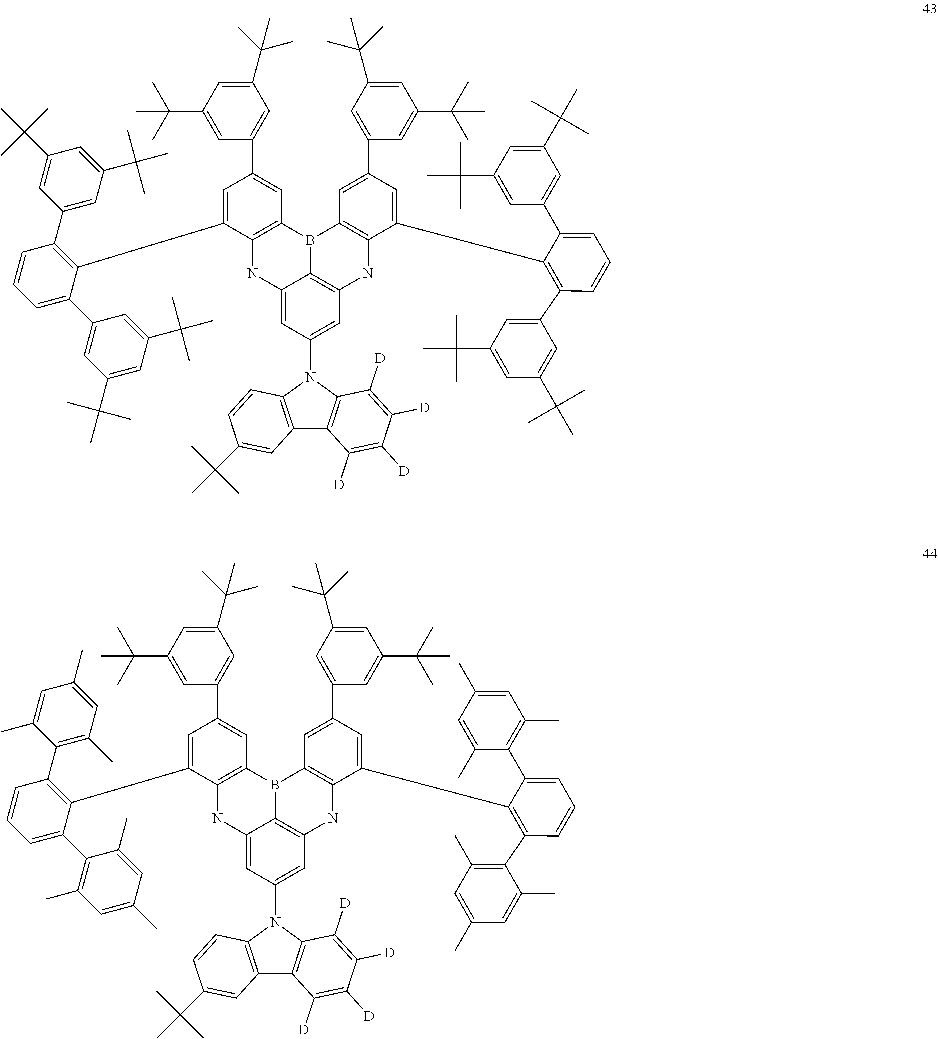

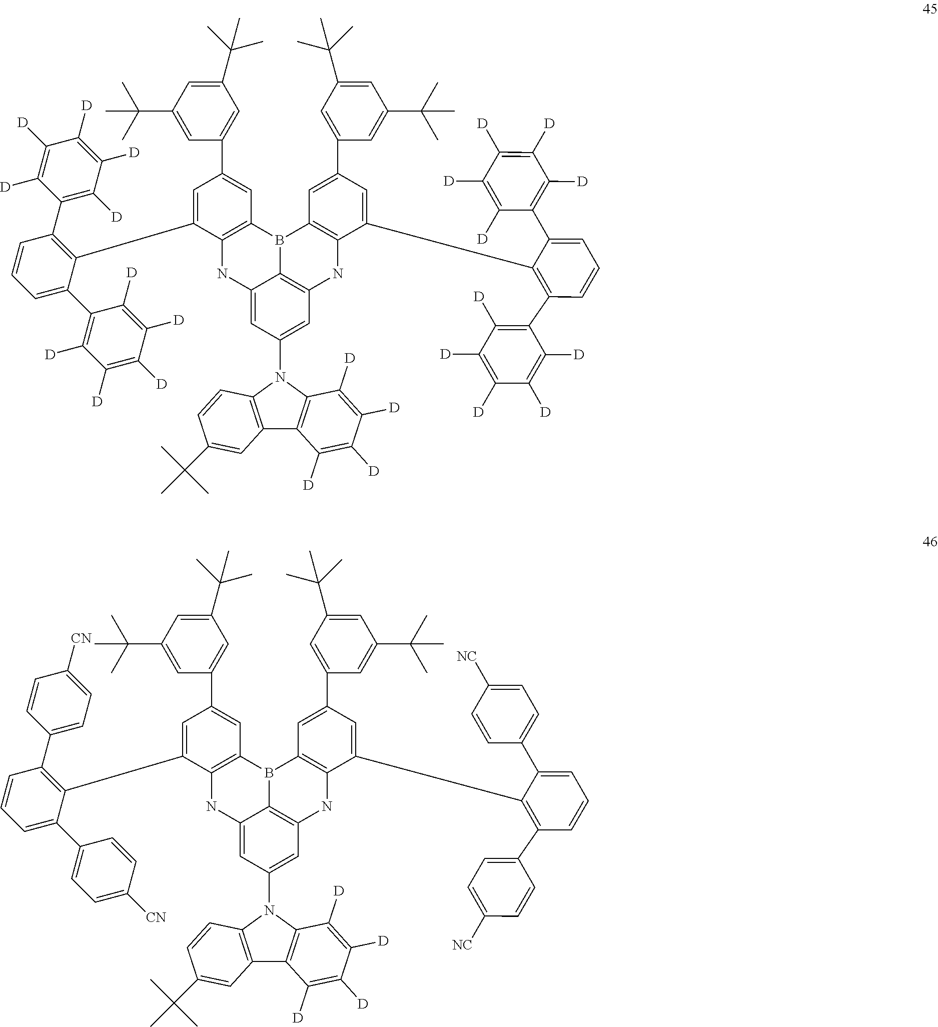

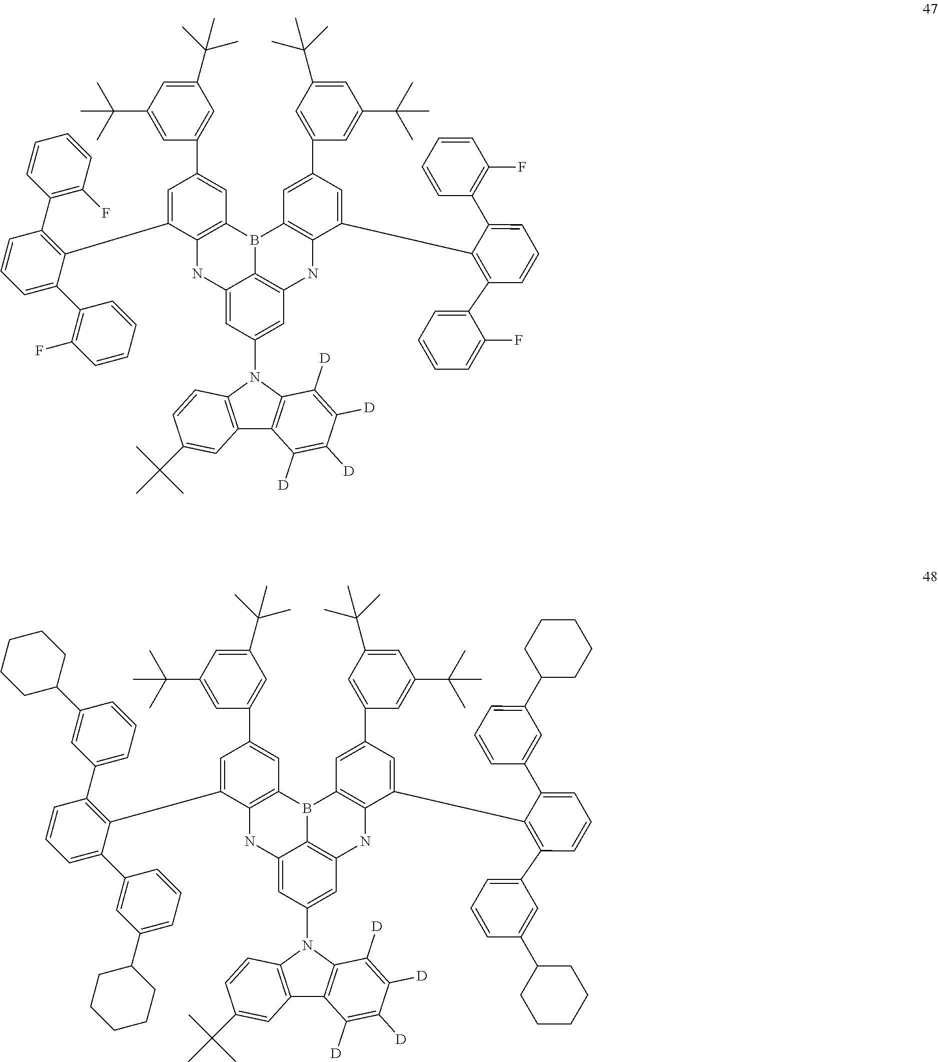 [SMILES: [2H]c1c([2H])c([2H])c2c(c1[2H])c1cc(C(C)(C)C)ccc1n2-c1cc2c3c(c1)Nc1c(cc(-c4cc(C(C)(C)C)cc(C(C)(C)C)c4)cc1-c1c(-c4ccccc4F)cccc1-c1ccccc1F)B3c1cc(-c3cc(C(C)(C)C)cc(C(C)(C)C)c3)cc(-c3c(-c4ccccc4F)cccc3-c3ccccc3F)c1N2 ; [2H]c1c([2H])c([2H])c2c(c1[2H])c1cc(C(C)(C)C)ccc1n2-c1cc2c3c(c1)Nc1c(cc(-c4cc(C(C)(C)C)cc(C(C)(C)C)c4)cc1-c1c(-c4cccc(C5CCCCC5)c4)cccc1-c1cccc(C4CCCCC4)c1)B3c1cc(-c3cc(C(C)(C)C)cc(C(C)(C)C)c3)cc(-c3c(-c4cccc(C5CCCCC5)c4)cccc3-c3cccc(C4CCCCC4)c3)c1N2]

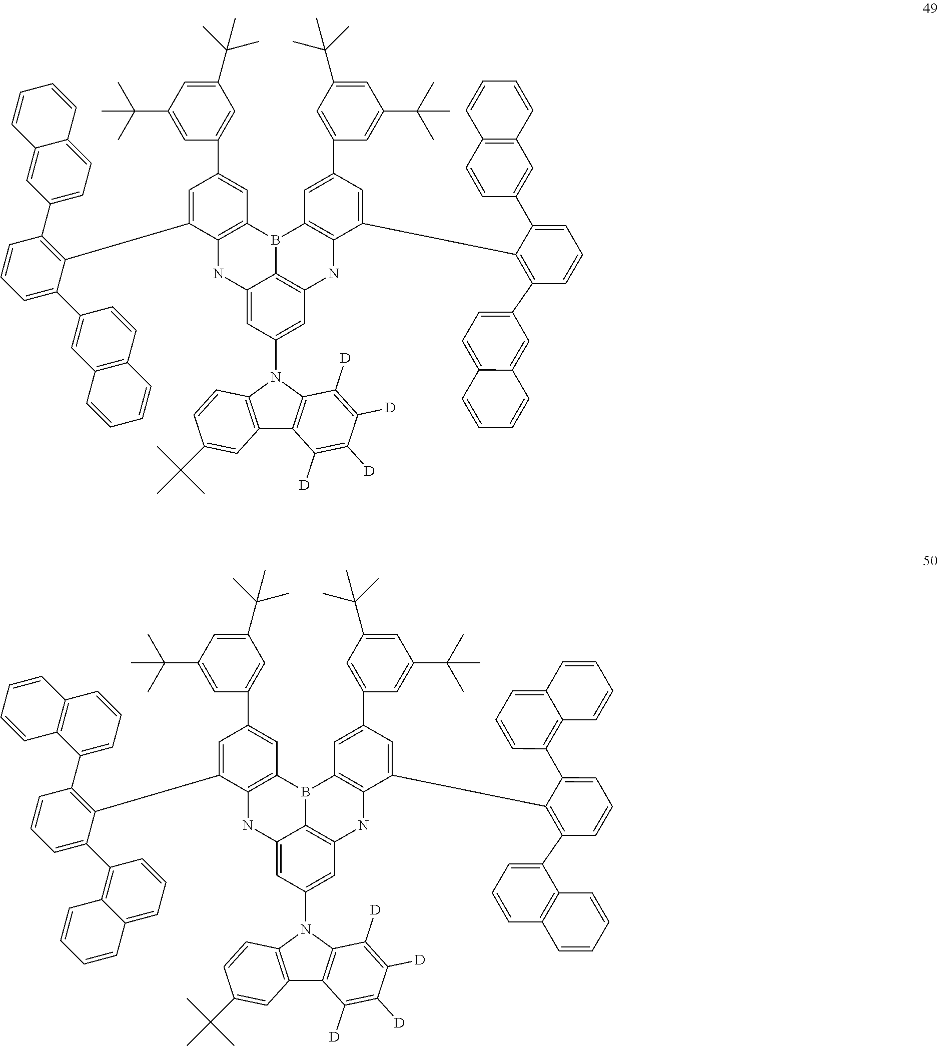 [SMILES: [2H]c1c([2H])c([2H])c2c(c1[2H])c1cc(C(C)(C)C)ccc1n2-c1cc2c3c(c1)Nc1c(cc(-c4cc(C(C)(C)C)cc(C(C)(C)C)c4)cc1-c1c(-c4ccc5ccccc5c4)cccc1-c1ccc4ccccc4c1)B3c1cc(-c3cc(C(C)(C)C)cc(C(C)(C)C)c3)cc(-c3c(-c4ccc5ccccc5c4)cccc3-c3ccc4ccccc4c3)c1N2 ; [2H]c1c([2H])c([2H])c2c(c1[2H])c1cc(C(C)(C)C)ccc1n2-c1cc2c3c(c1)Nc1c(cc(-c4cc(C(C)(C)C)cc(C(C)(C)C)c4)cc1-c1c(-c4cccc5ccccc45)cccc1-c1cccc4ccccc14)B3c1cc(-c3cc(C(C)(C)C)cc(C(C)(C)C)c3)cc(-c3c(-c4cccc5ccccc45)cccc3-c3cccc4ccccc34)c1N2]

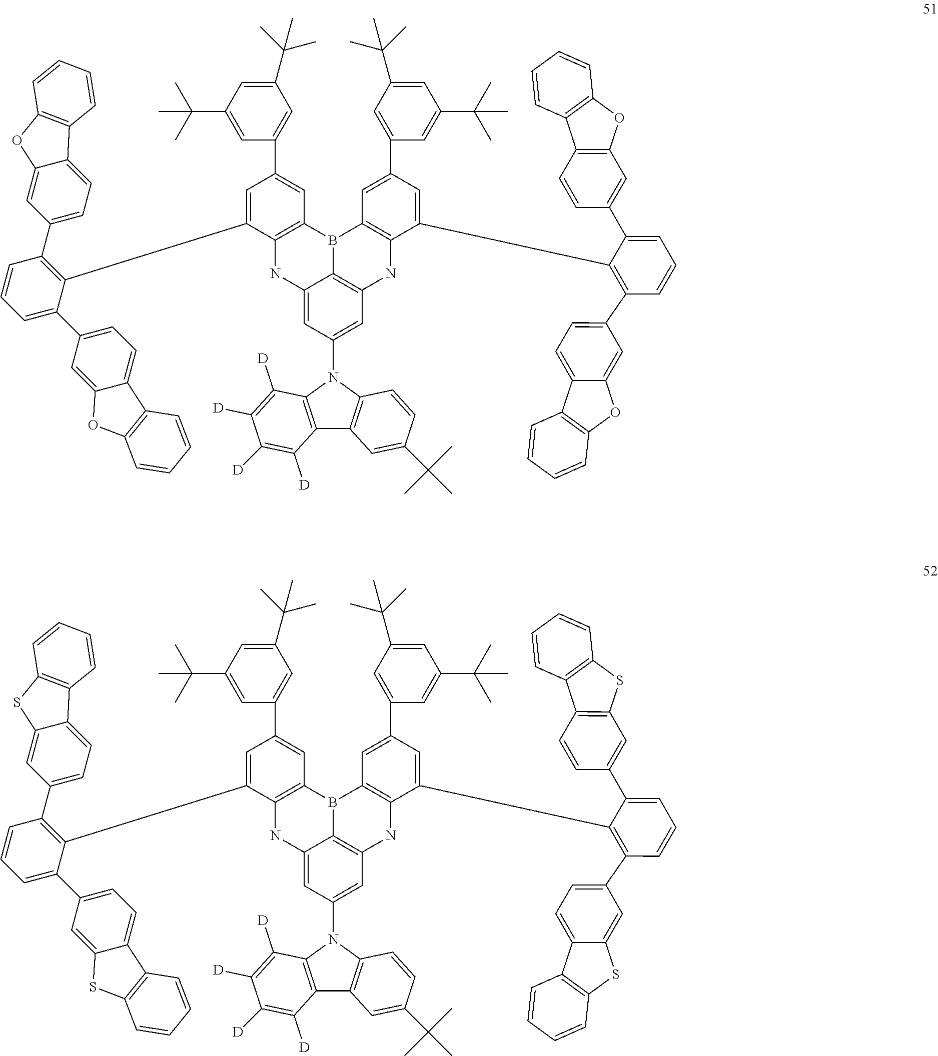

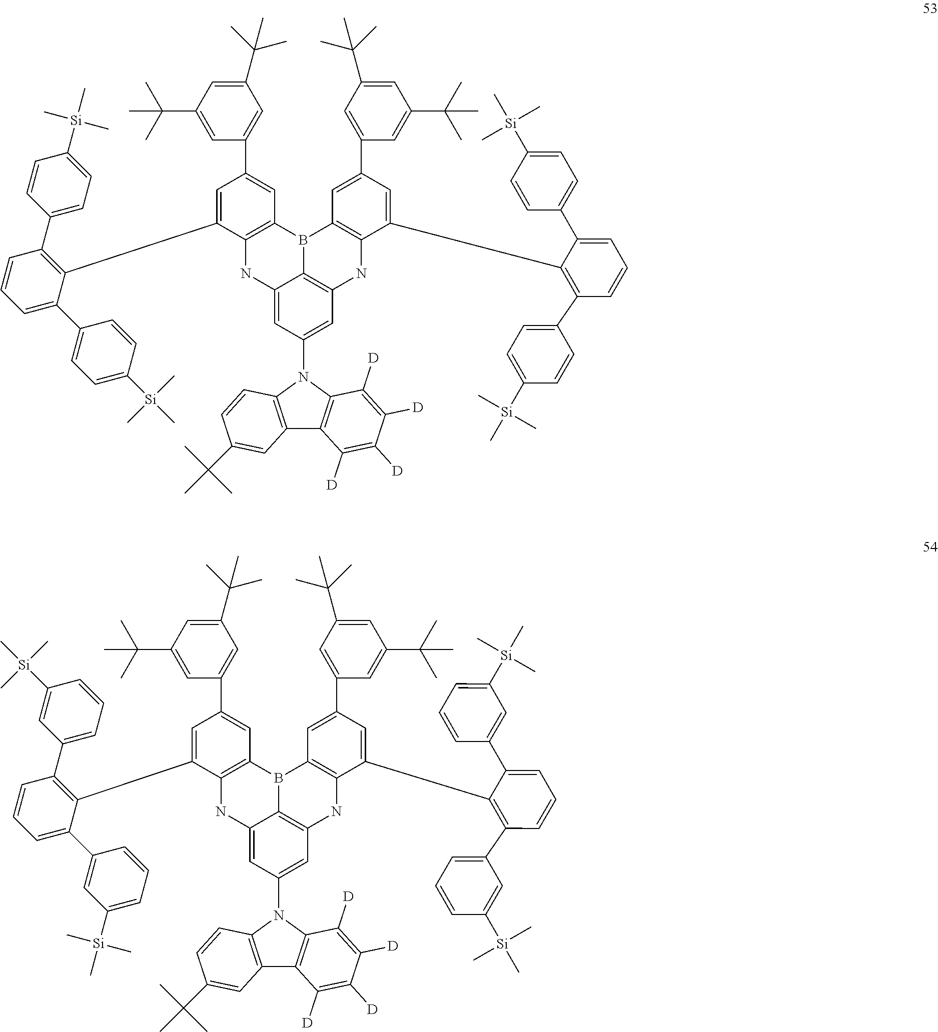

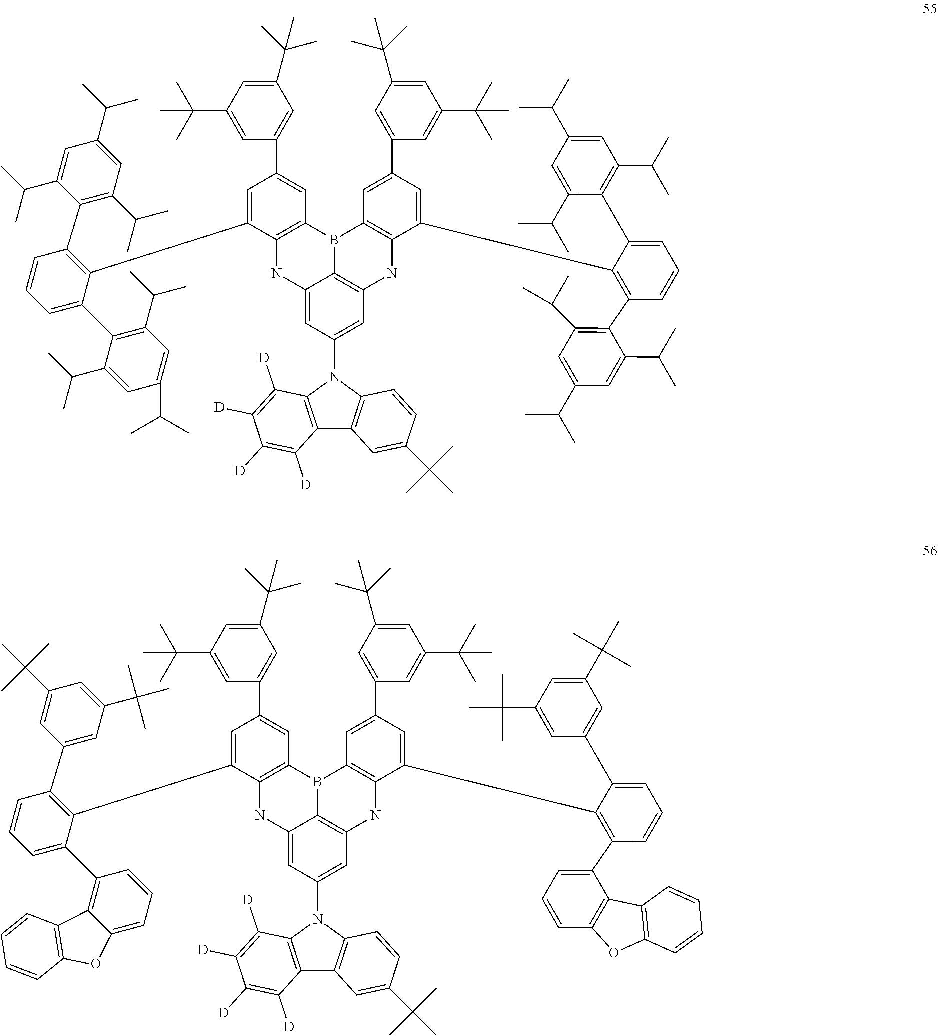

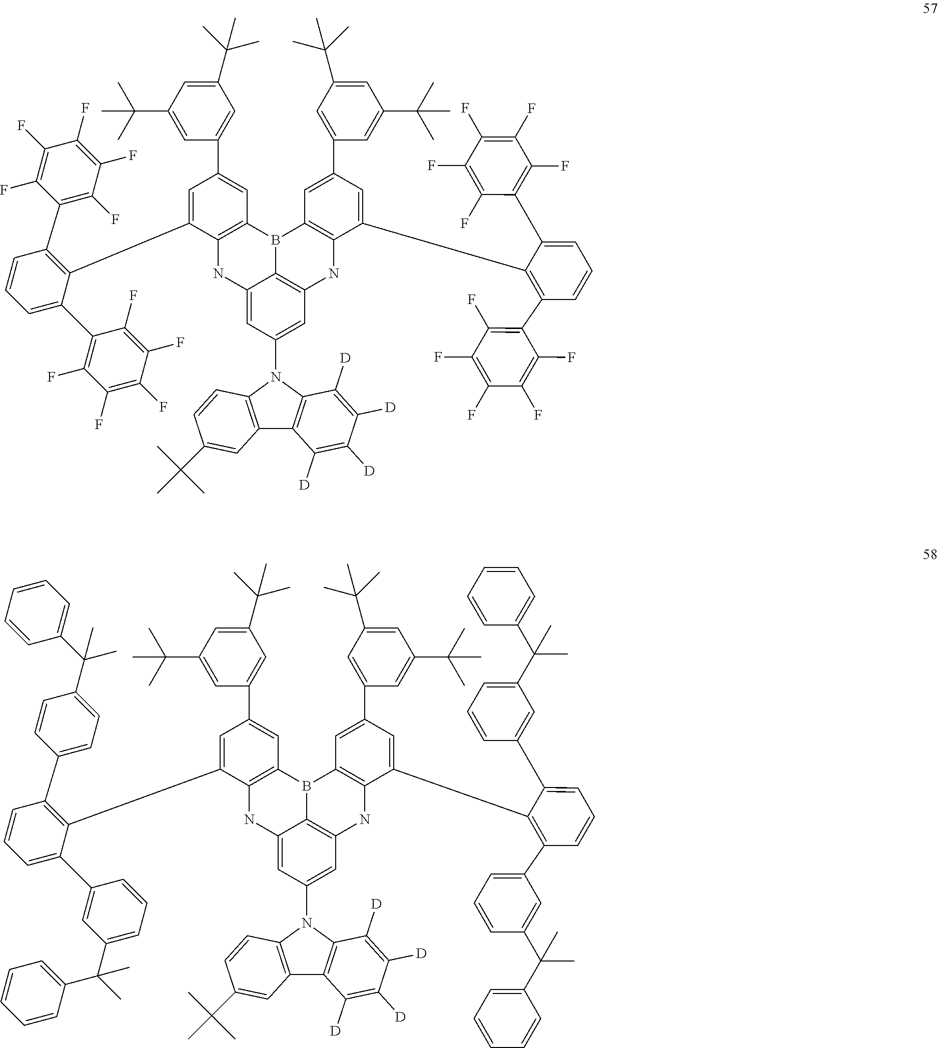

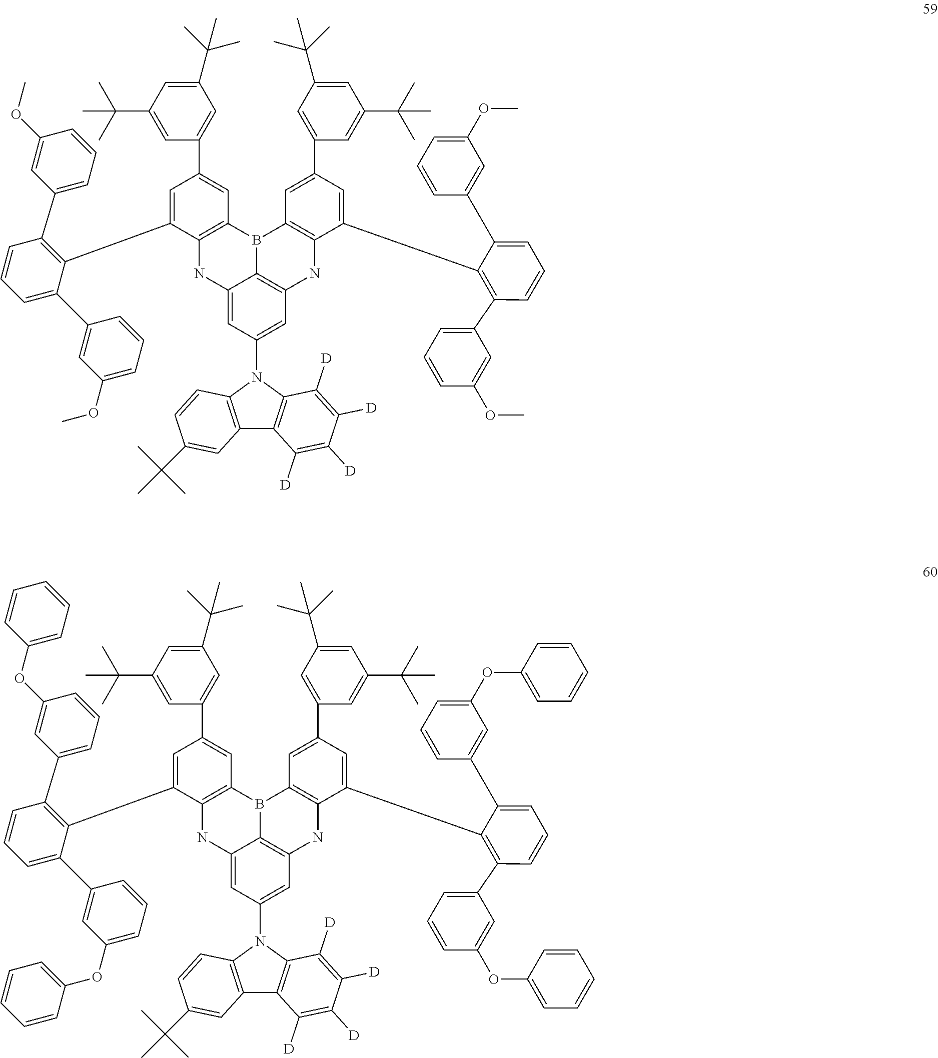 [SMILES: [2H]c1c([2H])c([2H])c2c(c1[2H])c1cc(C(C)(C)C)ccc1n2-c1cc2c3c(c1)Nc1c(cc(-c4cc(C(C)(C)C)cc(C(C)(C)C)c4)cc1-c1c(-c4cccc(OC)c4)cccc1-c1cccc(OC)c1)B3c1cc(-c3cc(C(C)(C)C)cc(C(C)(C)C)c3)cc(-c3c(-c4cccc(OC)c4)cccc3-c3cccc(OC)c3)c1N2 ; [2H]c1c([2H])c([2H])c2c(c1[2H])c1cc(C(C)(C)C)ccc1n2-c1cc2c3c(c1)Nc1c(cc(-c4cc(C(C)(C)C)cc(C(C)(C)C)c4)cc1-c1c(-c4cccc(Oc5ccccc5)c4)cccc1-c1cccc(Oc4ccccc4)c1)B3c1cc(-c3cc(C(C)(C)C)cc(C(C)(C)C)c3)cc(-c3c(-c4cccc(Oc5ccccc5)c4)cccc3-c3cccc(Oc4ccccc4)c3)c1N2]

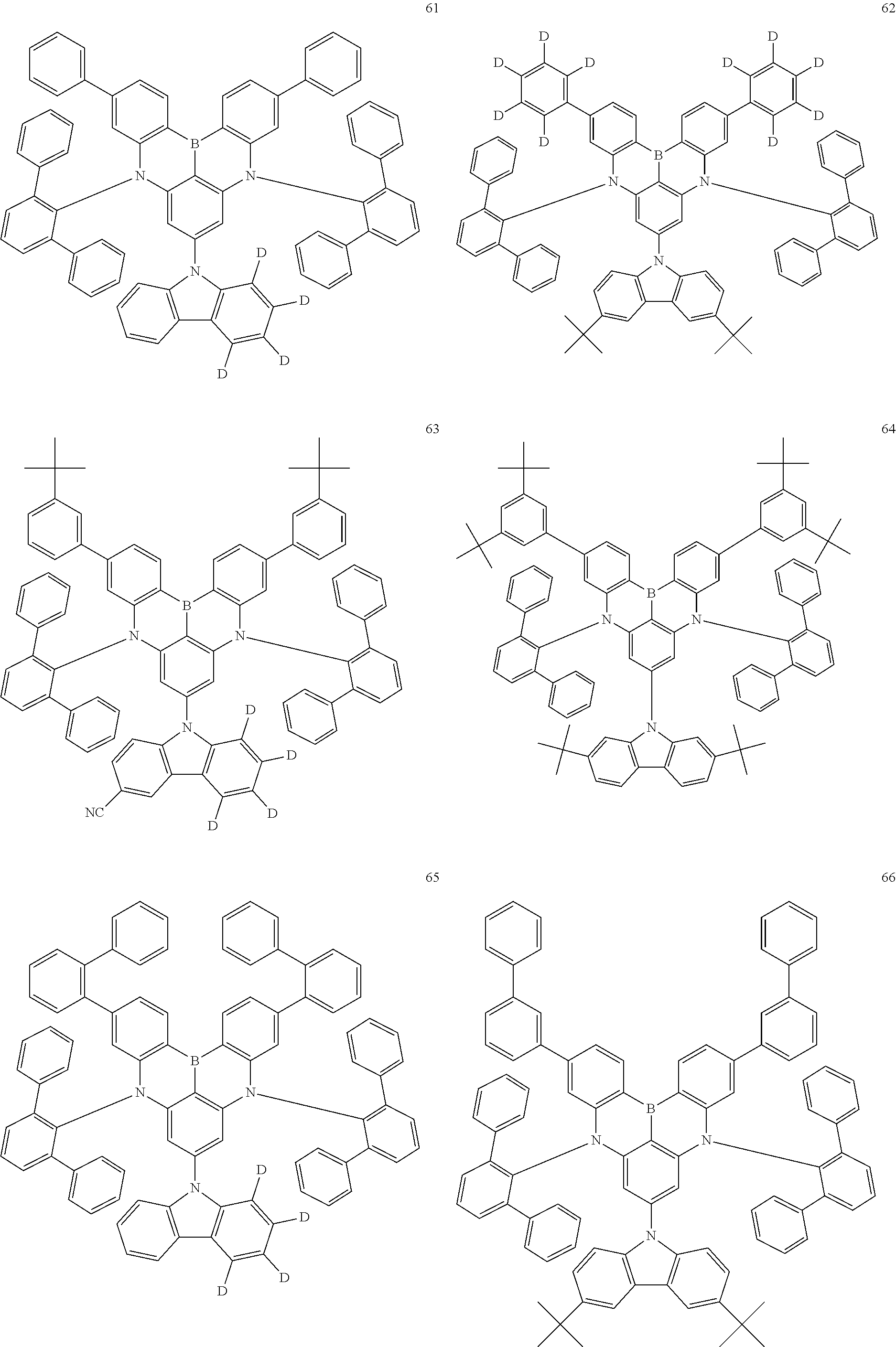

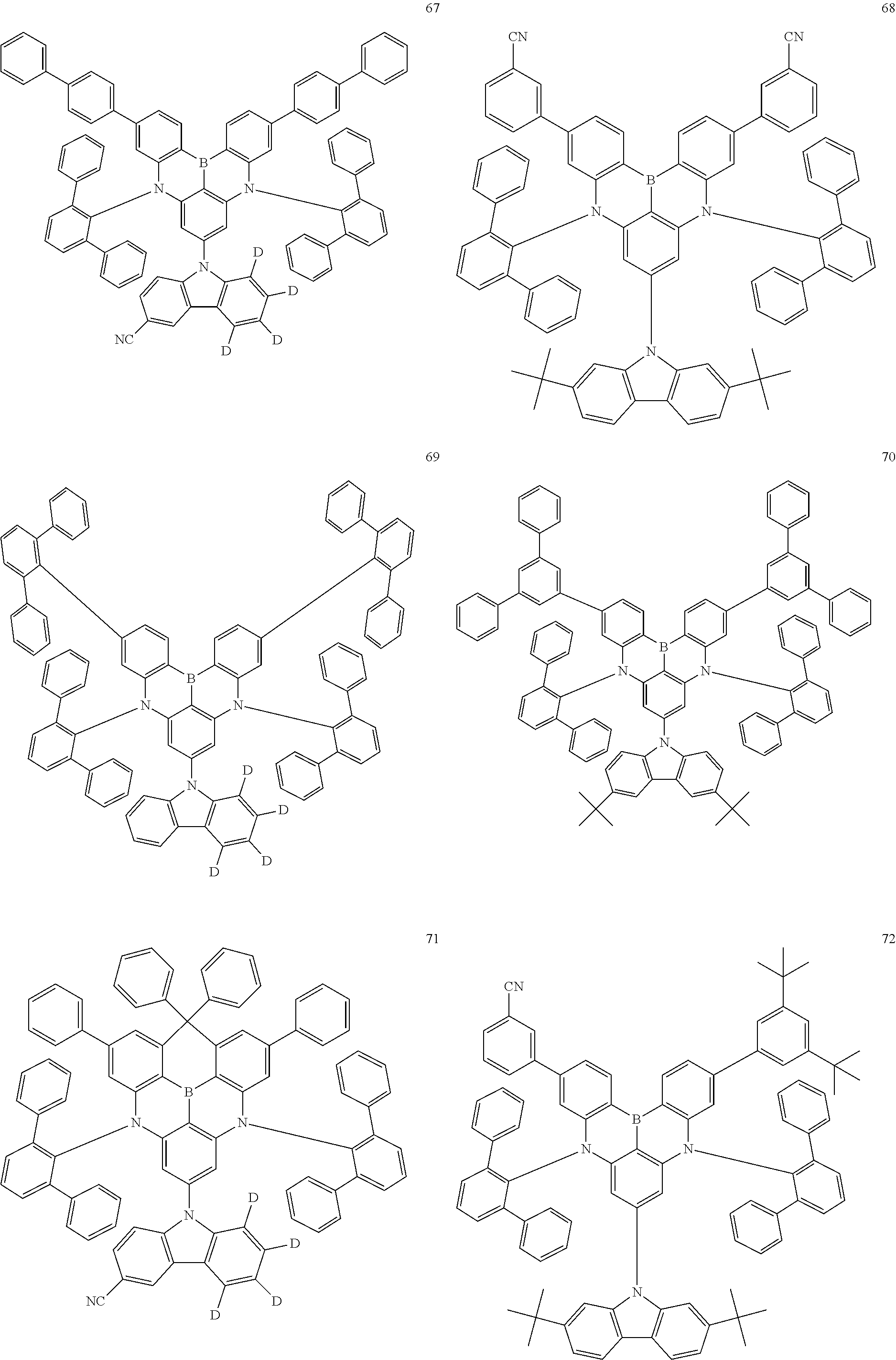

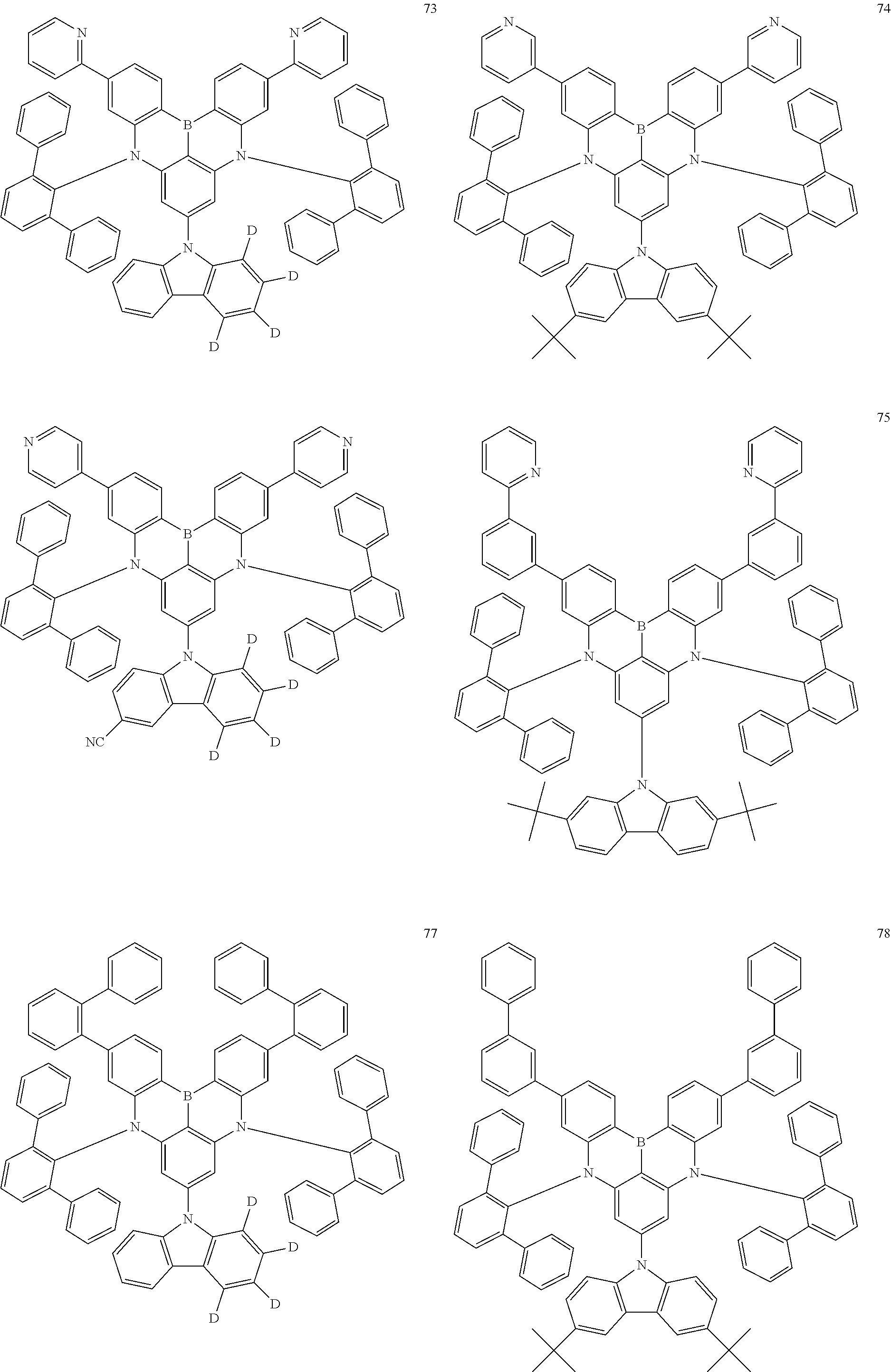

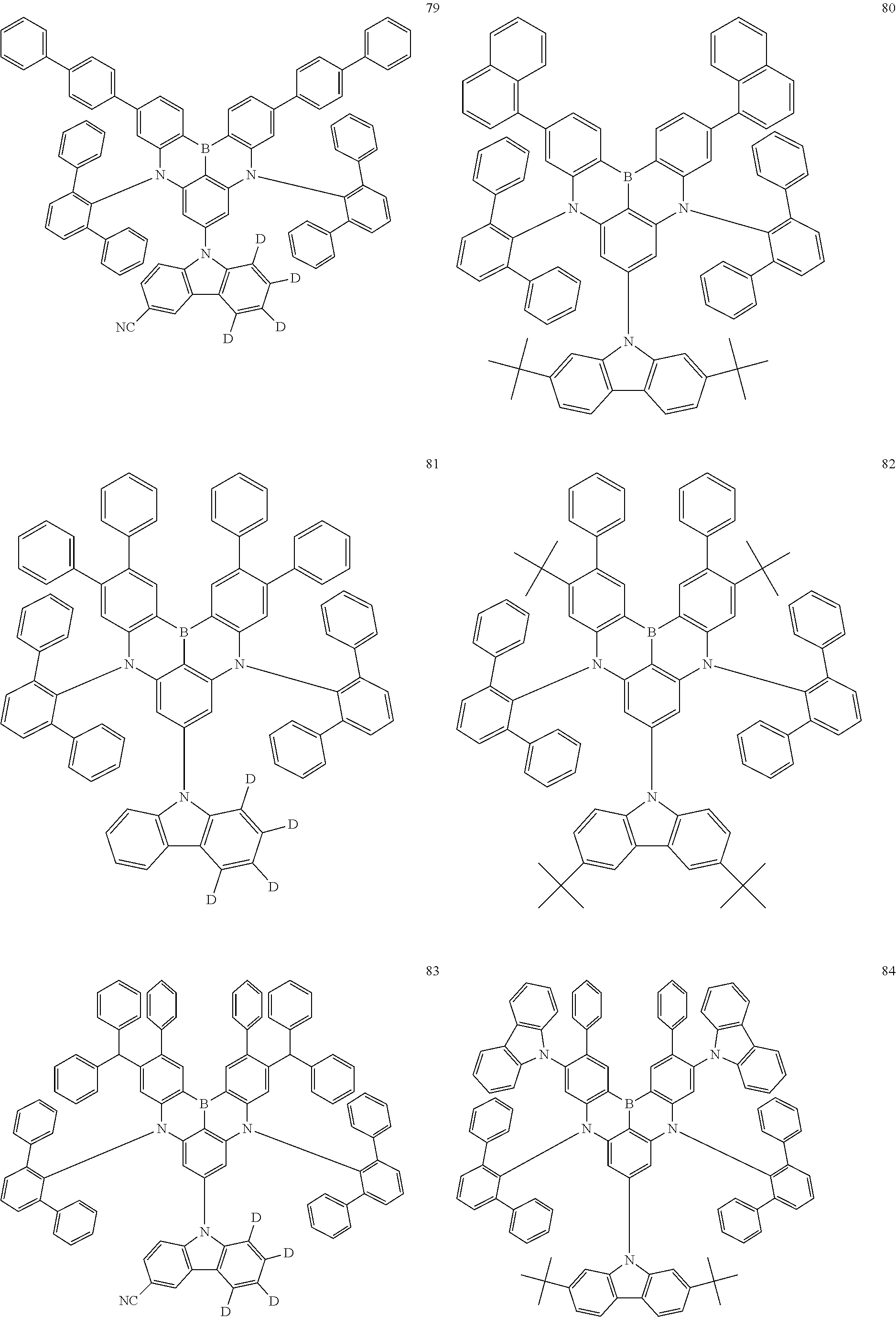

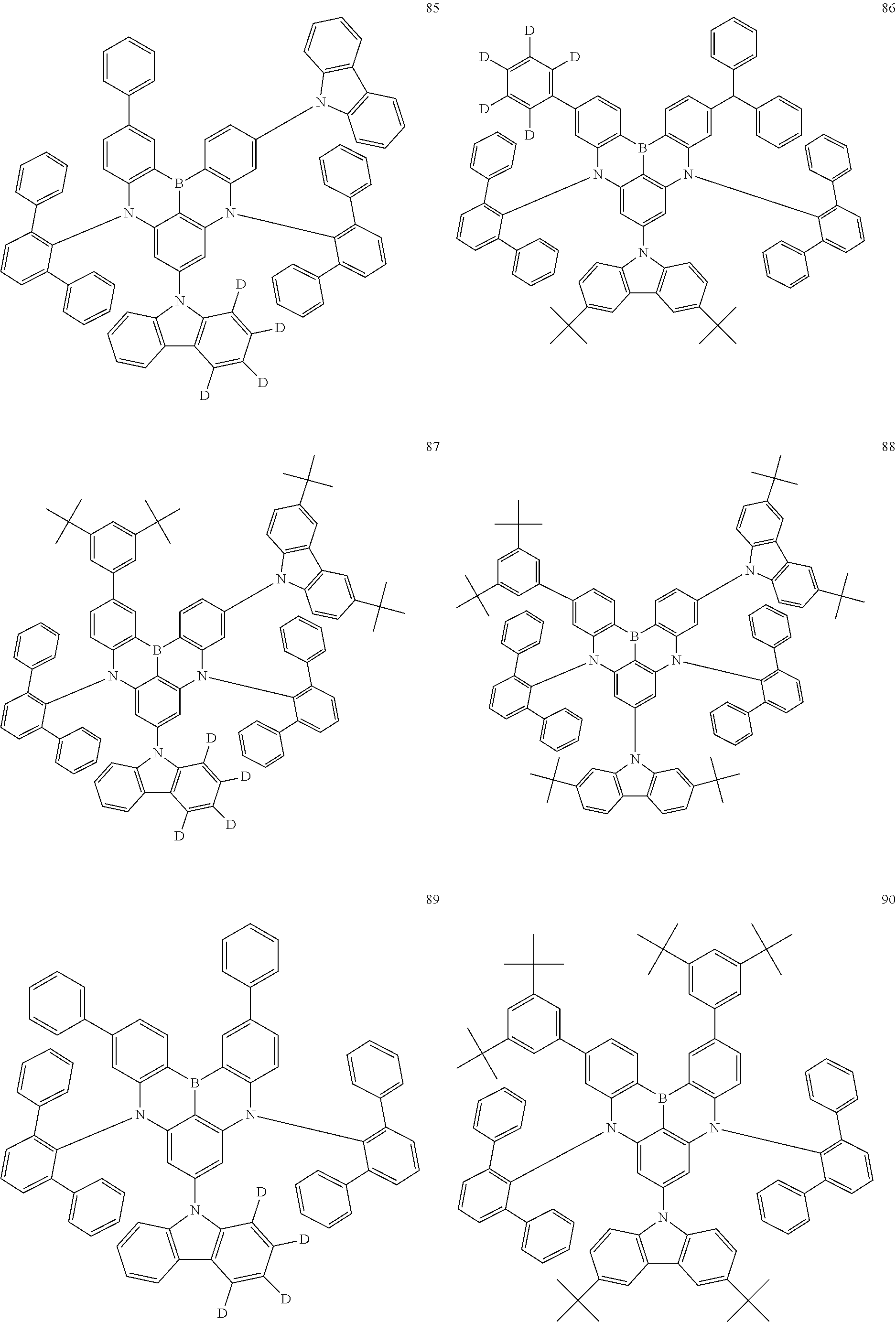

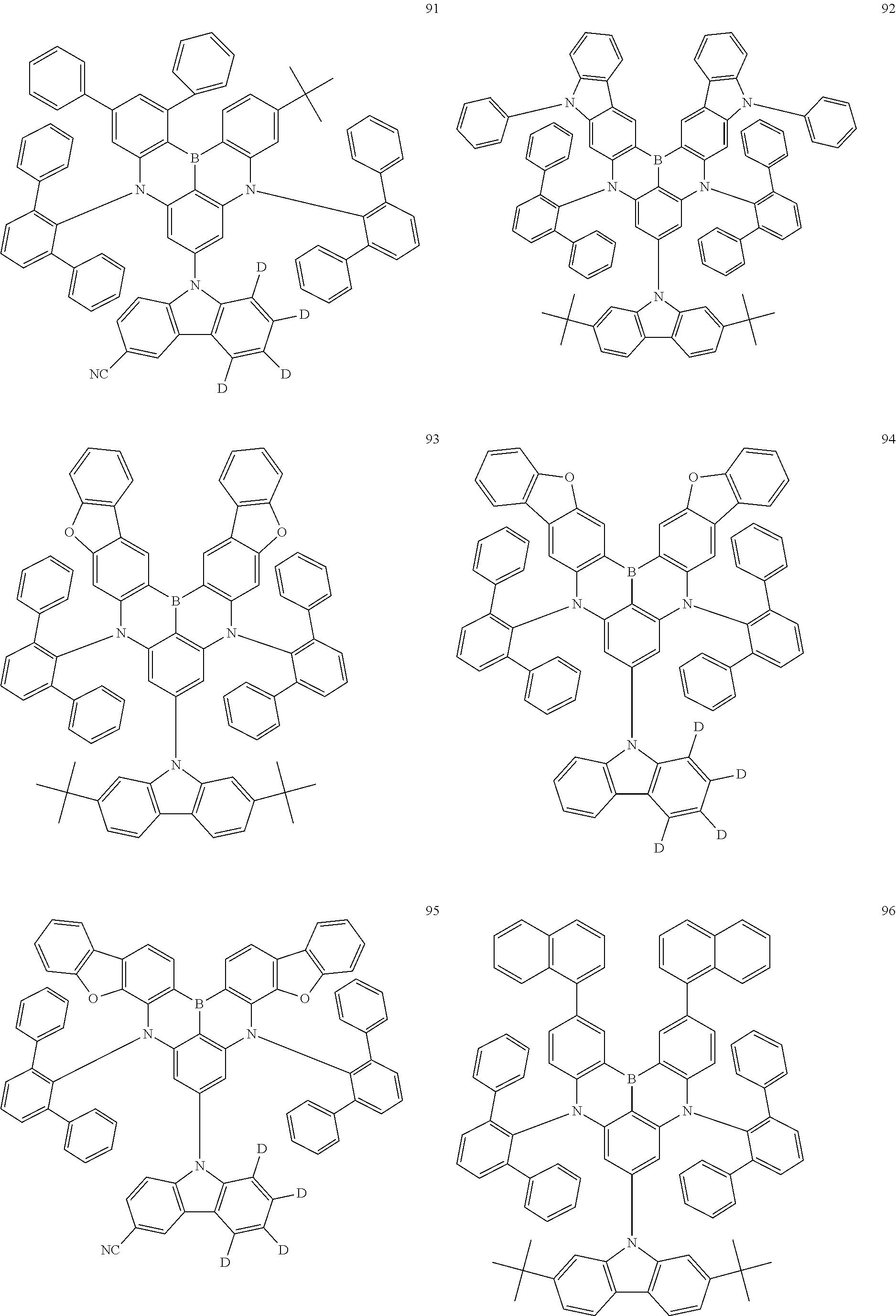

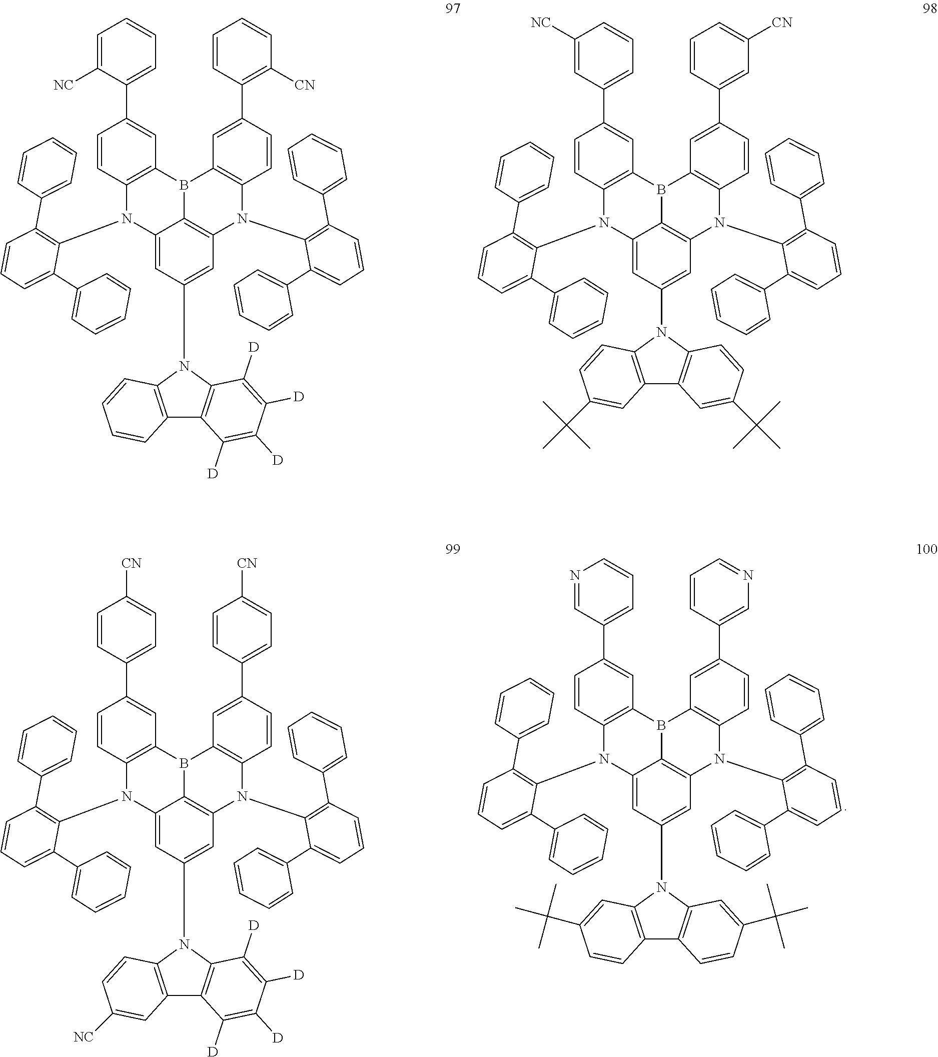

In Compound Group 1, D represents a deuterium atom.

An emission spectrum of the first compound represented by Formula 1 may have a full width at half maximum (FWHM) in a range of about 10 nm to about 50 nm. For example, an emission spectrum of the first compound represented by Formula 1 may have a FWHM in a range of about 20 nm to about 40 nm. The emission spectrum of the first compound represented by Formula 1 has a full width at half maximum in the above-described range, and if applied to a device, emission efficiency may be improved. If the first compound represented by Formula 1 is applied as a blue light emitting material for a light emitting device, device life may be improved.

The first compound represented by Formula 1 may be a material emitting thermally activated delayed fluorescence (TADF). The first compound represented by Formula 1 may be a thermally activated delayed fluorescence (TADF) dopant having a difference (ΔE_{ST}) between a lowest excitation triplet energy level (T1) and a lowest excitation singlet energy level (Si) equal to or less than about 0.3 eV. For example, the ΔE_{ST} of the first compound represented by Formula 1 may be equal to or less than about 0.22 eV.

The first compound represented by Formula 1 may be a light emitting material having a central wavelength emitted light in a range of about 430 nm to about 470 nm. For example, the first compound represented by Formula 1 may be a blue thermally activated delayed fluorescence (TADF) dopant. However, embodiments are not limited thereto, and if the first compound used as a light emitting material, the first compound may be used as a dopant material emitting light in various wavelength regions, such as a red emitting dopant or a green emitting dopant.

In the light emitting device ED according to an embodiment, the emission layer EML may emit delayed fluorescence. For example, the emission layer EML may emit thermally activated delayed fluorescence (TADF).

The emission layer EML of the light emitting device ED may emit blue light. For example, the emission layer EML of the light emitting device ED according to an embodiment may emit blue light having a central wavelength in a range of about 430 nm to about 470 nm. However, embodiments are not limited thereto, and the emission layer EML may emit blue light having a wavelength greater than about 470 nm, or may emit green light or red light.

In the light emitting device ED according to an embodiment, the emission layer EML may include a host for emitting delayed fluorescence and a dopant for emitting delayed fluorescence, and may further include the first compound as a dopant for emitting delayed fluorescence. The emission layer EML may include at least one compound selected from Compound Group 1 as a thermally activated delayed fluorescence dopant.

In the light emitting device ED, the emission layer EML may include a host. The host may not emit light in the light emitting device ED but may transfer energy to a dopant. The emission layer EML may include one or more types of hosts. For example, the emission layer EML may include two different types of hosts. If the emission layer EML includes two types of hosts, the two types of hosts may include a hole transport host and an electron transport host. However, embodiments are not limited thereto, and the emission layer EML may include one type of a host, or a mixture of two or more types of different hosts.

In an embodiment, the emission layer EML may include two different types of hosts. The host may include a second compound, and a third compound which is different from the second compound. The host may include the second compound as a hole transport host, and the third compound as an electron transport host. In the light emitting device ED, the hole transport host and the electron transport host may form an exciplex. A triplet energy of the exciplex formed by the hole transport host and the electron transport host may correspond to a T1 gap of a lowest unoccupied molecular orbital (LUMO) energy level and a highest occupied molecular orbital (HOMO) energy level.

In the light emitting device, a lowest triplet excitation energy level (T1) formed by the hole transport host and the electron transport host may be in a range of about 2.4 eV to about 3.0 eV.

A lowest excitation triplet energy level (T1) of the exciplex may be a smaller value than an energy gap of each host material. Accordingly, the exciplex may have a lowest excitation triplet energy level (T1) equal to or less than about 3.0 eV, which is the energy gap between the hole transport host and the electron transport host.

In an embodiment, the host may include a second compound represented by Formula 2, and a third compound represented by Formula 3. The second compound may be a hole transport host, and the third compound may be an electron transport host.

The emission layer EML according to an embodiment may include a second compound including a carbazole group-derived moiety. The second compound may be represented by Formula 2:

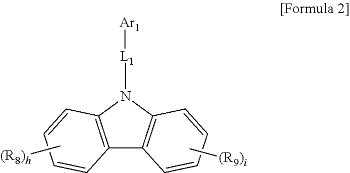

In Formula 2, L₁ may be a direct linkage, a substituted or unsubstituted arylene group of 6 to 30 ring-forming carbon atoms, or a substituted or unsubstituted heteroarylene group of 2 to 30 ring-forming carbon atoms. In Formula 2, Ar₁ may be a substituted or unsubstituted aryl group of 6 to 30 ring-forming carbon atoms, or a substituted or unsubstituted heteroaryl group of 2 to 30 ring-forming carbon atoms.

In Formula 2, R₈ and R₉ may each independently be a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring. For example, R₈ and R₉ may each independently be a hydrogen atom or a deuterium atom.

In Formula 2, h and i may each independently be an integer from 0 to 4. If h and i are each 2 or more, multiple R₈ groups and multiple R₉ groups may be all the same, or at least one thereof may be different. For example, in Formula 2, h and i may each be 0. If h and i are each 0, the carbazole group of Formula 2 may be unsubstituted at each of the benzo rings.

In an embodiment, in Formula 2, L₁ may be a direct linkage, a phenylene group, a divalent biphenyl group, a divalent carbazole group, etc., but embodiments are not limited thereto. In an embodiment, in Formula 2, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In the light emitting device ED according to an embodiment, the emission layer EML may include a compound represented by Formula 3 as the third compound:

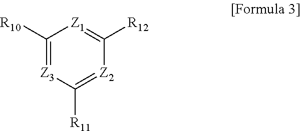

In Formula 3, at least one of Z₁ to Z₃ may each be N, and the remainder of Z₁ to Z₃ may each independently be C(R₁₃). Thus, the third compound represented by Formula 3 may include a pyridine moiety, a pyrimidine moiety, or a triazine moiety.

In Formula 3, R₁₀ to R₁₃ may each independently be a hydrogen atom, a deuterium atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring.

In an embodiment, in Formula 3, R₁₀ to R₁₃ may each independently be a substituted or unsubstituted phenyl group, a substituted or unsubstituted carbazole group, etc., but embodiments are not limited thereto.

If the emission layer EML of the light emitting device ED of an embodiment includes the second compound represented by Formula 2 and the third compound represented by Formula 3, excellent emission efficiency and long-life characteristics may be shown. In the emission layer EML of the light emitting device ED according to an embodiment, a host may be an exciplex formed by the second compound represented by Formula 2 and the third compound represented by Formula 3.

Among two host materials included in the emission layer EML, the second compound may be a hole transport host, and the third compound may be an electron transport host. The light emitting device ED may include both the second compound having excellent hole transport properties and the third compound having excellent electron transport properties in the emission layer EML, to enable efficient energy transfer to a dopant compound, which will be explained later.

The light emitting device ED according to an embodiment may further include a fourth compound in the emission layer EML, in addition to the first compound represented by Formula 1. The emission layer EML may include an organometallic complex including platinum (Pt) as a central metal atom and ligands bonded to the central metal atom as the fourth compound. In the light emitting device ED, the emission layer EML may include a fourth compound represented by Formula 4:

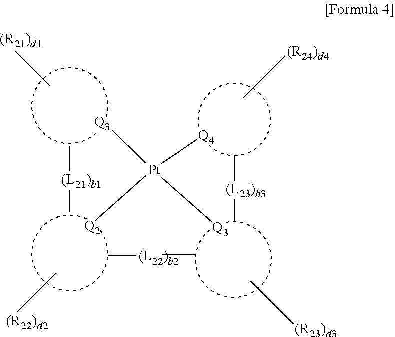

In Formula 4, Q₁ to Q₄ may each independently be C or N.

In Formula 4, C1 to C4 may each independently be a substituted or unsubstituted hydrocarbon ring of 5 to 30 ring-forming carbon atoms, or a substituted or unsubstituted heterocycle of 2 to 30 ring-forming carbon atoms.

In Formula 4, L₂₁ to L₂₃ may each independently be a direct linkage,

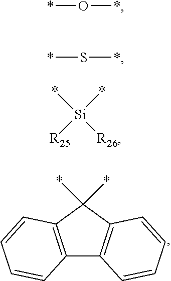

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₂₁ to L₂₃, [symbol] represents a bonding site to one of C1 to C4.

In Formula 4, b1 to b3 may each independently be 0 or 1. If b1 is 0, C1 and C2 may not be connected with each other. If b2 is 0, C2 and C3 may not be connected with each other. If b3 is 0, C3 and C4 may not be connected with each other.

In Formula 4, R₂₁ to R₂₆ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 1 to 30 ring-forming carbon atoms, or may be combined with an adjacent group to form a ring. For example, R₂₁ to R₂₆ may each independently be a methyl group or a t-butyl group.

In Formula 4, d1 to d4 may each independently be an integer from 0 to 4. If d1 to d4 are each 2 or more, multiple groups of each of R₂₁ to R₂₄ may all be the same, or at least one thereof may be different.

In an embodiment, in Formula 4, C1 to C4 may each independently be a substituted or unsubstituted hydrocarbon ring or a substituted or unsubstituted heterocycle, represented by any one of C-1 to C-3:

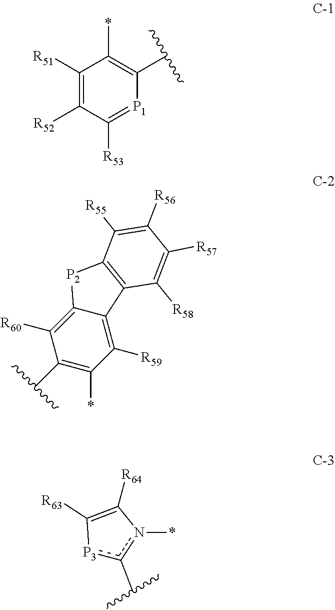

In C-1 to C-3, P₁ may be [symbol] or C(R₅₄), P₂ may be [symbol] or N(R₆₁), and P₃ may be [symbol] or N(R₆₂). In C-1 to C-3, R₁ to R₆₄ may each independently be a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring.

In C-1 to C-3,

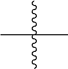

represents a bonding site to Pt that is a central metal atom, and [symbol] represents a bonding site to a neighboring cyclic group (C1 to C4) or to a linker (L₂₁ to L₂₃).

The fourth compound represented by Formula 4 may be a phosphorescence dopant.

In an embodiment, the first compound may be a light emitting dopant that emits blue light, and the emission layer EML may emit fluorescence. For example, the emission layer EML may emit delayed fluorescence as blue light.

In an embodiment, the fourth compound included in the emission layer EML may be a sensitizer. In the light emitting device ED according to an embodiment, the fourth compound included in the emission layer EML may function as a sensitizer, and may transfer energy from a host to the first compound that is a light emitting dopant. For example, the fourth compound may be auxiliary dopant that accelerates the transfer of energy to the first compound, which is a light emitting dopant, to increase the emission ratio of the first compound. Accordingly, the emission efficiency of the emission layer EML may be improved. If energy transfer to the first compound increases, the excitons formed in the emission layer EML may not accumulate in the emission layer EML but may rapidly emit light, and deterioration of the device may be reduced. Accordingly, the lifetime of the light emitting device ED may be improved.

In an embodiment, a weight ratio of the second compound to the third compound in the light emitting device ED may be in a range of about 4:6 to about 7:3. For example, a weight ratio of the second compound to the third compound may be about 4:6, about 5:5, about 6:4, or about 7:3. However, embodiments are not limited thereto. If the relative amounts of the second compound to the third compound satisfy the above-described ratios, charge balance properties in the emission layer EML may be improved, and emission efficiency and device life may increase. If the relative amounts of the second compound to the third compound deviate from the above-described ratios, charge balance in the emission layer EML may not be achieved, emission efficiency may be degraded, and the device may readily deteriorate.

The light emitting device ED according to an embodiment may include the first compound, the second compound, the third compound, and the fourth compound, and the emission layer EML may include two host materials and two dopant materials. In the light emitting device ED, the emission layer EML may include different two hosts, a first compound emitting delayed fluorescence, and a fourth compound including an organometallic complex, and may show excellent emission efficiency properties.

In an embodiment, the second compound represented by Formula 2 may be any compound selected from Compound Group 2. The emission layer EML may include at least one compound selected from Compound Group 2 as a hole transport host material:

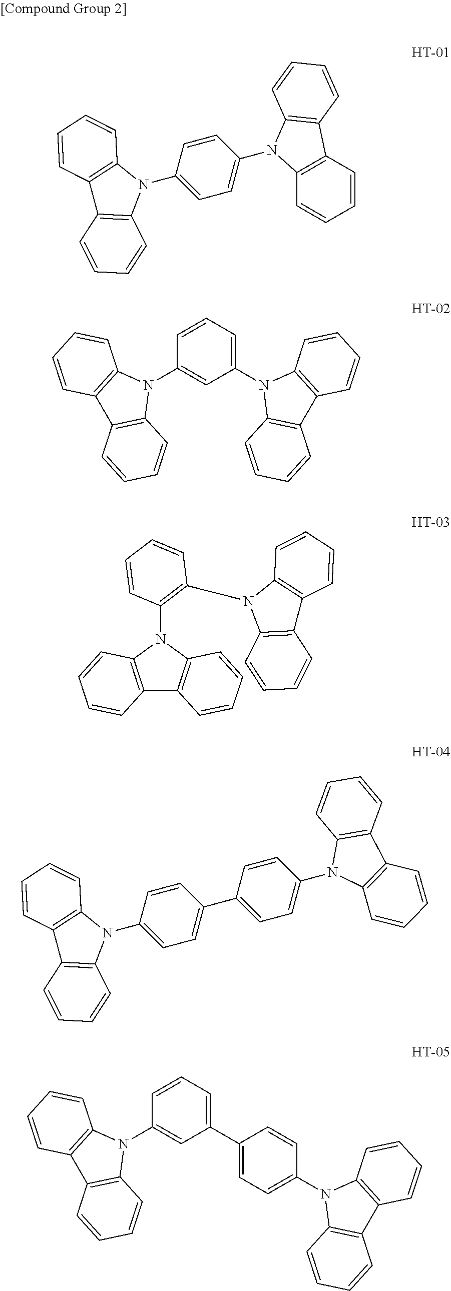 [SMILES: c1ccc2c(c1)c1ccccc1n2-c1ccc(-n2c3ccccc3c3ccccc32)cc1 ; c1cc(-n2c3ccccc3c3ccccc32)cc(-n2c3ccccc3c3ccccc32)c1 ; c1ccc(-n2c3ccccc3c3ccccc32)c(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2ccc(-n3c4ccccc4c4ccccc43)cc2)cc(-n2c3ccccc3c3ccccc32)c1]

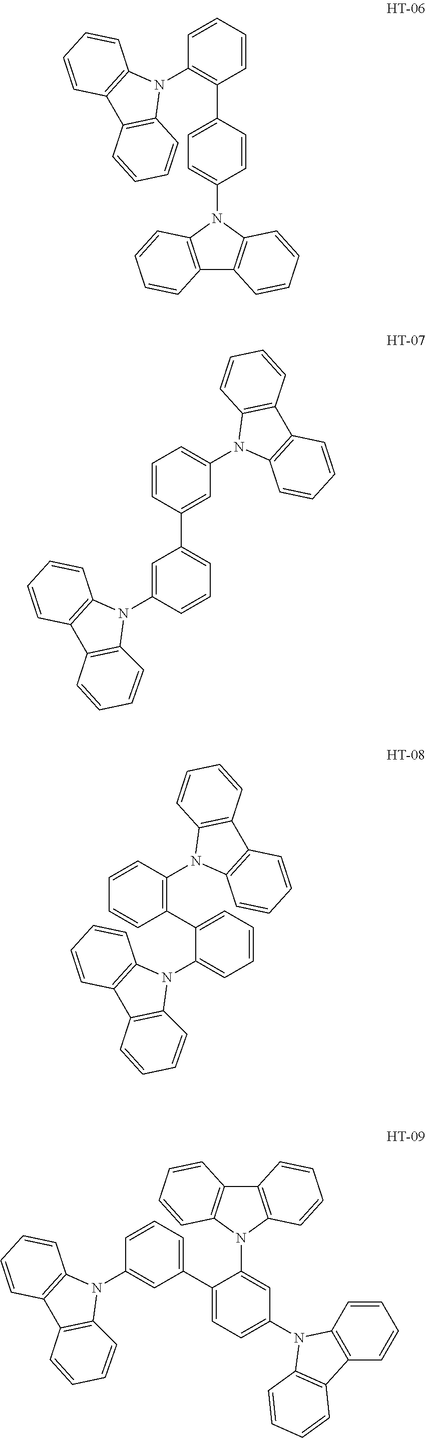 [SMILES: c1ccc(-n2c3ccccc3c3ccccc32)c(-c2ccc(-n3c4ccccc4c4ccccc43)cc2)c1 ; c1cc(-c2cccc(-n3c4ccccc4c4ccccc43)c2)cc(-n2c3ccccc3c3ccccc32)c1 ; c1ccc(-n2c3ccccc3c3ccccc32)c(-c2ccccc2-n2c3ccccc3c3ccccc32)c1 ; c1cc(-c2ccc(-n3c4ccccc4c4ccccc43)cc2-n2c3ccccc3c3ccccc32)cc(-n2c3ccccc3c3ccccc32)c1]

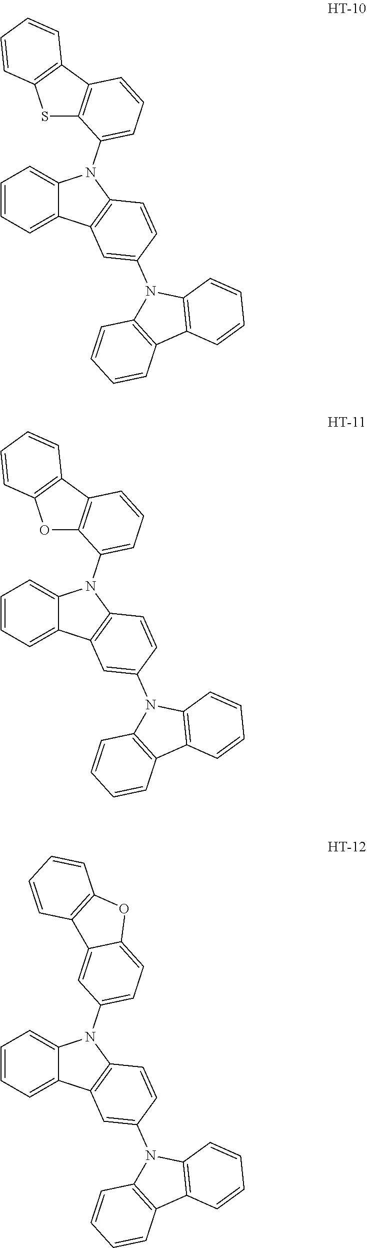 [SMILES: c1ccc2c(c1)sc1c(-n3c4ccccc4c4cc(-n5c6ccccc6c6ccccc65)ccc43)cccc12 ; c1ccc2c(c1)oc1c(-n3c4ccccc4c4cc(-n5c6ccccc6c6ccccc65)ccc43)cccc12 ; c1ccc2c(c1)oc1ccc(-n3c4ccccc4c4cc(-n5c6ccccc6c6ccccc65)ccc43)cc12]

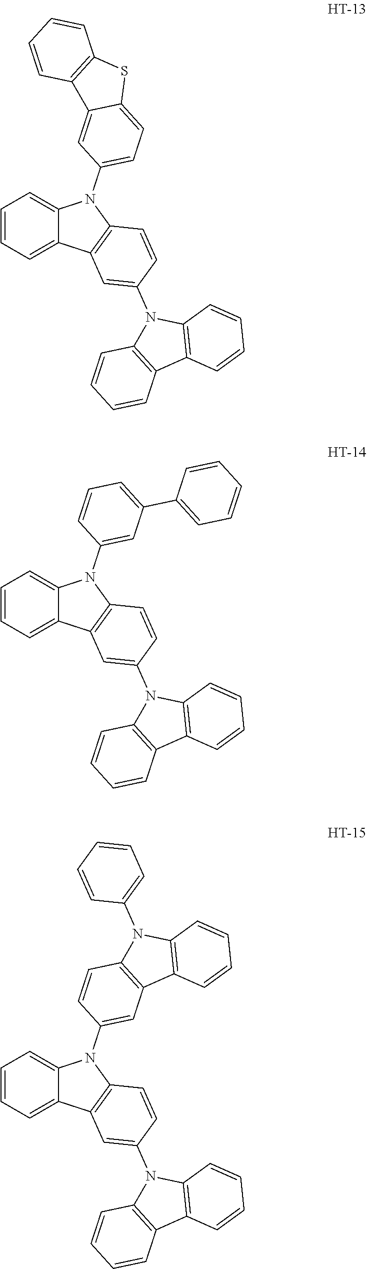 [SMILES: c1ccc2c(c1)sc1ccc(-n3c4ccccc4c4cc(-n5c6ccccc6c6ccccc65)ccc43)cc12 ; c1ccc(-c2cccc(-n3c4ccccc4c4cc(-n5c6ccccc6c6ccccc65)ccc43)c2)cc1 ; c1ccc(-n2c3ccccc3c3cc(-n4c5ccccc5c5cc(-n6c7ccccc7c7ccccc76)ccc54)ccc32)cc1]

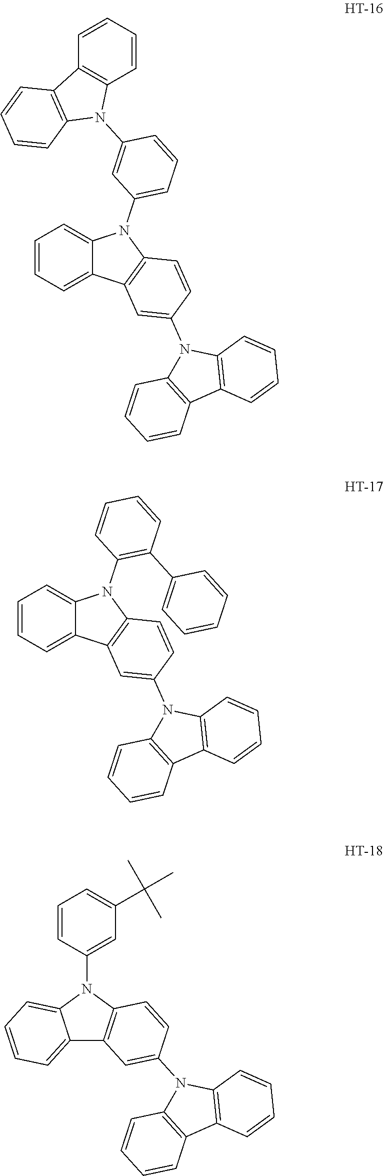 [SMILES: c1cc(-n2c3ccccc3c3ccccc32)cc(-n2c3ccccc3c3cc(-n4c5ccccc5c5ccccc54)ccc32)c1 ; c1ccc(-c2ccccc2-n2c3ccccc3c3cc(-n4c5ccccc5c5ccccc54)ccc32)cc1 ; CC(C)(C)c1cccc(-n2c3ccccc3c3cc(-n4c5ccccc5c5ccccc54)ccc32)c1]

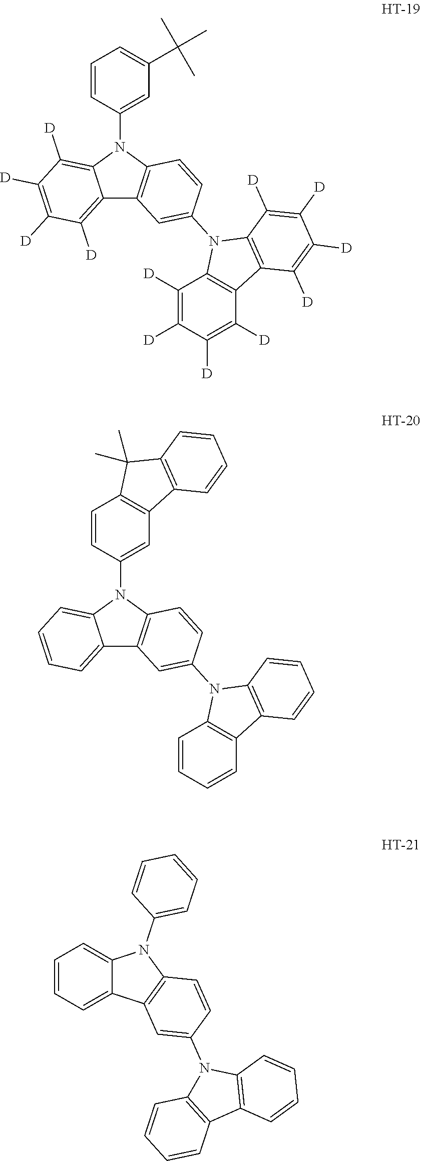 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; CC1(C)c2ccccc2-c2cc(-n3c4ccccc4c4cc(-n5c6ccccc6c6ccccc65)ccc43)ccc21 ; c1ccc(-n2c3ccccc3c3cc(-n4c5ccccc5c5ccccc54)ccc32)cc1]

In an embodiment, the third compound represented by Formula 3 may be any compound selected from Compound Group 3. The emission layer EML may include at least one compound selected from Compound Group 3 as an electron transport host material:

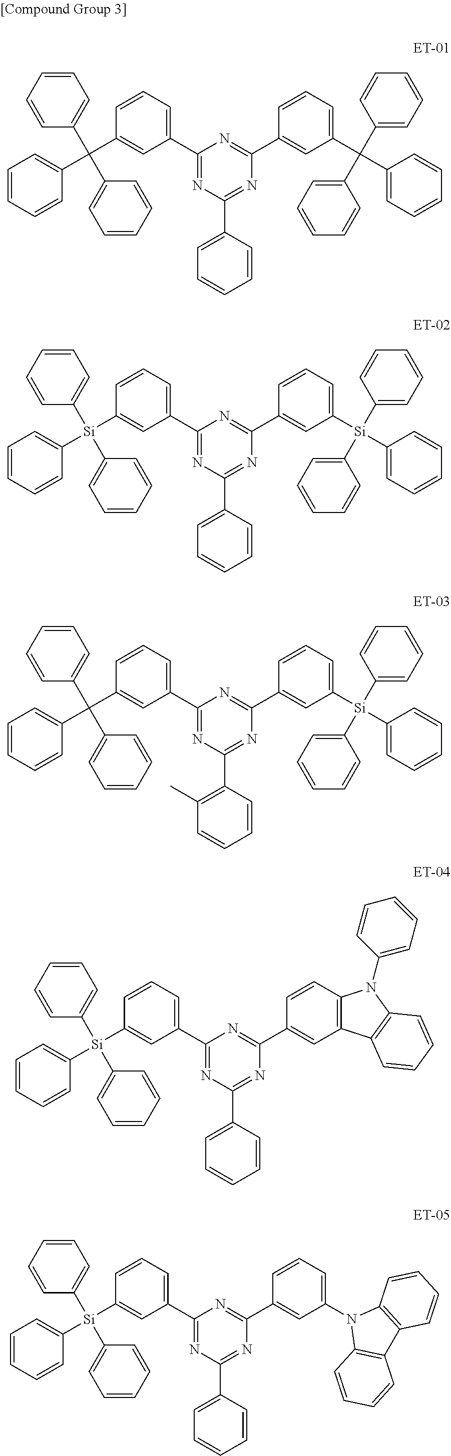

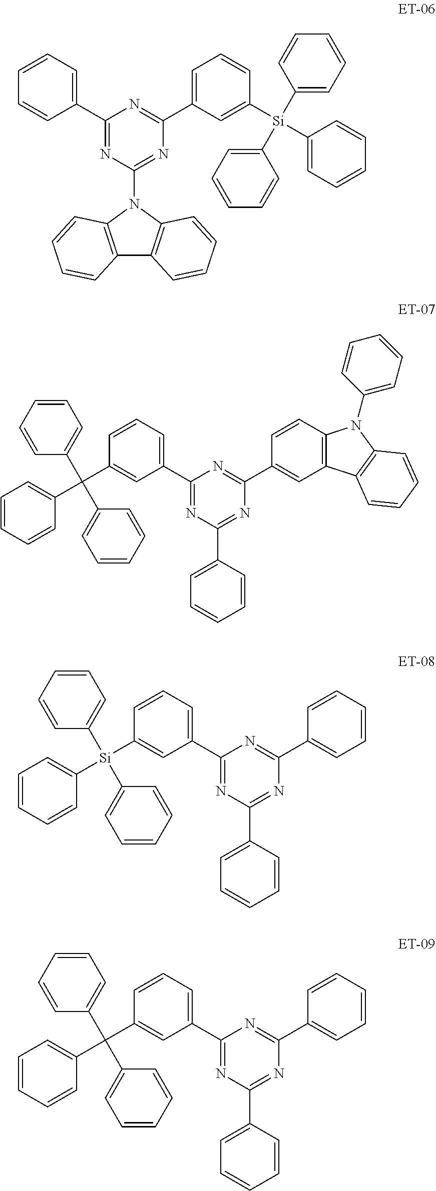 [SMILES: c1ccc(-c2nc(-c3cccc([Si](c4ccccc4)(c4ccccc4)c4ccccc4)c3)nc(-n3c4ccccc4c4ccccc43)n2)cc1 ; c1ccc(-c2nc(-c3cccc(C(c4ccccc4)(c4ccccc4)c4ccccc4)c3)nc(-c3ccc4c(c3)c3ccccc3n4-c3ccccc3)n2)cc1 ; c1ccc(-c2nc(-c3ccccc3)nc(-c3cccc([Si](c4ccccc4)(c4ccccc4)c4ccccc4)c3)n2)cc1 ; c1ccc(-c2nc(-c3ccccc3)nc(-c3cccc(C(c4ccccc4)(c4ccccc4)c4ccccc4)c3)n2)cc1]

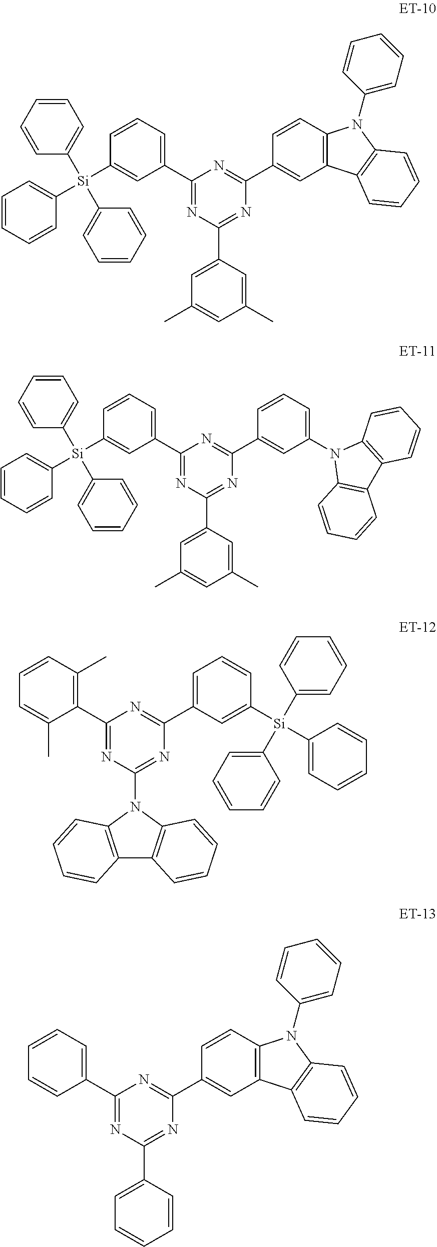 [SMILES: Cc1cc(C)cc(-c2nc(-c3cccc([Si](c4ccccc4)(c4ccccc4)c4ccccc4)c3)nc(-c3ccc4c(c3)c3ccccc3n4-c3ccccc3)n2)c1 ; Cc1cc(C)cc(-c2nc(-c3cccc(-n4c5ccccc5c5ccccc54)c3)nc(-c3cccc([Si](c4ccccc4)(c4ccccc4)c4ccccc4)c3)n2)c1 ; Cc1cccc(C)c1-c1nc(-c2cccc([Si](c3ccccc3)(c3ccccc3)c3ccccc3)c2)nc(-n2c3ccccc3c3ccccc32)n1 ; c1ccc(-c2nc(-c3ccccc3)nc(-c3ccc4c(c3)c3ccccc3n4-c3ccccc3)n2)cc1]

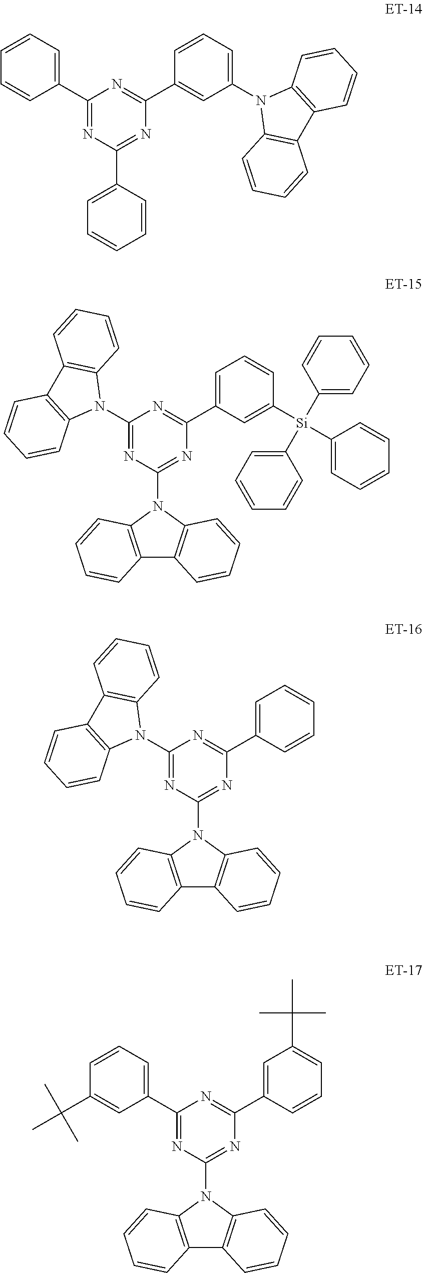 [SMILES: c1ccc(-c2nc(-c3ccccc3)nc(-c3cccc(-n4c5ccccc5c5ccccc54)c3)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In an embodiment, the fourth compound represented by Formula 4 may be any compound selected from Compound Group 4. The emission layer EML may include at least one compound selected from Compound Group 4 as a sensitizer material.

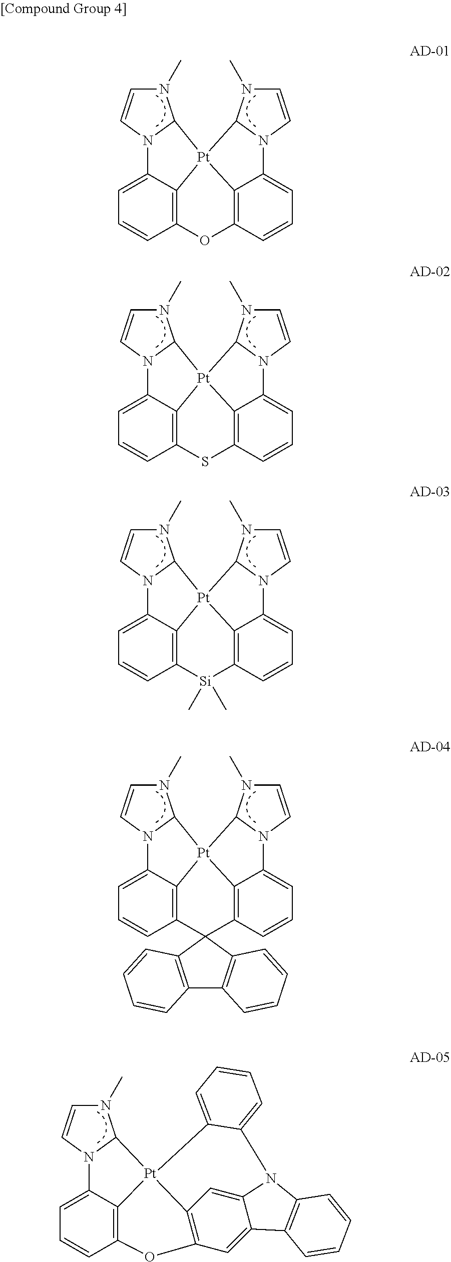

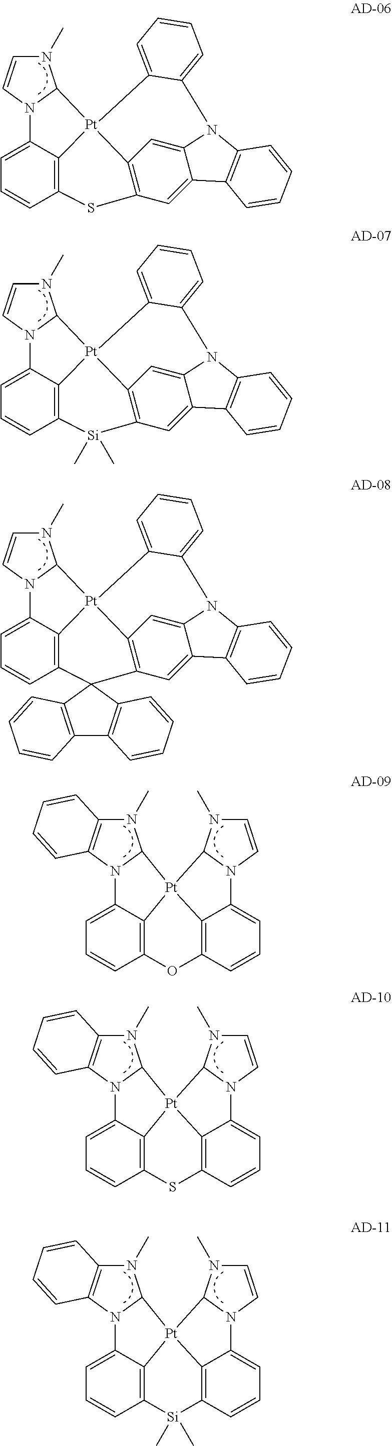

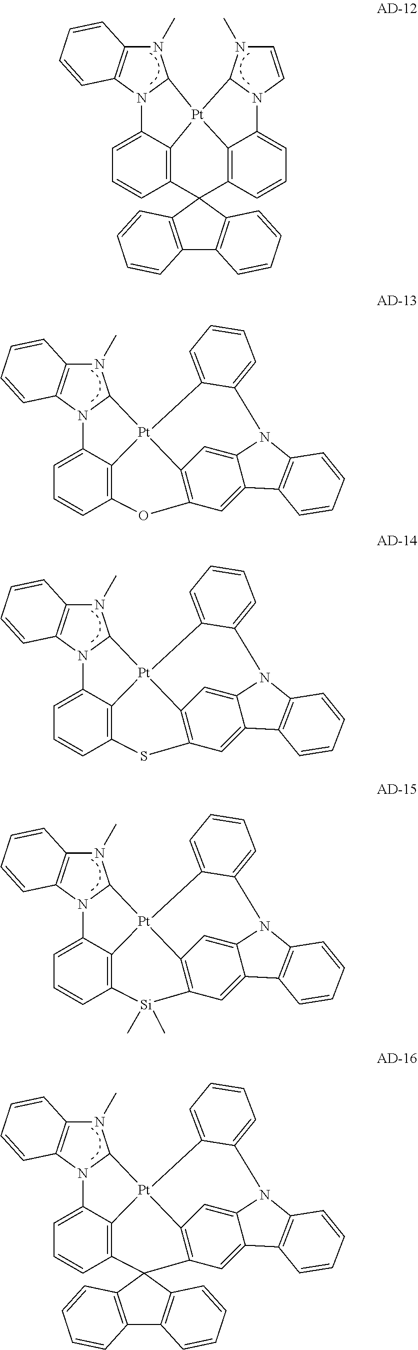

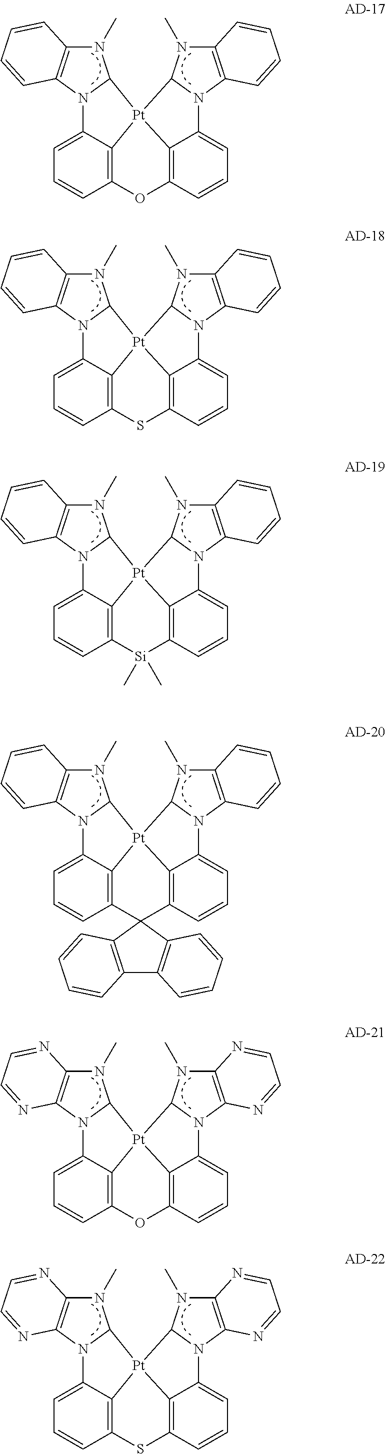

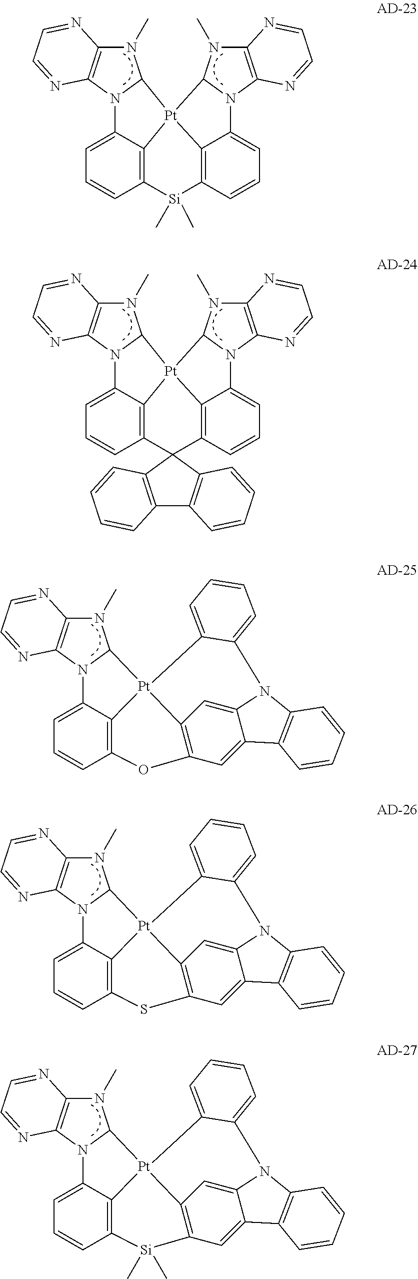

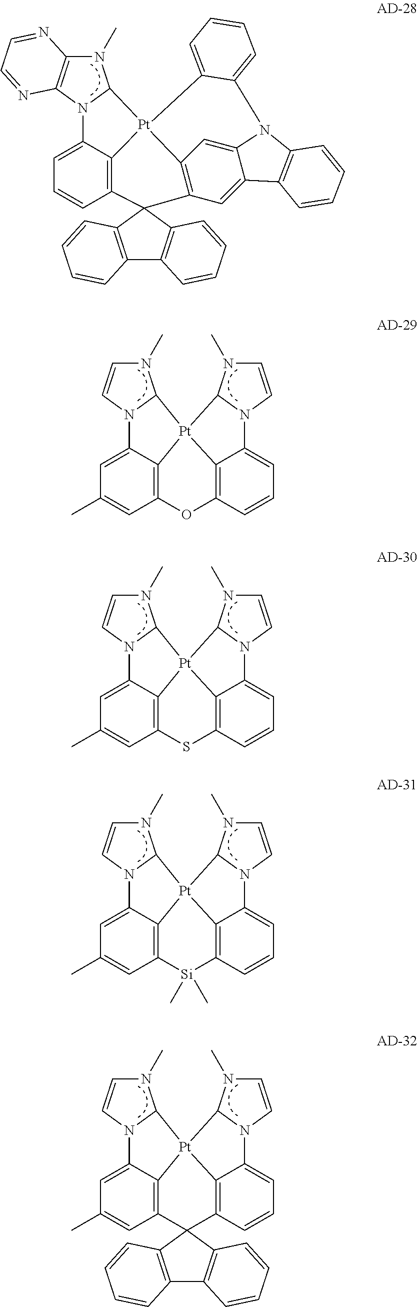

In an embodiment, the light emitting device ED may include multiple emission layers. The multiple emission layers may be provided by stacking in a thickness direction, and the light emitting device ED including multiple emission layers may emit white light. The light emitting device including multiple emission layers may be a light emitting device with a tandem structure. If the light emitting device ED includes multiple emission layers, at least one emission layer EML thereof may include the first compound, the second compound, the third compound, and the fourth compound, as described above.

In the light emitting device ED according to an embodiment, the emission layer EML may further include anthracene derivatives, pyrene derivatives, fluoranthene derivatives, chrysene derivatives, dihydrobenzanthracene derivatives, or triphenylene derivatives. For example, the emission layer EML may include anthracene derivatives or pyrene derivatives.

In the light emitting devices ED according to embodiments shown in FIG. 3 to FIG. 6, the emission layer EML may further include hosts and dopants of the related art, in addition to the above-described host and dopant. The emission layer EML may include a compound represented by Formula E-1. The compound represented by Formula E-1 may be used as a fluorescence host material:

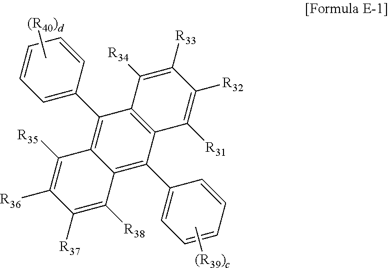

In Formula E-1, R₃₁ to R₄₀ may each independently be a hydrogen atom, a deuterium atom, a halogen atom, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring. For example, in Formula E-1, R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

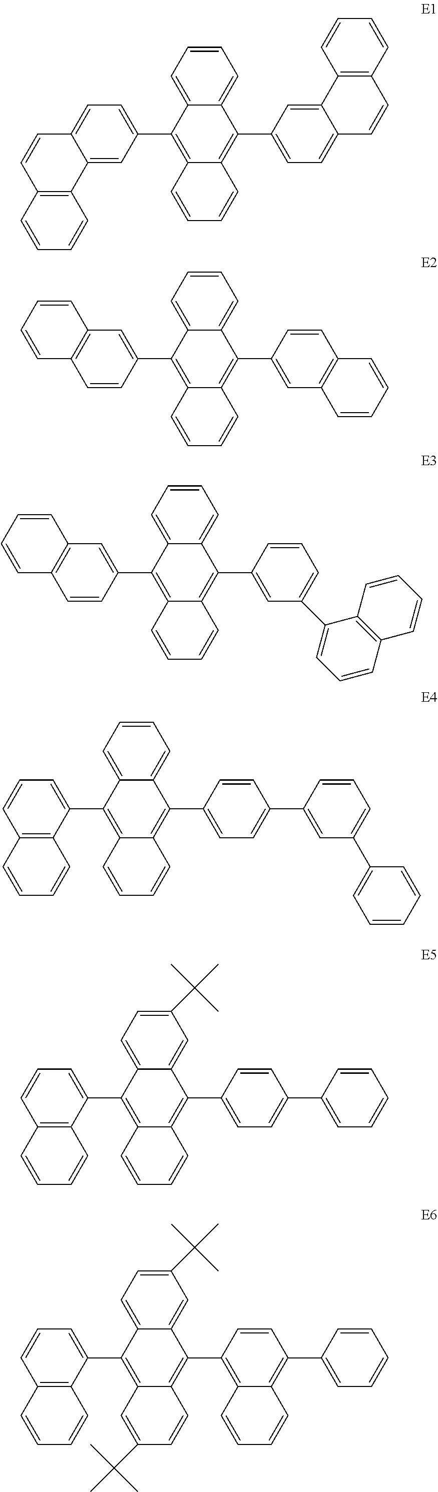

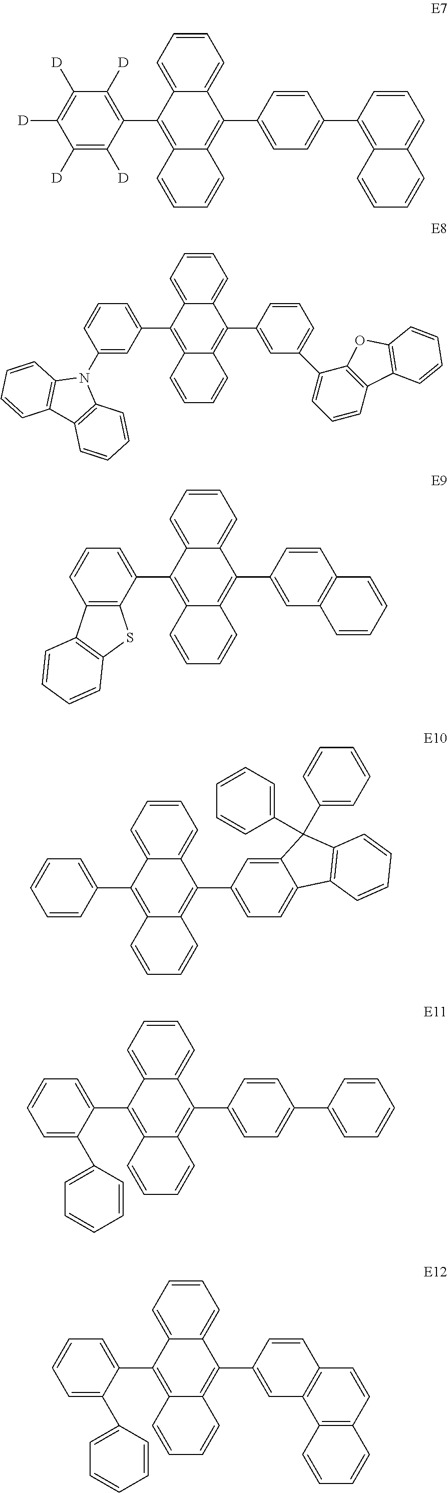

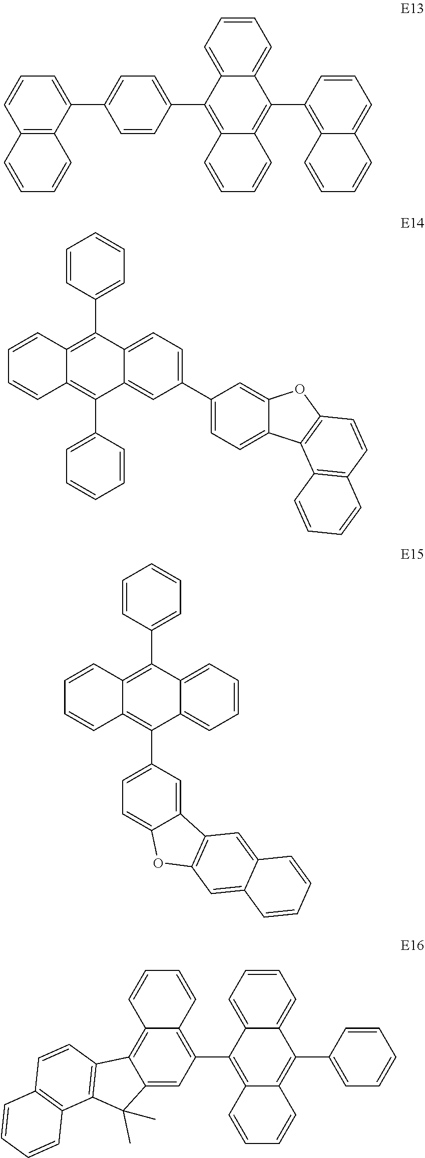

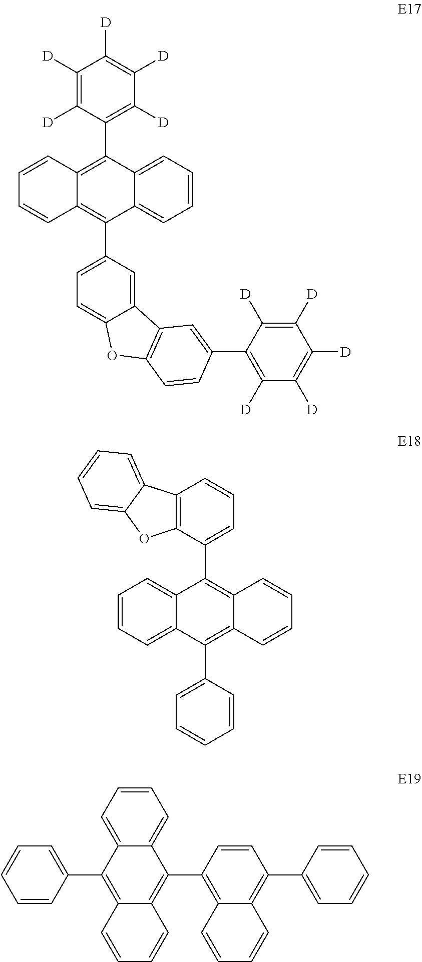

In an embodiment, the emission layer EML may include a compound represented by Formula E-2a or Formula E-2b. The compound represented by Formula E-2a or Formula E-2b may be used as a phosphorescence host material:

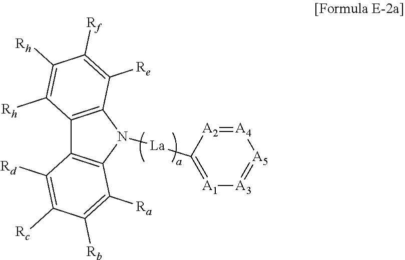

In Formula E-2a, a may be an integer from 0 to 10; and Lₐ may be a direct linkage, a substituted or unsubstituted arylene group of 6 to 30 ring-forming carbon atoms, or a substituted or unsubstituted heteroarylene group of 2 to 30 ring-forming carbon atoms. If a is 2 or more, multiple Lₐ groups may each independently be a substituted or unsubstituted arylene group of 6 to 30 ring-forming carbon atoms, or a substituted or unsubstituted heteroarylene group of 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring. For example, Rₐ to Rᵢ may be combined with an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

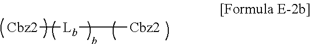

In Formula E-2b, Cbz1 and Cbz2 may each independently be an unsubstituted carbazole group, or a carbazole group substituted with an aryl group of 6 to 30 ring-forming carbon atoms. In Formula E-2b, L_{b} may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10, and if b is 2 or more, multiple L_{b} groups may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be any selected from Compound Group E-2. However, the compounds listed in Compound Group E-2 are only examples, and the compound represented by Formula E-2a or Formula E-2b is not limited to Compound Group E-2:

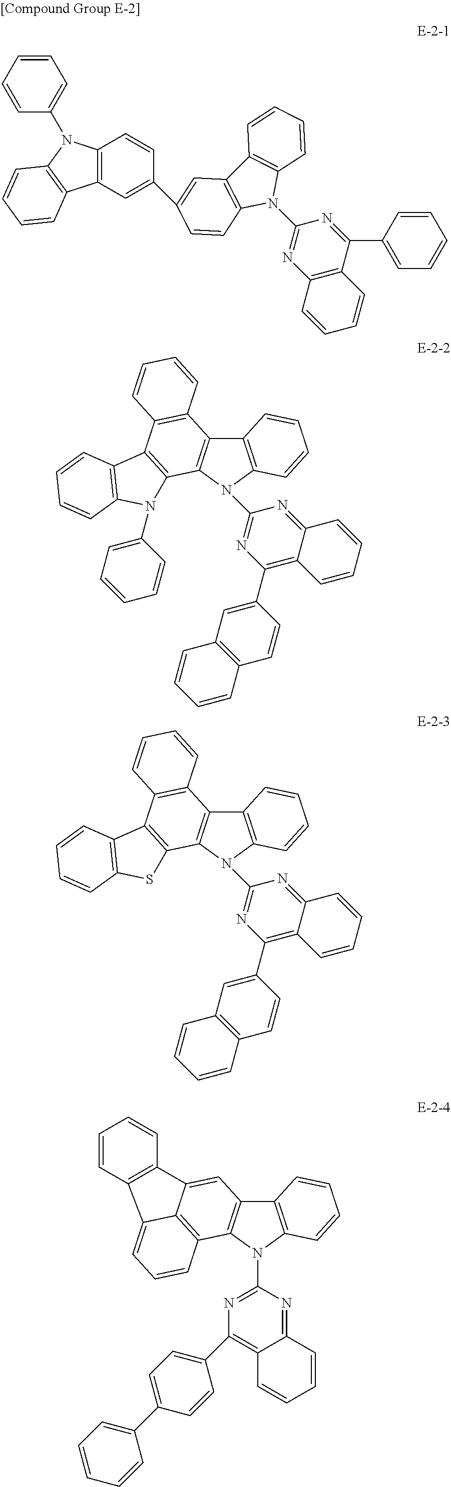

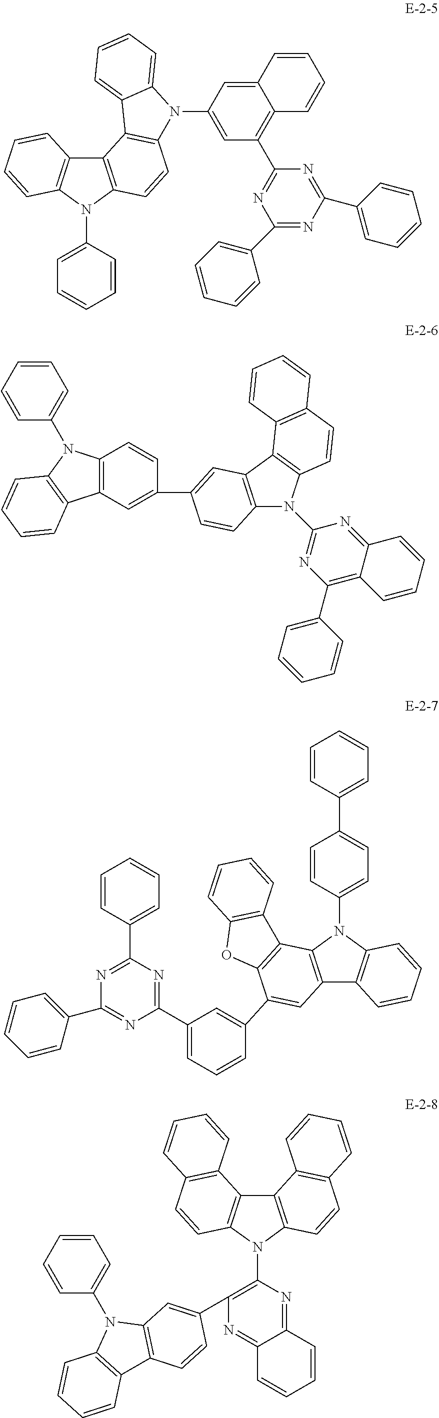

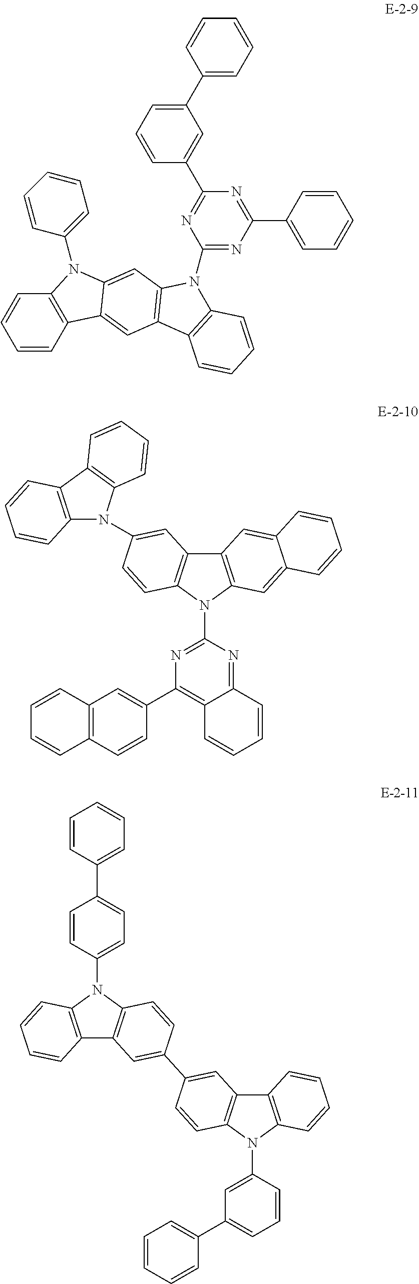 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

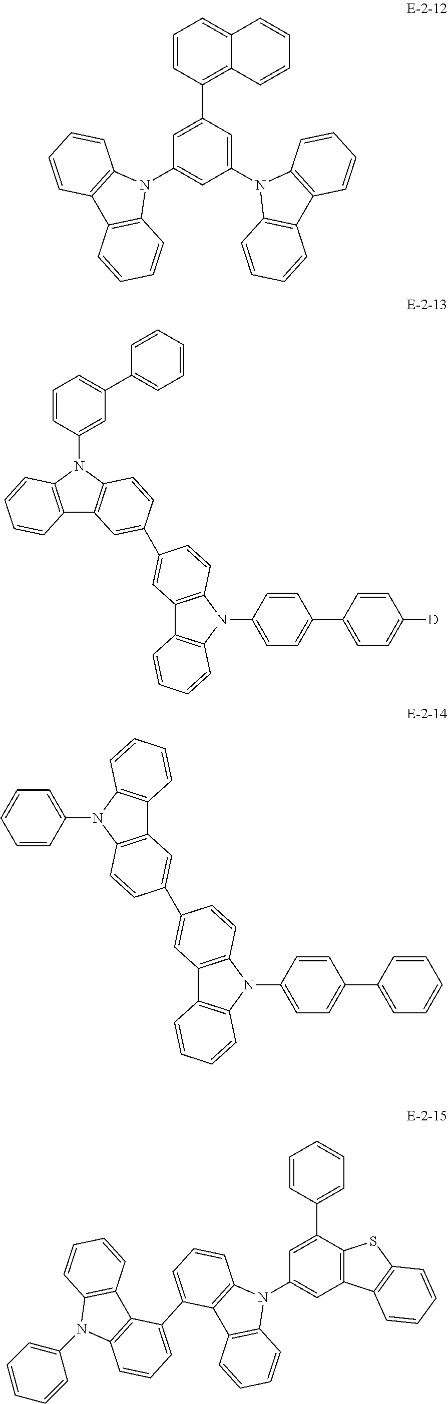 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

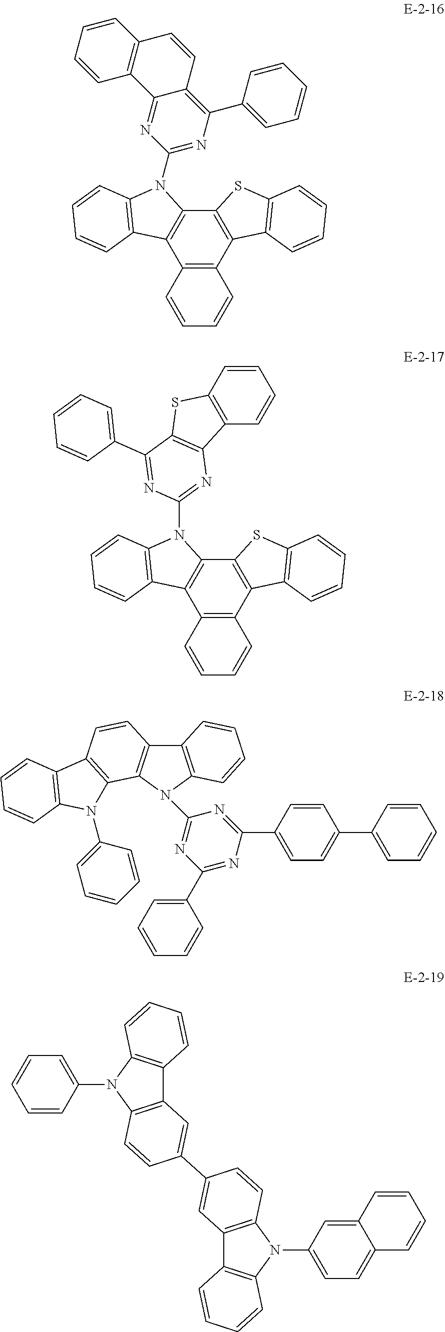

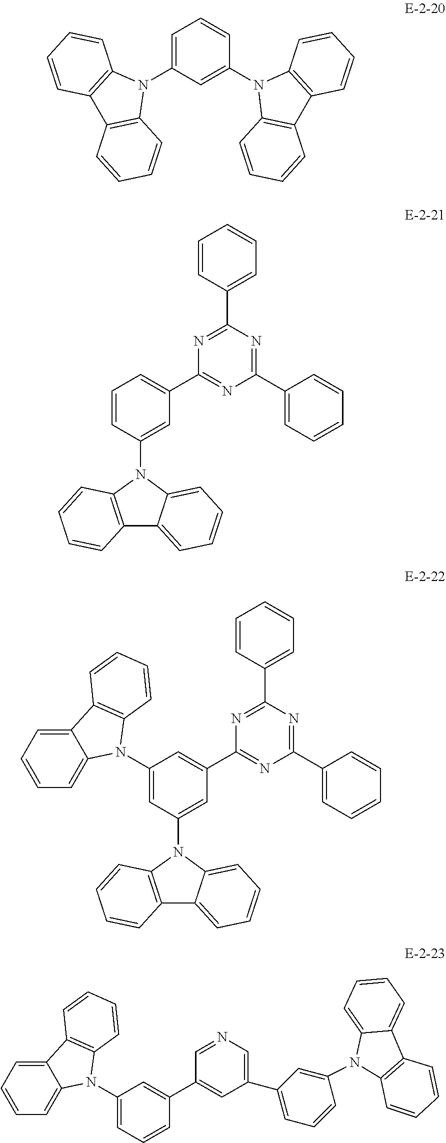 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

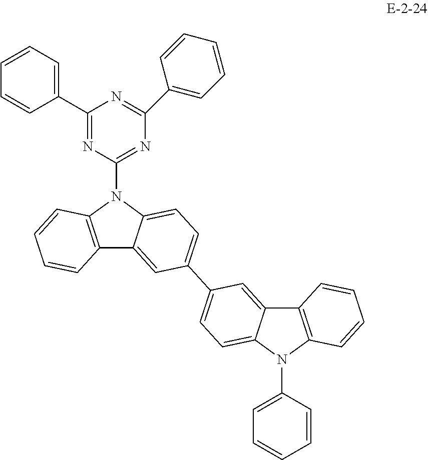 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

The emission layer EML may include a compound represented by Formula M-a. The compound represented by Formula M-a may be used as a phosphorescence dopant material:

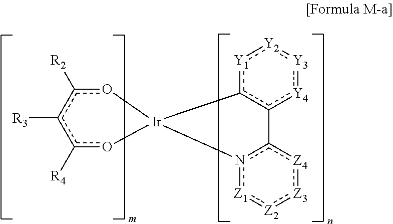

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring. In Formula M-a, m may be 0 or 1, and n may be 2 or 3. In Formula M-a, if m is 0, n may be 3, and if m is 1, n may be 2.

The compound represented by Formula M-a may be used as a phosphorescence dopant.

The compound represented by Formula M-a may be any compound selected from Compounds M-a1 to M-a25. However, Compounds M-a1 to M-a25 are only examples, and the compound represented by Formula M-a is not limited to Compounds M-a1 to M-a25:

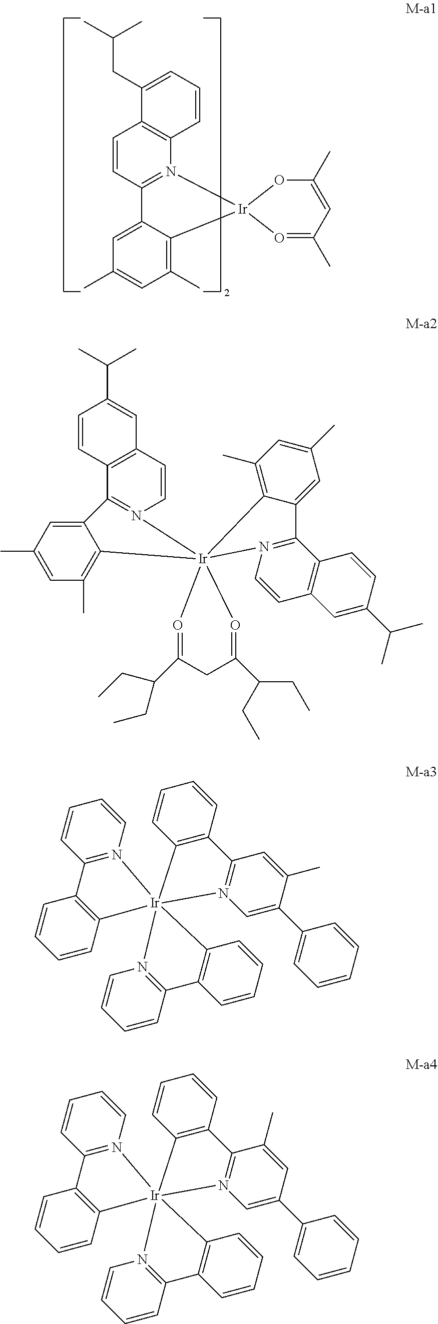

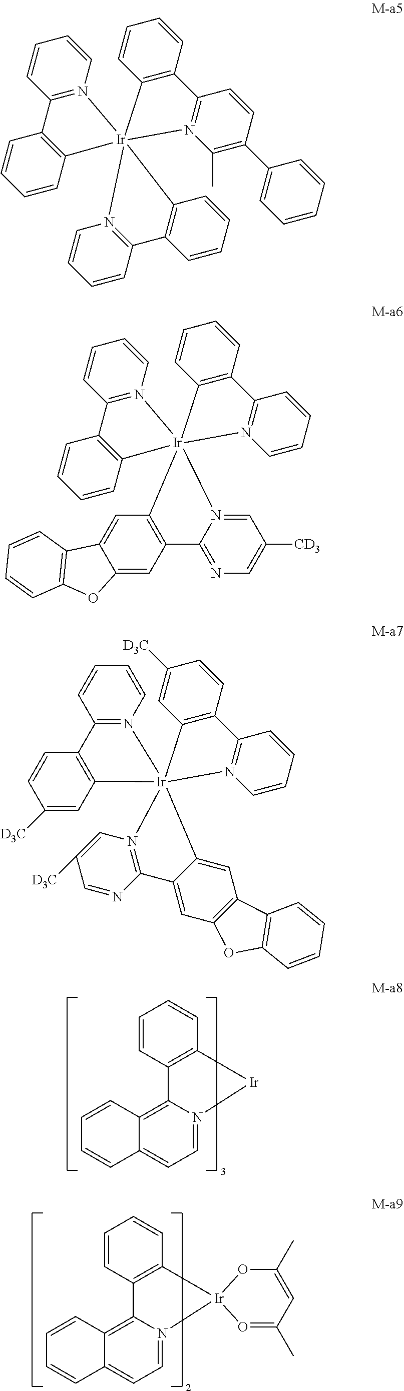

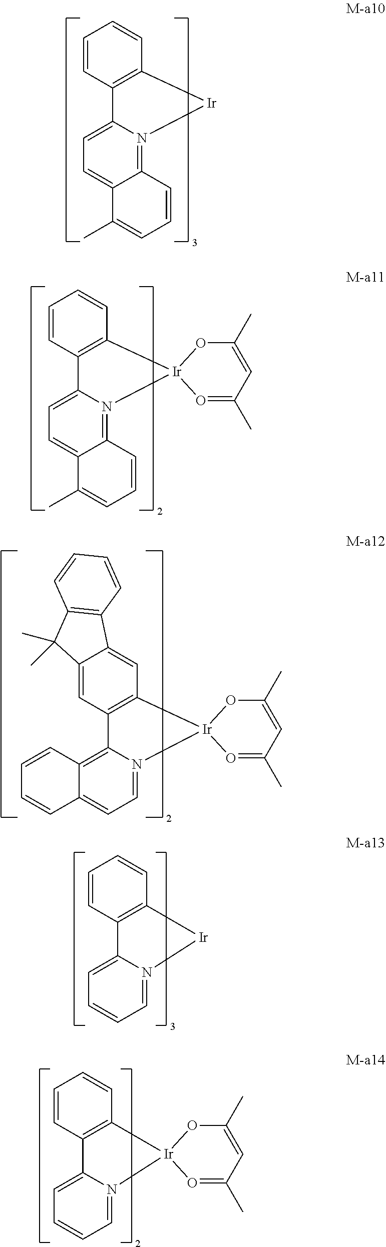

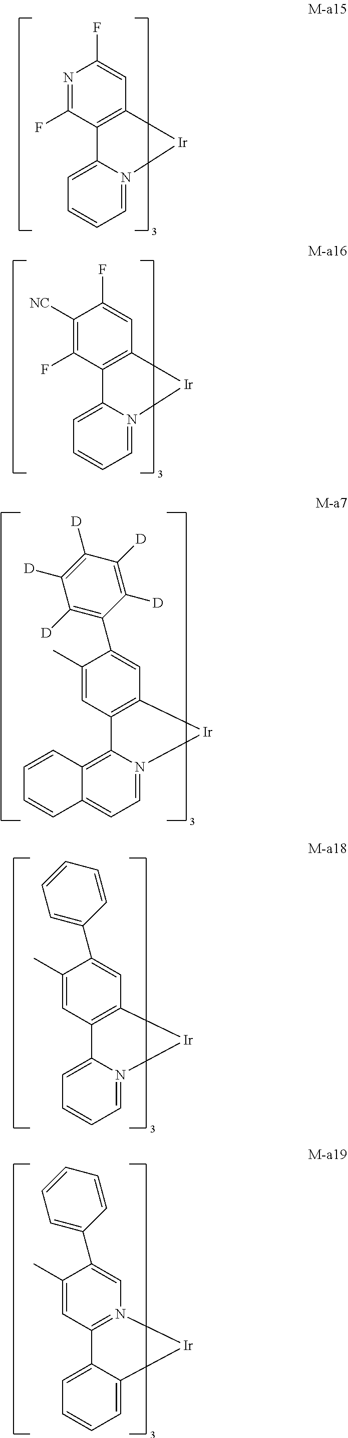

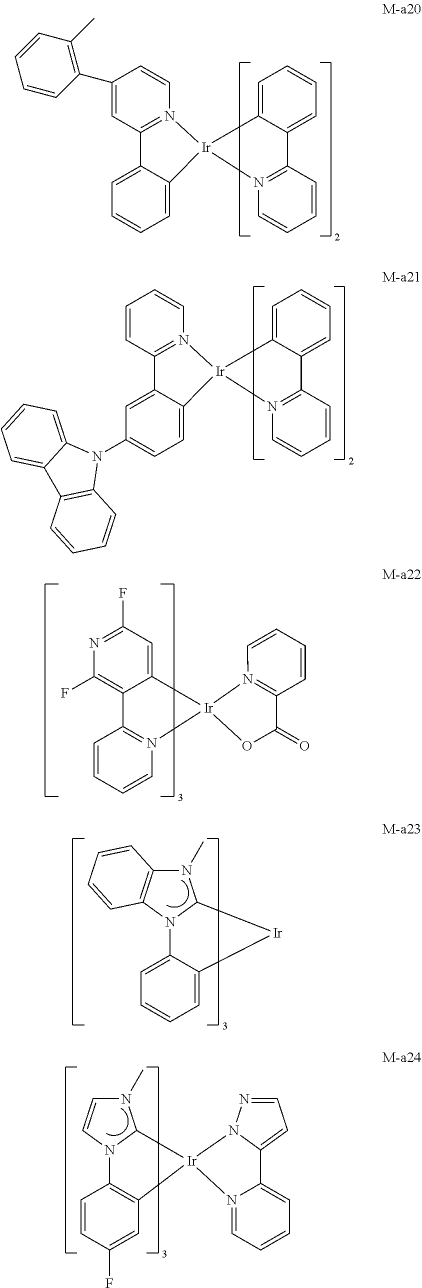

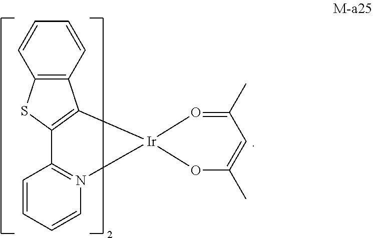

The emission layer EML may further include a compound represented by any one of Formula F-a to Formula F-c. The compounds represented by Formula F-a to Formula F-c may be used as fluorescence dopant materials:

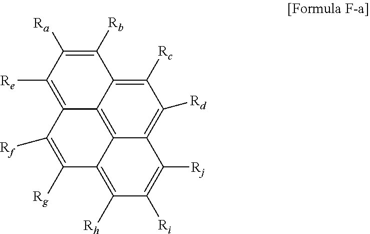

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by *—NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one of Ar₁ and Ar₂ may be a heteroaryl group including O or S as a ring-forming atom.

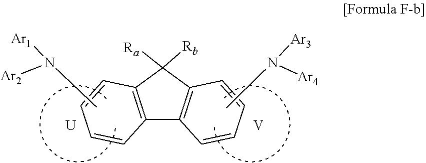

In Formula F-b, Ar₁ to Ar₄ may each independently be a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring.

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may each independently be 0 or 1. For example, in Formula F-b, if the number of U or V is 1, a fused ring may be present at the part designated by U or V, and if the number of U or V is 0, a fused ring may not be present at the part designated by U or V. If the number of U is 0 and the number of V is 1, or if the number of U is 1 and the number of V is 0, a fused ring having the fluorene core of Formula F-b may be a fused polycyclic compound with four rings. If the number of U and V is each 0, a fused ring having the fluorene core Formula F-b may be a fused polycyclic compound with three rings. If the number of U and V is each 1, a fused ring having the fluorene core of Formula F-b may be a fused polycyclic compound with five rings.

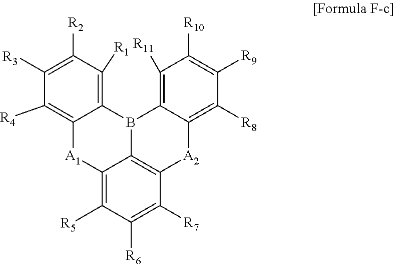

In Formula F-c, A₁ and A₂ may each independently be O, S, Se, or N(Rₘ); and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or may be combined with an adjacent group to form a ring.

In Formula F-c, A₁ and A₂ may each independently be combined with the substituents of an adjacent ring to form a fused ring. For example, if A₁ and A₂ are each independently N(Rₘ), A₁ may be combined with R₄ or R₅ to form a ring. For example, A₂ may be combined with R₇ or R₈ to form a ring.

In an embodiment, the emission layer EML may include as a dopant material of the related art, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), etc.

The emission layer EML may include a phosphorescence dopant material of the related art. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′) (FIrpic), bis(2,4-difluorophenylpyridinato)-tetrakis(1-pyrazolyl)borate iridium(III) (Fir6), or platinum octaethyl porphyrin (PtOEP) may be used as the phosphorescence dopant. However, embodiments are not limited thereto.

The emission layer EML may include a quantum dot. The quantum dot may be a Group II-VI compound, a Group III-VI compound, a Group I-III-VI compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof; or any combination thereof.

The Group III-VI compound may include: a binary compound such as In₂S₃, and In₂Se₃; a ternary compound such as InGaS₃, and InGaSe₃; or any combination thereof.

The Group I-III-VI compound may include: a ternary compound selected from the group consisting of AgInS, AgInS₂, CuInS, CuInS₂, AgGaS₂, CuGaS₂, CuGaO₂, AgGaO₂, AgAlO₂ and mixtures thereof; a quaternary compound such as AgInGaS₂, and CuInGaS₂; or any combination thereof.

The Group III-V compound may include: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof; or any combination thereof. In an embodiment, the Group III-V compound may further include a Group II metal. For example, InZnP, etc. may be selected as a Group III-II-V compound.

The Group IV-VI compound may include: a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; a quaternary compound selected from the group consisting of SnPbSSe, SnPbSeTe, SnPbSTe, and mixtures thereof; or any combination thereof. The Group IV element may be Si, Ge, or a mixture thereof. The Group IV compound may include a binary compound selected from the group consisting of SiC, SiGe, or a mixture thereof.

A binary compound, a ternary compound, or a quaternary compound may be present in a particle at a uniform concentration, or may be present in a particle at a partially different concentration distribution. In an embodiment, a quantum dot may have a core/shell structure in which one quantum dot surrounds another quantum dot. A quantum dot having a core/shell structure may have a concentration gradient at an interface between the core and the shell in which the concentration of a material that is present in the shell decreases toward the core.

In embodiments, the quantum dot may have the above-described core-shell structure including a core including a nanocrystal and a shell surrounding the core. The shell of the quantum dot may serve as a protection layer for preventing the chemical deformation of the core to maintain semiconductor properties and/or may serve as a charging layer for imparting the quantum dot with electrophoretic properties. The shell may be a single layer or a multilayer. Examples of the shell of the quantum dot may include a metal oxide, a non-metal oxide, a semiconductor compound, or combinations thereof.

For example, the metal oxide or the non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO; a ternary compound such as MgAl₂O₄, CoFe₂O₄, NiFe₂O₄ and CoMn₂O₄; or any combination thereof. However, embodiments are not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. When the quantum dot has a FWHM of an emission wavelength spectrum in any of the above ranges, color purity or color reproducibility may be improved. Light emitted through a quantum dot may be emitted in all directions, so that light viewing angle properties may be improved.

The form of the quantum dot may be any form that is used in the related art, without specific limitation. For example, the quantum dot may have a spherical shape, a pyramidal shape, a multi-arm shape, or a cubic shape, or the quantum dot may be in the form of a nanoparticle, a nanotube, a nanowire, a nanofiber, a nanoplate particle, etc.

The quantum dot may control the color of light emitted according to a particle size thereof. Accordingly, the quantum dot may have various emission colors such as blue, red, or green.

In the light emitting device ED according to embodiments shown in FIG. 3 to FIG. 6, the electron transport region ETR is provided on the emission layer EML. The electron transport region ETR may include at least one of an electron blocking layer HBL, an electron transport layer ETL, or an electron injection layer EIL. However, embodiments are not limited thereto.

The electron transport region ETR may be a layer formed of a single material, a layer formed of different materials, or a structure having multiple layers formed of different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated from the emission layer EML, but embodiments are not limited thereto. A thickness of the electron transport region ETR may be, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-1:

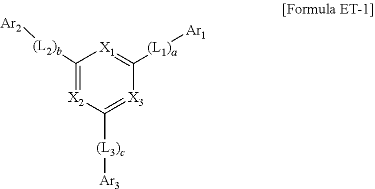

In Formula ET-1, at least one of X₁ to X₃ may each be N, and the remainder of X₁ to X₃ may each independently be C(Rₐ). In Formula ET-1, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-1, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each 2 or more, multiple groups of each of L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), and mixtures thereof, without limitation.

In an embodiment, the electron transport region ETR may include at least one compound selected from Compounds ET1 to ET36:

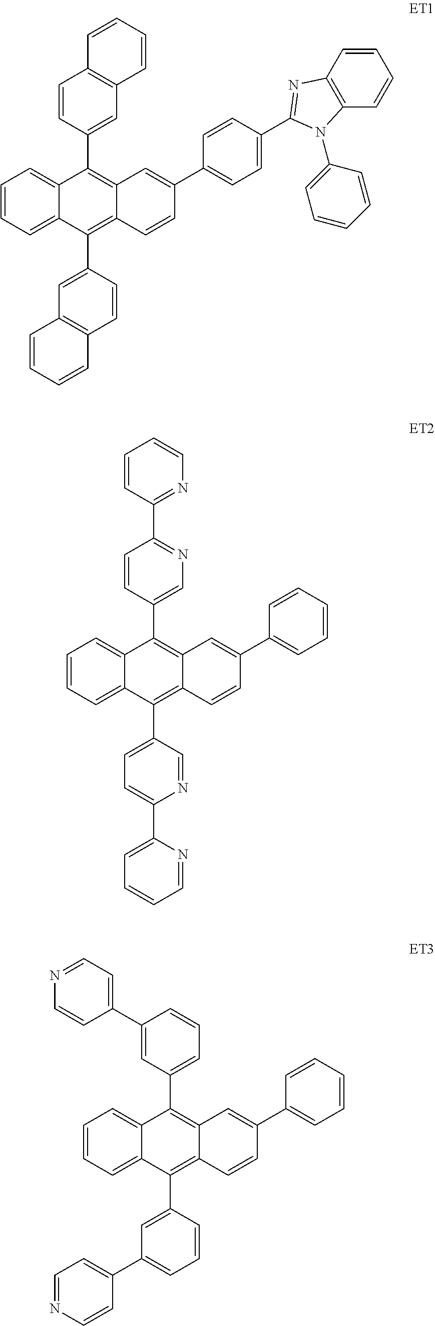 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

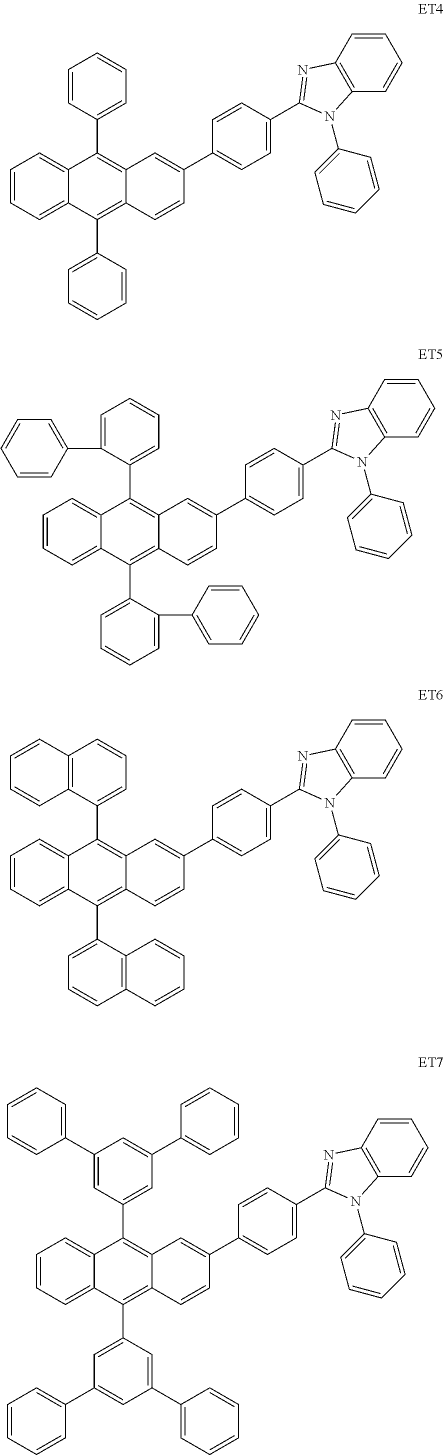 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

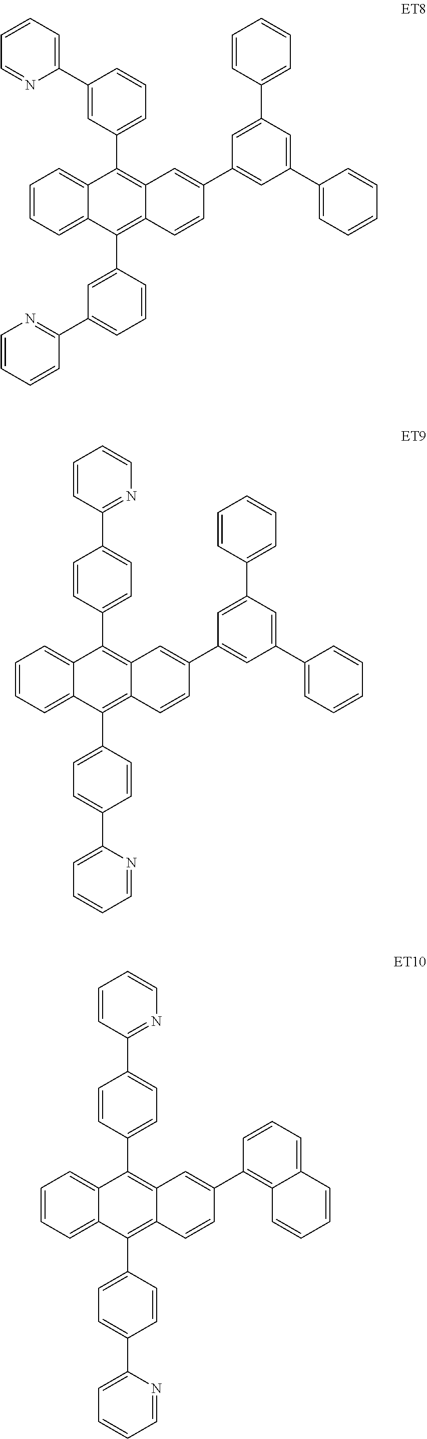 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

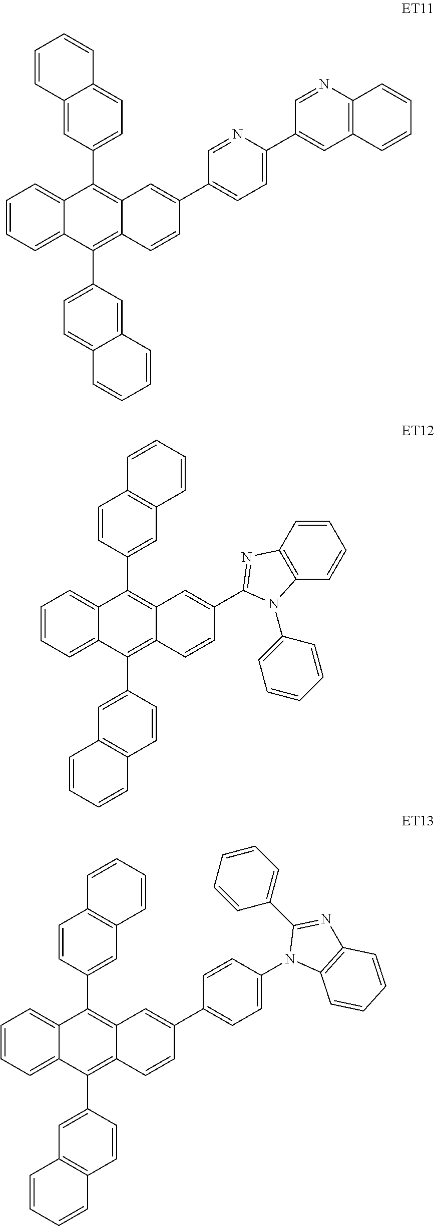 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2nc3ccccc3n2-c2ccc(-c3ccc4c(-c5ccc6ccccc6c5)c5ccccc5c(-c5ccc6ccccc6c5)c4c3)cc2)cc1]

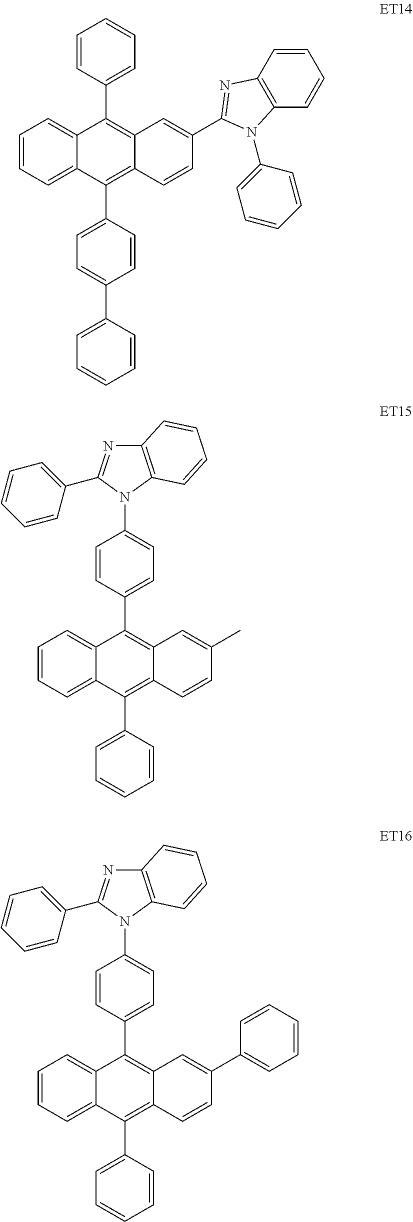 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

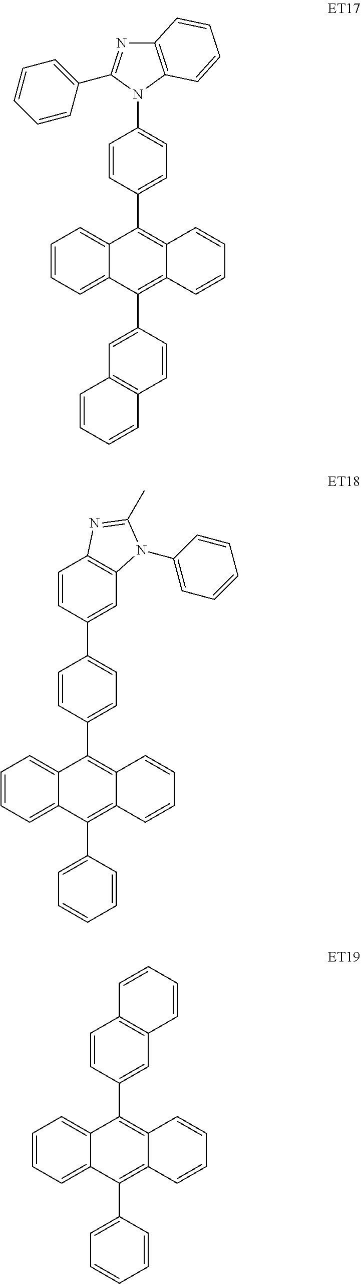

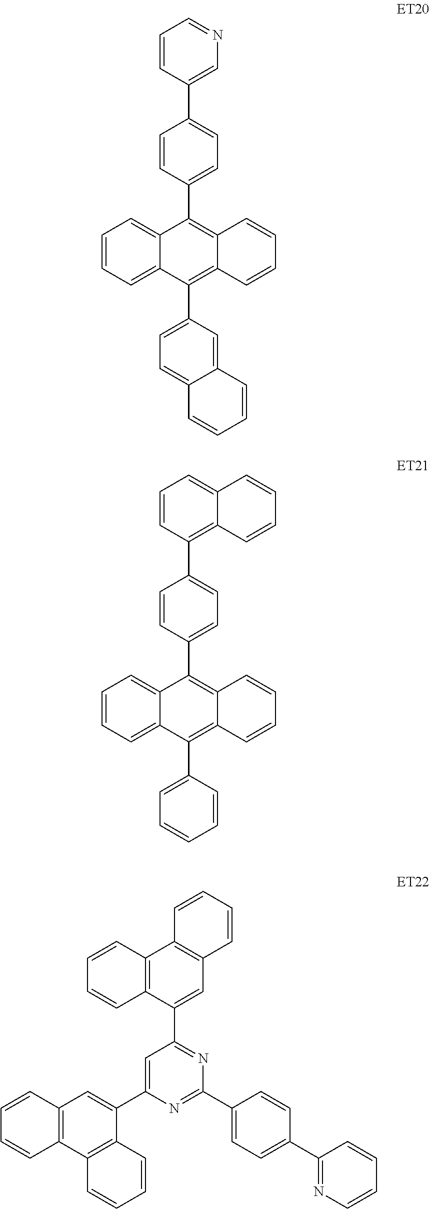

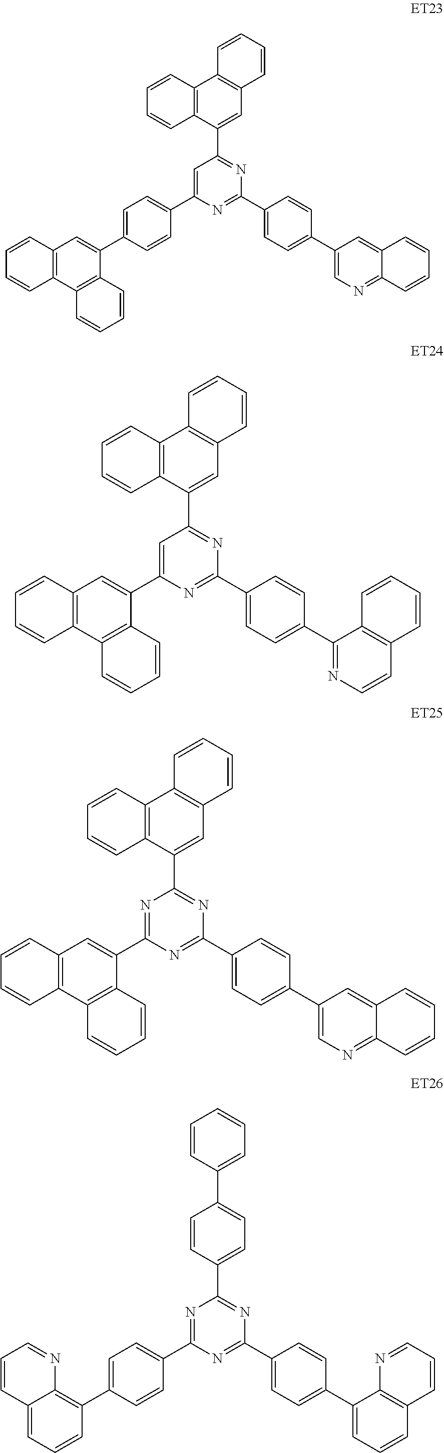 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

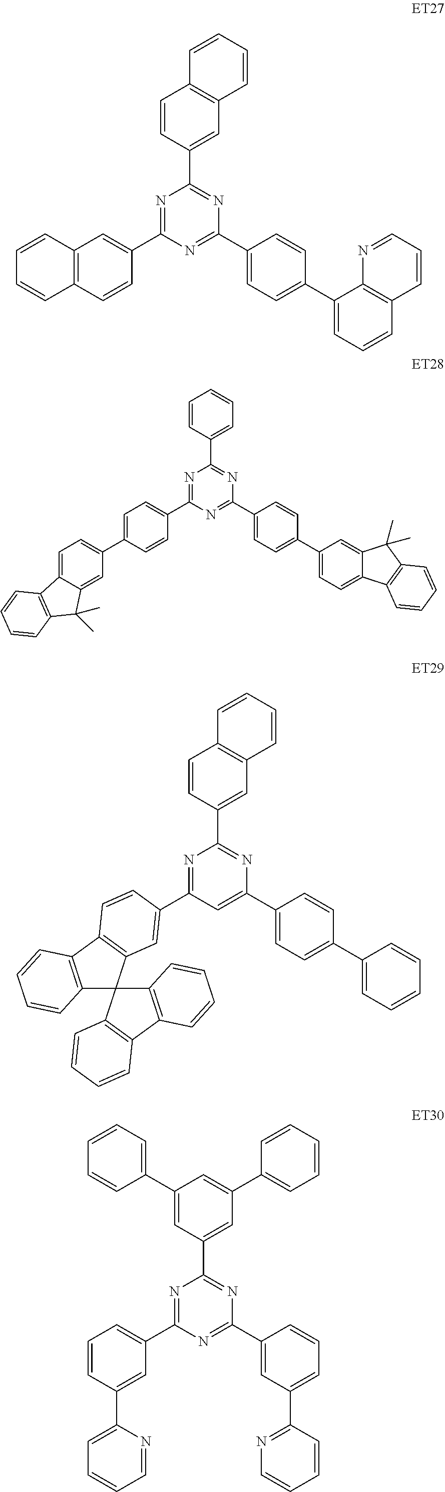

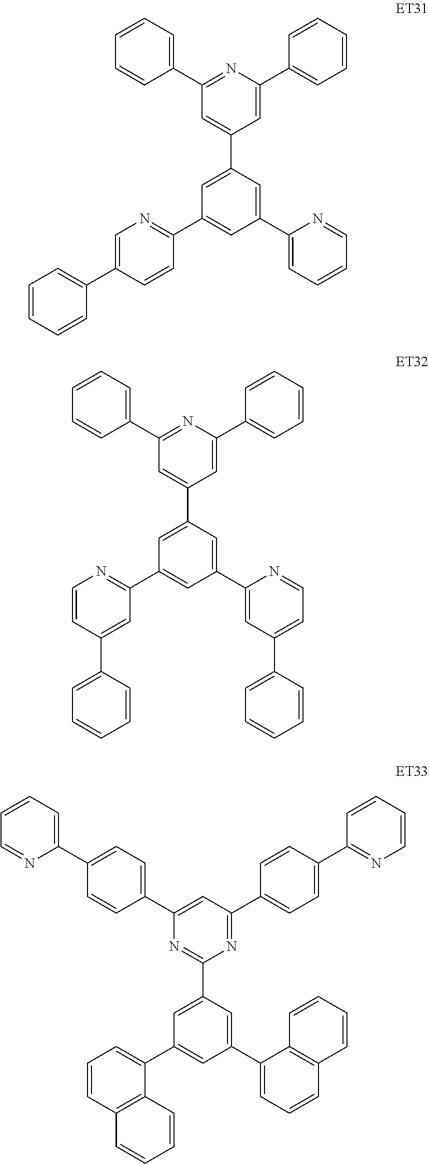 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

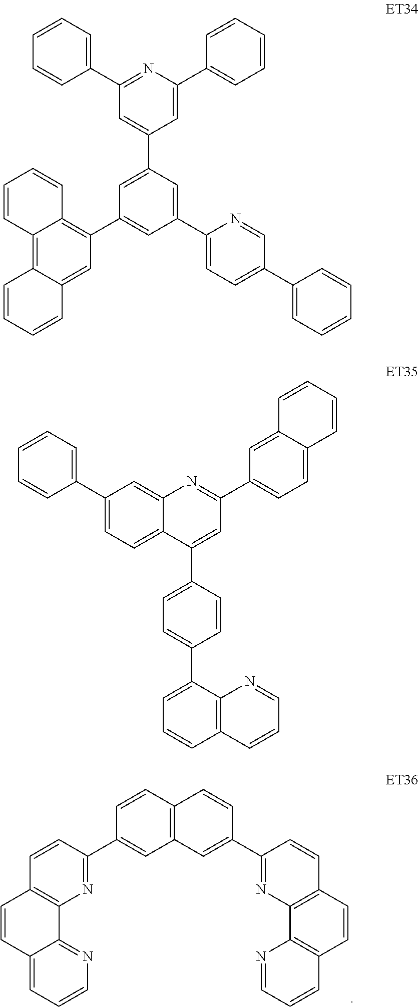

The electron transport region ETR may include: a metal halide such as LiF, NaCl, CsF, RbCl, RbI, CuI, and KI; a lanthanide metal such as Yb; or a co-deposited material of the metal halide and the lanthanide metal. For example, the electron transport region ETR may include KI:Yb, RbI:Yb, etc., as a co-deposited material. The electron transport region ETR may include a metal oxide such as Li₂O and BaO, or 8-hydroxy-lithium quinolate (Liq). However, embodiments are not limited thereto. The electron transport region ETR also may be formed of a mixture material of an electron transport material and an insulating organometallic salt. The organometallic salt may be a material having an energy band gap equal to or greater than about 4 eV. For example, the organometallic salt may include metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen), in addition to the aforementioned materials. However, embodiments are not limited thereto.

The electron transport region ETR may include the compounds of the electron transport region in at least one of an electron injection layer EIL, an electron transport layer ETL, or a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of from about 150 Å to about 500 Å. If the thickness of the electron transport layer ETL satisfies any of the above-described ranges, satisfactory electron transport properties may be obtained without a substantial increase of driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies any of the above described ranges, satisfactory electron injection properties may be obtained without a substantial increase of driving voltage.

The second electrode EL2 is provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode, or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgAg). In another embodiment, the second electrode EL2 may have a multilayered structure including a reflective layer or a transflective layer formed of the above-described materials and a transparent conductive layer formed of ITO, IZO, ZnO, ITZO, etc. For example, the second electrode EL2 may include the aforementioned metal materials, combinations of two or more metal materials selected from the aforementioned metal materials, or oxides of the aforementioned metal materials.

Although not shown in the drawings, the second electrode EL2 may be electrically connected to an auxiliary electrode. If the second electrode EL2 is electrically connected to an auxiliary electrode, the resistance of the second electrode EL2 may decrease.

In an embodiment, the light emitting device ED may further include a capping layer CPL disposed on the second electrode EL2. The capping layer CPL may be a multilayer or a single layer.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNx, SiOy, etc.

For example, if the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or may include an epoxy resin, or acrylate such as methacrylate. The capping layer CPL may include at least one of Compounds P1 to P5, but embodiments are not limited thereto:

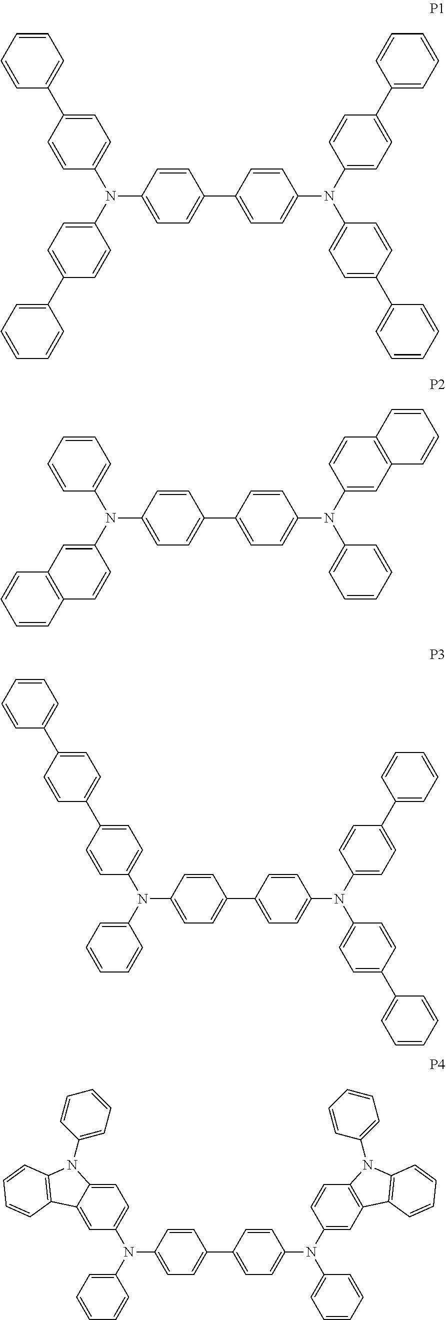 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

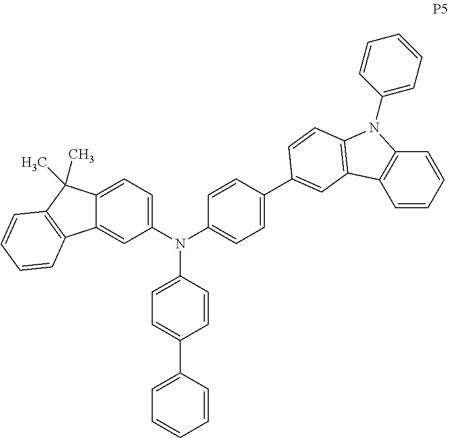 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6 with respect to light in a wavelength range of about 550 nm to about 660 nm may.

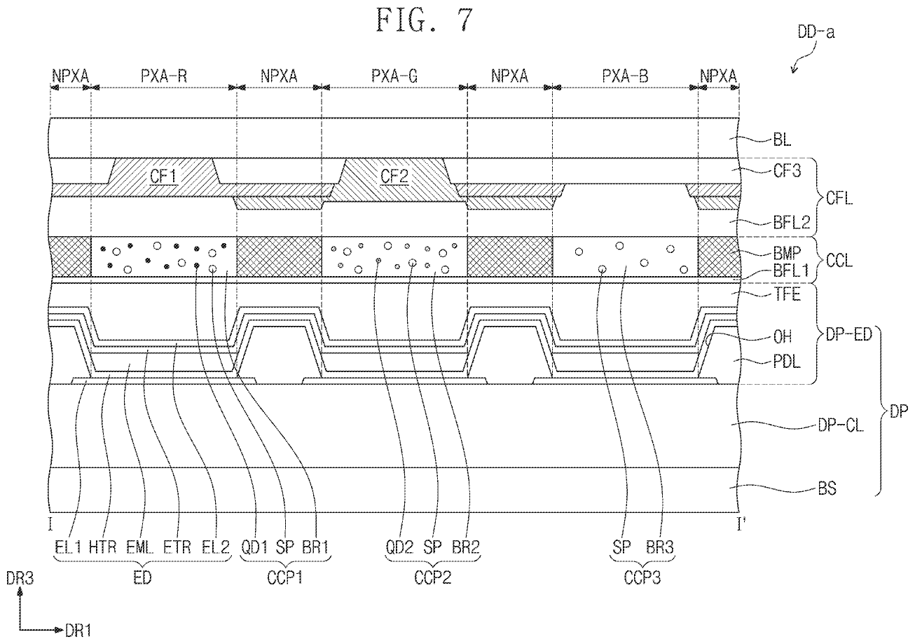

FIG. 7 to FIG. 10 are each a schematic cross-sectional view of a display apparatus according to embodiments. In the explanation on the display apparatuses according to embodiments with reference to FIG. 7 to FIG. 10, the features which have been explained above with respect to FIG. 1 to FIG. 6 will not be explained again, and the different features will be described.

Referring to FIG. 7, a display apparatus DD-a according to an embodiment may include a display panel DP including a display device layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS, and a display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting device ED shown in FIG. 7 may be the same as a structure of a, light emitting device according to one of FIG. 3 to FIG. 6 as described herein.

In the display apparatus DD-a according to an embodiment, the emission layer EML of the light emitting device ED may include: the first compound; and at least one of the second compound, the third compound, and the fourth compound, as described herein.

Referring to FIG. 7, the emission layer EML may be disposed in an opening OH defined in a pixel definition layer PDL. For example, the emission layer EML, which is separated by the pixel definition layer PDL and provided corresponding to each of the luminous areas PXA-R, PXA-G, and PXA-B, may each emit light in a same wavelength region. In the display apparatus DD-a, the emission layer EML may emit blue light. Although not shown in the drawings, in an embodiment, the emission layer EML may be provided as a common layer for all of the luminous areas PXA-R, PXA-G, and PXA-B.

The light controlling layer CCL may be disposed on the display panel DP. The light controlling layer CCL may include a light converter. The light converter may be a quantum dot or a phosphor. The light converter may convert the wavelength of a provided light and may emit the resulting light. For example, the light controlling layer CCL may be a layer including a quantum dot or a layer including a phosphor.

The light controlling layer CCL may include light controlling parts CCP1, CCP2, and CCP3. The light controlling parts CCP1, CCP2, and CCP3 may be separated from one another.

Referring to FIG. 7, a partition pattern BMP may be disposed between the separated light controlling parts CCP1, CCP2, and CCP3, but embodiments are not limited thereto. In FIG. 7, it is shown that the partition pattern BMP does not overlap the light controlling parts CCP1, CCP2, and CCP3, but at least a portion of the edges of the light controlling parts CCP1, CCP2, and CCP3 may be overlap the partition pattern BMP.

The light controlling layer CCL may include a first light controlling part CCP1 including a first quantum dot QD1 converting a first color light provided from the light emitting device ED into second color light, a second light controlling part CCP2 including a second quantum dot QD2 converting the first color light into third color light, and a third light controlling part CCP3 transmitting the first color light.

In an embodiment, the first light controlling part CCP1 may provide red light, which is the second color light, and the second light controlling part CCP2 may provide green light, which is the third color light. The third color controlling part CCP3 may transmit and provide blue light, which is the first color light provided from the light emitting device ED. For example, the first quantum dot QD1 may be a red quantum dot, and the second quantum dot QD2 may be a green quantum dot. The quantum dots QD1 and QD2 may each be a quantum dot as described herein.

The light controlling layer CCL may further include a scatterer SP. The first light controlling part CCP1 may include the first quantum dot QD1 and a scatterer SP, the second light controlling part CCP2 may include the second quantum dot QD2 and a scatterer SP, and the third light controlling part CCP3 may not include a quantum dot but may include a scatterer SP.

The scatterer SP may be an inorganic particle. For example, the scatterer SP may include at least one of TiO₂, ZnO, Al₂O₃, SiO₂, or hollow silica. The scatterer SP may include any one of TiO₂, ZnO, Al₂O₃, SiO₂, and hollow silica, or the scatterer SP may be a mixture of two or more materials selected from TiO₂, ZnO, Al₂O₃, SiO₂, and hollow silica.

The first light controlling part CCP1, the second light controlling part CCP2, and the third light controlling part CCP3 may each include base resins BR1, BR2, and BR3 in which the quantum dots QD1 and QD2 and the scatterer SP are dispersed. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3. The base resins BR1, BR2, and BR3 are mediums in which the quantum dots QD1 and QD2 and the scatterer SP are dispersed, and may be composed of various resin compositions which may be generally referred to as a binder. For example, the base resins BR1, BR2, and BR3 may be acrylic resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light controlling layer CCL may include a barrier layer BFL1. The barrier layer BFL1 may block the penetration of moisture and/or oxygen (hereinafter, will be referred to as “humidity/oxygen”). The barrier layer BFL1 may be disposed between the light controlling parts CCP1, CCP2, and CCP3 and the encapsulating layer TFE to block the exposure of the light controlling parts CCP1, CCP2, and CCP3 to humidity/oxygen. The barrier layer BFL1 may cover the light controlling parts CCP1, CCP2, and CCP3. A color filter layer CFL, which will be explained later, may include a barrier layer BFL2 disposed on the light controlling parts CCP1, CCP2, and CCP3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. The barrier layers BFL1 and BFL2 may each independently further include an organic layer. The barrier layers BFL1 and BFL2 may each independently be formed of a single layer or of multiple layers.

In the display apparatus DD-a according to an embodiment, the color filter layer CFL may be disposed on the light controlling layer CCL.

The color filter layer CFL may include a light blocking part (not shown) and filters CF1, CF2, and CF3. The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. The filters CF1, CF2, and CF3 may each include a polymer photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymer photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may be provided as one body, without distinction.

The light blocking part (not shown) may be a black matrix. The light blocking part (not shown) may include an organic light blocking material or an inorganic light blocking material that includes a black pigment or black dye. The light blocking part (not shown) may prevent light leakage and may separate the boundaries between adjacent filters CF1, CF2, and CF3. In an embodiment, the light blocking part (not shown) may be formed as a blue filter.

The first to third filters CF1, CF2, and CF3 may each be disposed to respectively correspond to the red luminous area PXA-R, the green luminous area PXA-G, and the blue luminous area PXA-B.

Abase substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

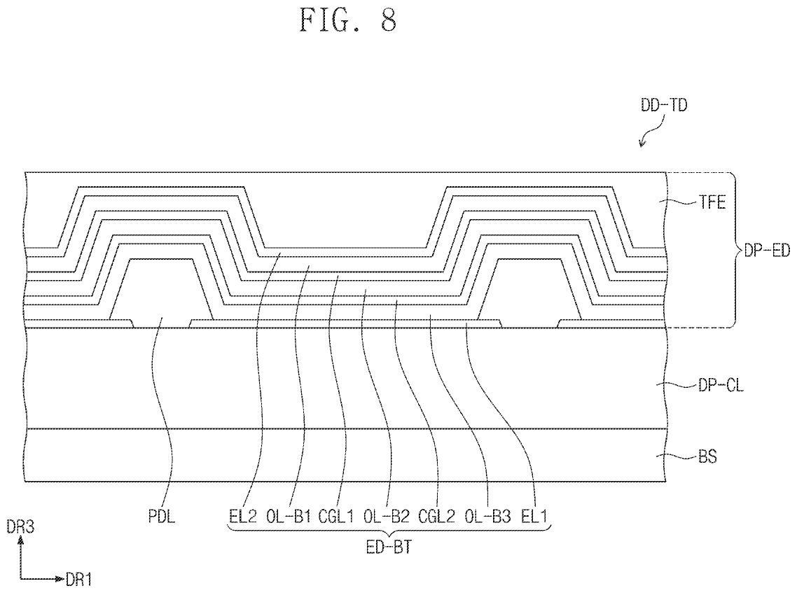

FIG. 8 is a schematic cross-sectional view showing a portion of the display apparatus DD-a according to an embodiment. FIG. 8 shows a schematic cross-sectional view of a portion corresponding to the display panel DP of FIG. 7. In a display apparatus DD-TD according to an embodiment, the light emitting device ED-BT may include light emitting structures OL-B1, OL-B2, and OL-B3. The light emitting device ED-BT may include oppositely disposed first electrode EL1 and second electrode EL2, and the light emitting structures OL-B1, OL-B2, and OL-B3 stacked in a thickness direction and provided between the first electrode EL1 and the second electrode EL2. The light emitting structures OL-B1, OL-B2, and OL-B3 may each include an emission layer EML (FIG. 7), and a hole transport region HTR and an electron transport region ETR disposed with the emission layer EML (FIG. 7) therebetween.

For example, the light emitting device ED-BT included in the display apparatus DD-TD may be a light emitting device having a tandem structure and including multiple emission layers.

In an embodiment shown in FIG. 8, light emitted from each of the light emitting structures OL-B1, OL-B2, and OL-B3 may be all blue light. However, embodiments are not limited thereto, and the wavelength regions of light emitted from each of the light emitting structures OL-B1, OL-B2, and OL-B3 may be different from each other. For example, the light emitting device ED-BT, which include the light emitting structures OL-B1, OL-B2, and OL-B3 that emit light in different wavelength regions, may emit white light.

Charge generating layers CGL1 and CGL2 may be disposed between neighboring light emitting structures OL-B1, OL-B2, and OL-B3. Charge generating layers CGL1 and CGL2 may each independently include a p-type charge generating layer and/or an n-type charge generating layer.

At least one of the light emitting structures OL-B1, OL-B2, and OL-B3 included in the display apparatus DD-TD may include: the first compound; and at least one of the second compound, the third compound, and the fourth compound.

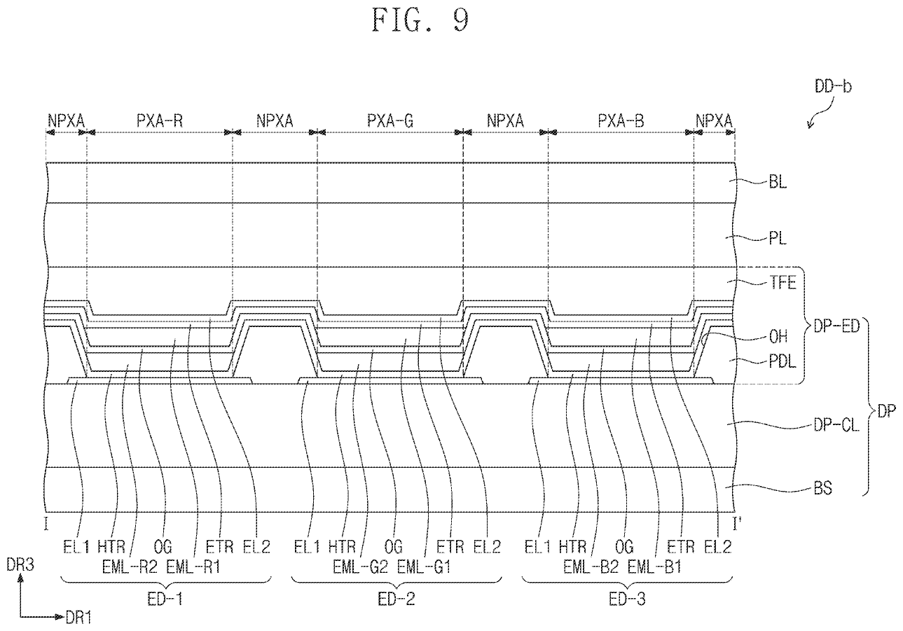

Referring to FIG. 9, a display apparatus DD-b according to an embodiment may include light emitting devices ED-1, ED-2, and ED-3, which may each include two emission layers that are stacked. In comparison to the display apparatus DD shown in FIG. 2, the embodiment shown in FIG. 9 is different at least in that the first to third light emitting devices ED-1, ED-2, and ED-3 each include two emission layers that are stacked in a thickness direction. In the first to third light emitting devices ED-1, ED-2, and ED-3, two emission layers may emit light in a same wavelength region.

The first light emitting device ED-1 may include a first red emission layer EML-R₁ and a second red emission layer EML-R₂. The second light emitting device ED-2 may include a first green emission layer EML-G1 and a second green emission layer EML-G2. The third light emitting device ED-3 may include a first blue emission layer EML-B1 and a second blue emission layer EML-B2. An emission auxiliary part OG may be disposed between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generating layer. For example, the emission auxiliary part OG may include an electron transport region, a charge generating layer, and a hole transport region, stacked in that order. The emission auxiliary part OG may be provided as a common layer for all of the first to third light emitting devices ED-1, ED-2, and ED-3. However, embodiments are not limited thereto, and the emission auxiliary part OG may be patterned and provided in an opening OH defined in a pixel definition layer PDL.

The first red emission layer EML-R₁, the first green emission layer EML-G1, and the first blue emission layer EML-B1 may each be disposed between the emission auxiliary part OG and the electron transport region ETR. The second red emission layer EML-R₂, the second green emission layer EML-G2, and the second blue emission layer EML-B2 may each be disposed between the hole transport region HTR and the emission auxiliary part OG.

For example, the first light emitting device ED-1 may include a first electrode EL1, a hole transport region HTR, a second red emission layer EML-R₂, an emission auxiliary part OG, a first red emission layer EML-R₁, an electron transport region ETR, and a second electrode EL2, stacked in that order. The second light emitting device ED-2 may include a first electrode EL1, a hole transport region HTR, a second green emission layer EML-G2, an emission auxiliary part OG, a first green emission layer EML-G1, an electron transport region ETR, and a second electrode EL2, stacked in that order. The third light emitting device ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in that order.

An optical auxiliary layer PL may be disposed on a display device layer DP-ED. The optical auxiliary layer PL may include a polarization layer. The optical auxiliary layer PL may be disposed on a display panel DP and may control light reflected at the display panel DP from an external light. Although not shown in the drawings, in an embodiment, the optical auxiliary layer PL may be omitted from the display apparatus DD-b.

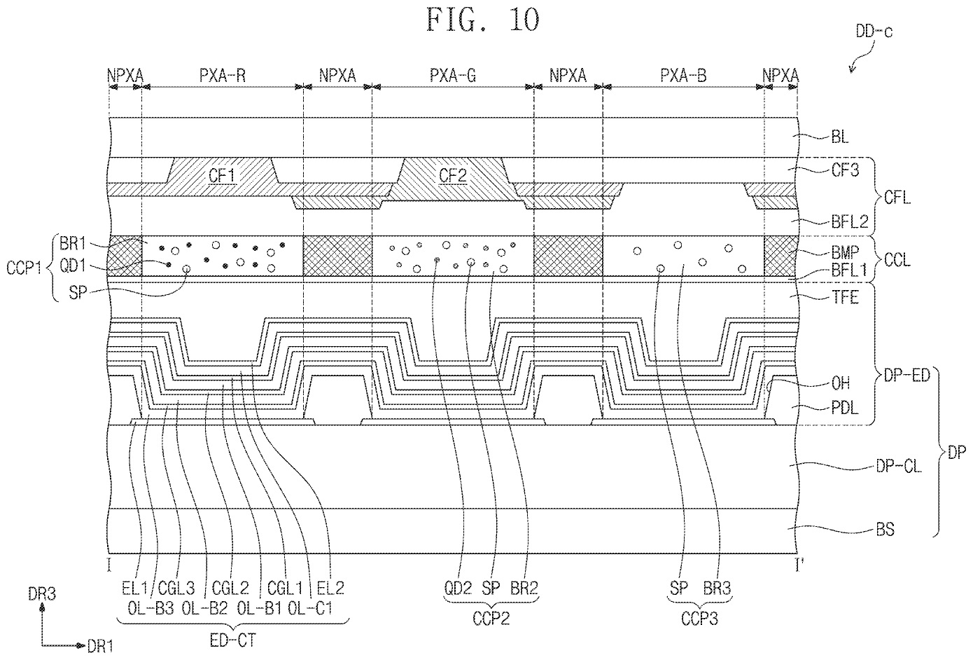

In contrast to FIG. 8 and FIG. 9, FIG. 10 shows a display apparatus DD-c that is different at least in that it includes four light emitting structures OL-B1, OL-B2, OL-B3, and OL-C1. A light emitting device ED-CT may include oppositely disposed first electrode EL1 and second electrode EL2, and first to fourth light emitting structures OL-B1, OL-B2, OL-B3, and OL-C1 that are stacked in a thickness direction between the first electrode EL1 and the second electrode EL2. Charge generating layers CGL1, CGL2 and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, embodiments are not limited thereto, and the first to fourth light emitting structures OL-B1, OL-B2, OL-B3 and OL-C1 may emit light having wavelengths that are different from each other.

The charge generating layers CGL1, CGL2, and CGL3 which are disposed between neighboring light emitting structures OL-B1, OL-B2, OL-B3, and OL-C1 may each independently include a p-type charge generating layer and/or an n-type charge generating layer.

In the display apparatus DD-c, at least one of the light emitting structures OL-B1, OL-B2, OL-B3, and OL-C1 may include: the first compound; and at least one of the second compound, the third compound, and the fourth compound.

In an embodiment, the light emitting device ED may include the first compound according to an embodiment in at least one of a hole transport region HTR, an emission layer EML, an electron transport region ETR, or a capping layer CPL.

For example, the first compound according to an embodiment may be included in an emission layer EML of the light emitting device ED, and the light emitting device ED may show excellent emission efficiency and long-life characteristics.

The first compound according to an embodiment includes a structure in which two ortho-type terphenyl groups are bonded to a fused structure formed with a boron atom as a center, and may show reduced intermolecular interaction and excellent thermal stability. Thus, deterioration of a device during manufacture or operation may be reduced, and device life may be improved. The trigonal bonding structure of a boron atom may be protected by two terphenyl groups, and molecular stability and multiple resonance may be improved.

The first compound may further include a substituted or unsubstituted aryl group at a meta- or para-position with respect to a boron atom, and the absorption of a molecule may be improved, FRET efficiency may be improved, and excellent device efficiency may be shown.

The first compound may further include a substituted or unsubstituted carbazole group bonded at a para-position with respect to a boron atom, and multiple resonance effects may be maximized, material stability may be improved, and device life may be improved.

The light emitting device according to embodiments includes the first compound represented by Formula 1 in an emission layer, and the emission efficiency and device life of the device may be improved.

Hereinafter, a fused polycyclic compound used as a first compound according to an embodiment and a light emitting device according to an embodiment will be explained with reference to the Examples and the Comparative Examples. The Examples described below are only provided as illustrations to assist in understanding the disclosure, and the scope thereof is not limited thereto.

### EXAMPLES

1. Synthesis of Fused Polycyclic Compound

A synthesis method of the fused polycyclic compound according to an embodiment will be explained by illustrating synthesis methods for Compound 1, Compound 29, Compound 37, Compound 64, Compound 84, Compound 88, Compound 92, and Compound 94. The synthesis methods of the fused polycyclic compounds explained hereinafter are provided only as examples, and the synthesis method of the fused polycyclic compound according to an embodiment is not limited to the Examples below.

(1) Synthesis of Compound 1

Compound 1 according to an embodiment may be synthesized, for example, by the reactions below.

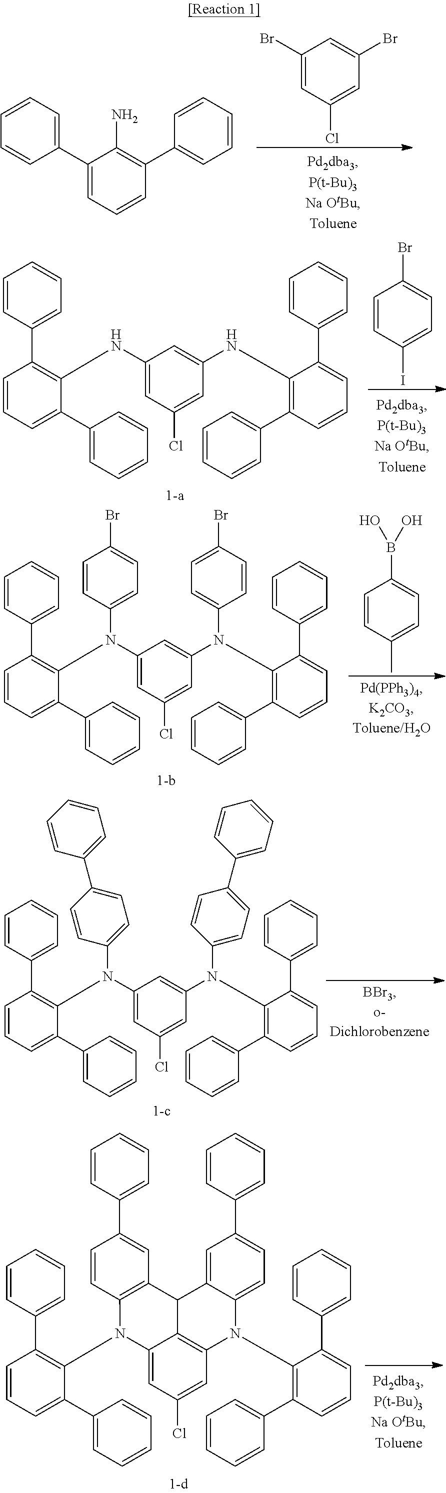

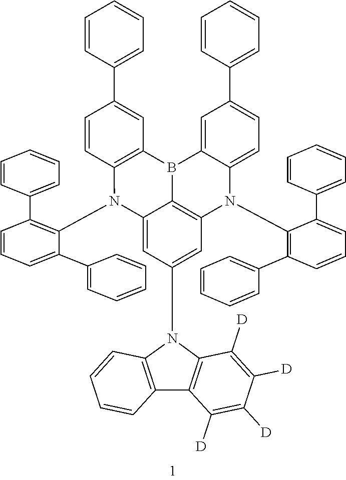 [SMILES: [2H]c1c([2H])c([2H])c2c(c1[2H])c1ccccc1n2-c1cc2c3c(c1)N(c1c(-c4ccccc4)cccc1-c1ccccc1)c1ccc(-c4ccccc4)cc1B3c1cc(-c3ccccc3)ccc1N2c1c(-c2ccccc2)cccc1-c1ccccc1]

1) Synthesis of Intermediate Compound 1-a

Under an argon atmosphere, to a 2 L flask, [1,1′:3′,1″-terphenyl]-2′-amine (18 g, 74 mmol), 1,3-dibromo-5-chlorobenzene (10 g, 37 mmol), pd₂dba₃ (1.7 g, 1.9 mmol), tris-tert-butyl phosphine (1.7 mL, 2.0 mmol), and sodium tert-butoxide (11 g, 111 mmol) were added and dissolved in 400 mL of o-xylene, and the reaction solution was stirred at about 140 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 1-a (white solid, 15 g, 70%). Through ESI-LCMS, the compound thus obtained was identified as Compound 1-a.

ESI-LCMS: [M]⁺: C₄₂H₃₁ClN₂. 598.2212.

2) Synthesis of Intermediate Compound 1-b

Under an argon atmosphere, to a 2 L flask, Compound 1-a (15 g, 25 mmol), 4-iodo-bromobenzene (35 g, 125 mmol), pd₂dba₃ (1.1 g, 1.3 mmol), tris-tert-butyl phosphine (1.1 mL, 2.6 mmol), and sodium tert-butoxide (7.2 g, 75 mmol) were added and dissolved in 300 mL of o-xylene, and the reaction solution was stirred at about 140 degrees for about 72 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 1-b (white solid, 15 g, 56%). Through ESI-LCMS, the compound thus obtained was identified as Compound 1-b.

ESI-LCMS: [M]⁺: C₅₄H₃₇N₂ClBr₂. 906.1010.

3) Synthesis of Intermediate Compound 1-c

Under an argon atmosphere, to a 1 L flask, Compound 1-b (12 g, 13 mmol), phenyl boronic acid (3.3 g, 26 mmol), pd(PPh₃)₄ (0.5 g, 0.4 mmol), and potassium carbonate (5.4 g, 39 mmol) were added and dissolved in 150 mL of toluene and 50 mL of H₂O, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 1-c (white solid, 8.3 g, 71%). Through ESI-LCMS, the compound thus obtained was identified as Compound 1-c.

ESI-LCMS: [M]⁺: C₆₆H₄₇N₂Cl. 903.5701.

4) Synthesis of Intermediate Compound 1-d

Under an argon atmosphere, to 1 L flask, Compound 1-c (8 g) was added and dissolved in 200 mL of o-dichlorobenzene, and cooled using water-ice. BBr₃ (5 equiv.) was slowly added thereto dropwise, and the reaction solution was stirred at about 180 degrees for about 12 hours. After cooling, triethylamine (5 equiv.) was added to quench the reaction, extraction with water/CH₂Cl₂ was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 1-d (yellow solid, 0.98 g, 11%). Through ESI-LCMS, the compound thus obtained was identified as Compound 1-d.

ESI-LCMS: [M]⁺: C₆₆H₄₄N₂ClB. 910.3306.

5) Synthesis of Compound 1

Under an argon atmosphere, to a 2 L flask, Compound 1-d (1 g, 1 mmol), 9H-carbazole-1,2,3,4-d4 (0.2 g, 1.1 mmol), pd₂dba₃ (0.05 g, 0.05 mmol), tris-tert-butyl phosphine (0.05 mL, 0.1 mmol), and sodium tert-butoxide (0.3 g, 3 mmol) were added and dissolved in 10 mL of o-xylene, and the reaction solution was stirred at about 140 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 1 (yellow solid, 0.78 g, 78%). Through ¹H-NMR and ESI-LCMS, the compound thus obtained was identified as Compound 1.

¹H-NMR (400 MHz, CDCl₃): δ=9.12 (d, 2H), 8.36 (s, 4H), 7.86 (d, 4H), 7.75 (d, 6H), 7.62 (d, 2H), 7.55 (m, 12H), 7.41 (m, 3H), 7.23 (s, 2H), 7.11 (d, 2H), 6.93 (s, 2H), 1.43 (s, 36H).

ESI-LCMS: [M]⁺: C₇₈H₄₈N₃BD₄. 1045.4545.

(2) Synthesis of Compound 29

Compound 29 according to an embodiment may be synthesized, for example, by the reactions below.

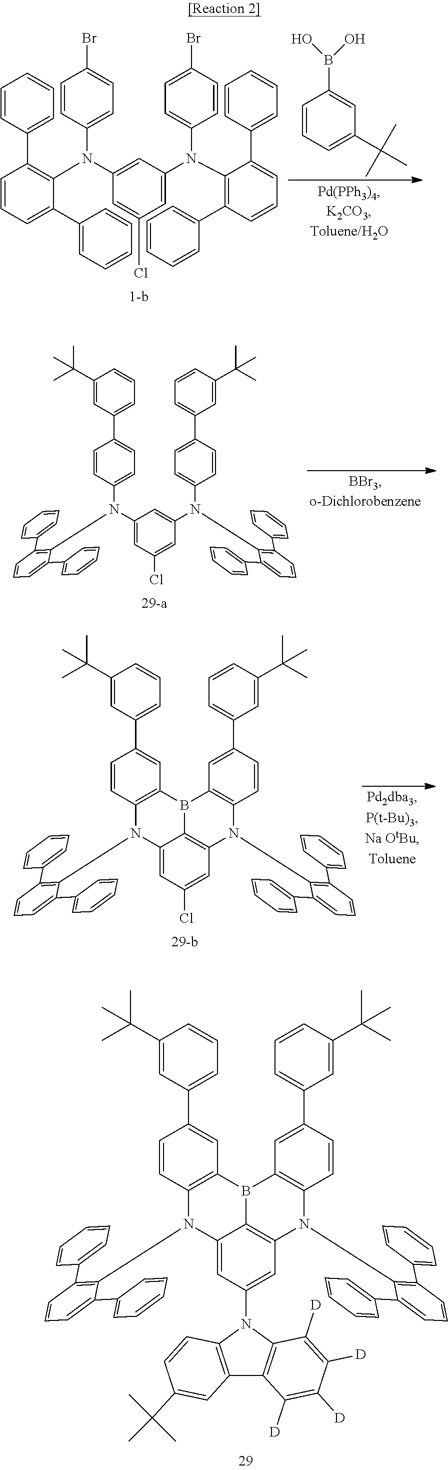

1) Synthesis of Intermediate Compound 29-a

Under an argon atmosphere, to a 1 L flask, Compound 1-b (9.1 g, 10 mmol), (3-(tert-butyl)phenyl)boronic acid (4.3 g, 24 mmol), Pd(PPh₃)₄ (0.34 g, 0.3 mmol), and potassium carbonate (4.14 g, 30 mmol) were added and dissolved in 150 mL of toluene and 50 mL of H₂O, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 29-a (white solid, 6.9 g, 68%). Through ESI-LCMS, the white solid thus obtained was identified as Compound 29-a.

ESI-LCMS: [M]⁺: C₇₄H₆₃N₂Cl. 1014.4787.

2) Synthesis of Intermediate Compound 29-b

Under an argon atmosphere, to 1 L flask, Compound 29-a (6.9 g) was added and dissolved in 120 mL of o-dichlorobenzene, and cooled using water-ice. BBr₃ (5 equiv.) was slowly added thereto dropwise, and the reaction solution was stirred at about 180 degrees for about 12 hours. After cooling, triethylamine (5 equiv.) was added to quench the reaction, extraction with water/CH₂Cl₂ was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 29-b (yellow solid, 1.11 g, 16%). Through ESI-LCMS, the yellow solid thus obtained was identified as Compound 29-b.

ESI-LCMS: [M]⁺: C₇₄H₆₀N₂ClB. 1022.4503.

3) Synthesis of Compound 29

Under an argon atmosphere, to a 2 L flask, Compound 29-b (1 g, 1 mmol), 3-(tert-butyl)-9H-carbazole-5,6,7,8-d4 (0.22 g, 1 mmol), Pd₂dba₃ (0.05 g, 0.05 mmol), tris-tert-butyl phosphine (0.05 mL, 0.1 mmol), and sodium tert-butoxide (0.3 g, 3 mmol) were added and dissolved in 10 mL of toluene, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 29 (yellow solid, 0.87 g, 72%). Through ¹H-NMR and ESI-LCMS, the yellow solid thus obtained was identified as Compound 29.

¹H-NMR (400 MHz, CDCl₃): δ=9.22 (d, 2H), 8.95 (s, 1H), 8.32 (d, 4H), 7.93 (s, 2H), 7.86 (d, 1H), 7.52 (m, 4H), 7.43 (m, 20H), 7.08 (m, 9H), 6.89 (s, 2H), 1.43 (s, 18H), 1.32 (s, 9H).

ESI-LCMS: [M]⁺: C₉₀H₇₂N₃BD₄. 1213.6432.

(3) Synthesis of Compound 31

Compound 31 according to an embodiment may be synthesized, for example, by the reactions below.

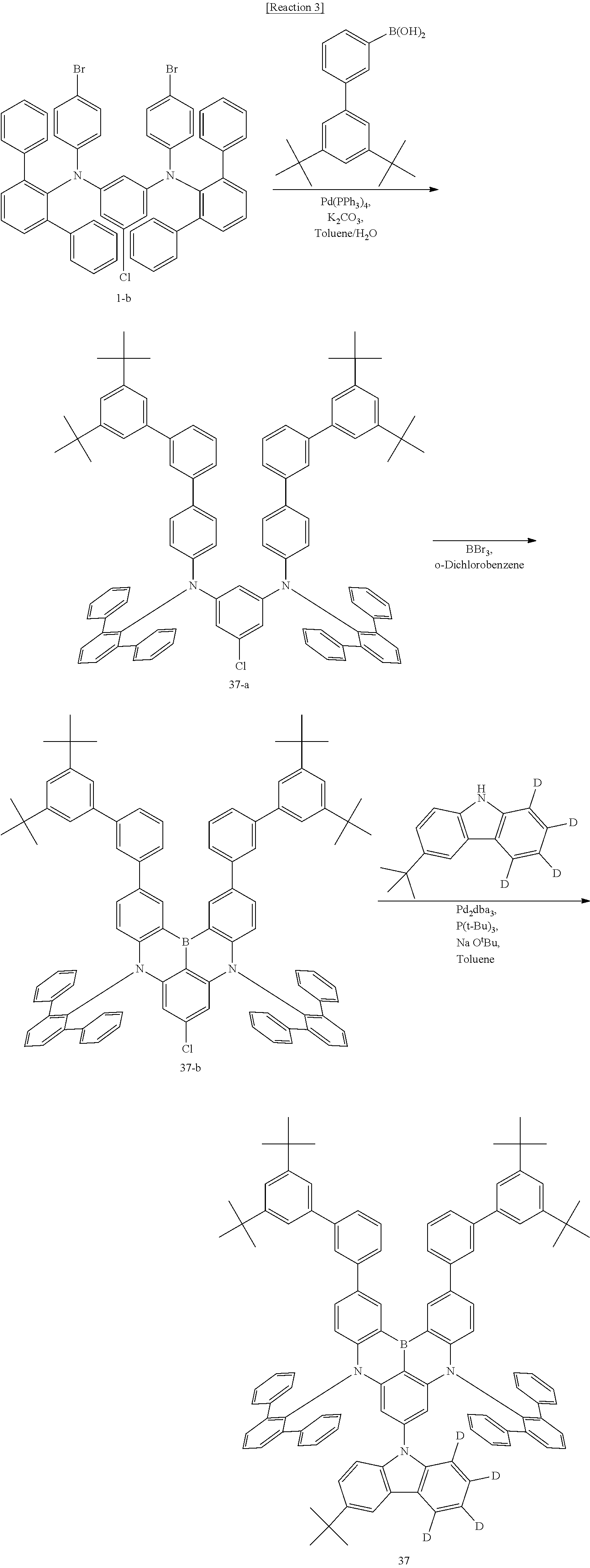

1) Synthesis of Intermediate Compound 37-a

Under an argon atmosphere, to a 1 L flask, Compound 1-b (9.1 g, 10 mmol), (3′,5′-di-tert-butyl-[1,1′-biphenyl]-3-yl)boronic acid (7.44 g, 24 mmol), Pd(PPh₃)₄ (0.34 g, 0.3 mmol), and potassium carbonate (4.14 g, 30 mmol) were added and dissolved in 150 mL of toluene and 50 mL of H₂O, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 37-a (white solid, 9.7 g, 76%). Through ESI-LCMS, the white solid thus obtained was identified as Compound 37-a.

ESI-LCMS: [M]⁺: C₉₄H₈₇N₂Cl. 1278.6616.

2) Synthesis of Intermediate Compound 37-b

Under an argon atmosphere, to 1 L flask, Compound 37-a (9.7 g) was added and dissolved in 200 mL of o-dichlorobenzene, and cooled using water-ice. BBr₃ (5 equiv.) was slowly added thereto dropwise, and the reaction solution was stirred at about 180 degrees for about 12 hours. After cooling, triethylamine (5 equiv.) was added to quench the reaction, extraction with water/CH₂Cl₂ was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 37-b (yellow solid, 1.1 g, 11%). Through ESI-LCMS, the yellow solid thus obtained was identified as Compound 37-b.

ESI-LCMS: [M]⁺: C₉₄H₈₄N₂ClB. 1286.6434.

3) Synthesis of Compound 37

Under an argon atmosphere, to a 2 L flask, Compound 37-b (1.3 g, 1 mmol), 3-(tert-butyl)-9H-carbazole-5,6,7,8-d4 (0.22 g, 1 mmol), Pd₂dba₃ (0.05 g, 0.05 mmol), tris-tert-butyl phosphine (0.05 mL, 0.1 mmol), and sodium tert-butoxide (0.3 g, 3 mmol) were added and dissolved in 10 mL of toluene, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 37 (yellow solid, 1.2 g, 83%). Through ¹H-NMR and ESI-LCMS, the yellow solid thus obtained was identified as Compound 37.

¹H-NMR (400 MHz, CDCl₃): δ=9.22 (d, 2H), 8.95 (s, 1H), 8.32 (d, 4H), 7.94 (s, 2H), 7.86 (d, 1H), 7.73 (s, 6H), 7.57 (m, 8H), 7.43 (m, 16H), 7.08 (m, 9H), 6.89 (s, 2H), 1.43 (s, 9H), 1.32 (s, 36H).

ESI-LCMS: [M]⁺: C₁₁₀H₉₆N₃BD₄. 1477.8312.

(4) Synthesis of Compound 64

Compound 64 according to an embodiment may be synthesized, for example, by the reactions below.

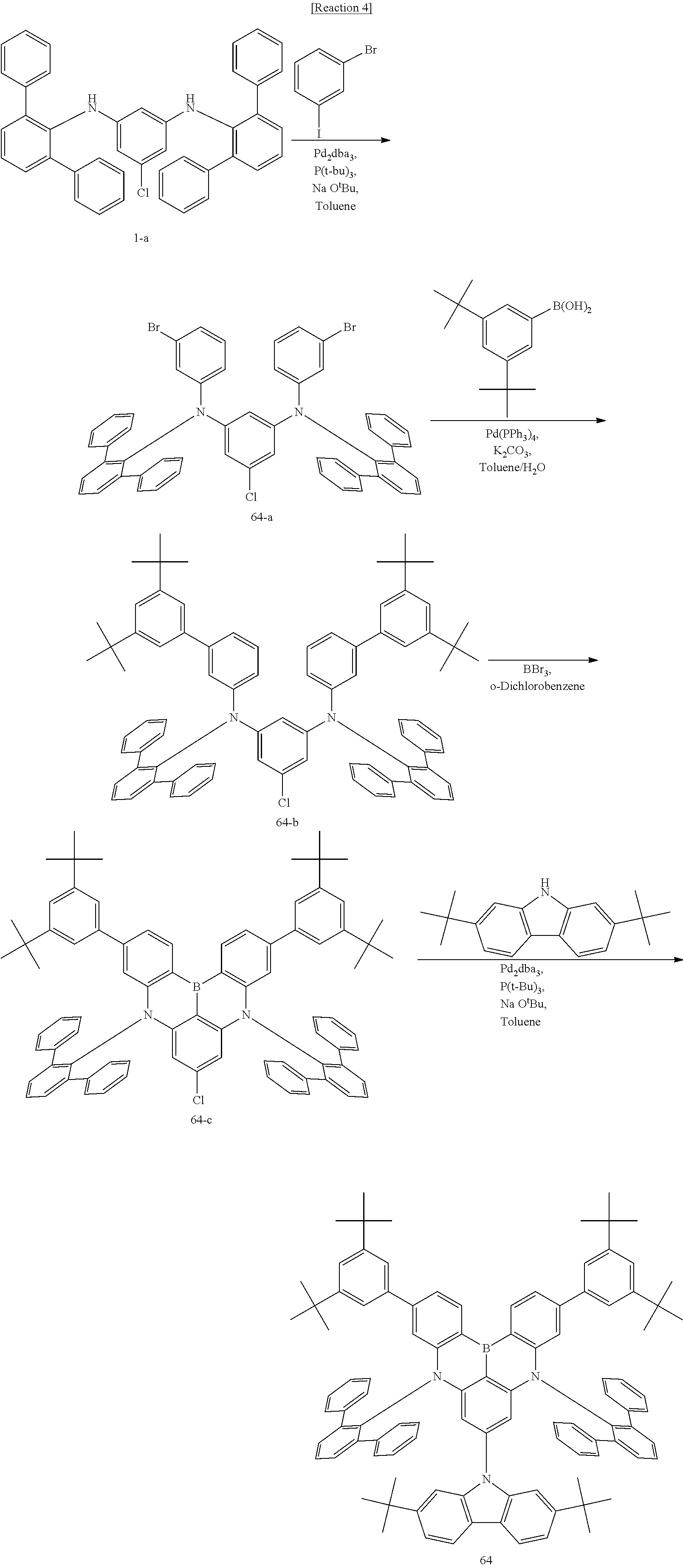

1) Synthesis of Intermediate Compound 64-a

Under an argon atmosphere, to a 2 L flask, Compound 1-a (20 g, 33 mmol), 3-bromo-1-iodobenzene (42 g, 150 mmol), Pd₂dba₃ (1.5 g, 1.65 mmol), tris-tert-butyl phosphine (1.4 mL, 3.3 mmol), and sodium tert-butoxide (96 g, 100 mmol) were added and dissolved in 10 mL of toluene, and the reaction solution was stirred at about 100 degrees for about 24 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 64-a (white solid, 16 g, 53%). Through ESI-LCMS, the white solid thus obtained was identified as Compound 64-a.

ESI-LCMS: [M]⁺: C₅₄H₃₇Br₂ClN₂. 906.0945.

2) Synthesis of Intermediate Compound 64-b

Under an argon atmosphere, to a 1 L flask, Compound 64-a (9.1 g, 10 mmol), 3,5-di-tert-butylphenyl)boronic acid (5.6 g, 24 mmol), Pd(PPh₃)₄ (0.34 g, 0.3 mmol), and potassium carbonate (4.14 g, 30 mmol) were added and dissolved in 150 mL of toluene and 50 mL of H₂O, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 64-b (white solid, 8.7 g, 77%). Through ESI-LCMS, the white solid thus obtained was identified as Compound 64-b.

ESI-LCMS: [M]⁺: C₈₂H₇₉N₂Cl. 1126.5959.

3) Synthesis of Intermediate Compound 64-c

Under an argon atmosphere, to 1 L flask, Compound 64-c (8.7 g) was added and dissolved in 200 mL of o-dichlorobenzene, and cooled using water-ice. BBr₃ (5 equiv.) was slowly added thereto dropwise, and the reaction solution was stirred at about 180 degrees for about 12 hours. After cooling, triethylamine (5 equiv.) was added to quench the reaction, extraction with water/CH₂Cl₂ was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 64-c (yellow solid, 1.14 g, 13%). Through ESI-LCMS, the yellow solid thus obtained was identified as Compound 64-d.

ESI-LCMS: [M]⁺: C₈₂H₇₆N₂ClB. 1134.5868.

4) Synthesis of Compound 64

Under an argon atmosphere, to a 2 L flask, Compound 64-c (1 g, 1 mmol), 2,7-di-tert-butyl-9H-carbazole (0.28 g, 1 mmol), Pd₂dba₃ (0.05 g, 0.05 mmol), tris-tert-butyl phosphine (0.05 mL, 0.1 mmol), and sodium tert-butoxide (0.3 g, 3 mmol) were added and dissolved in 10 mL of toluene, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 64 (yellow solid, 0.95 g, 68%). Through ¹H-NMR and ESI-LCMS, the yellow solid thus obtained was identified as Compound 64.

¹H-NMR (400 MHz, CDCl₃): δ=9.17 (d, 2H), 8.35 (d, 2H), 8.24 (m, 4H), 8.13 (s, 2H), 7.86 (d, 1H), 7.73 (s, 4H), 7.55 (s, 2H), 7.43 (m, 16H), 7.27 (s, 2H), 7.08 (m, 8H), 6.89 (s, 2H), 1.38 (s, 18H), 1.31 (s, 36H).

ESI-LCMS: [M]⁺: C₁₀₂H₁₀₀N₃B. 1377.7968.

(5) Synthesis of Compound 84

Compound 84 according to an embodiment may be synthesized, for example, by the reactions below.

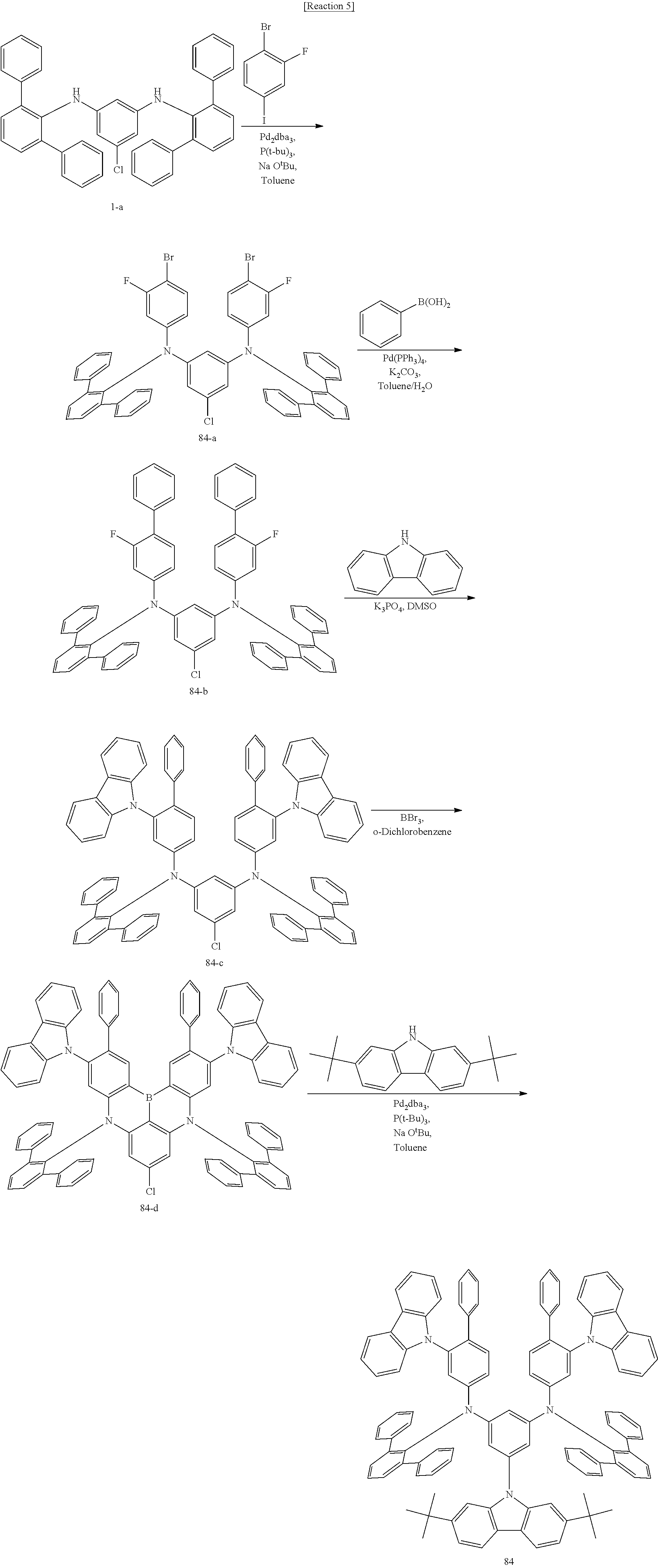

1) Synthesis of Intermediate Compound 84-a

Under an argon atmosphere, to a 2 L flask, Compound 1-a (20 g, 33 mmol), 1-bromo-2-fluoro-4-iodobenzene (45 g, 150 mmol), Pd₂dba₃ (1.5 g, 1.65 mmol), tris-tert-butyl phosphine (1.4 mL, 3.3 mmol), and sodium tert-butoxide (96 g, 100 mmol) were added and dissolved in 300 mL of toluene, and the reaction solution was stirred at about 100 degrees for about 24 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 84-a (white solid, 13 g, 43%). Through ESI-LCMS, the white solid thus obtained was identified as Compound 84-a.

ESI-LCMS: [M]⁺: C₅₄H₃₅Br₂ClF₂N₂. 942.0811.

2) Synthesis of Intermediate Compound 84-b

Under an argon atmosphere, to a 1 L flask, Compound 84-a (13 g, 14 mmol), phenyl boronic acid (3.4 g, 28 mmol), Pd(PPh₃)₄ (0.48 g, 0.4 mmol), and potassium carbonate (5.8 g, 42 mmol) were added and dissolved in 150 mL of toluene and 50 mL of H₂O, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 84-b (white solid, 10.6 g, 81%). Through ESI-LCMS, the white solid thus obtained was identified as Compound 84-b.

ESI-LCMS: [M]⁺: C₆₆H₄₅N₂C₁F₂. 938.3217.

3) Synthesis of Intermediate Compound 84-c

Under an argon atmosphere, to a 1 L flask, Compound 84-b (10 g, 10 mmol), carbazole (3.5 g, 20 mmol), and potassium phosphate tribasic (6.3 g, 30 mmol) were added and dissolved in 100 mL of DMSO, and the reaction solution was stirred at about 160 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 84-c (white solid, 7.5 g, 71%). Through ESI-LCMS, the white solid thus obtained was identified as Compound 84-c.

ESI-LCMS: [M]⁺: C₉₀H₆₁N₄Cl. 1232.4664.

4) Synthesis of Intermediate Compound 84-d

Under an argon atmosphere, to 1 L flask, Compound 84-c (7.5 g) was added and dissolved in 200 mL of o-dichlorobenzene, and cooled using water-ice. BBr₃ (5 equiv.) was slowly added thereto dropwise, and the reaction solution was stirred at about 180 degrees for about 12 hours. After cooling, triethylamine (5 equiv.) was added to quench the reaction, extraction with water/CH₂Cl₂ was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 84-d (yellow solid, 1.4 g, 16%). Through ESI-LCMS, the yellow solid thus obtained was identified as Compound 84-d.

ESI-LCMS: [M]⁺: C₉₀H₅₈N₄ClB. 1240.4432.

5) Synthesis of Compound 84

Under an argon atmosphere, to a 2 L flask, Compound 84-d (1.3 g, 1 mmol), 2,7-di-tert-butyl-9H-carbazole (0.28 g, 1 mmol), Pd₂dba₃ (0.05 g, 0.05 mmol), tris-tert-butyl phosphine (0.05 mL, 0.1 mmol), and sodium tert-butoxide (0.3 g, 3 mmol) were added and dissolved in 10 mL of toluene, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 84 (yellow solid, 1.1 g, 73%). Through ¹H-NMR and ESI-LCMS, the yellow solid thus obtained was identified as Compound 84.

¹H-NMR (400 MHz, CDCl₃): δ=9.24 (d, 2H), 8.55 (d, 4H), 8.33 (d, 2H), 8.20 (d, 4H), 8.13 (s, 2H), 7.94 (d, 4H), 7.77 (s, 2H), 7.50 (d, 2H), 7.43 (m, 18H), 7.19 (m, 8H), 7.08 (m, 8H), 6.89 (s, 2H), 1.38 (s, 18H).

ESI-LCMS: [M]⁺: C₁₁₀H₈₂N₅B. 1483.6617.

(6) Synthesis of Compound 88

Compound 88 according to an embodiment may be synthesized, for example, by the reactions below.

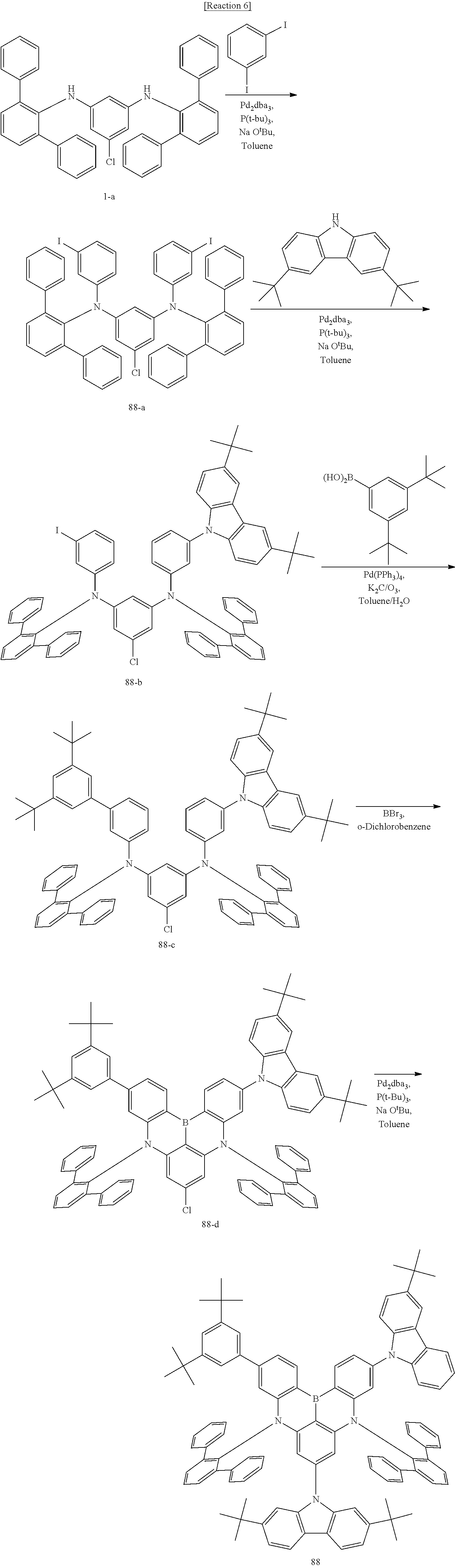

1) Synthesis of Intermediate Compound 88-a

Under an argon atmosphere, to a 2 L flask, Compound 1-a (20 g, 33 mmol), 1,3-diiodobenzene (50 g, 150 mmol), Pd₂dba₃ (1.5 g, 1.65 mmol), tris-tert-butyl phosphine (1.4 mL, 3.3 mmol), and sodium tert-butoxide (96 g, 100 mmol) were added and dissolved in 300 mL of toluene, and the reaction solution was stirred at about 100 degrees for about 24 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 88-a (white solid, 16.5 g, 50%). Through ESI-LCMS, the white solid thus obtained was identified as Compound 88-a.

ESI-LCMS: [M]⁺: C₅₄H₃₇Cl₂l₂N₂. 1002.0739.

2) Synthesis of Intermediate Compound 88-b

Under an argon atmosphere, to a 2 L flask, Compound 88-a (16 g, 16 mmol), carbazole (2.7 g, 16 mmol), Pd₂dba₃ (0.3 g, 0.32 mmol), tris-tert-butyl phosphine (0.3 mL, 0.32 mmol), and sodium tert-butoxide (4.5 g, 48 mmol) were added and dissolved in 300 mL of toluene, and the reaction solution was stirred at about 100 degrees for about 24 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 88-b (white solid, 10.5 g, 56%). Through ESI-LCMS, the white solid thus obtained was identified as Compound 88-b.

ESI-LCMS: [M]⁺: C₇₄H₆₁CllN₃. 1153.3336.

3) Synthesis of Intermediate Compound 88-c

Under an argon atmosphere, to a 1 L flask, Compound 84-b (10 g, 8.6 mmol), 3,5-di-tert-butyl-phenyl boronic acid (2.1 g, 8.6 mmol), Pd(PPh₃)₄ (0.3 g, 0.3 mmol), and potassium carbonate (4.1 g, 30 mmol) were added and dissolved in 100 mL of toluene and 50 mL of H₂O, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 84-c (white solid, 7.7 g, 74%). Through ESI-LCMS, the white solid thus obtained was identified as Compound 84-c.

ESI-LCMS: [M]⁺: C₈₈H₈₂N₃Cl. 1215.6127.

4) Synthesis of Intermediate Compound 88-d

Under an argon atmosphere, to 1 L flask, Compound 88-c (7.7 g) was added and dissolved in 200 mL of o-dichlorobenzene, and cooled using water-ice. BBr₃ (5 equiv.) was slowly added thereto dropwise, and the reaction solution was stirred at about 180 degrees for about 12 hours. After cooling, triethylamine (5 equiv.) was added to quench the reaction, extraction with water/CH₂Cl₂ was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 88-d (yellow solid, 1.1 g, 15%). Through ESI-LCMS, the yellow solid thus obtained was identified as Compound 88-d.

ESI-LCMS: [M]⁺: C₈₈H₇₉N₃ClB. 1223.6161.

5) Synthesis of Compound 88

Under an argon atmosphere, to a 2 L flask, Compound 88-d (1.1 g, 1 mmol), 2,7-di-tert-butyl-9H-carbazole (0.28 g, 1 mmol), Pd₂dba₃ (0.05 g, 0.05 mmol), tris-tert-butyl phosphine (0.05 mL, 0.1 mmol), and sodium tert-butoxide (0.3 g, 3 mmol) were added and dissolved in 10 mL of toluene, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 88 (yellow solid, 1 g, 73%). Through ¹H-NMR and ESI-LCMS, the yellow solid thus obtained was identified as Compound 88.

¹H-NMR (400 MHz, CDCl₃): δ=9.32 (d, 2H), 8.95 (s, 2H), 8.35 (s, 2H), 8.20 (d, 4H), 8.13 (s, 2H), 8.04 (d, 2H), 7.91 (d, 2H), 7.73 (s, 2H), 7.62 (d, 2H), 7.55 (s, 1H), 7.43 (m, 18H), 7.23 (s, 2H), 7.08 (m, 8H), 6.84 (s, 2H), 1.43 (s, 9H), 1.32 (s, 9H), 1.08 (s, 9H).

ESI-LCMS: [M]⁺: C₁₀₈H₁₀₃N₄B. 1466.8319.

(7) Synthesis of Compound 92

Compound 92 according to an embodiment may be synthesized, for example, by the reactions below.

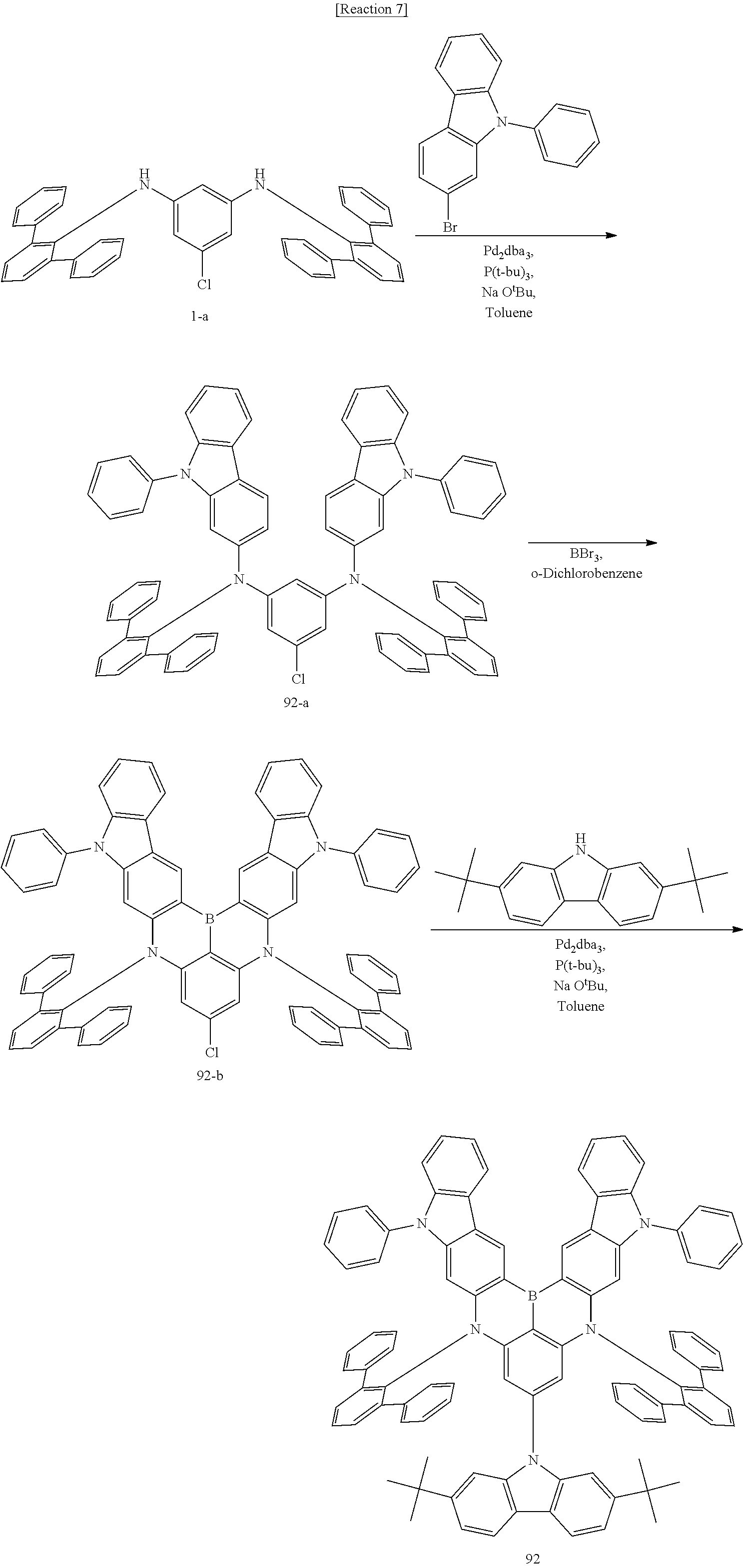

1) Synthesis of Intermediate Compound 92-a

Under an argon atmosphere, to a 2 L flask, Compound 1-a (20 g, 33 mmol), 2-bromo-9-phenyl-9H-carbazole (48 g, 150 mmol), Pd₂dba₃ (1.5 g, 1.65 mmol), tris-tert-butyl phosphine (1.4 mL, 3.3 mmol), and sodium tert-butoxide (96 g, 100 mmol) were added and dissolved in 300 mL of toluene, and the reaction solution was stirred at about 100 degrees for about 24 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Intermediate Compound 92-a (white solid, 16.4 g, 46%). Through ESI-LCMS, the white solid thus obtained was identified as Compound 92-a.

ESI-LCMS: [M]⁺: C₇₈H₅₃ClN₄. 1080.3039.

2) Synthesis of Intermediate Compound 92-b

Under an argon atmosphere, to 1 L flask, Compound 92-a (16 g) was added and dissolved in 300 mL of o-dichlorobenzene, and cooled using water-ice. BBr₃ (5 equiv.) was slowly added thereto dropwise, and the reaction solution was stirred at about 180 degrees for about 12 hours. After cooling, triethylamine (5 equiv.) was added to quench the reaction, extraction with water/CH₂Cl₂ was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 92-b (yellow solid, 2 g, 13%). Through ESI-LCMS, the yellow solid thus obtained was identified as Compound 92-b.

ESI-LCMS: [M]⁺: C₇₈H₅₀N₄ClB. 1088.3879.

3) Synthesis of Compound 92

Under an argon atmosphere, to a 2 L flask, Compound 92-b (1 g, 1 mmol), 2,7-di-tert-butyl-9H-carbazole (0.28 g, 1 mmol), Pd₂dba₃ (0.05 g, 0.05 mmol), tris-tert-butyl phosphine (0.05 mL, 0.1 mmol), and sodium tert-butoxide (0.3 g, 3 mmol) were added and dissolved in 10 mL of toluene, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 92 (yellow solid, 0.9 g, 73%). Through ¹H-NMR and ESI-LCMS, the yellow solid thus obtained was identified as Compound 92.

¹H-NMR (400 MHz, CDCl₃): δ=8.94 (s, 2H), 8.45 (d, 2H), 8.19 (d, 2H), 8.13 (s, 2H), 7.93 (s, 2H), 7.62 (t, 2H), 7.55 (m, 10H), 7.43 (m, 18H), 7.20 (t, 2H), 7.08 (m, 8H), 6.86 (s, 2H), 1.35 (s, 18H).

ESI-LCMS: [M]⁺: C₉₈H₇₄N₅B. 1331.5997.

(8) Synthesis of Compound 94

Compound 94 according to an embodiment may be synthesized, for example, by the reactions below.

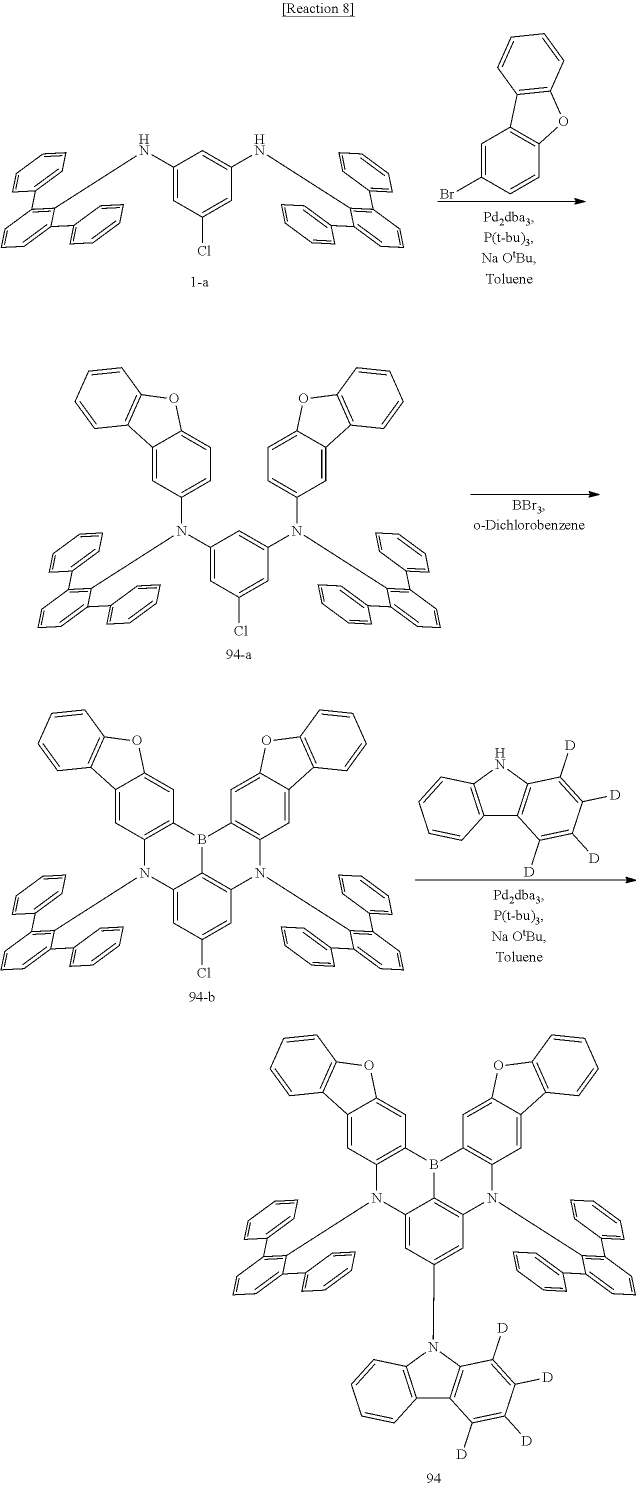

1) Synthesis of Intermediate Compound 94-a

Under an argon atmosphere, to a 2 L flask, Compound 1-a (20 g, 33 mmol), 2-bromo-dibenzo[b,d]furan (37 g, 150 mmol), Pd₂dba₃ (1.5 g, 1.65 mmol), tris-tert-butyl phosphine (1.4 mL, 3.3 mmol), and sodium tert-butoxide (96 g, 100 mmol) were added and dissolved in 300 mL of toluene, and the reaction solution was stirred at about 100 degrees for about 24 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 94-a (white solid, 16 g, 52%). Through ESI-LCMS, the white solid thus obtained was identified as Compound 94-a.

ESI-LCMS: [M]⁺: C₆₆H₄₃ClO₂N₂. 930.2997.

2) Synthesis of Intermediate Compound 94-b

Under an argon atmosphere, to 1 L flask, Compound 94-a (16 g) was added and dissolved in 300 mL of o-dichlorobenzene, and cooled using water-ice. BBr₃ (5 equiv.) was slowly added thereto dropwise, and the reaction solution was stirred at about 180 degrees for about 12 hours. After cooling, triethylamine (5 equiv.) was added to quench the reaction, extraction with water/CH₂Cl₂ was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 94-b (yellow solid, 1.3 g, 8%). Through ESI-LCMS, the yellow solid thus obtained was identified as Compound 94-b.

ESI-LCMS: [M]⁺: C₆₆H₄₀N₂ClO₂B. 938.2911.

3) Synthesis of Compound 94

Under an argon atmosphere, to a 2 L flask, Compound 94-b (0.94 g, 1 mmol), 9H-carbazole-1,2,3,4-d4 (0.17 g, 1 mmol), Pd₂dba₃ (0.05 g, 0.05 mmol), tris-tert-butyl phosphine (0.05 mL, 0.1 mmol), and sodium tert-butoxide (0.3 g, 3 mmol) were added and dissolved in 10 mL of toluene, and the reaction solution was stirred at about 100 degrees for about 12 hours. After cooling, water (1 L) and ethyl acetate (300 mL) were added, extraction was performed, and organic layers were collected, dried over MgSO₄, and filtered. The solvent of the filtrate solution was removed under a reduced pressure, and the solid thus obtained was separated and purified by column chromatography using silica gel and a developing solvent of CH₂Cl₂ and hexane to obtain Compound 94 (yellow solid, 0.75 g, 73%). Through ¹H-NMR and ESI-LCMS, the yellow solid thus obtained was identified as Compound 94.

¹H-NMR (400 MHz, CDCl₃): δ=9.33 (s, 2H), 8.55 (s, 1H), 8.22 (m, 6H), 7.99 (d, 2H), 7.94 (d, 1H), 7.54 (d, 2H), 7.44 (m, 14H), 7.16 (s, 1H), 7.08 (m, 8H), 6.88 (s, 2H).

ESI-LCMS: [M]⁺: C₇₈H₄₄N₃BO₂D₄. 1073.4001.

2. Manufacture and Evaluation of Light Emitting Device Including Fused Polycyclic Compound

Light emitting devices of Examples 1 to 8 were manufactured using Compound 1, Compound 29, Compound 37, Compound 64, Compound 84, Compound 88, Compound 92, and Compound 94 as the dopant materials of an emission layer. The Example Compounds correspond to the above-described first compound.

### Example Compounds

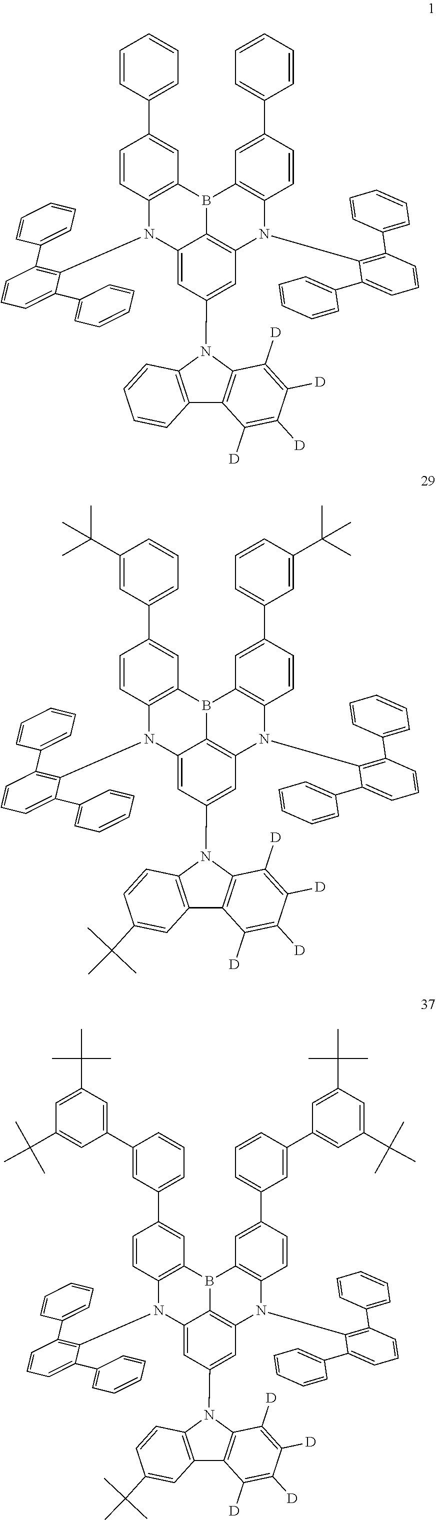

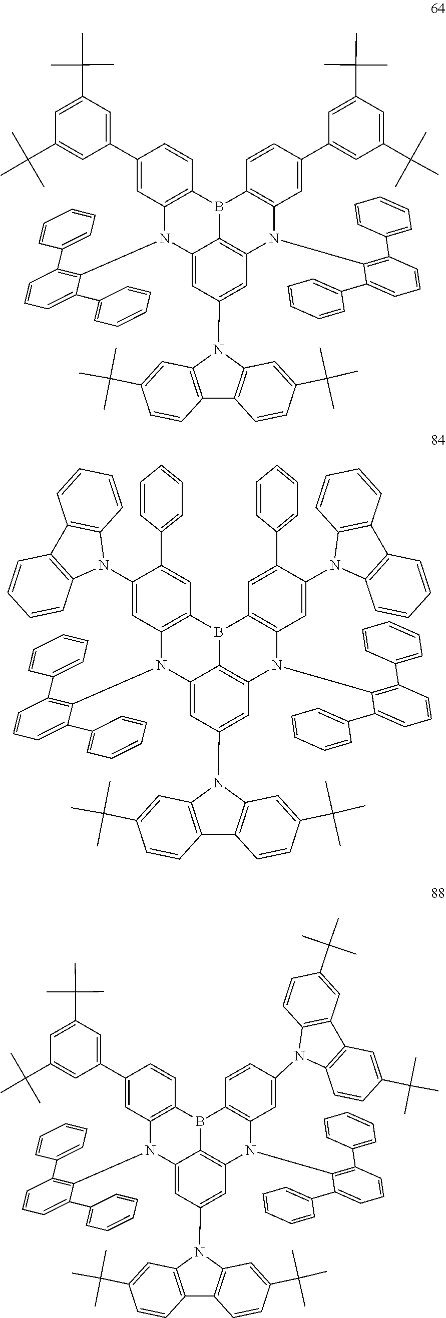

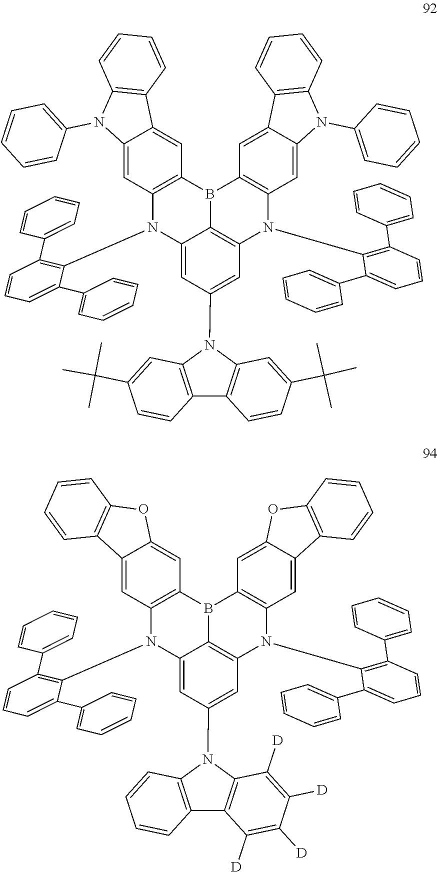 [SMILES: CC(C)(C)c1ccc2c3ccc(C(C)(C)C)cc3n(-c3cc4c5c(c3)N(c3c(-c6ccccc6)cccc3-c3ccccc3)c3cc6c(cc3B5c3cc5c7ccccc7n(-c7ccccc7)c5cc3N4c3c(-c4ccccc4)cccc3-c3ccccc3)c3ccccc3n6-c3ccccc3)c2c1 ; [2H]c1c([2H])c([2H])c2c(c1[2H])c1ccccc1n2-c1cc2c3c(c1)N(c1c(-c4ccccc4)cccc1-c1ccccc1)c1cc4c(cc1B3c1cc3oc5ccccc5c3cc1N2c1c(-c2ccccc2)cccc1-c1ccccc1)oc1ccccc14]

Compound C1 to Compound C5 were used for the manufacture of the devices of Comparative Example 1 to Comparative Example 5.

### Comparative Compounds

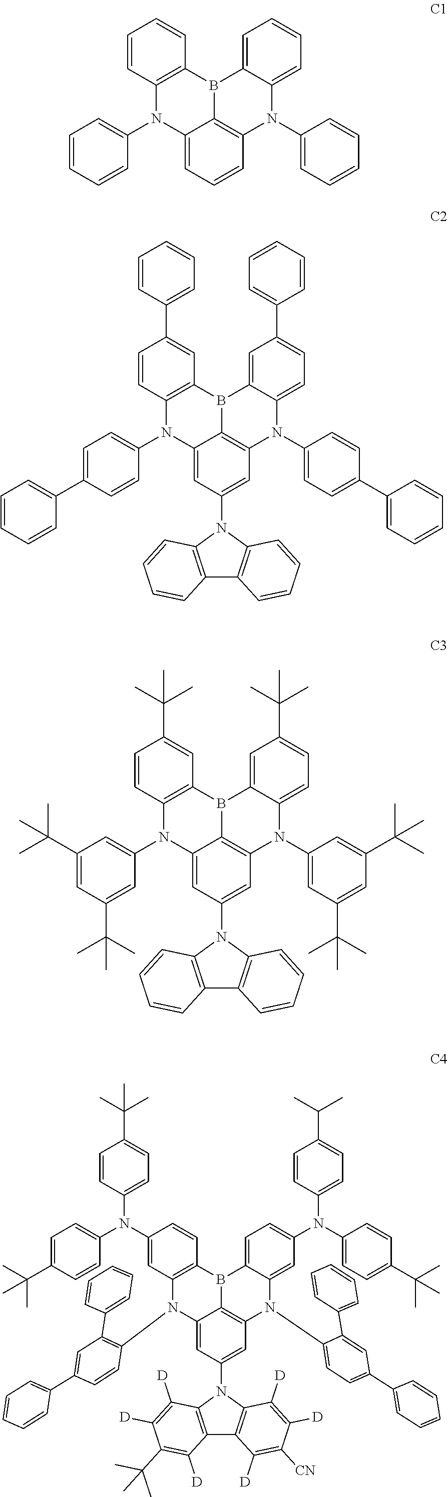

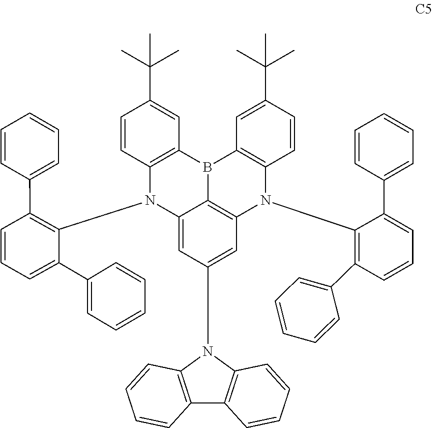 [SMILES: CC(C)(C)c1ccc2c(c1)B1c3cc(C(C)(C)C)ccc3N(c3c(-c4ccccc4)cccc3-c3ccccc3)c3cc(-n4c5ccccc5c5ccccc54)cc(c31)N2c1c(-c2ccccc2)cccc1-c1ccccc1]

(Manufacture of Light Emitting Device)

An ITO glass substrate was cut into a size of about 50 mm×50 mm×0.7 mm, washed by ultrasonic waves using isopropyl alcohol and distilled water for about 5 minutes each, and cleaned by irradiating ultraviolet rays for about 30 minutes and cleaned by ozone. The ITO glass substrate was installed in a vacuum deposition apparatus. A hole injection layer with a thickness of about 300 Å was formed of NPD, and on the hole injection layer, a hole transport layer with a thickness of about 200 Å was formed of HTL-6. On the hole transport layer, an emission auxiliary layer with a thickness of about 100 Å was formed of CzSi.

In accordance with an embodiment, on the emission auxiliary layer, a host compound of a mixture of a first host of HT-14 and a second host of ET-15 according to embodiments in a ratio of 1:1, and a dopant compound using the Example Compound or Comparative Compound were co-deposited in a weight ratio of about 97:3 to form an emission layer EML with a thickness of about 200 Å.

In accordance with another embodiment, on the emission auxiliary layer, a host compound of a mixture of a first host of HT-14 and a second host of ET-15 according to embodiments in a ratio of 1:1, a dopant compound using the Example Compound or Comparative Compound, and a sensitizer material of AD-37 were co-deposited in a weight ratio of about 85:14:1 to form an emission layer EML with a thickness of about 200 Å.

On the emission layer, a hole blocking layer with a thickness of about 200 Å was formed of TSPO1. An electron transport layer with a thickness of about 300 Å was formed of TPBi, and on the electron transport layer, an electron injection layer with a thickness of about 10 Å was formed of LiF. A LiF/Al electrode with a thickness of about 3000 Å was formed of Al. All layers were formed by a vapor deposition method.

The compounds which were used for the manufacture of the light emitting devices according to the Examples and the Comparative Examples are shown below. The materials below were used after purchasing commercial products and performing sublimation purification.

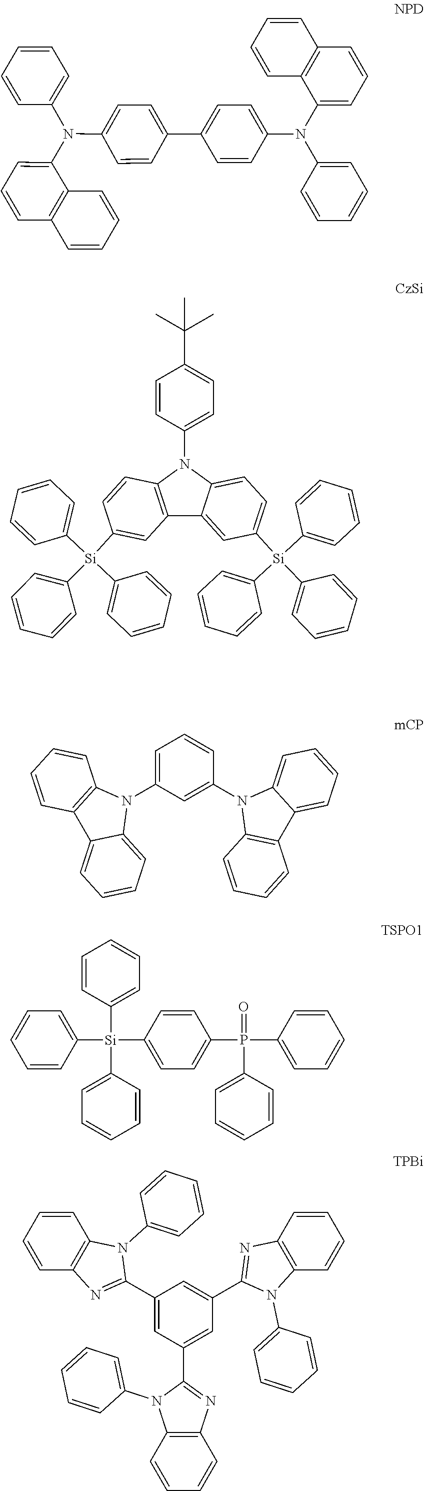

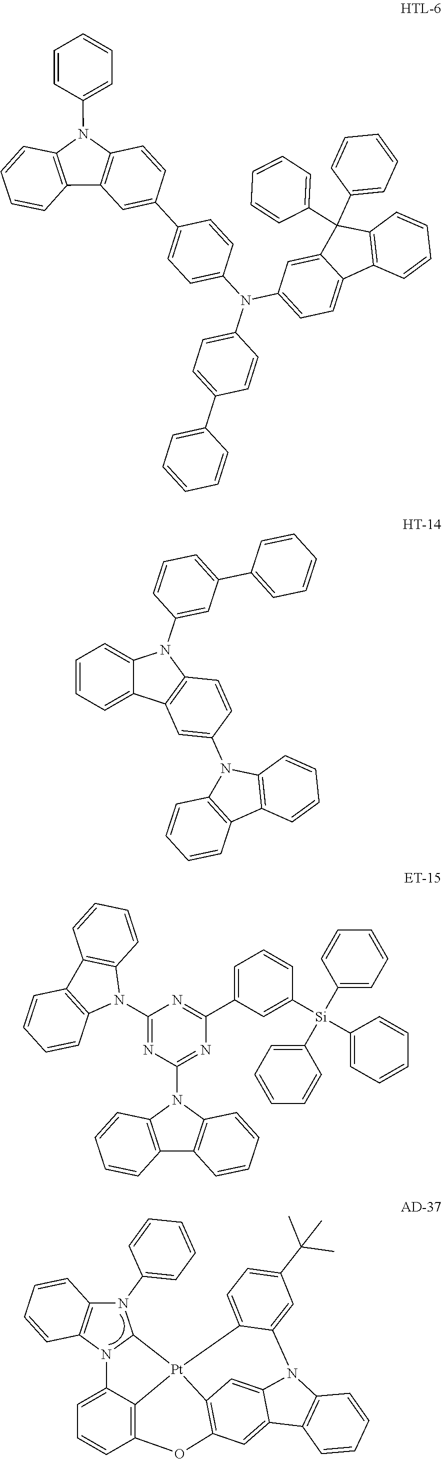

(Evaluation of physical properties of Example Compounds and Comparative Compounds)

In Table 1 and Table 2, the physical properties of the Example Compounds, i.e., Compound 1, Compound 29, Compound 37, Compound 64, Compound 84, Compound 88, Compound 92 and Compound 94, and the Comparative Compounds, i.e., Compound C1, Compound C2, Compound C3 and Compound C4 were evaluated and shown.

In Table 1, the lowest unoccupied molecularorbital (LUMO) energy level, the highest occupied molecular orbital (HOMO) energy level, the lowest excitation triplet energy level (Ti), the lowest excitation singlet energy level (S1), and a difference (S1-T1, hereinafter, ΔE_{ST}) between the lowest excitation singlet energy level (S1) and the lowest excitation triplet energy level (T1) of the Example Compounds and the Comparative Compounds are shown.

TABLE 1

| | | HOMO | LUMO | S1 | T1 | ΔE_{ST} |
|---|---|---|---|---|---|---|
| Division | Dopant | (eV) | (eV) | (eV) | (eV) | (eV) |
| Example 1 | Compound 1 | −5.43 | −2.46 | 2.73 | 2.57 | 0.16 |
| Example 2 | Compound 29 | −5.36 | −2.19 | 2.71 | 2.51 | 0.2 |
| Example 3 | Compound 37 | −5.37 | −2.37 | 2.71 | 2.54 | 0.17 |
| Example 4 | Compound 64 | −5.25 | −2.18 | 2.71 | 2.52 | 0.19 |
| Example 5 | Compound 84 | −5.43 | −2.22 | 2.68 | 2.52 | 0.16 |
| Example 6 | Compound 88 | −5.38 | −2.18 | 2.71 | 2.52 | 0.19 |
| Example 7 | Compound 92 | −5.31 | −2.31 | 2.70 | 2.48 | 0.22 |
| Example 8 | Compound 94 | −5.39 | −2.28 | 2.68 | 2.47 | 0.21 |
| Comparative | Compound C1 | −5.12 | −2.33 | 2.72 | 2.51 | 0.21 |
| Example 1 | | | | | | |
| Comparative | Compound C2 | −5.29 | −2.38 | 2.71 | 2.54 | 0.17 |
| Example 2 | | | | | | |
| Comparative | Compound C3 | −5.21 | −2.31 | 2.69 | 2.53 | 0.16 |
| Example 3 | | | | | | |
| Comparative | Compound C4 | −5.25 | −2.38 | 2.71 | 2.53 | 0.18 |
| Example 4 | | | | | | |
| Comparative | Compound C5 | −5.28 | −2.36 | 2.73 | 2.55 | 0.18 |
| Example 5 | | | | | | |

Referring to Table 1, the compounds included in the light emitting devices of Example 1 to Example 8 and the light emitting devices of Comparative Example 1 to Comparative Example 5 may be thermally activated delayed fluorescence dopants with a ΔE_{ST} that is equal to or less than about 0.3 eV. For example, the compounds included in the light emitting devices of Example 1 to Example 8 and the light emitting devices of Comparative Example 1 to Comparative Example 5 may have a ΔE_{ST} equal to or less than about 0.22 eV. In Table 2, the t, emission efficiency (Photoluminescence Quantum Yield (PLQY)), λ_{Abs}, λₑₘᵢ, λ_{film}, Stokes-shift, and full width at quarter maximum (FWQM) of the Example Compounds and Comparative Compounds were measured.

In Table 2, t is fluorescence lifetime for a delayed component during emitting light in a device.

In Table 2, the λ_{Abs} is the absorption maximum wavelength, the λₑₘᵢ is the emission maximum wavelength, and the λ_{film} is the emission maximum wavelength at film composed of a corresponding compound.

In Table 2, the full width at quarter maximum (FWQM) is a width at a ¼ point of the maximum peak in an emission spectrum.

TABLE 2

| | | t | PLQY | λ_{Abs} | λₑₘᵢ | λ_{film} | Stokes- | FWQM |
|---|---|---|---|---|---|---|---|---|
| Division | Dopant | (ms) | (%) | (nm) | (nm) | (nm) | shift | (nm) |
| Example 1 | Compound 1 | 32 | 81 | 446 | 454 | 456 | 8 | 31 |
| Example 2 | Compound 29 | 38 | 88 | 447 | 456 | 458 | 9 | 32 |
| Example 3 | Compound 37 | 36 | 86 | 445 | 455 | 457 | 10 | 33 |
| Example 4 | Compound 64 | 33 | 81 | 446 | 456 | 458 | 10 | 32 |
| Example 5 | Compound 84 | 38 | 88 | 447 | 459 | 461 | 12 | 34 |
| Example 6 | Compound 88 | 26 | 89 | 446 | 456 | 458 | 10 | 31 |
| Example 7 | Compound 92 | 156 | 82 | 448 | 461 | 463 | 13 | 28 |
| Example 8 | Compound 94 | 89 | 95 | 447 | 459 | 461 | 12 | 34 |
| Comparative | Compound C1 | 133 | 91 | 444 | 456 | 465 | 12 | 39 |
| Example 1 | | | | | | | | |
| Comparative | Compound C2 | 38 | 86 | 446 | 458 | 462 | 12 | 33 |
| Example 2 | | | | | | | | |
| Comparative | Compound C3 | 44 | 80 | 437 | 450 | 460 | 13 | 37 |
| Example 3 | | | | | | | | |
| Comparative | Compound C4 | 39 | 89 | 436 | 449 | 459 | 13 | 43 |
| Example 4 | | | | | | | | |
| Comparative | Compound C5 | 40 | 83 | 440 | 453 | 456 | 13 | 44 |
| Example 5 | | | | | | | | |

Referring to the results of Table 2, referring to the λ_{Abs}, λₑₘᵢ, and λ_{film} values of Example 1 to Example 8 and Comparative Example 1 to Comparative Example 5, it could be confirmed that the light emitting devices of Example 1 to Example 8 and the light emitting devices of Comparative Example 1 to Comparative Example 5 emitted light with a maximum emission wavelength value of about 460 nm. Thus, the light emitting devices of Example 1 to Example 8 and the light emitting devices of Comparative Example 1 to Comparative Example 5 emitted pure blue light. The FWQM range of the light emitting devices of Example 1 to Example 8 was in a range of about 28 nm to about 34 nm. The FWQM range of the light emitting devices of Comparative Example 1 to Comparative Example 5 was in a range of about 33 nm to about 44 nm. It could be confirmed that the FWQM range of the light emitting devices of the Examples was smaller than the FWQM range of the light emitting devices of the Comparative Examples.

It could be confirmed that the range of the Stokes-shift values of the light emitting devices of Example 1 to Example 8 was smaller than the range of the Stokes-shift values of the light emitting devices of Comparative Example 1 to Comparative Example 5.

(Evaluation of Properties of Light Emitting Device)

The evaluation of the properties of the light emitting devices manufactured was conducted using a measurement apparatus of brightness orientation properties. In Table 3 to Table 6, in order to evaluate the properties of the light emitting devices according to the Examples and Comparative Examples, driving voltages, efficiency, emission wavelengths, full width of half maximum (FWHM), lifetime ratios, CIE color coordinate values and internal quantum efficiency (hereinafter, Q.E.) were measured. The driving voltages (V) and emission efficiency (cd/A) at a current density of 10 mA/cm², and a luminance of 1,000 cd/m² for the light emitting devices manufactured were measured. The lifetime ratio was shown by measuring the time for deterioration of the luminance to about 95% compared to an initial luminance, and comparison values were recorded by setting the lifetime of Comparative Example 1 to 1.0.

In Table 3 to Table 6, Compound HT1 was used as a first host material, Compound ET1 was used as a second host material, and Compound PS1 was used as a sensitizer, for all of Example 1 to Example 8 and Comparative Example 1 to Comparative Example 5.

In Table 3, light emitting devices including a first host, a second host, and a TADF dopant in an emission layer were evaluated. The light emitting devices of Table 3 are bottom-emission type light emitting devices.

TABLE 3

| | | Driving | | Emission | Lifetime | | |
|---|---|---|---|---|---|---|---|
| | | voltage | Efficiency | wavelength | ratio | CIE | Q · E |
| Division | Dopant | (V) | (cd/A) | (nm) | (T95) | (x, y) | (%) |
| Example 1 | Compound 1 | 4.5 | 7.9 | 459 | 2.4 | 0.141, 0.103 | 10.2 |
| Example 2 | Compound 29 | 4.5 | 8.2 | 459 | 2.8 | 0.140, 0.111 | 10.0 |
| Example 3 | Compound 37 | 4.4 | 8.1 | 460 | 2.5 | 0.141, 0.113 | 10.5 |
| Example 4 | Compound 64 | 4.4 | 8.7 | 459 | 3.2 | 0.139, 0.116 | 10.3 |
| Example 5 | Compound 84 | 4.4 | 8.3 | 461 | 1.6 | 0.135, 0.108 | 9.3 |
| Example 6 | Compound 88 | 4.5 | 8.9 | 457 | 1.8 | 0.140, 0.103 | 11.0 |
| Example 7 | Compound 92 | 4.7 | 7.2 | 460 | 3.0 | 0.138, 0.113 | 7.0 |
| Example 8 | Compound 94 | 4.8 | 7.5 | 459 | 2.2 | 0.139, 0.109 | 7.7 |
| Comparative | Compound C1 | 5.5 | 2.4 | 462 | 1.0 | 0.133, 0.135 | 3.0 |
| Example 1 | | | | | | | |
| Comparative | Compound C2 | 4.9 | 7.3 | 461 | 1.4 | 0.134, 0.098 | 7.2 |
| Example 2 | | | | | | | |
| Comparative | Compound C3 | 5.4 | 4.4 | 460 | 1.2 | 0.140, 0.111 | 5.3 |
| Example 3 | | | | | | | |
| Comparative | Compound C4 | 5.1 | 4.5 | 457 | 1.2 | 0.140, 0.108 | 4.3 |
| Example 4 | | | | | | | |
| Comparative | Compound C5 | 5.2 | 5.1 | 457 | 2.2 | 0.143, 0.086 | 6.2 |
| Example 5 | | | | | | | |

Referring to the results of Table 3, it is thought that the light emitting devices of Example 1 to Example 8 and the light emitting devices of Comparative Example 1 to Comparative Example 5 emit blue light considering the emission wavelengths and CIE color coordinate values. The light emitting devices of Example 1 to Example 8 showed lower driving voltages, higher lifetime ratios, and higher Q.E. values when compared to the light emitting devices of Comparative Example 1 to Comparative Example 5. The light emitting devices of Example 1 to Example 8 showed higher emission efficiency when compared to the light emitting devices of Comparative Example 1 to Comparative Example 5.

In Table 4, light emitting devices including a first host, a second host, a TADF dopant, and a sensitizer were evaluated. The light emitting devices of Table 4 are top-emission type light emitting devices. In Table 4 to Table 6, the FWHM was additionally evaluated in comparison to Table 3.

TABLE 4

| | | Driving | | Emission | | Lifetime | | |
|---|---|---|---|---|---|---|---|---|
| | | voltage | Efficiency | wavelength | FWHM | ratio | CIE | Q · E |
| Division | Dopant | (V) | (cd/A) | (nm) | (nm) | (T95) | (x, y) | (%) |
| Example 1 | Compound 1 | 4.1 | 23.1 | 461 | 46 | 9.2 | 0.137, 0.052 | 51.6 |
| Example 2 | Compound 29 | 4.0 | 24.1 | 461 | 46 | 10.3 | 0.138, 0.053 | 52.7 |
| Example 3 | Compound 37 | 4.1 | 23.8 | 462 | 48 | 8.8 | 0.139, 0.058 | 52.3 |
| Example 4 | Compound 64 | 4.1 | 25.9 | 461 | 48 | 12.1 | 0.137, 0.051 | 55.0 |
| Example 5 | Compound 84 | 4.4 | 22.5 | 462 | 47 | 8.2 | 0.134, 0.057 | 47.2 |
| Example 6 | Compound 88 | 4.5 | 21.4 | 461 | 48 | 7.4 | 0.134, 0.056 | 48.1 |
| Example 7 | Compound 92 | 4.6 | 20.0 | 460 | 47 | 6.8 | 0.140, 0.046 | 43.8 |
| Example 8 | Compound 94 | 4.4 | 20.7 | 462 | 46 | 9.7 | 0.134, 0.056 | 46.9 |
| Comparative | Compound C1 | 5.3 | 16.3 | 462 | 46 | 1 | 0.135, 0.057 | 35.5 |
| Example 1 | | | | | | | | |
| Comparative | Compound C2 | 4.4 | 18.3 | 463 | 52 | 3.5 | 0.133, 0.061 | 43.3 |
| Example 2 | | | | | | | | |
| Comparative | Compound C3 | 4.2 | 17.9 | 460 | 54 | 4.9 | 0.138, 0.050 | 40.9 |
| Example 3 | | | | | | | | |
| Comparative | Compound C4 | 4.3 | 16.8 | 459 | 53 | 3.1 | 0.132, 0.050 | 36.2 |
| Example 4 | | | | | | | | |
| Comparative | Compound C5 | 4.3 | 17.0 | 460 | 53 | 2.7 | 0.138, 0.048 | 39.6 |
| Example 5 | | | | | | | | |

Referring to the results of Table 4, it is thought that the light emitting devices of Example 1 to Example 8 and the light emitting devices of Comparative Example 1 to Comparative Example 5 emit blue light considering the emission wavelengths and CIE color coordinate values. The light emitting devices of Example 1 to Example 8 showed higher emission efficiency when compared to the light emitting devices of Comparative Example 1 to Comparative Example 5.

The light emitting devices of Example 1 to Example 8 showed narrower average FWHM, higher lifetime ratios, and higher Q.E. values when compared to the light emitting devices of Comparative Example 1 to Comparative Example 5.

In Table 5, light emitting devices including a first host, a second host, a TADF dopant, and a sensitizer were evaluated. The light emitting devices of Table 5 are bottom-emission type light emitting devices.

TABLE 5

| | | Driving | | Emission | | Lifetime | | |
|---|---|---|---|---|---|---|---|---|
| | | voltage | Efficiency | wavelength | FWHM | ratio | CIE | Q · E |
| Division | Dopant | (V) | (cd/A) | (nm) | (nm) | (T95) | (x, y) | (%) |
| Example 1 | Compound 1 | 4.5 | 20.0 | 461 | 46 | 4.6 | 0.138, 0.156 | 19.7 |
| Example 2 | Compound 29 | 4.6 | 17.8 | 462 | 48 | 5.0 | 0.136, 0.146 | 17.7 |
| Example 3 | Compound 37 | 4.7 | 18.3 | 462 | 47 | 4.7 | 0.135, 0.145 | 18.9 |
| Example 4 | Compound 64 | 4.6 | 20.3 | 461 | 48 | 5.4 | 0.136, 0.145 | 20.7 |
| Example 5 | Compound 84 | 4.5 | 19.5 | 461 | 46 | 3.3 | 0.133, 0.145 | 19.0 |
| Example 6 | Compound 88 | 4.4 | 20.4 | 462 | 47 | 3.8 | 0.136, 0.143 | 20.2 |
| Example 7 | Compound 92 | 4.6 | 17.7 | 463 | 46 | 5.0 | 0.137, 0.147 | 17.6 |
| Example 8 | Compound 94 | 4.6 | 20.1 | 463 | 48 | 4.2 | 0.134, 0.143 | 18.8 |
| Comparative | Compound C1 | 4.9 | 13.3 | 462 | 48 | 1.0 | 0.137, 0.158 | 13.4 |
| Example 1 | | | | | | | | |
| Comparative | Compound C2 | 4.8 | 15.0 | 463 | 50 | 2.4 | 0.133, 0.142 | 16.3 |
| Example 2 | | | | | | | | |
| Comparative | Compound C3 | 4.6 | 15.3 | 462 | 49 | 1.7 | 0.136, 0.155 | 16.9 |
| Example 3 | | | | | | | | |
| Comparative | Compound C4 | 4.8 | 16.3 | 459 | 49 | 1.3 | 0.138, 0.150 | 17.2 |
| Example 4 | | | | | | | | |
| Comparative | Compound C5 | 4.5 | 17.1 | 458 | 49 | 2.3 | 0.136, 0.125 | 18.2 |
| Example 5 | | | | | | | | |

Referring to the results of Table 5, it is thought that the light emitting devices of Example 1 to Example 8 and the light emitting devices of Comparative Example 1 to Comparative Example 5 emit blue light considering the emission wavelengths and CIE color coordinate values. The light emitting devices of Example 1 to Example 8 showed higher emission efficiency, higher lifetime ratios and higher Q.E. values when compared to the light emitting devices of Comparative Example 1 to Comparative Example 5. The FWHM of the light emitting devices of Example 1 to Example 8 was equal or less of the FWHM of the light emitting devices of Comparative Example 1 to Comparative Example 5.

The light emitting devices of Example 1 to Example 8 showed lowers average driving voltage values when compared to the light emitting devices of Comparative Example 1 to Comparative Example 5.

In Table 6, light emitting devices including a first host, a second host, a TADF dopant, and a sensitizer were evaluated. In Table 6, the type of the dopant and the co-deposition ratio of the first host and the second host were changed. The light emitting devices of Table 6 are top-emission type light emitting devices.

TABLE 6

| | | Host | | | | | | | |
|---|---|---|---|---|---|---|---|---|---|
| | | co-deposition | Driving | | Emission | | Lifetime | | |
| | | ratio | voltage | Efficiency | wavelength | FWHM | ratio | CIE | Q · E |
| Division | Dopant | (HT1:ET1) | (V) | (cd/A) | (nm) | (nm) | (T95) | (x, y) | (%) |
| Example 1 | Compound 1 | 5:5 | 4.1 | 23.1 | 461 | 46 | 7.2 | 0.137, 0.052 | 51.6 |
| Example 2 | | 4:6 | 4.2 | 20.6 | 461 | 47 | 6.3 | 0.138, 0.050 | 47.3 |
| Example 3 | | 6:4 | 4.3 | 23.5 | 462 | 46 | 8.8 | 0.136, 0.052 | 52.2 |
| Example 4 | | 7:3 | 4.1 | 24.0 | 461 | 46 | 9.3 | 0.140, 0.047 | 53.0 |
| Example 5 | Compound 64 | 5:5 | 4.1 | 25.9 | 461 | 48 | 9.1 | 0.137, 0.051 | 55.0 |
| Example 6 | | 4:6 | 4.0 | 22.2 | 463 | 48 | 7.8 | 0.134, 0.057 | 45.6 |
| Example 7 | | 6:4 | 4.1 | 26.3 | 462 | 48 | 9.5 | 0.137, 0.049 | 56.8 |
| Example 8 | | 7:3 | 4.1 | 26.7 | 460 | 48 | 11.4 | 0.139, 0.047 | 58.0 |
| Comparative | Compound C3 | 5:5 | 4.2 | 17.9 | 460 | 54 | 4.9 | 0.138, 0.050 | 40.9 |
| Example 1 | | | | | | | | | |
| Comparative | | 4:6 | 4.3 | 15.8 | 457 | 53 | 4.7 | 0.143, 0.041 | 33.2 |
| Example 2 | | | | | | | | | |
| Comparative | | 6:4 | 4.3 | 18.0 | 459 | 54 | 5.1 | 0.143, 0.042 | 40.5 |
| Example 3 | | | | | | | | | |
| Comparative | | 7:3 | 4.2 | 19.1 | 460 | 54 | 5.4 | 0.137, 0.052 | 46.7 |
| Example 4 | | | | | | | | | |

Referring to the results of Table 6, it is thought that the light emitting devices of Example 1 to Example 8 and the light emitting devices of Comparative Example 1 to Comparative Example 4 emit blue light considering the emission wavelengths and CIE color coordinate values. The light emitting devices of Example 1 to Example 8 showed lower driving voltages, higher efficiency, narrower FWHM, higher lifetime ratios and higher Q.E. values when compared to the light emitting device of Comparative Example 1.

The light emitting devices of Example 2 and Example 6 showed lower driving voltages, higher efficiency, narrower FWHM, higher lifetime ratios, and higher Q.E. values when compared to the light emitting device of Comparative Example 2.

The light emitting devices of Example 3 and Example 7 showed higher efficiency, narrower FWHM, higher lifetime ratios, and higher Q.E. values when compared to the light emitting device of Comparative Example 3. The driving voltages of the light emitting devices of Example 3 and Example 7 showed the same or less driving voltage of the light emitting device of Comparative Example 3.

The light emitting devices of Example 4 and Example 8 showed lower driving voltages, higher efficiency, narrower FWHM, higher lifetime ratios and higher Q.E. values when compared to the light emitting device of Comparative Example 4.

Referring to Table 1 to Table 6 together, Compound C₁ discloses a fused structure of multiple aromatic rings via a boron atom and two heteroatoms, but does not include an ortho-type terphenyl group bonded to a heteroatom, an aryl group or a heterole group connected at the meta or para position with respect to the boron atom, and a substituted or unsubstituted carbazole group connected at the para position to the boron atom. Accordingly, Compound C₁ has lower absorption than the Example Compounds and low FRET efficiency, and may show inferior material stability. As a result, intermolecular interaction may increase, and thermal stability may be weak in contrast to the Example Compounds, and the deterioration phenomenon of a device may increase via the reaction of materials having high energy such as radicals, excitons and polarons during manufacturing a device, and lifetime may be degraded.

Compound C2 discloses a fused structure of multiple aromatic rings via a boron atom and two heteroatoms, and includes an aryl group connected at the meta position to the boron atom and an unsubstituted carbazole group connected at the para position to the boron atom. However, the fused structure does not include an ortho-type terphenyl group bonded to a heteroatom, and thus, the suppression of intermolecular interaction may be difficult, the deterioration phenomenon of a device may increase via the reaction with materials having high energy such as radicals, excitons and polarons during manufacturing a device, and lifetime may be degraded. Compound C2 has an unsubstituted carbazole group connected at the para position to the boron atom, and since the molecular stability of the carbazole group is low, and the material stability of the whole molecule may be degraded.

Compound C3 discloses a fused structure of multiple aromatic rings via a boron atom and two heteroatoms. However, the fused structure does not include an ortho-type terphenyl group bonded to a heteroatom, but instead, a phenyl group substituted with a t-butyl group is bonded to the heteroatom, and thus, the suppression of intermolecular interaction may be difficult, and the deterioration phenomenon of a device may increase during manufacturing the device when compared to the Example Compounds. The fused structure also does not include an aryl group bonded at a para-position to the boron atom, but instead, the fused structure includes a t-butyl group bonded at a para-position to the boron atom, and thus, absorption may be low, FRET efficiency may be low, and material stability may be weak when compared to the Example Compounds. Since Compound C3 has an unsubstituted carbazole group connected at a para position to the boron atom, material stability may be degraded when compared to the Example Compounds.

Compound C4 discloses a fused structure of multiple aromatic rings via a boron atom and two heteroatoms, and a substituted carbazole group bonded at a para position to the boron atom. However, Compound C4 includes ortho- and para-terphenyl groups bonded to the two heteroatoms, respectively, instead of the ortho-type terphenyl groups according to the Example Compounds, and thus, Compound C4 shows different effects from the Example Compounds. In Compound C4, an arylamine group is bonded at a para position to the boron atom rather than an aryl group, and thus, absorption may be low, FRET efficiency may be low, and material stability may be weak when compared to the Example Compounds.

Compound C5 discloses a fused structure of multiple aromatic rings via a boron atom and two heteroatoms, an unsubstituted carbazole group connected at a para position to the boron atom, and ortho-type terphenyl groups bonded to the two heteroatoms. However, Compound C5 has an unsubstituted carbazole group bonded at a para position to the boron atom, and may show deteriorated material stability when compared to the Example Compounds. In Compound C5, a t-butyl group is bonded at a para position to the boron atom rather than an aryl group, and thus, absorption may be low, FRET efficiency may be low, and material stability may be degraded when compared to the Example Compounds.

Accordingly, Compound C1, Compound C2, Compound C3, Compound C4, and Compound C5 are thought to show degraded multiple resonance of a molecule and material stability, and degraded emission efficiency and lifetime ratio when used in a device.

Referring to the results of Table 3 to Table 6, it could be confirmed that the Examples of the light emitting devices using the fused polycyclic compound according to an embodiment as a light emitting material maintained emission wavelength of blue light, and showed improved driving voltages, emission efficiency and device life characteristics when compared to the Comparative Examples.

The first compound of an embodiment may include a fused structure of multiple aromatic rings via at least one boron atom and two heteroatoms. The first compound may include a connected structure of ortho-type terphenyl groups with two heteroatoms, respectively.

The first compound according to embodiments includes an ortho-type terphenyl group in a plate-shape structure including a boron atom, and intermolecular distance may be relatively increased, to reduce intermolecular interaction and improve the stability of a whole molecule.

The first compound includes a connected structure of an ortho-type terphenyl group in a fused structure including a boron atom, and thus, the combination of the boron atom with a nucleophile may be prevented, and the trigonal binding structure of the boron atom may be maintained. Accordingly, the stability and multiple resonance of a molecule may be reinforced, a low ΔE_{ST} value may be shown, and improved delayed fluorescence emission properties may be expected.

The first compound includes a carbazole group bonded at a para-position to the boron atom, and multiple resonance effects may be reinforced, a HOMO level may be lowered, the formation of triplet excitons may be suppressed during manufacturing a device, and device life may be improved. The first compound has a substituted structure of the carbazole group, and may achieve improved material stability.

The first compound includes a substituted or unsubstituted aryl group bonded at a meta- or para-position to the boron atom, and may show largely improved absorption, improved FRET efficiency from a host, and improved efficiency of a device during manufacturing the device. The first compound includes a substituted or unsubstituted aryl group bonded at a meta- or para-position to the boron atom, and may improve material stability due to radical stabilizing effects.

The light emitting device according to embodiments includes a first compound as a thermally activated delayed fluorescence dopant in an emission layer, and may show reduced deterioration phenomenon of a device, improved efficiency and lifetime of a device, and high color purity in a blue light wavelength region.

The light emitting device of an embodiment may show improved device properties of high efficiency and long lifetime.

The fused polycyclic compound of an embodiment may be included in the emission layer of a light emitting device and may contribute to the increase of efficiency and lifetime of the light emitting device.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting device, comprising:
a first electrode;
a second electrode facing the first electrode; and
an emission layer disposed between the first electrode and the second electrode, wherein
the emission layer comprises:
a first compound represented by Formula 1; and
at least one of a second compound represented by Formula 2, a third compound represented by Formula 3, and a fourth compound represented by Formula 4: 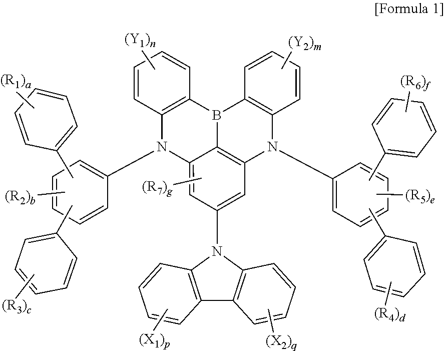
wherein in Formula 1,
X₁ and X₂ are each independently a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring,
p and q are each independently an integer from 0 to 4,
Y₁ and Y₂ are each independently a hydrogen atom, a deuterium atom, a substituted or unsubstituted amine group, a substituted or unsubstituted alkyl group of 1 to 20 carbon atoms, a substituted or unsubstituted oxy group, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring,
wherein for Y₁ and Y₂:
at least one of Y₁ and Y₂ is each independently a substituted or unsubstituted aryl group of 6 to 30 ring-forming carbon atoms, or a substituted or unsubstituted heteroaryl group of 2 to 30 ring-forming carbon atoms; or
at least one of Y₁ and Y₂ is combined with an adjacent group to form a substituted or unsubstituted aliphatic heterocycle of 2 to 30 ring-forming carbon atoms, or a substituted or unsubstituted aromatic heterocycle of 2 to 30 ring-forming carbon atoms,
n and m are each independently an integer from 1 to 4,
R₁ to R₇ are each independently a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring,
a, c, d, and f are each independently an integer from 0 to 5,
b and e are each independently an integer from 0 to 3, and
g is an integer from 0 to 2; 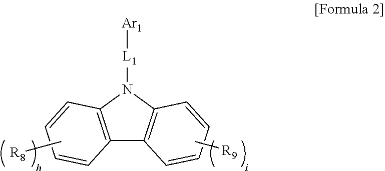
wherein in Formula 2,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Ar₁ is a substituted or unsubstituted aryl group of 6 to 30 ring-forming carbon atoms, or a substituted or unsubstituted heteroaryl group of 2 to 30 ring-forming carbon atoms,
R₈ and R₉ are each independently a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring, and
h and i are each independently an integer from 0 to 4; 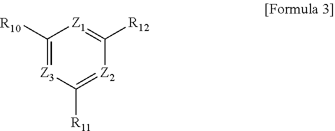
wherein in Formula 3,
at least one of Z₁ to Z₃ is each N,
the remainder of Z₁ to Z₃ are each independently C(R₁₃), and
R₁₀ to R₁₃ are each independently a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring; 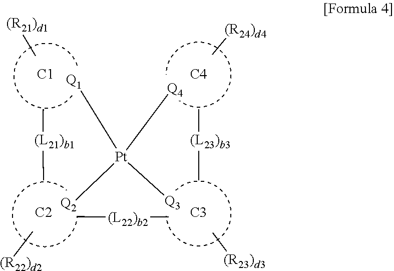
wherein in Formula 4,
Q₁ to Q₄ are each independently C or N,
C₁ to C₄ are each independently a substituted or unsubstituted hydrocarbon ring of 5 to 30 ring-forming carbon atoms, or a substituted or unsubstituted heterocycle of 2 to 30 ring-forming carbon atoms,
L₂₁ to L₂₃ are each independently a direct linkage, 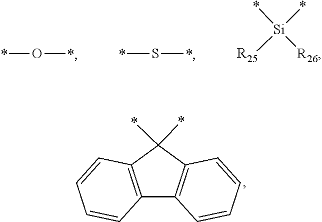
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b1 to b3 are each independently 0 or 1,
R₂₁ to R₂₆ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 1 to 30 ring-forming carbon atoms, or are combined with an adjacent group to form a ring, and
d1 to d4 are each independently an integer from 0 to 4.

2. The light emitting device of claim 1, wherein the emission layer emits delayed fluorescence.

3. The light emitting device of claim 1, wherein the emission layer emits light having a central wavelength in a range of about 430 nm to about 470 nm.

4. The light emitting device of claim 1, wherein the emission layer comprises the first compound, the second compound, and the third compound.

5. The light emitting device of claim 1, wherein the emission layer comprises the first compound, the second compound, the third compound, and the fourth compound.

6. The light emitting device of claim 1, wherein the first compound represented by Formula 1 is represented by Formula 1-1: 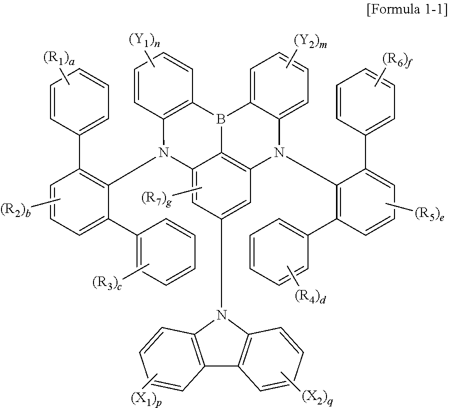
wherein in Formula 1-1,
X₁, X₂, Y₁, Y₂, R₁ to R₇, a to g, n, m, p, and q are each the same as defined in Formula 1.

7. The light emitting device of claim 1, wherein the first compound represented by Formula 1 is represented by one of Formula 1-2-1 to Formula 1-2-7: 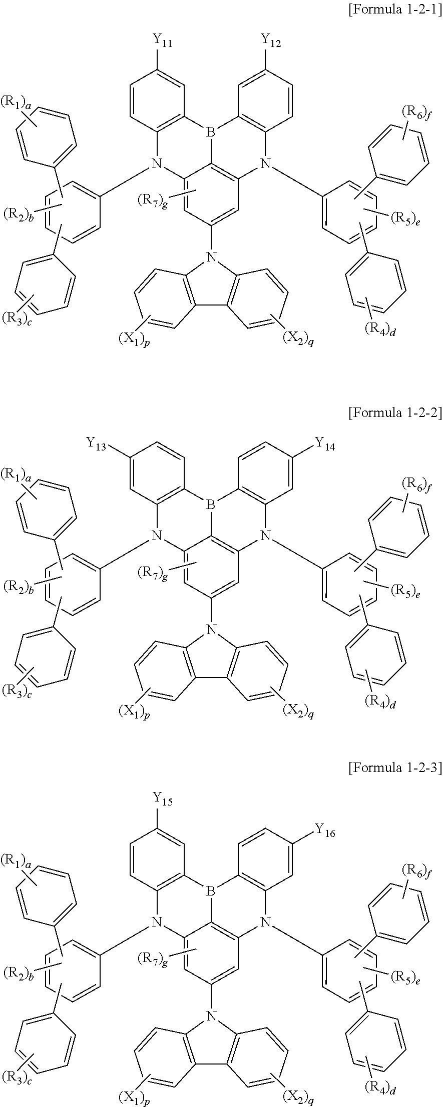 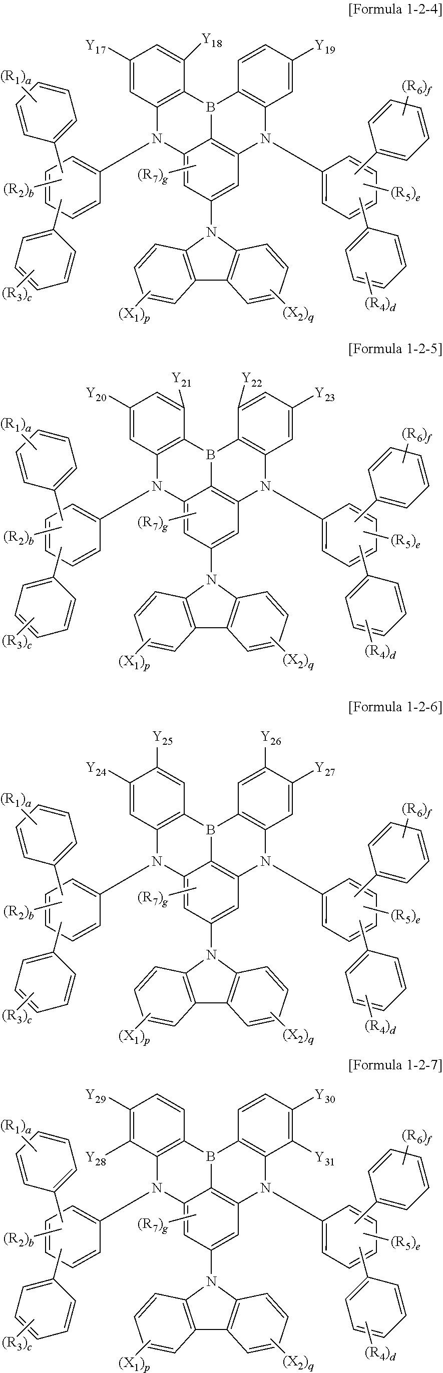
wherein in Formula 1-2-1 to Formula 1-2-7,
Y₁₁ to Y₃₁ are each independently a deuterium atom, a substituted or unsubstituted amine group, a substituted or unsubstituted oxy group, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring,
wherein for Y₁₁ to Y₃₁:
at least one of Y₁₁ and Y₁₂, at least one of Y₁₃ and Y₁₄, at least one of Y₁₅ and Y₁₆, at least one of Y₁₇ and Y₁₈, at least one of Y₂₀ and Y₂₁, and at least one of Y₂₂ and Y₂₃ are each independently a substituted or unsubstituted aryl group of 6 to 30 ring-forming carbon atoms, or a substituted or unsubstituted heteroaryl group of 2 to 30 ring-forming carbon atoms;
at least one of Y₂₄ and Y₂₅ or Y₂₆ and Y₂₇ are combined with each other to form a ring; and
at least one of Y₂₈ and Y₂₉ or Y₃₀ and Y₃₁ are combined with each other to form a ring, and
X₁, X₂, R₁ to R₇, a to g, p, and q are each the same as defined in Formula 1.

8. The light emitting device of claim 1, wherein in Formula 1,
Y₁ and Y₂ are each independently a hydrogen atom, a substituted or unsubstituted t-butyl group, a substituted or unsubstituted diphenyl amine group, a substituted or unsubstituted phenyl group, a substituted or unsubstituted biphenyl group, a substituted or unsubstituted terphenyl group, a substituted or unsubstituted naphthyl group, a substituted or unsubstituted carbazole group, a substituted or unsubstituted pyridine group, or are combined with an adjacent group to form a ring.

9. The light emitting device of claim 1, wherein in Formula 1,
Y₁ and Y₂ each independently comprises at least one substituent selected from Substituent Group Si:

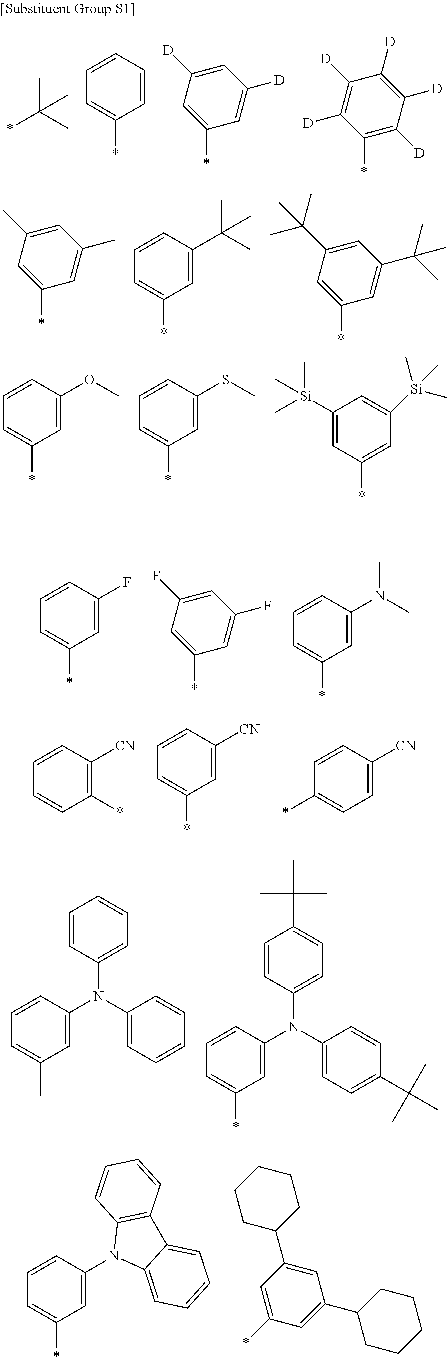

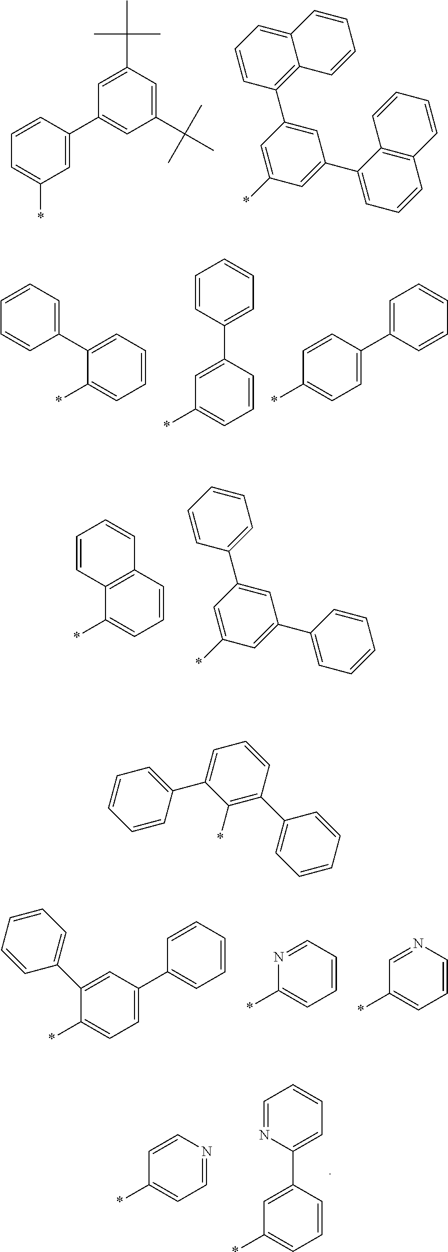

10. The light emitting device of claim 1, wherein in Formula 1,
a case of forming a ring via a combination of two adjacent Y₁ groups and a case of forming a ring via a combination of two adjacent Y₂ groups each comprises at least one substituent selected from Substituent Group S₂:

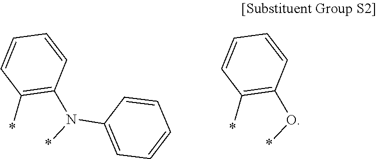 [SMILES: *c1ccccc1N(*)c1ccccc1 ; *Oc1ccccc1*]

11. The light emitting device of claim 1, wherein in Formula 1,
X₁ and X₂ are different from each other.

12. The light emitting device of claim 1, wherein in Formula 1,
X₁ and X₂ are the same.

13. The light emitting device of claim 1, wherein the first compound represented by Formula 1 is represented by Formula 1-3: 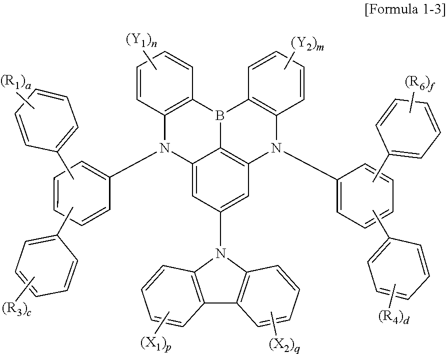
wherein in Formula 1-3,
X₁, X₂, R₁, R₃, R₄, R₆, Y₁, Y₂, a, c, d, f, n, m, p, and q are each the same as defined in Formula 1.

14. The light emitting device of claim 1, wherein in Formula 1,
R₁, R₃, R₄, and R₆ are each independently a hydrogen atom, a deuterium atom, a fluorine atom, a cyano group, a trimethylsilyl group, a methyl group, an isopropyl group, a cumenyl group, a t-butyl group, a cyclopentyl group, a methoxy group, a phenoxy group, or are combined with an adjacent group to form a ring.

15. The light emitting device of claim 1, wherein the first compound represented by Formula 1 comprises at least one compound selected from Compound Group 1: 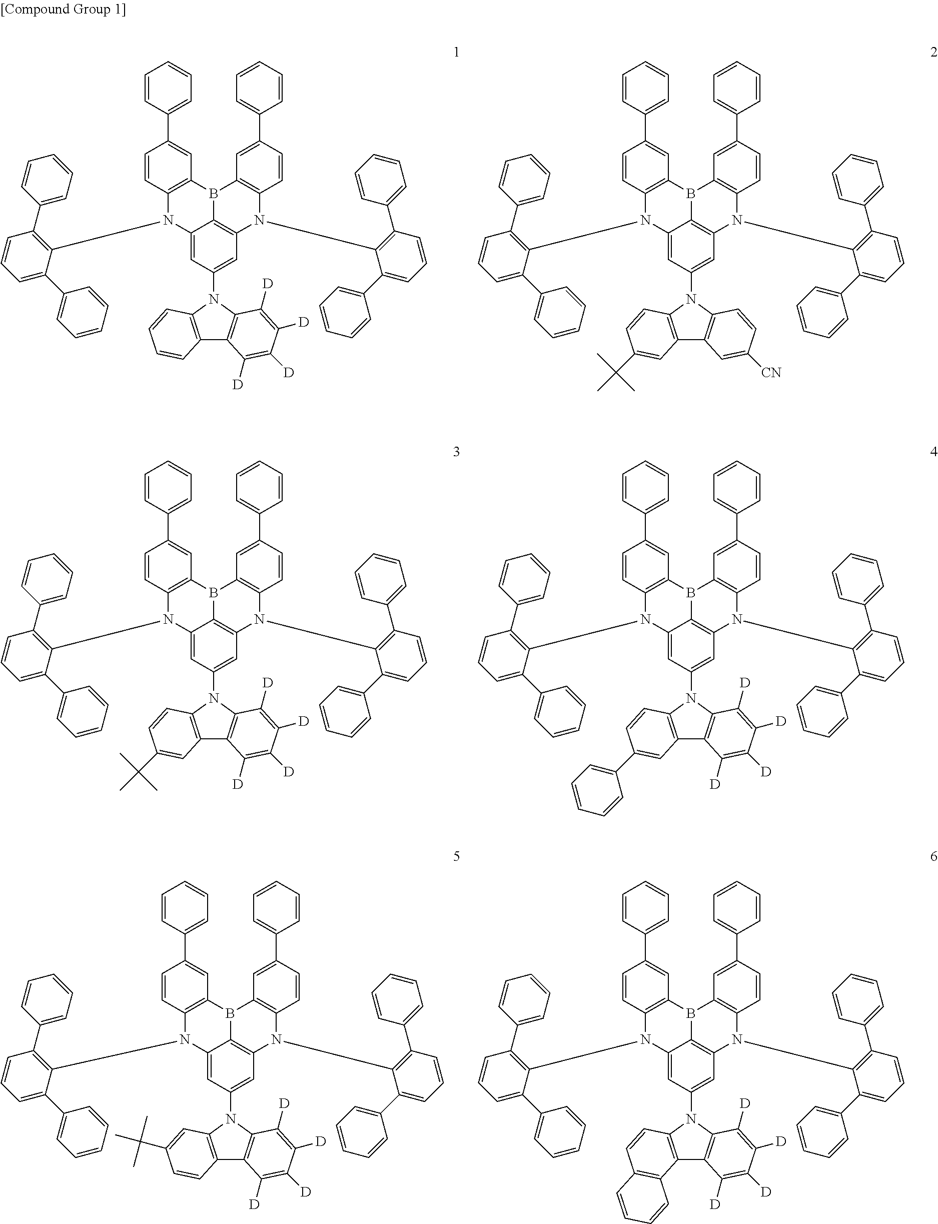 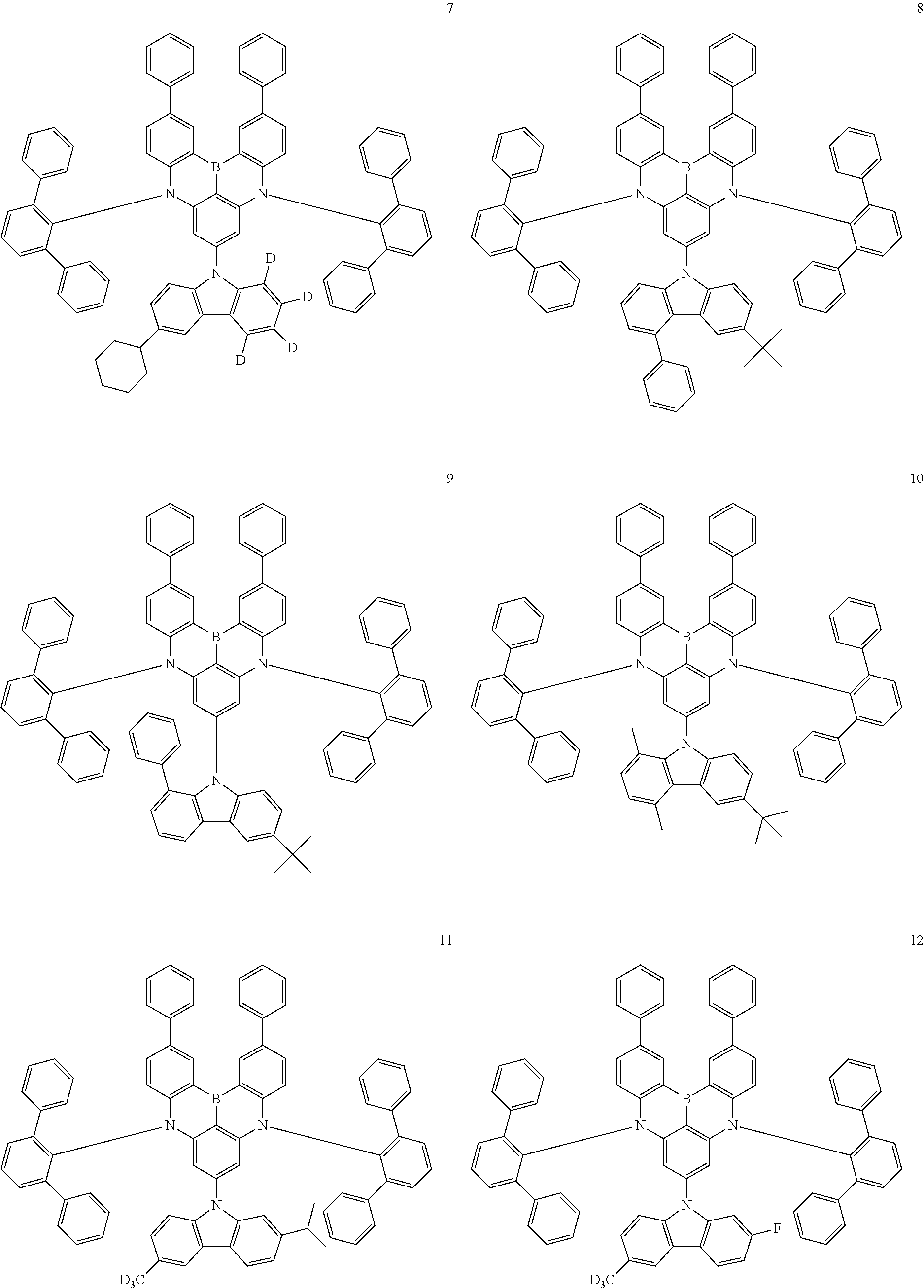 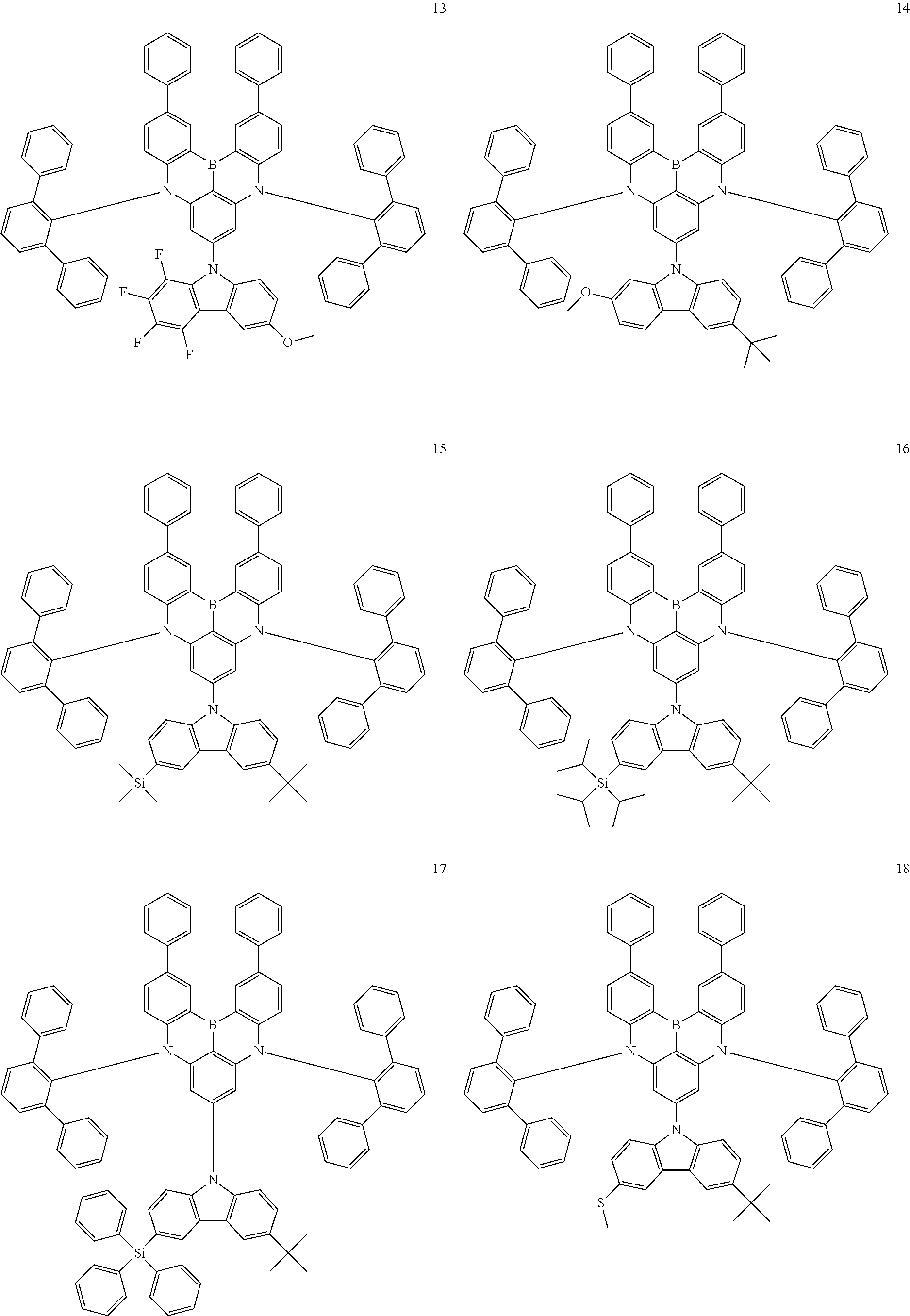 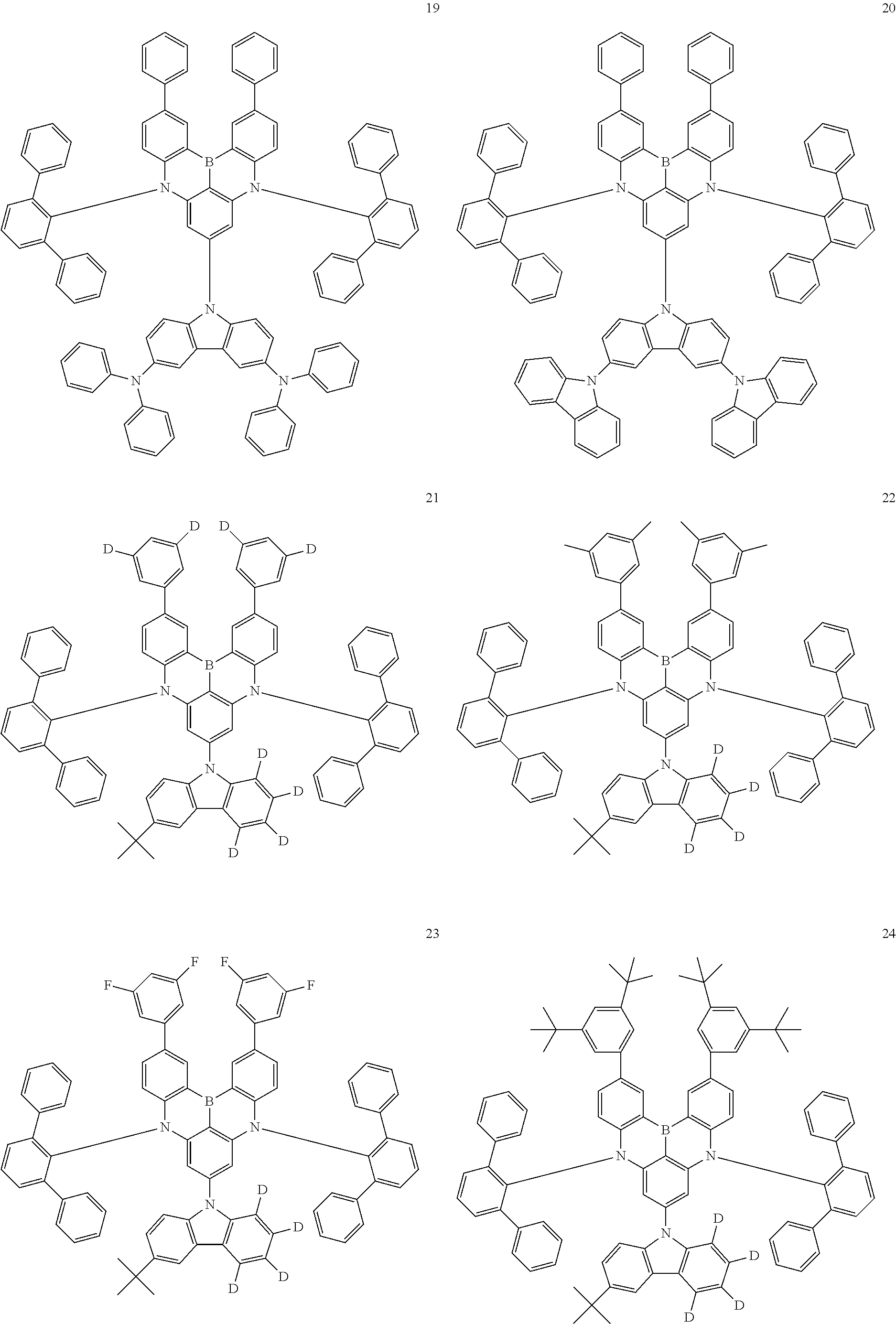 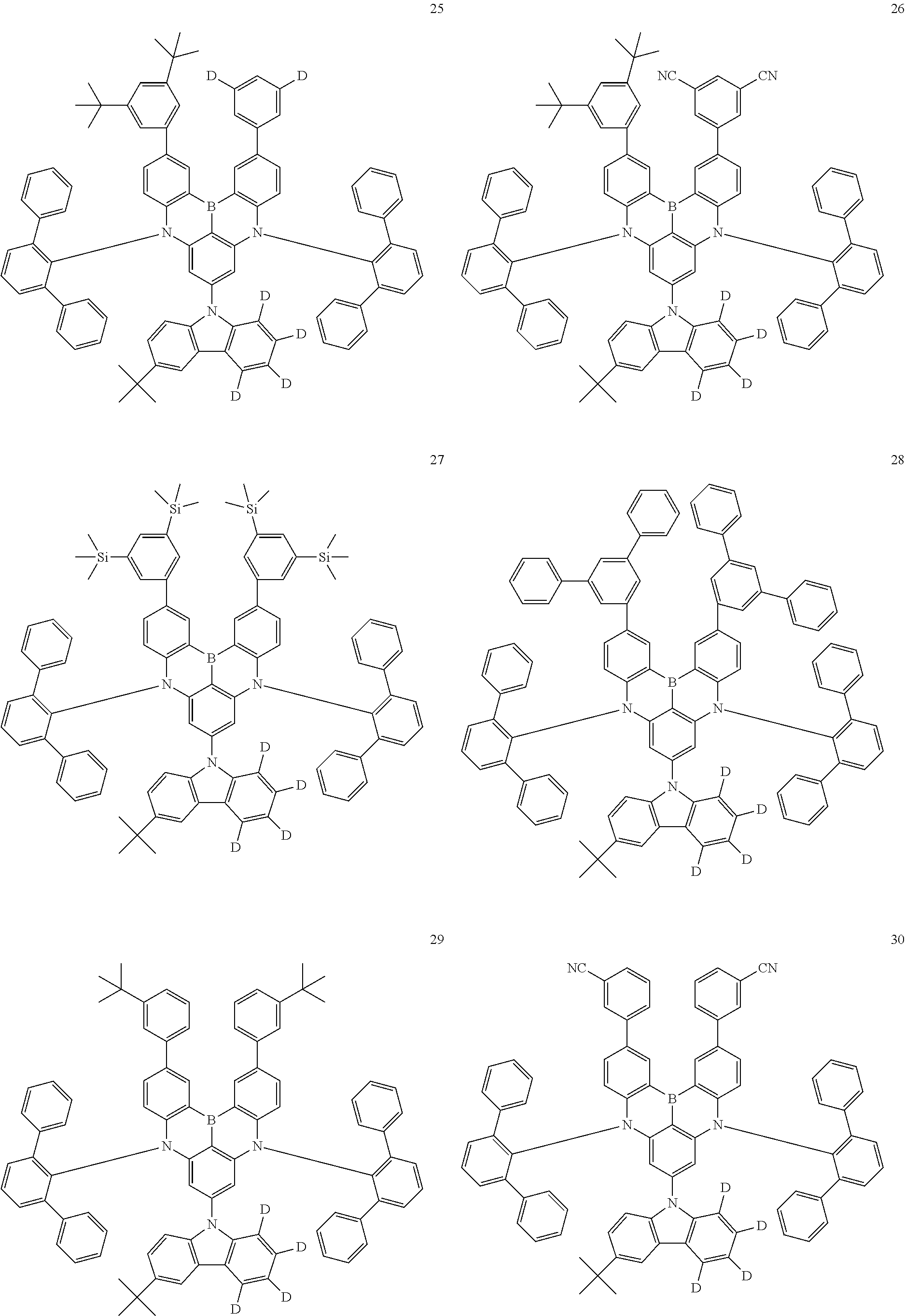 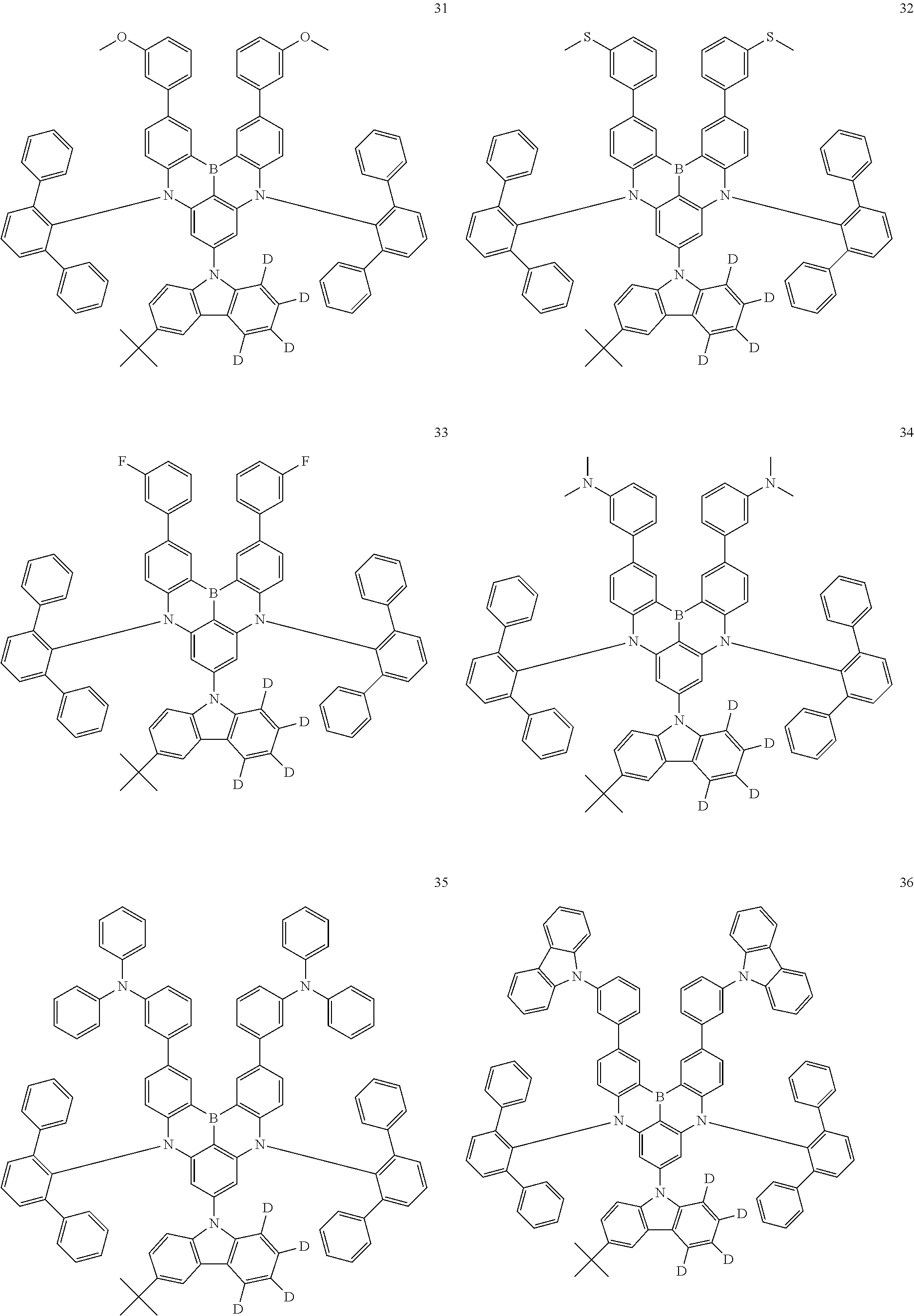 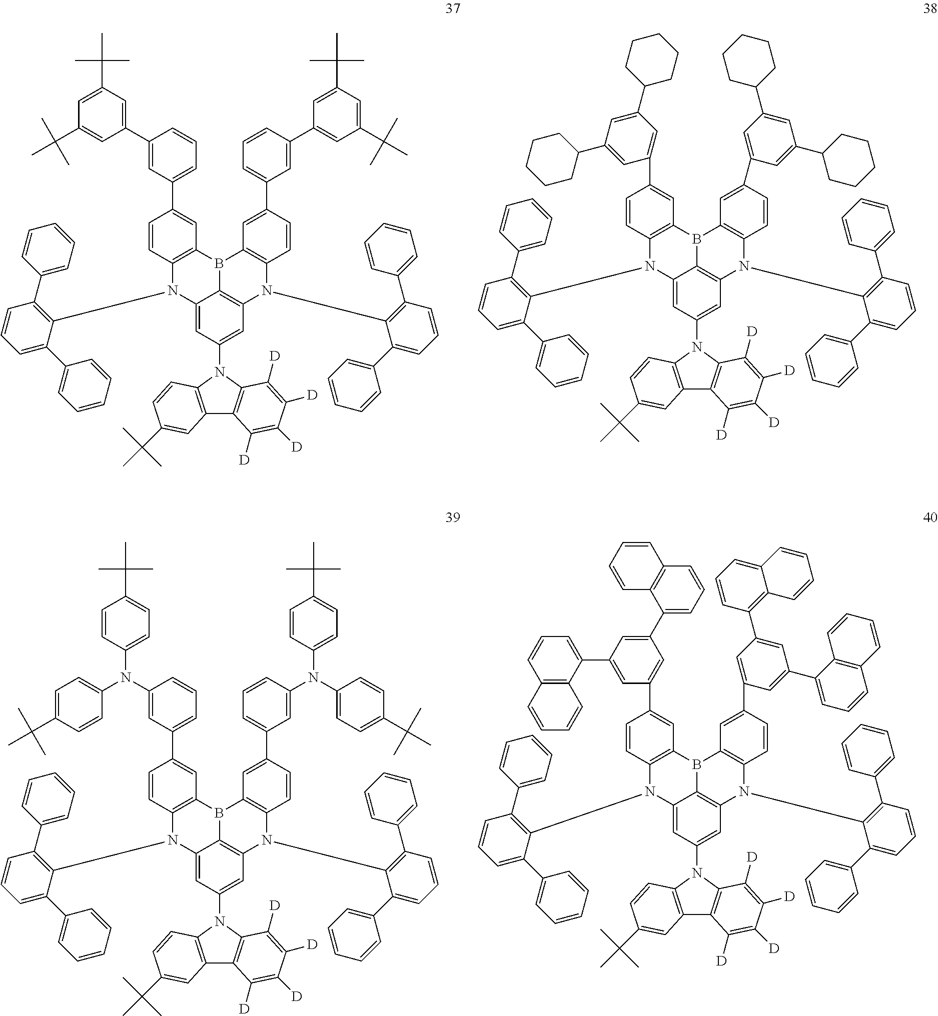 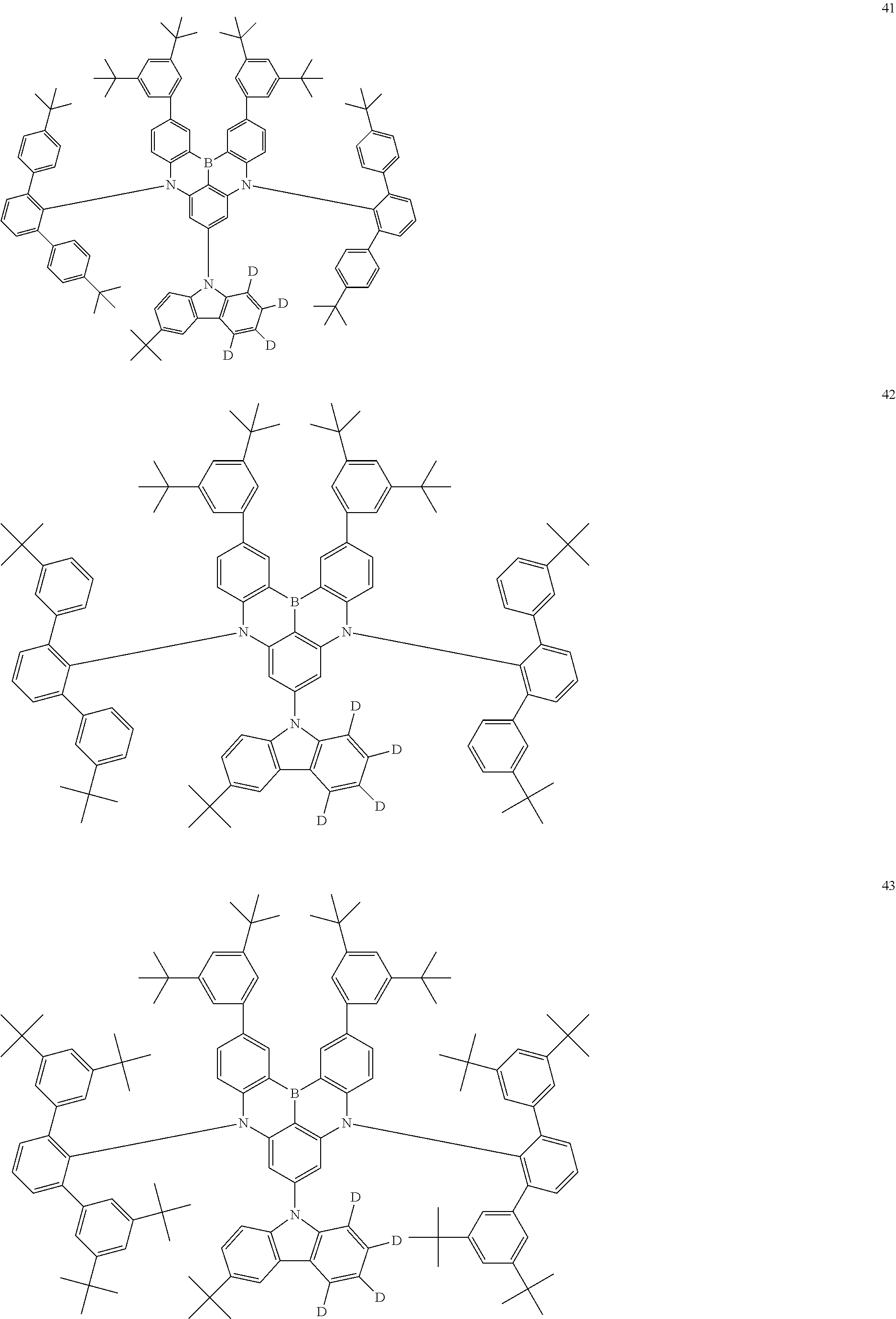 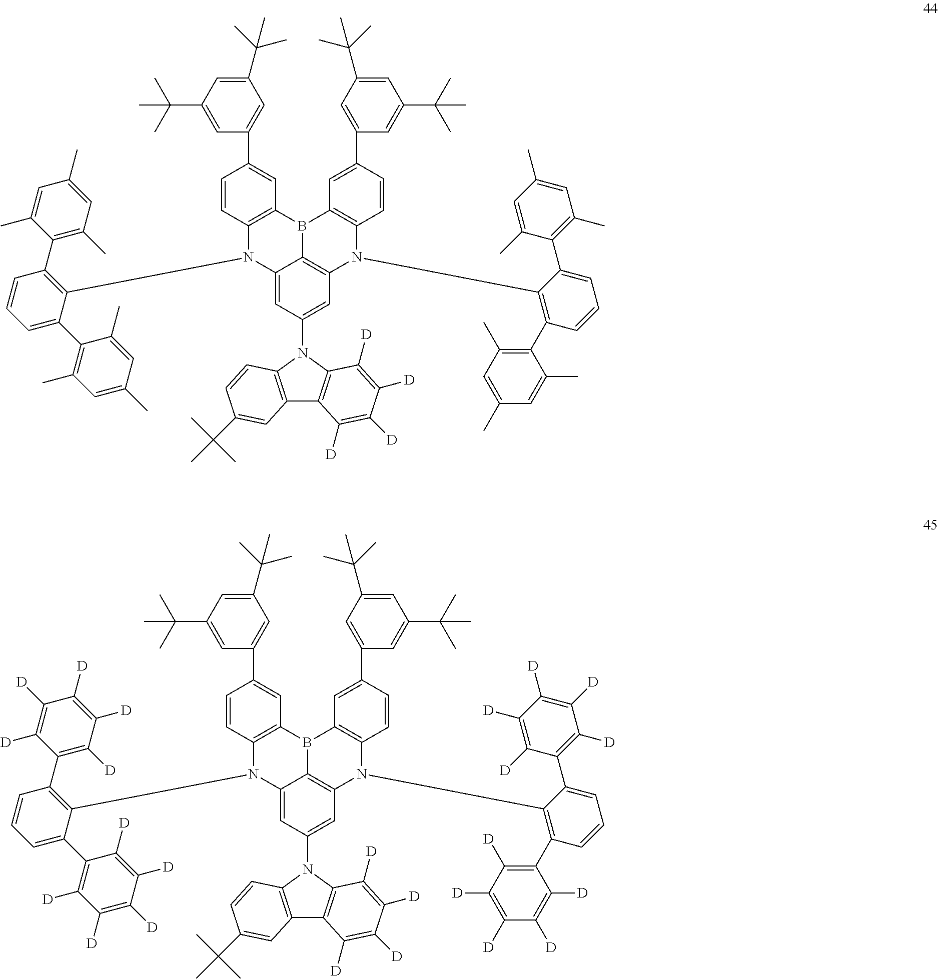 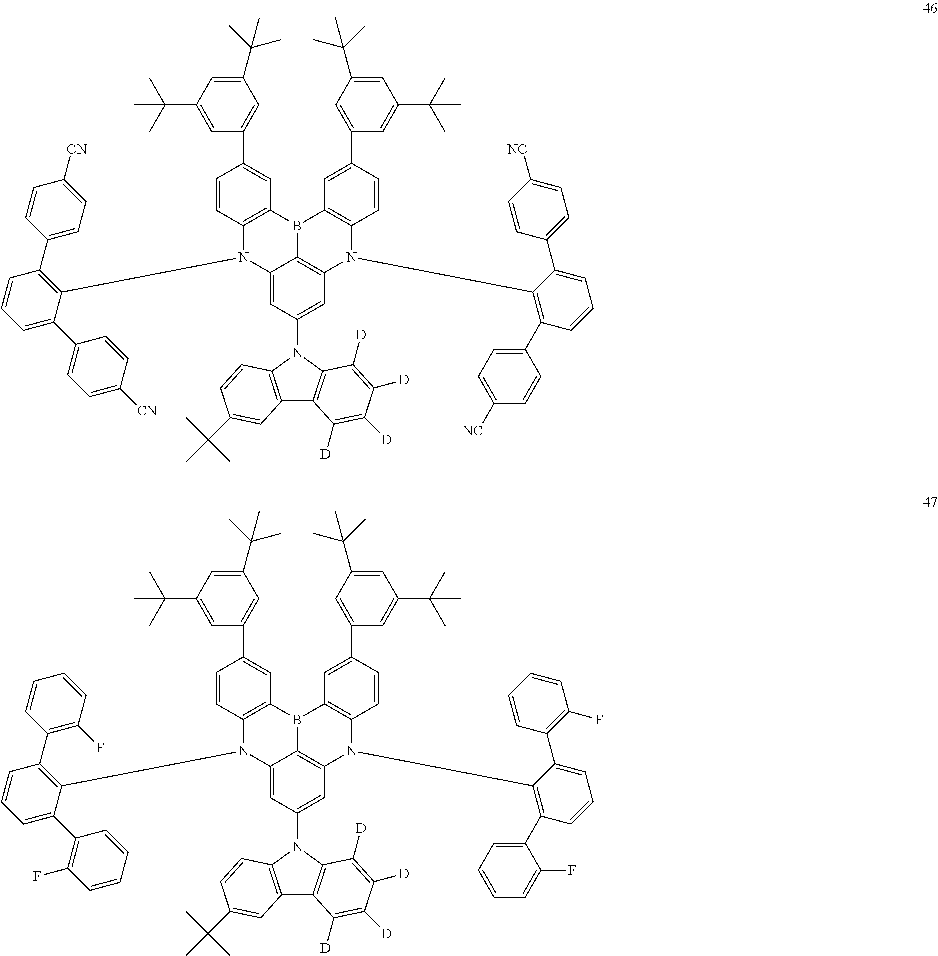 [SMILES: [2H]c1c([2H])c([2H])c2c(c1[2H])c1cc(C(C)(C)C)ccc1n2-c1cc2c3c(c1)N(c1c(-c4ccc(C#N)cc4)cccc1-c1ccc(C#N)cc1)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccc(C#N)cc2)cccc1-c1ccc(C#N)cc1 ; [2H]c1c([2H])c([2H])c2c(c1[2H])c1cc(C(C)(C)C)ccc1n2-c1cc2c3c(c1)N(c1c(-c4ccccc4F)cccc1-c1ccccc1F)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccccc2F)cccc1-c1ccccc1F] 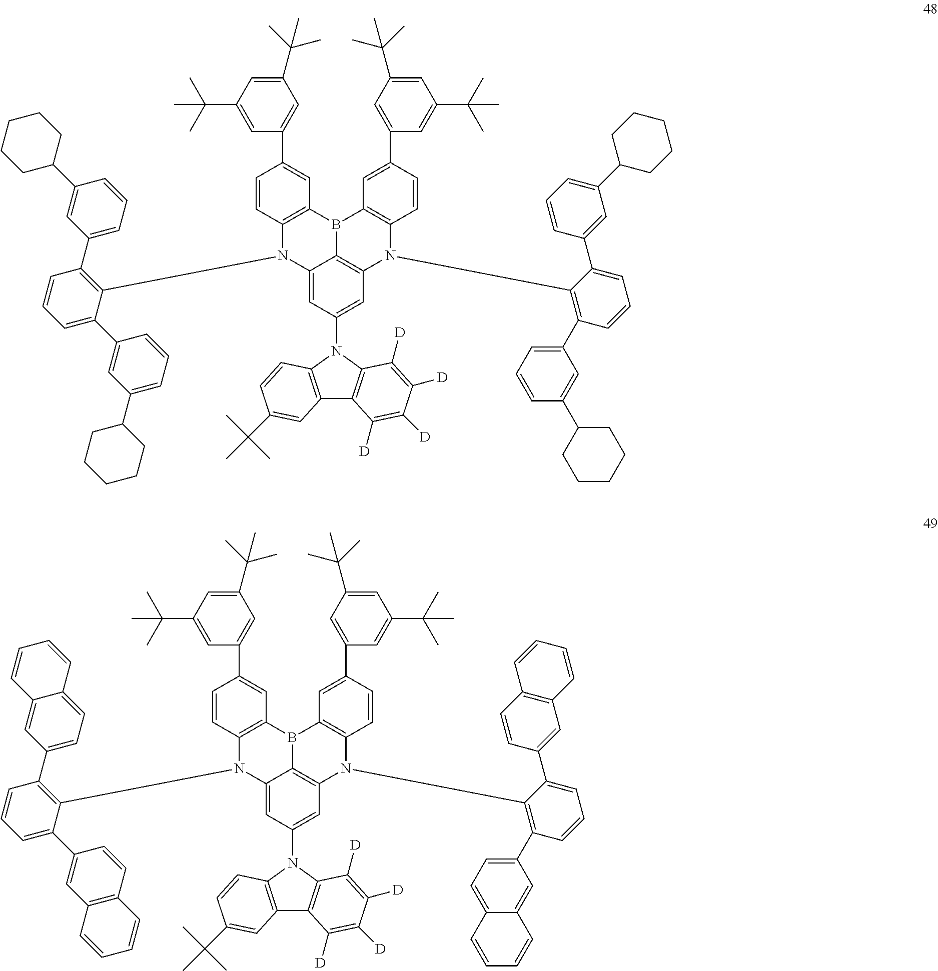 [SMILES: [2H]c1c([2H])c([2H])c2c(c1[2H])c1cc(C(C)(C)C)ccc1n2-c1cc2c3c(c1)N(c1c(-c4cccc(C5CCCCC5)c4)cccc1-c1cccc(C4CCCCC4)c1)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2cccc(C3CCCCC3)c2)cccc1-c1cccc(C2CCCCC2)c1 ; [2H]c1c([2H])c([2H])c2c(c1[2H])c1cc(C(C)(C)C)ccc1n2-c1cc2c3c(c1)N(c1c(-c4ccc5ccccc5c4)cccc1-c1ccc4ccccc4c1)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccc3ccccc3c2)cccc1-c1ccc2ccccc2c1] 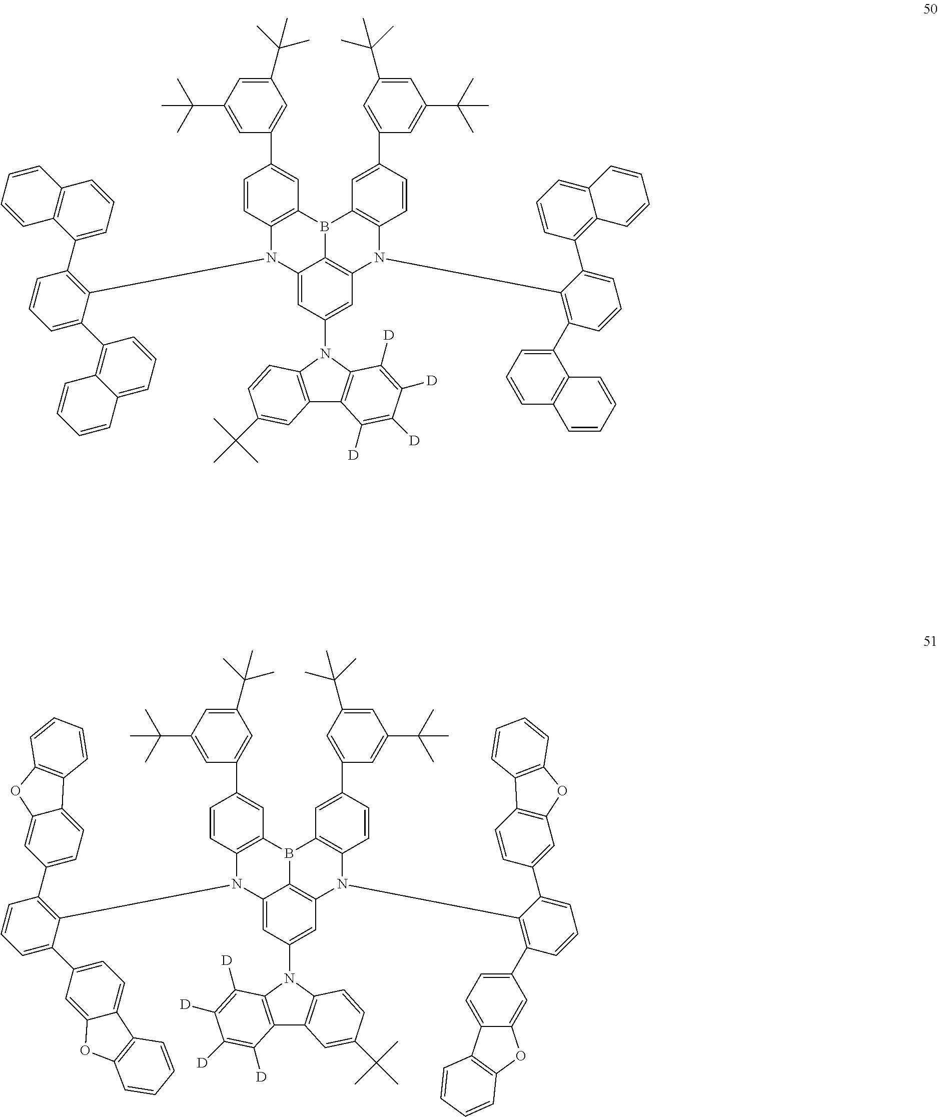 [SMILES: [2H]c1c([2H])c([2H])c2c(c1[2H])c1cc(C(C)(C)C)ccc1n2-c1cc2c3c(c1)N(c1c(-c4cccc5ccccc45)cccc1-c1cccc4ccccc14)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2cccc3ccccc23)cccc1-c1cccc2ccccc12 ; [2H]c1c([2H])c([2H])c2c(c1[2H])c1cc(C(C)(C)C)ccc1n2-c1cc2c3c(c1)N(c1c(-c4ccc5c(c4)oc4ccccc45)cccc1-c1ccc4c(c1)oc1ccccc14)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccc3c(c2)oc2ccccc23)cccc1-c1ccc2c(c1)oc1ccccc12] 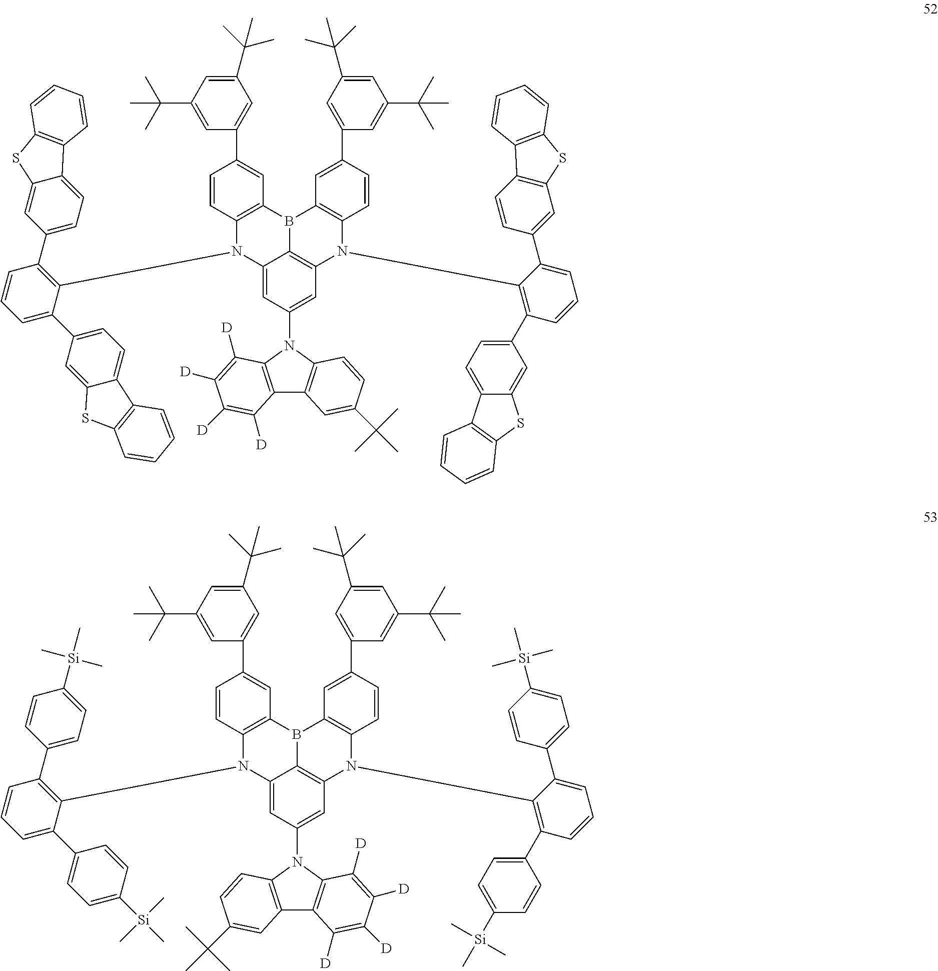 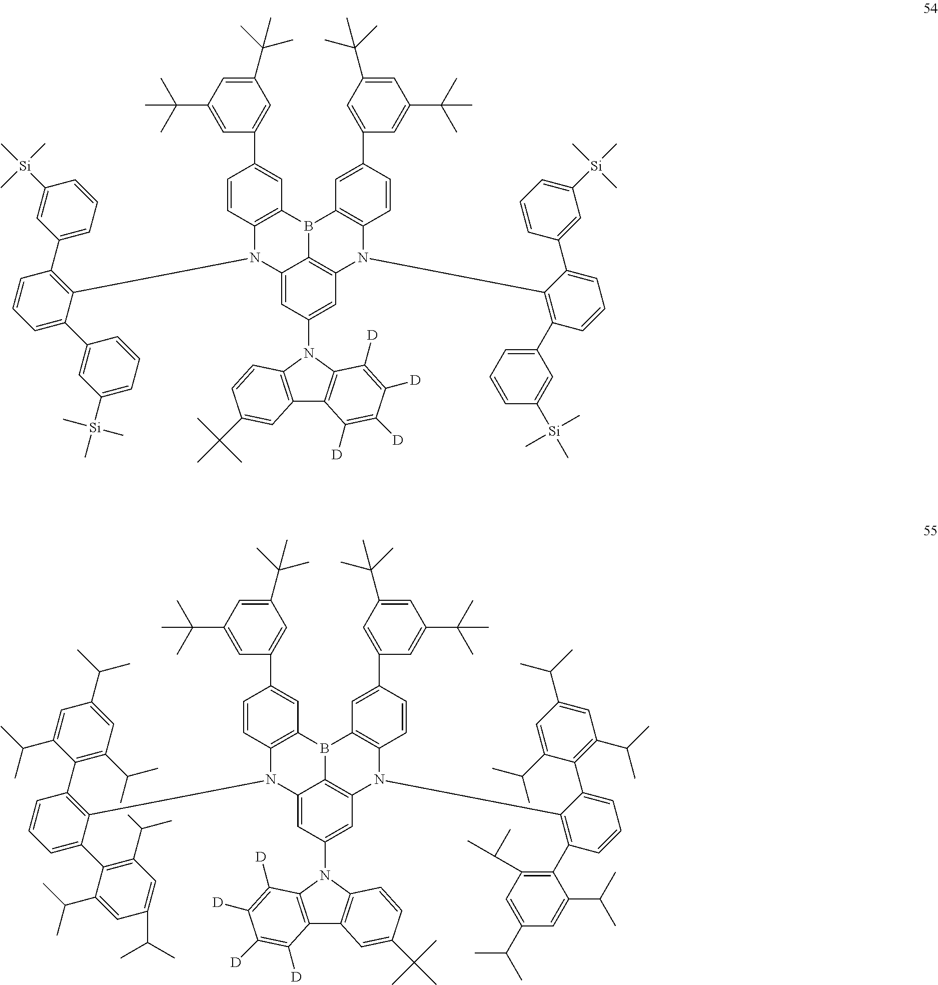 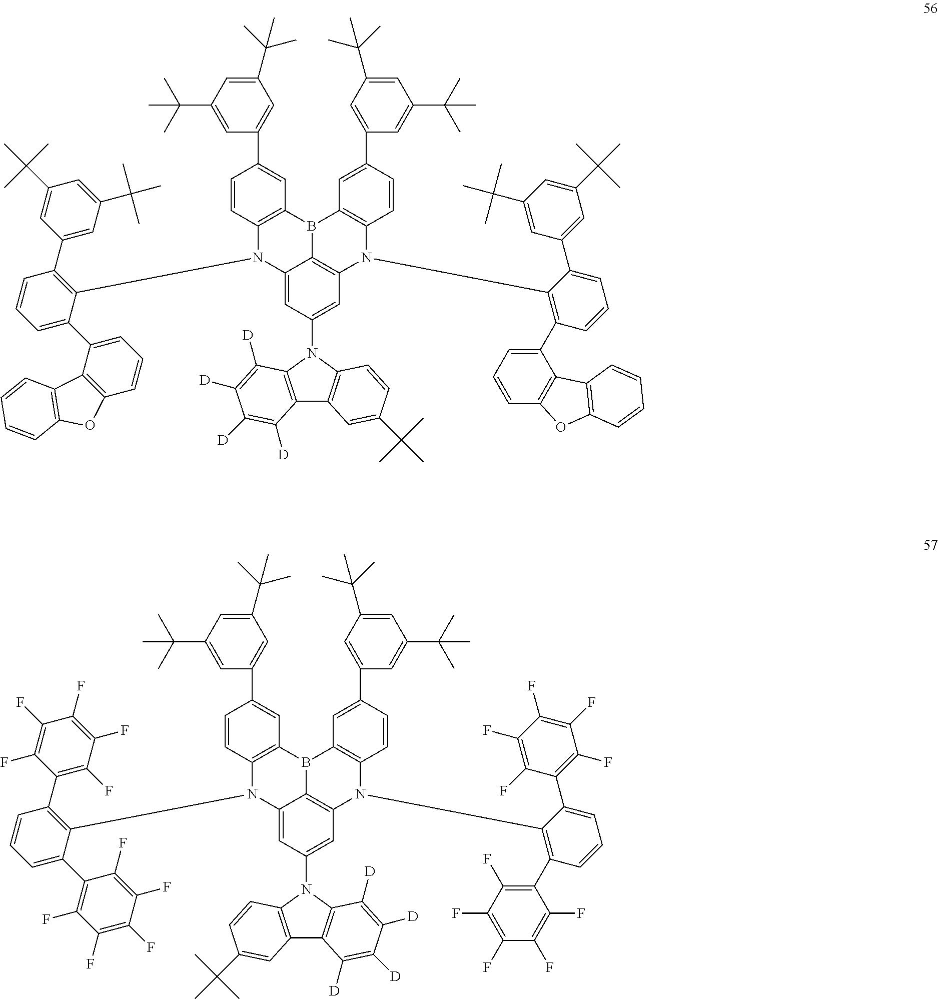 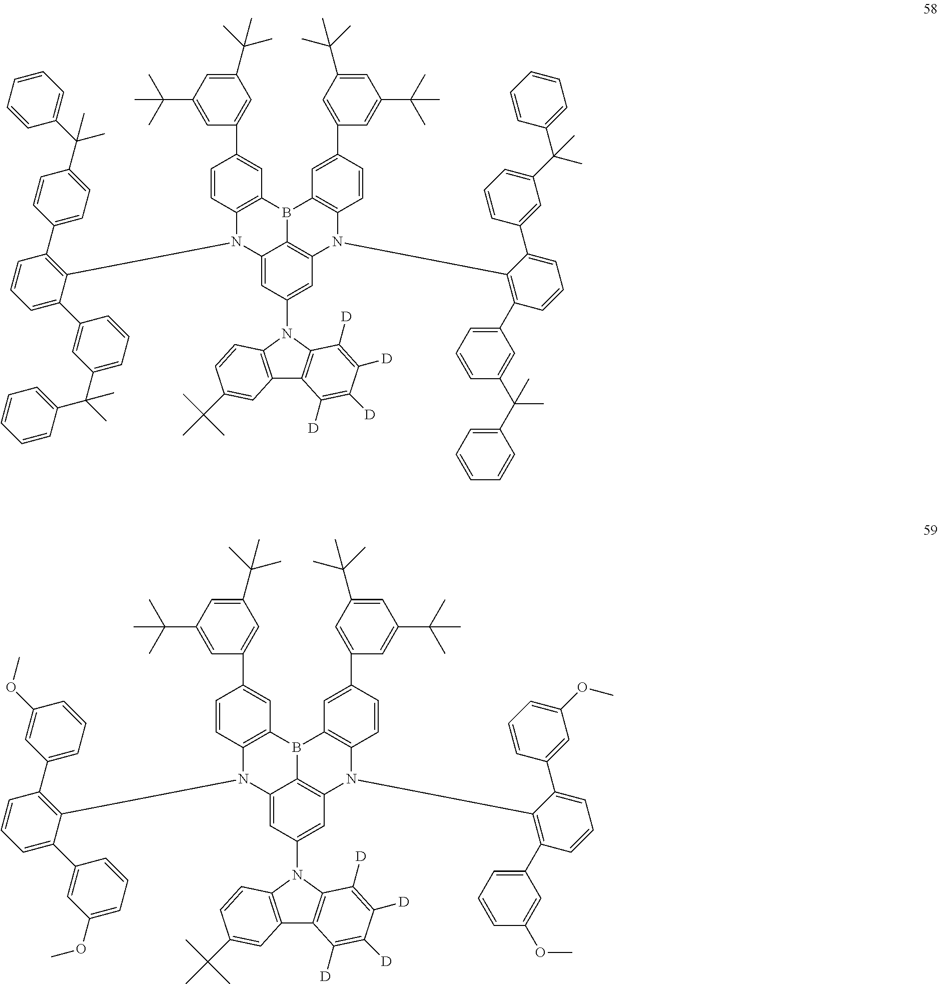 [SMILES: [2H]c1c([2H])c([2H])c2c(c1[2H])c1cc(C(C)(C)C)ccc1n2-c1cc2c3c(c1)N(c1c(-c4cccc(C(C)(C)c5ccccc5)c4)cccc1-c1cccc(C(C)(C)c4ccccc4)c1)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccc(C(C)(C)c3ccccc3)cc2)cccc1-c1cccc(C(C)(C)c2ccccc2)c1 ; [2H]c1c([2H])c([2H])c2c(c1[2H])c1cc(C(C)(C)C)ccc1n2-c1cc2c3c(c1)N(c1c(-c4cccc(OC)c4)cccc1-c1cccc(OC)c1)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2cccc(OC)c2)cccc1-c1cccc(OC)c1] 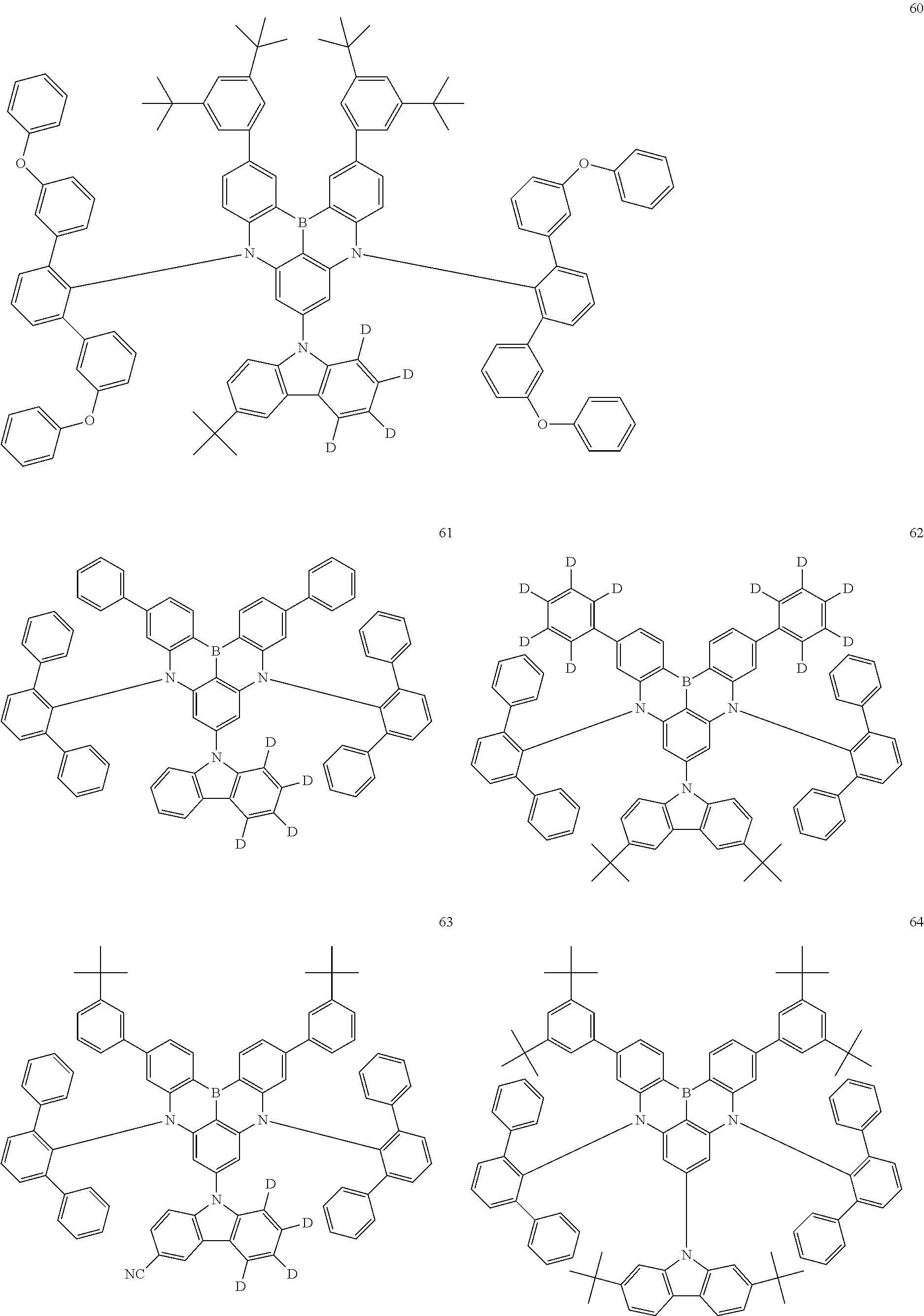 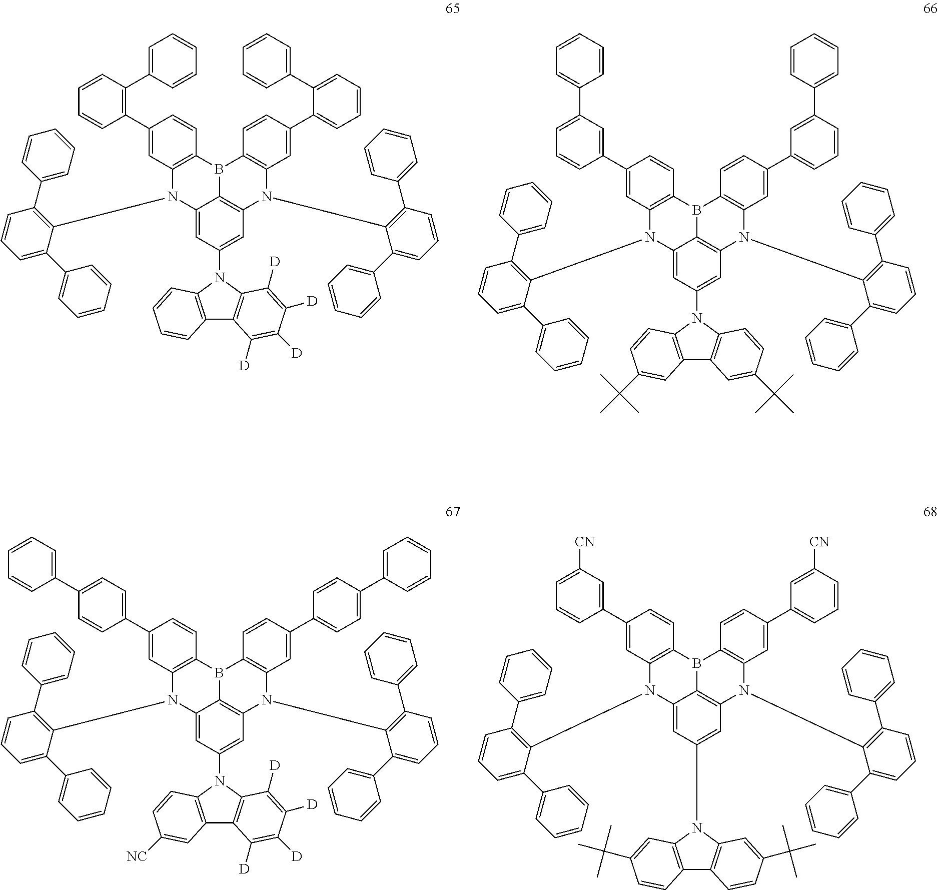 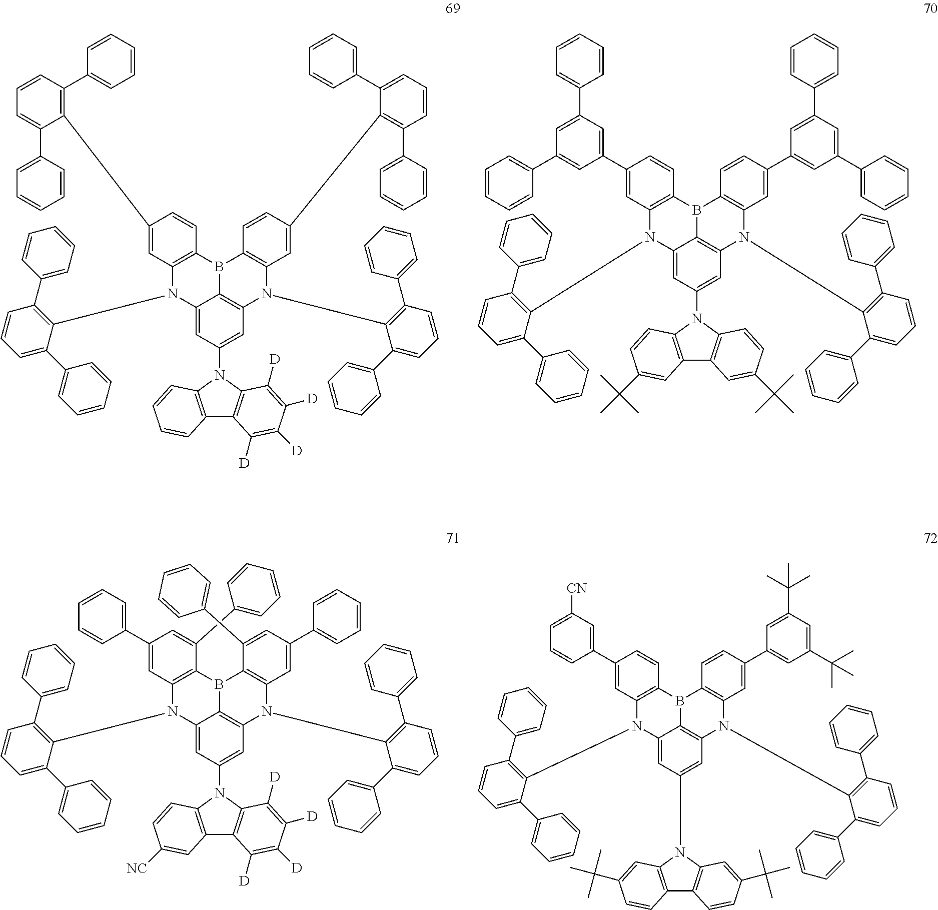 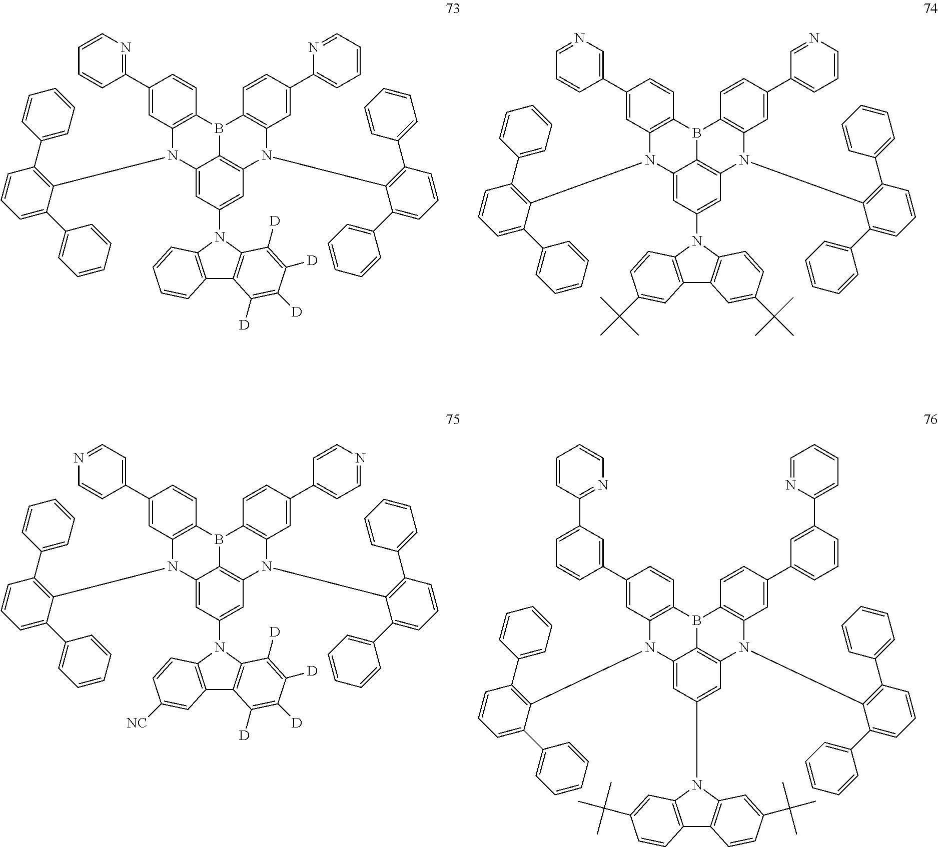 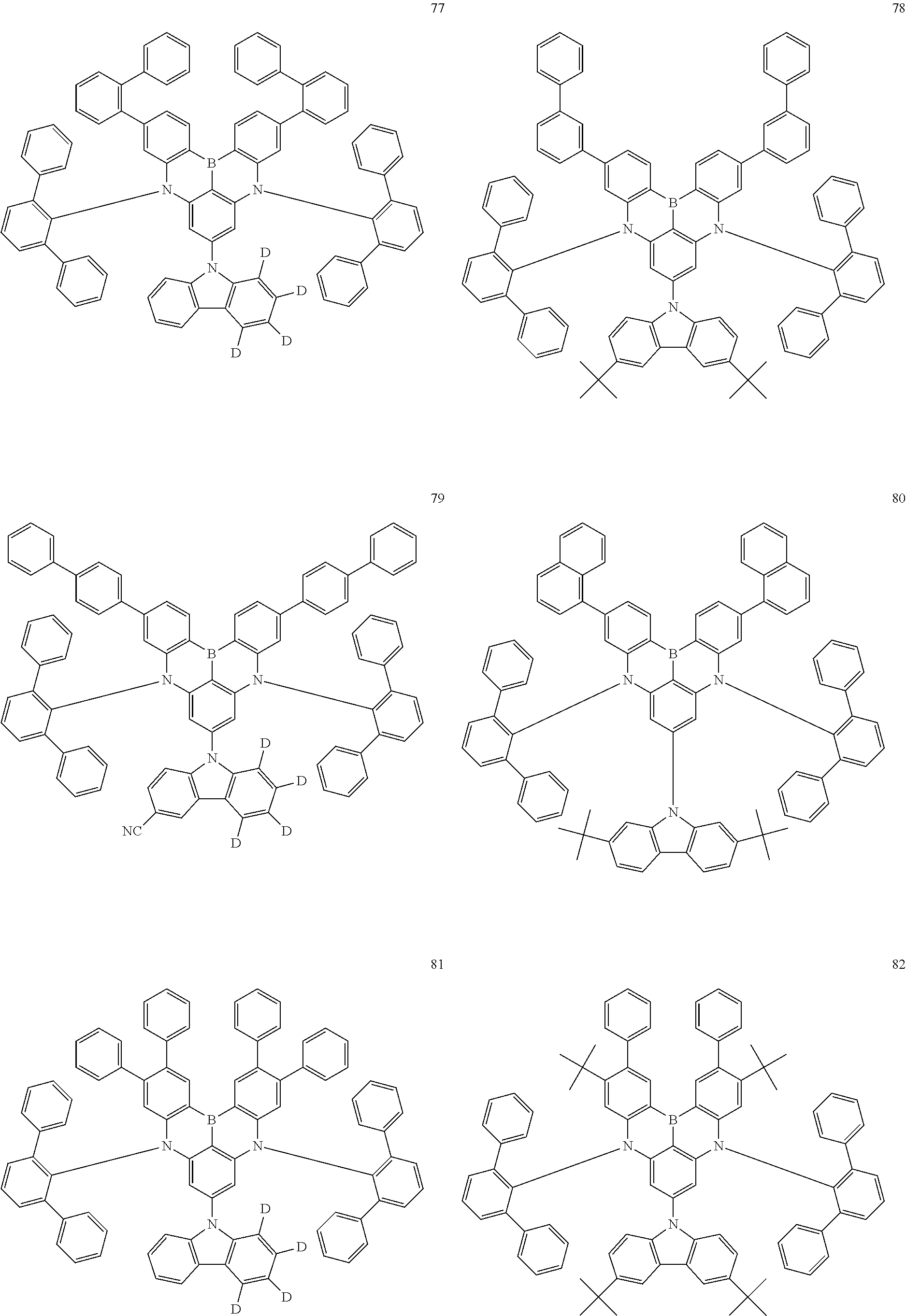 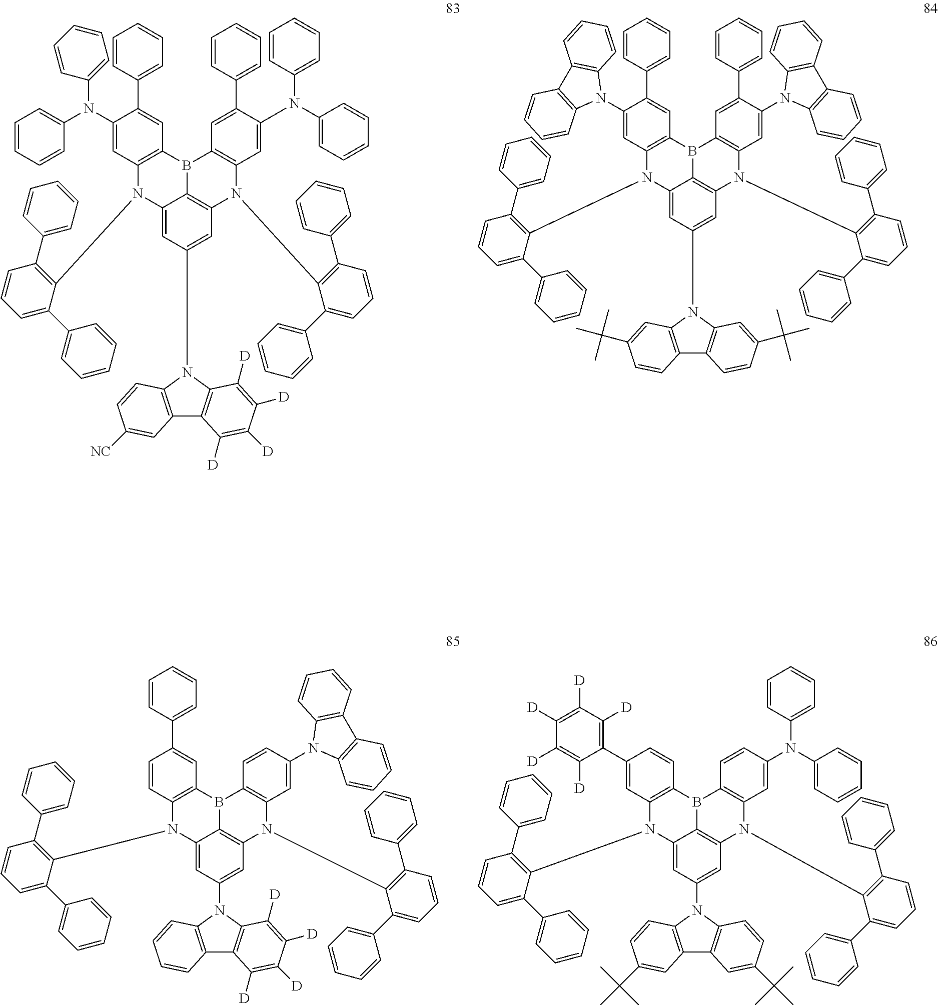 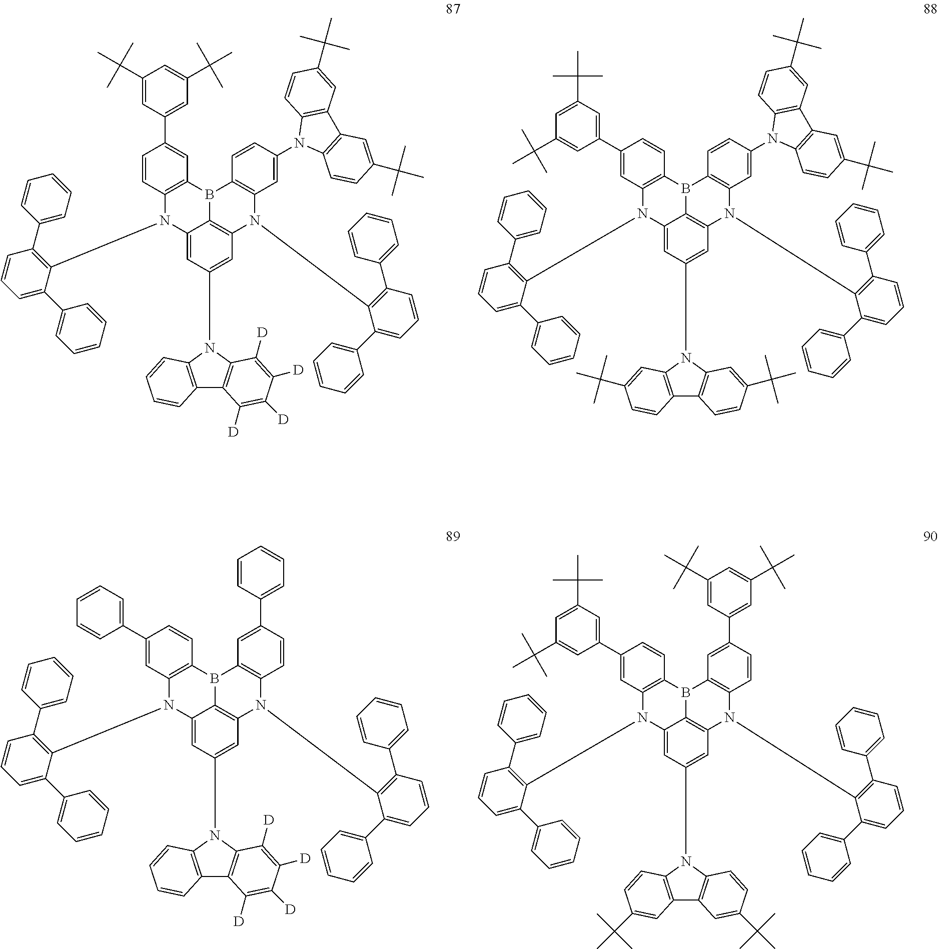 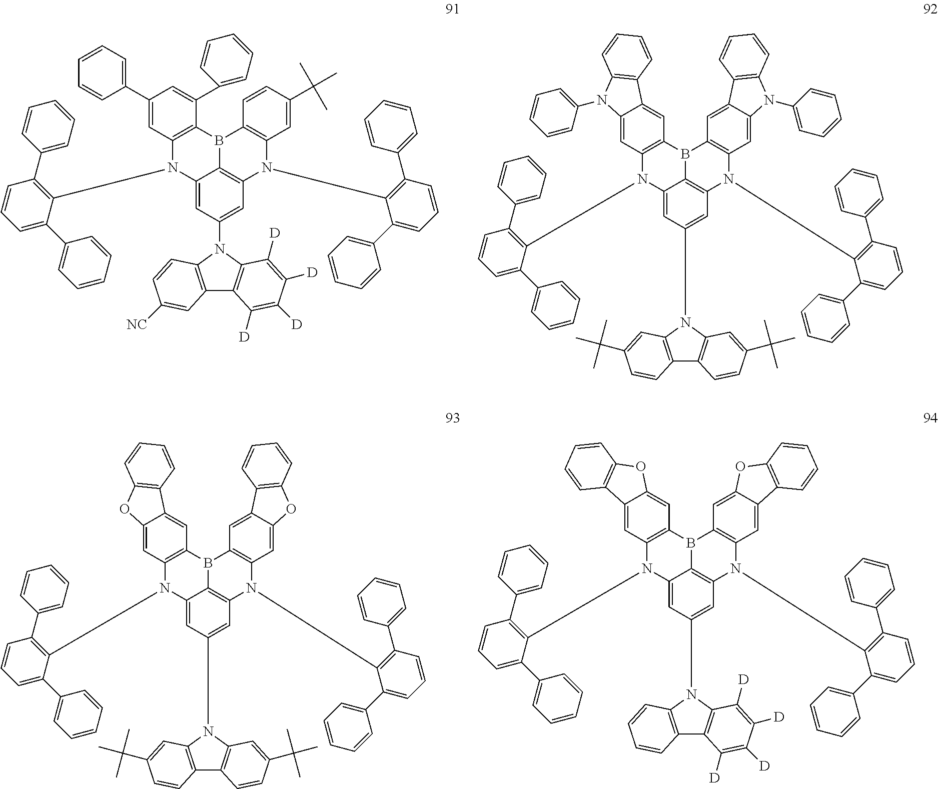 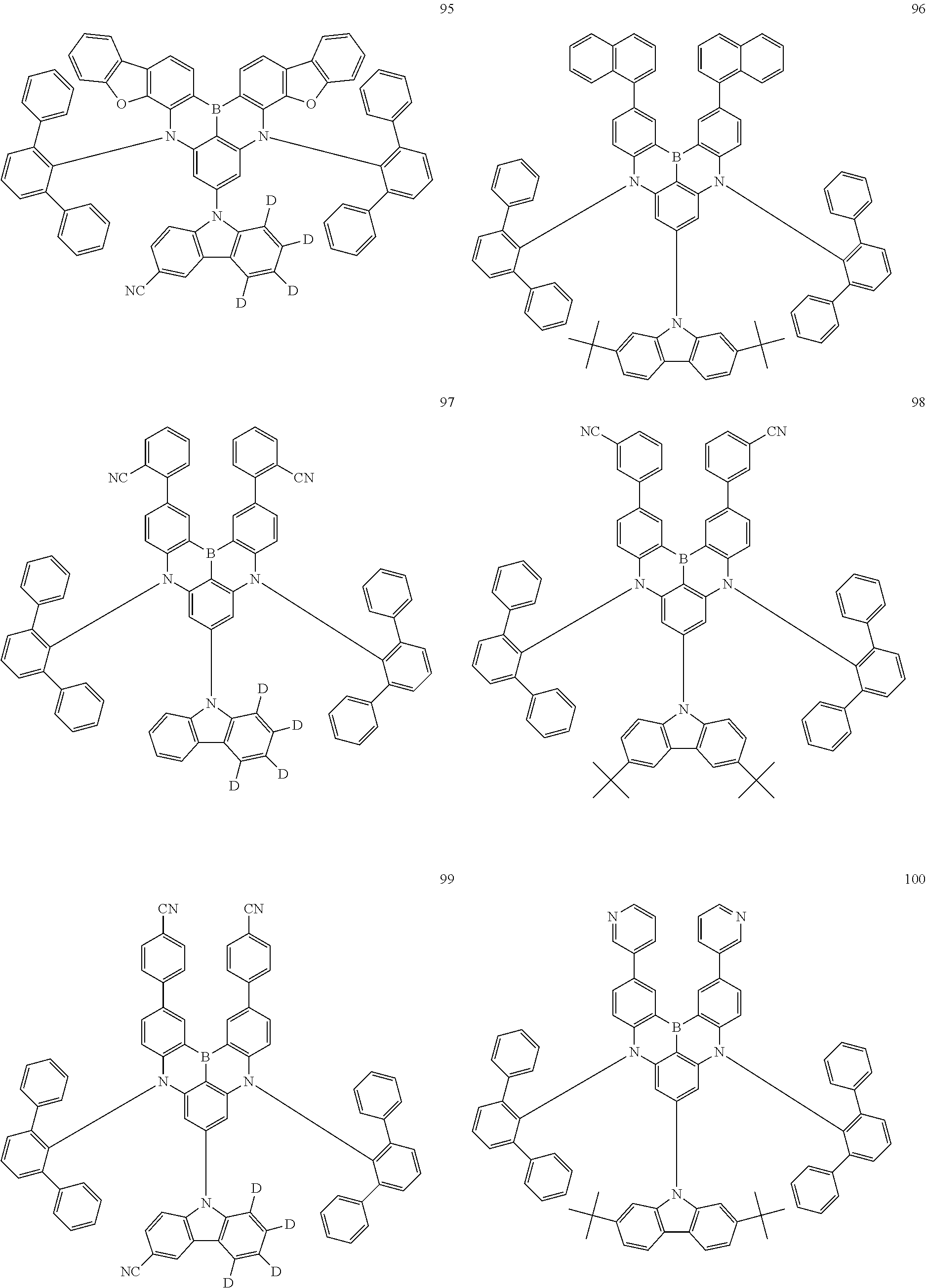
wherein in Compound Group 1,
D represents a deuterium atom.

16. A light emitting device, comprising:
a first electrode;
a hole transport region disposed on the first electrode;
an emission layer disposed on the hole transport region;
an electron transport region disposed on the emission layer; and
a second electrode disposed on the electron transport region, wherein
the emission layer comprises a first compound represented by Formula 1, a second compound represented by Formula 2, and a third compound represented by Formula 3: 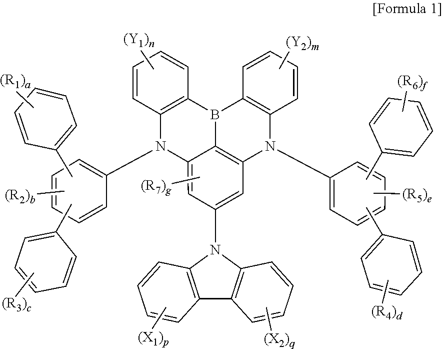
wherein in Formula 1,
X₁ and X₂ are each independently a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring,
p and q are each independently an integer from 1 to 4,
Y₁ and Y₂ are each independently a hydrogen atom, a deuterium atom, a substituted or unsubstituted amine group, a substituted or unsubstituted alkyl group of 1 to 20 carbon atoms, a substituted or unsubstituted oxy group, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring,
wherein for Y₁ and Y₂:
at least one of Y₁ and Y₂ is a substituted or unsubstituted aryl group of 6 to 30 ring-forming carbon atoms, or a substituted or unsubstituted heteroaryl group of 2 to 30 ring-forming carbon atoms; or
at least one of Y₁ and Y₂ is combined with an adjacent group to form a substituted or unsubstituted aliphatic heterocycle of 2 to 30 ring-forming carbon atoms, or a substituted or unsubstituted aromatic heterocycle of 2 to 30 ring-forming carbon atoms,
n and m are each independently an integer from 1 to 4,
R₁ to R₇ are each independently a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring,
a, c, d, and f are each independently an integer from 0 to 5,
b and e are each independently an integer from 0 to 3, and
g is an integer from 0 to 2; 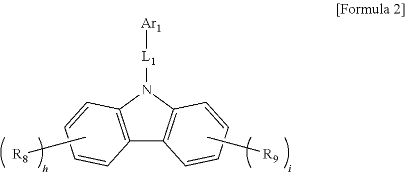
wherein in Formula 2,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Ar₁ is a substituted or unsubstituted aryl group of 6 to 30 ring-forming carbon atoms, or a substituted or unsubstituted heteroaryl group of 2 to 30 ring-forming carbon atoms,
R₈ and R₉ are each independently a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring, and
h and i are each independently an integer from 0 to 4; 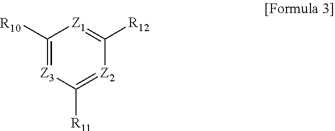
wherein in Formula 3,
at least one of Z₁ to Z₃ is each N,
the remainder of Z₁ to Z₃ are each independently C(R₁₃), and
R₁₀ to R₁₃ are each independently a hydrogen atom, a deuterium atom, a halogen atom, a cyano group, a substituted or unsubstituted silyl group, a substituted or unsubstituted thiol group, a substituted or unsubstituted oxy group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring.

17. The light emitting device of claim 16, wherein the first compound represented by Formula 1 is represented by Formula 1-1: 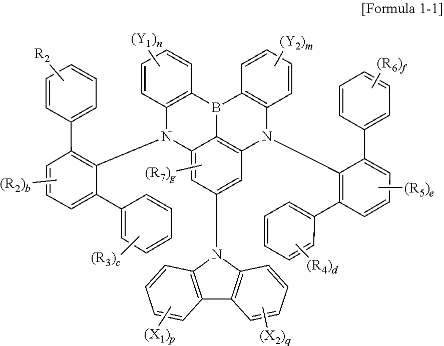
wherein in Formula 1-1,
X₁, X₂, Y₁, Y₂, R₁ to R₇, a to g, n, m, p, and q are each the same as defined in Formula 1.

18. The light emitting device of claim 16, wherein the first compound represented by Formula 1 is represented by one of Formula 1-2-1 to Formula 1-2-7: 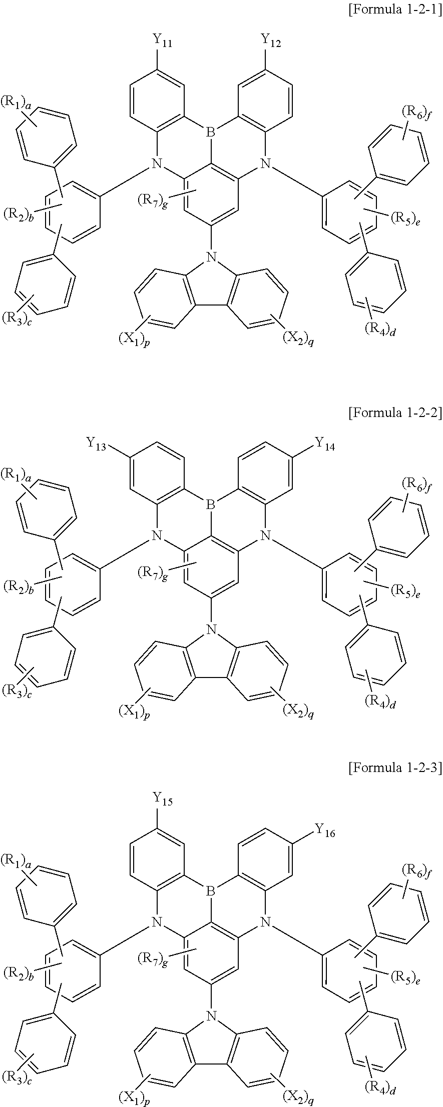 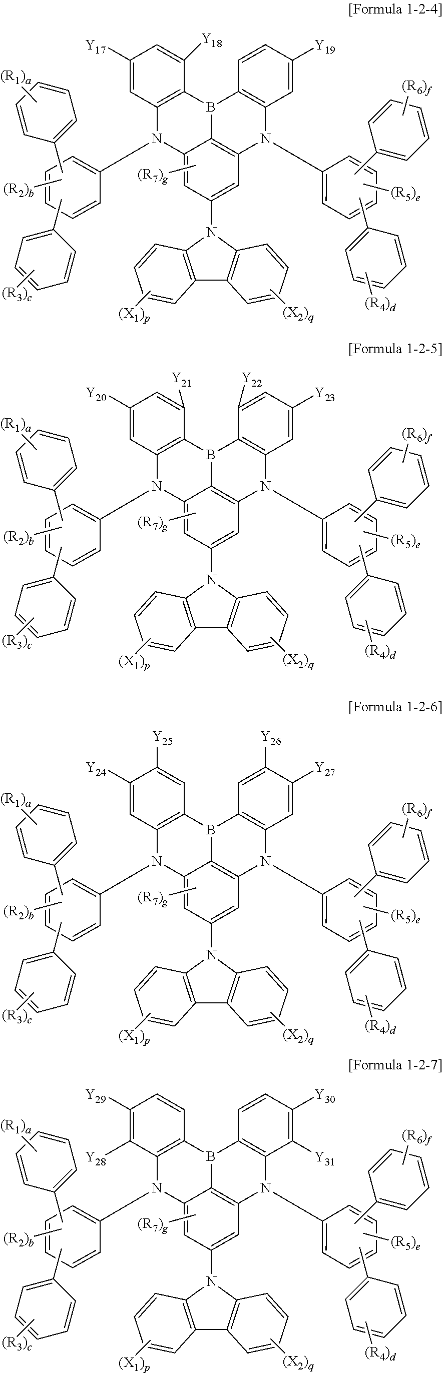
wherein in Formula 1-2-1 to Formula 1-2-7,
Y₁₁ to Y₃₁ are each independently a deuterium atom, a substituted or unsubstituted amine group, a substituted or unsubstituted oxy group, a substituted or unsubstituted aryl group of 6 to 30 ring-forming carbon atoms, a substituted or unsubstituted heteroaryl group of 2 to 30 ring-forming carbon atoms, or are combined with an adjacent group to form a ring,
wherein for Y₁₁ to Y₃₁:
at least one of Y₁₁ and Y₁₂, at least one of Y₁₃ and Y₁₄, at least one of Y₁₅ and Y₁₆, at least one of Y₁₇ and Y₁₈, at least one of Y₂₀ and Y₂₁, and at least one of Y₂₂ and Y₂₃ are each independently a substituted or unsubstituted aryl group of 6 to 30 ring-forming carbon atoms, or a substituted or unsubstituted heteroaryl group of 2 to 30 ring-forming carbon atoms;
at least one of Y₂₄ and Y₂₅ or Y₂₆ and Y₂₇ are combined with each other to form a ring; and
at least one of Y₂₈ and Y₂₉ or Y₃₀ and Y₃₁ are combined with each other to form a ring, and
X₁, X₂, R₁ to R₇, a to g, p, and q are each the same as defined in Formula 1.

19. The light emitting device of claim 16, wherein the first compound represented by Formula 1 is represented by Formula 1-3: 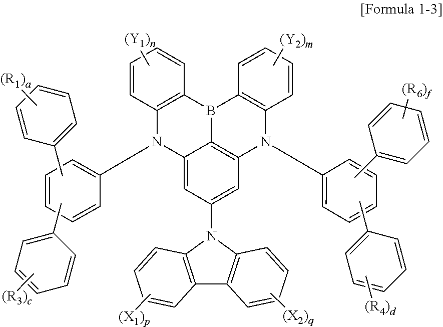
wherein in Formula 1-3,
X₁, X₂, R₁, R₃, R₄, R₆, Y₁, Y₂, a, c, d, f, n, m, p, and q are each the same as defined in Formula 1.

20. The light emitting device of claim 16, wherein the first compound represented by Formula 1 comprises at least one compound selected from Compound Group 1: 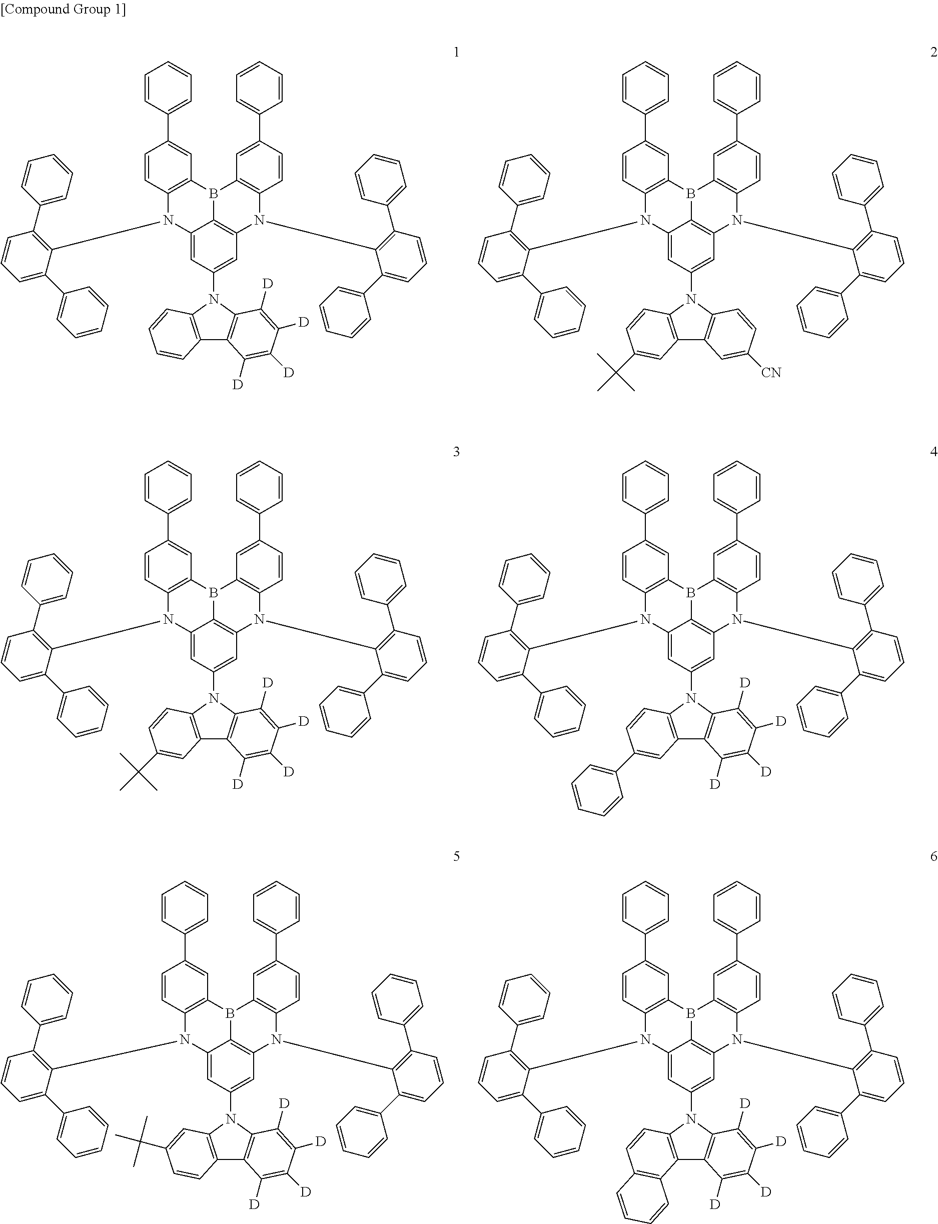 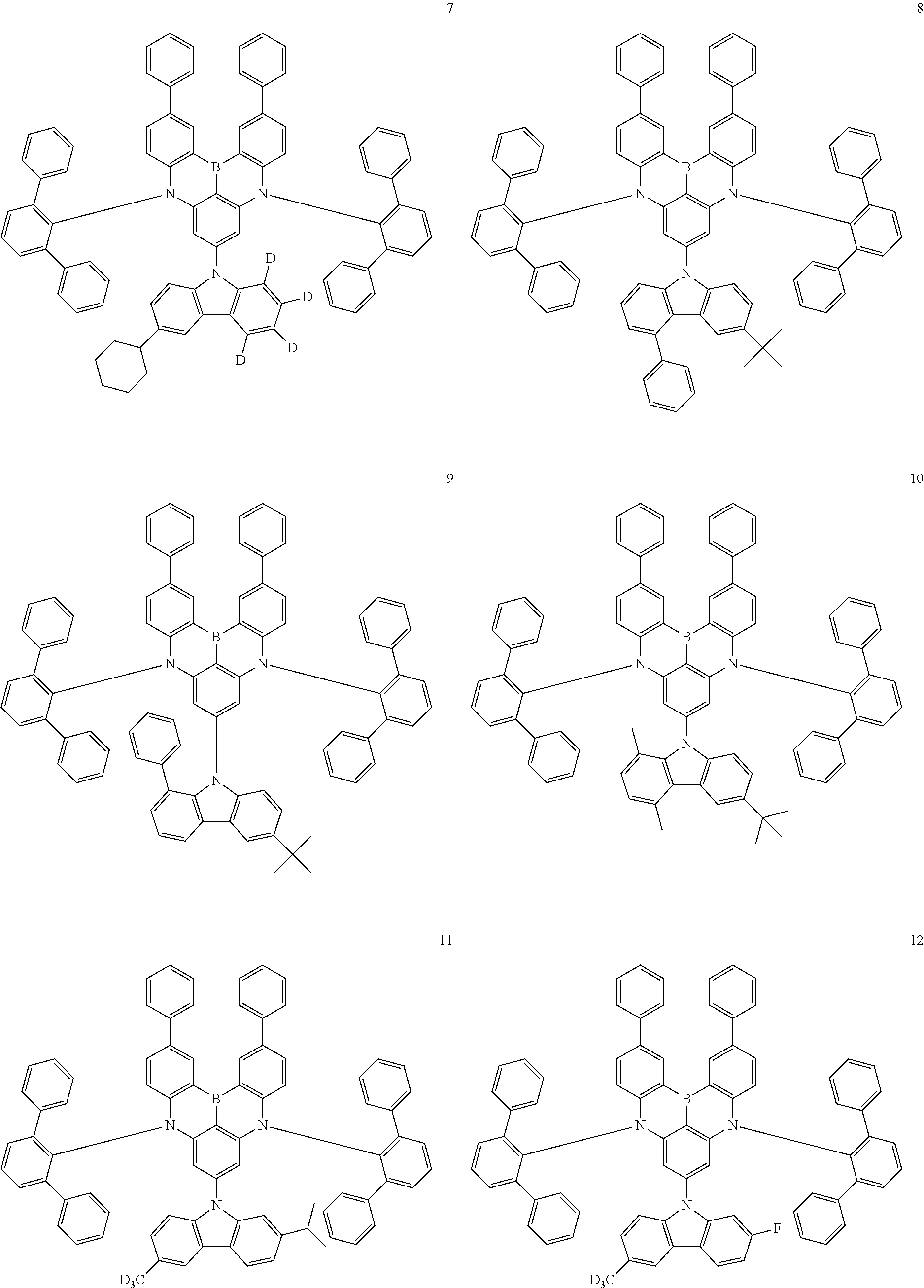 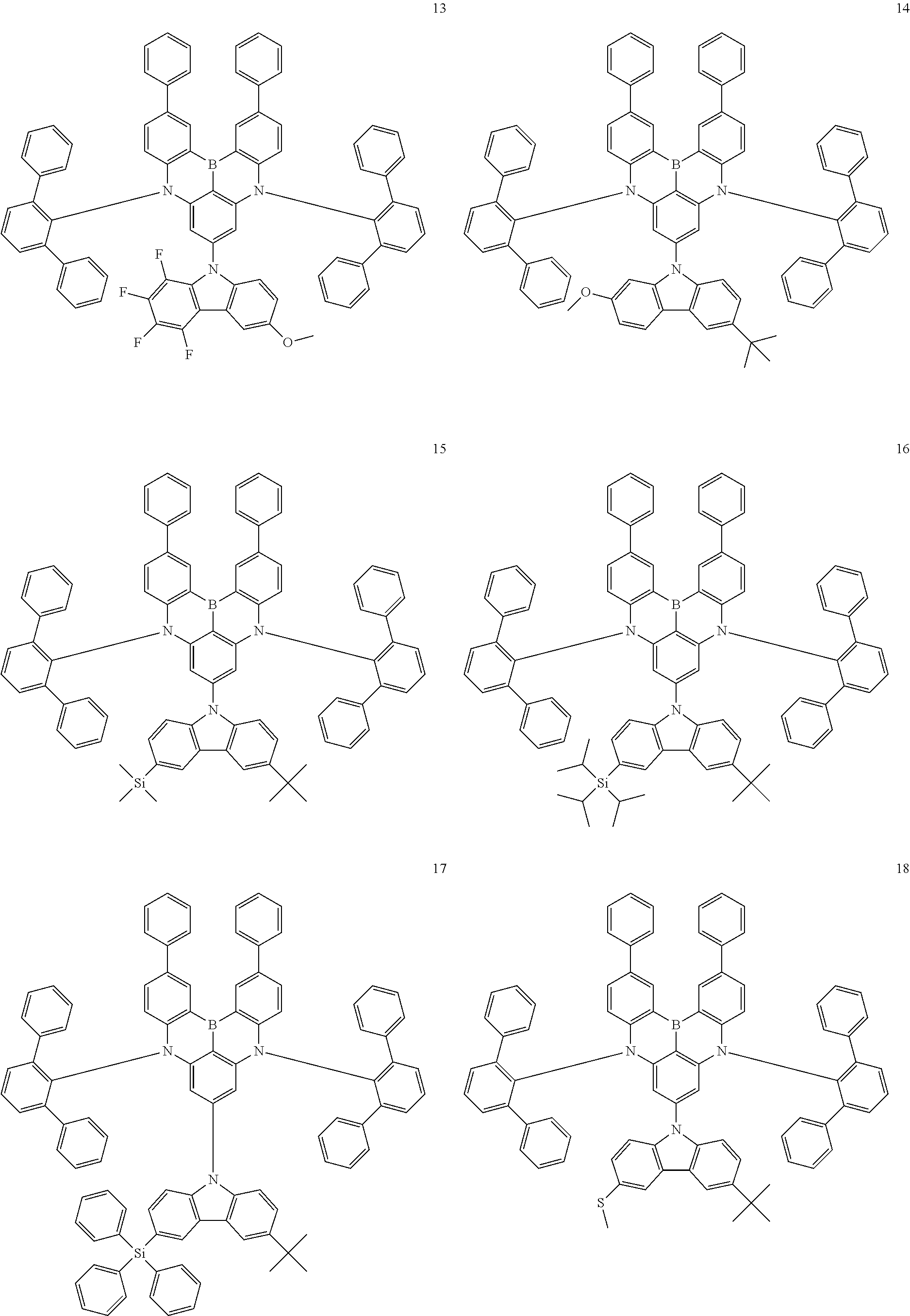 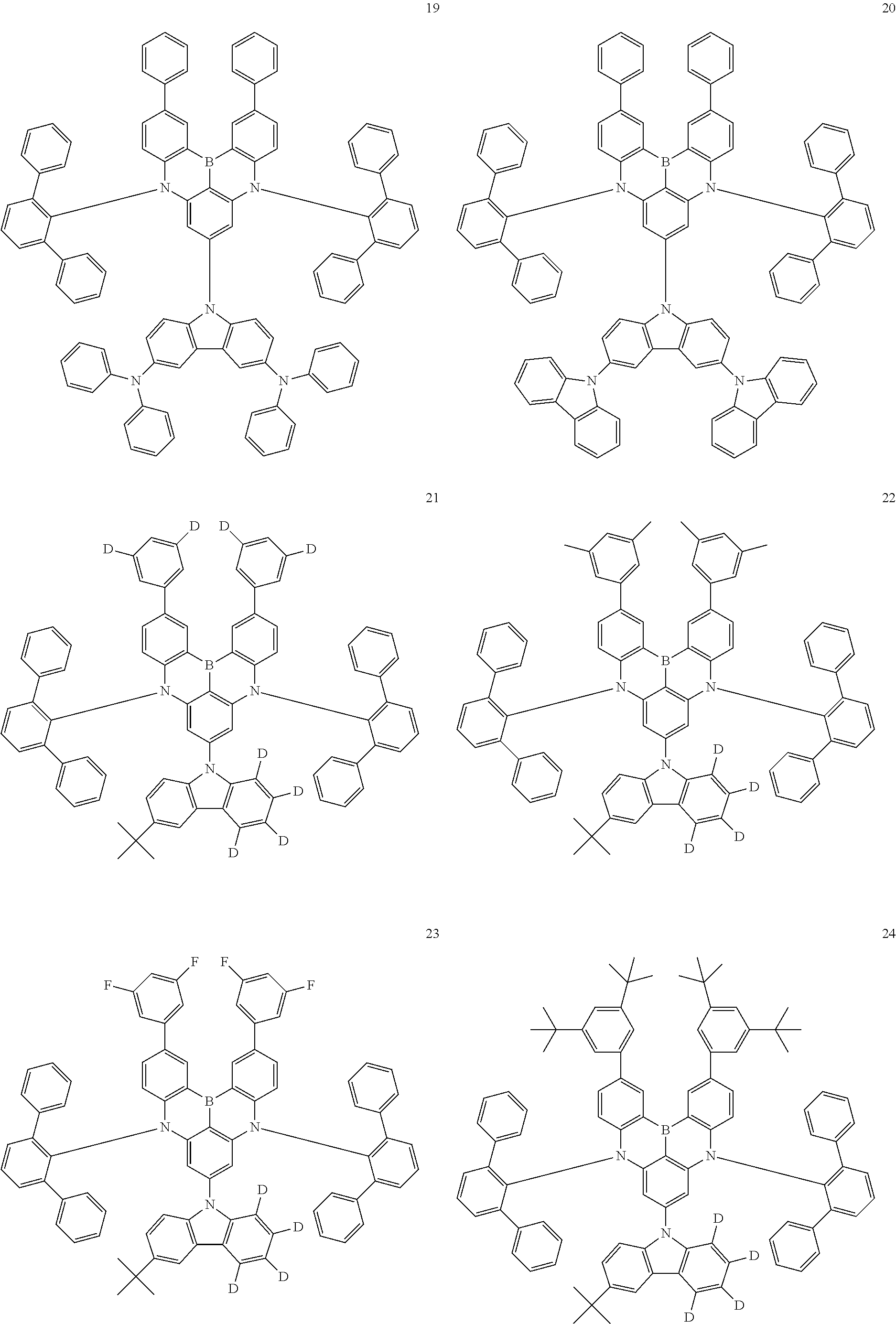 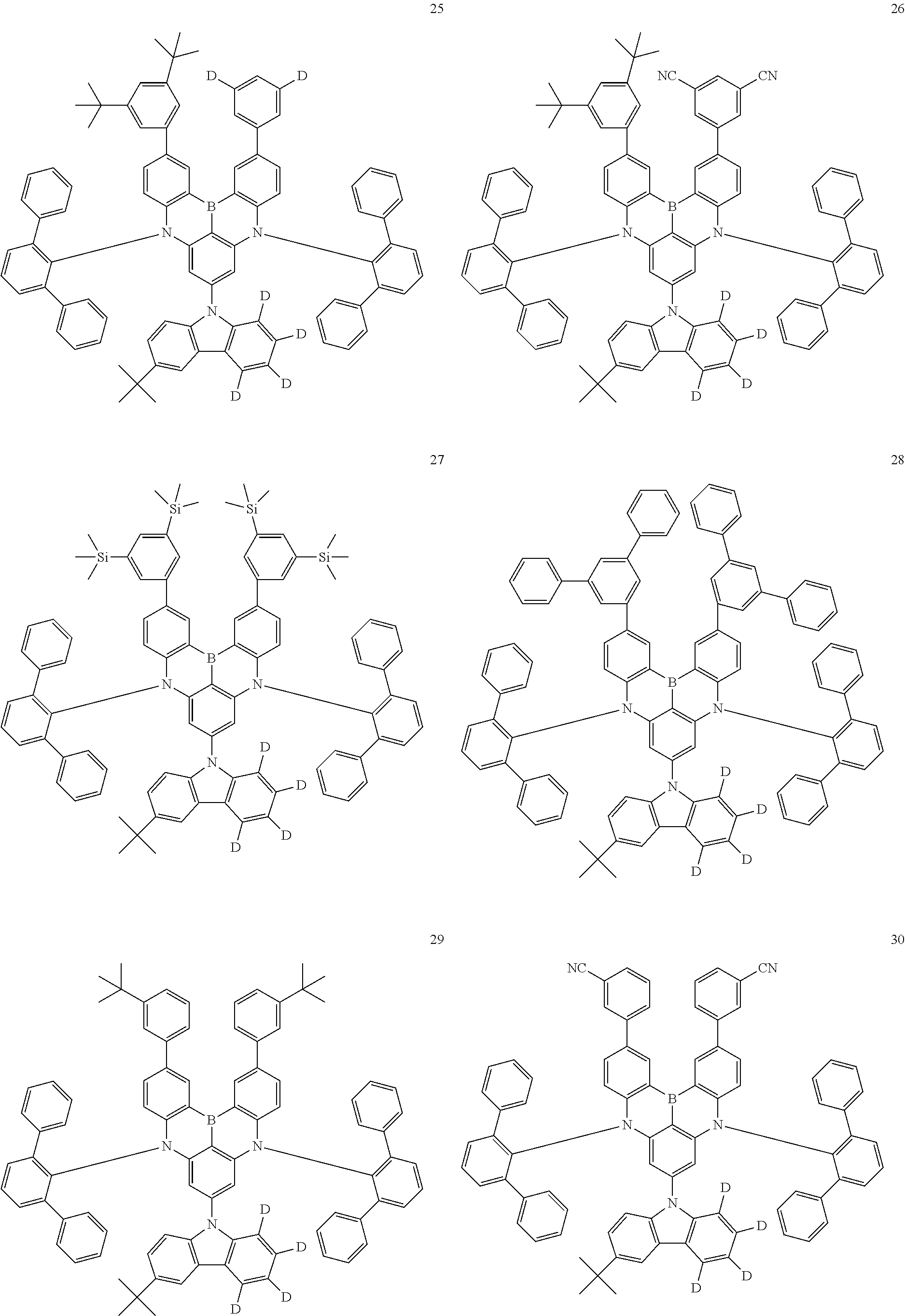 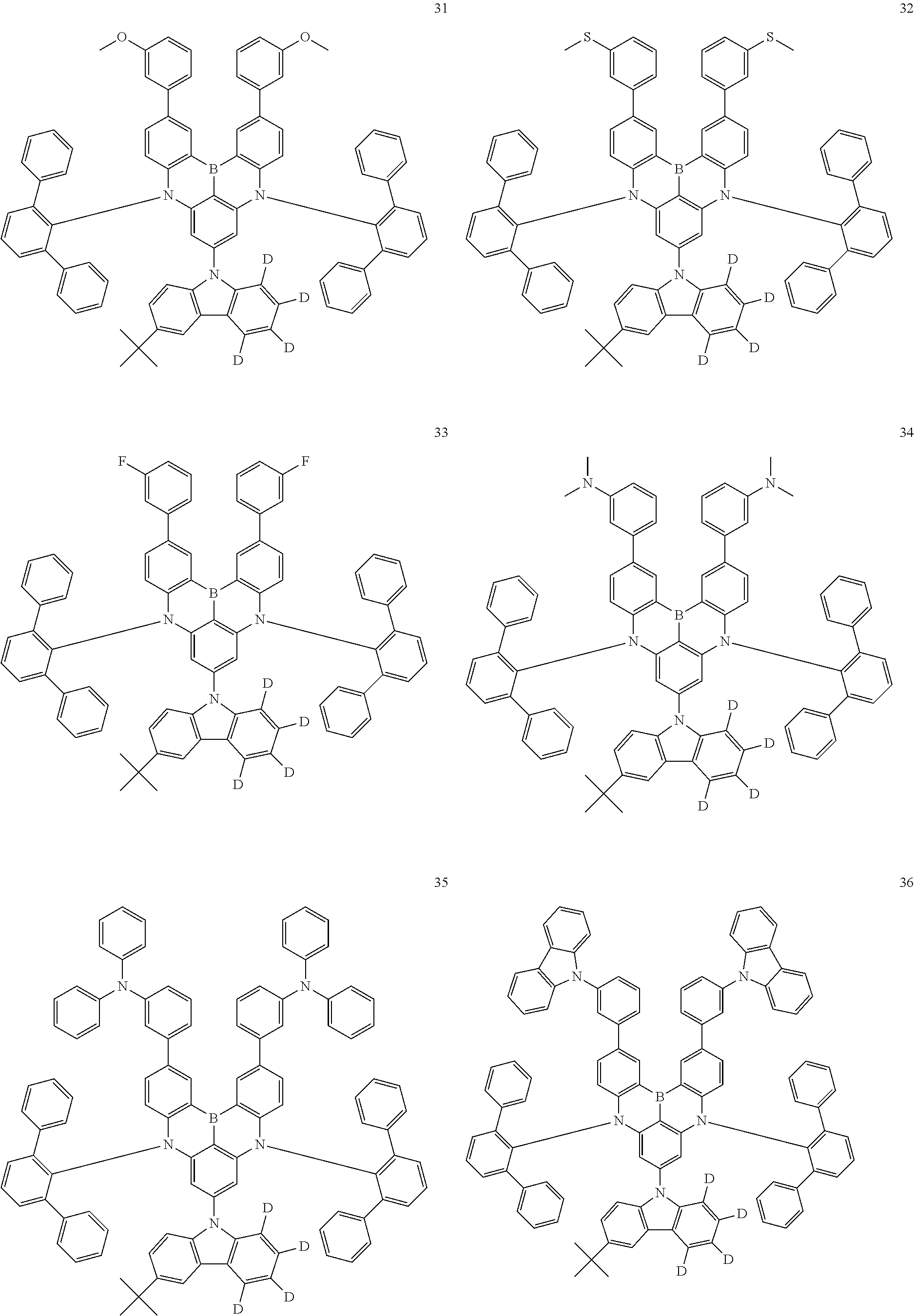 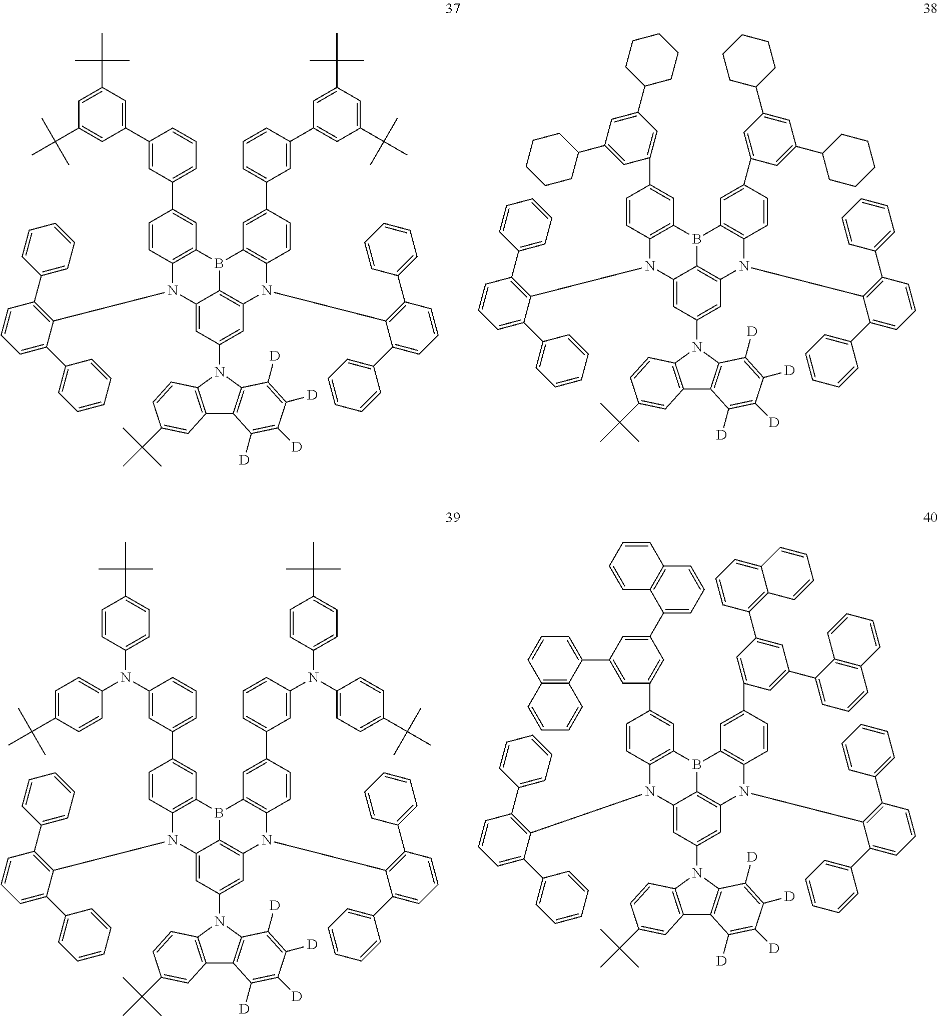 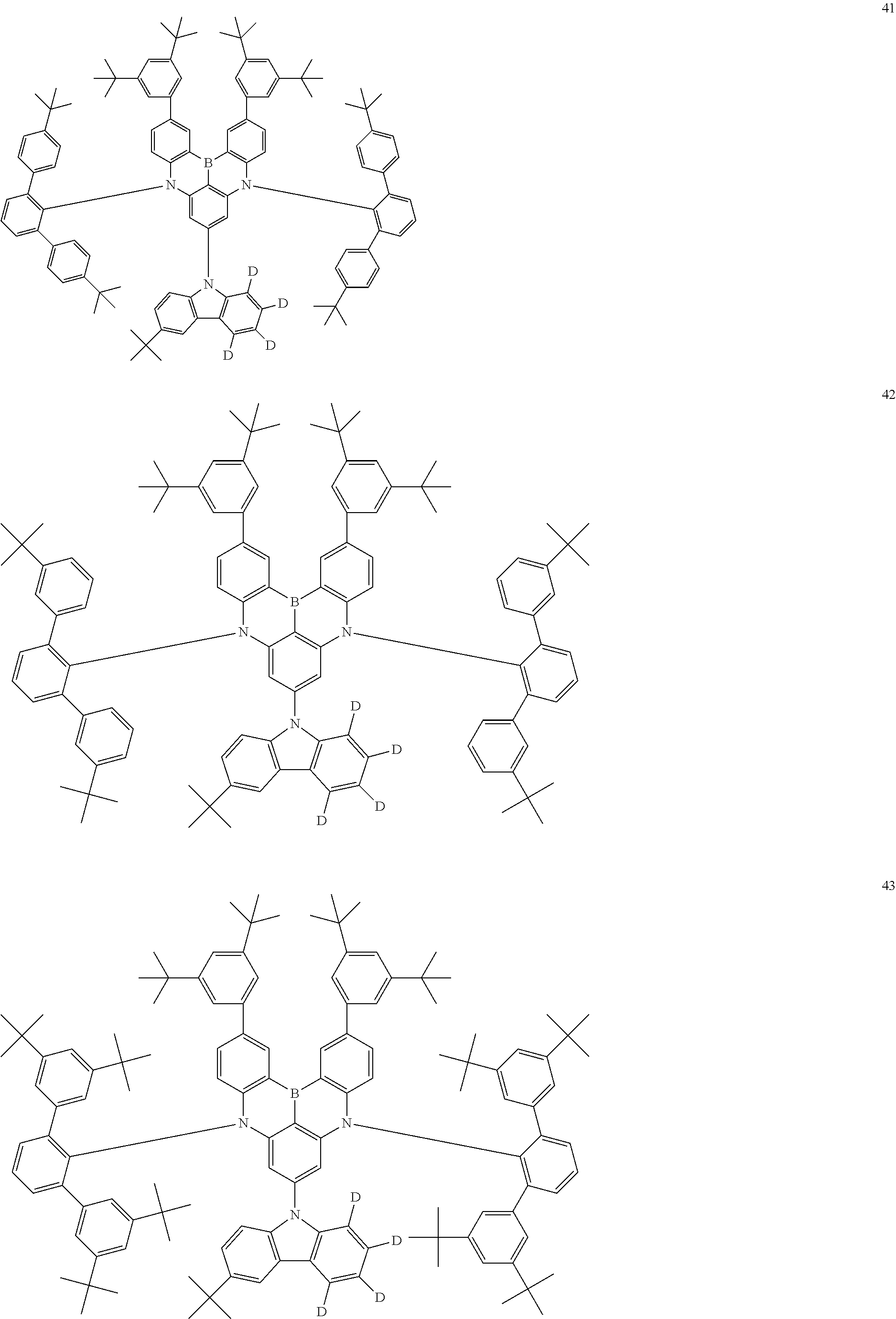 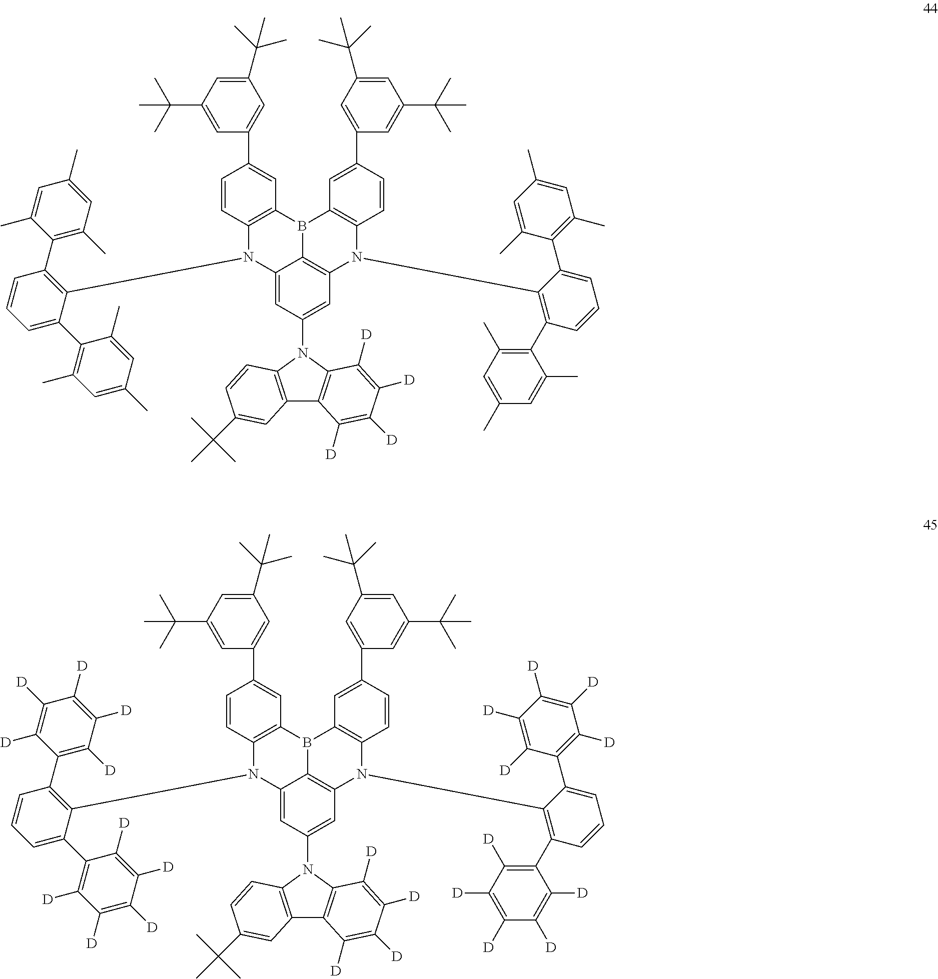 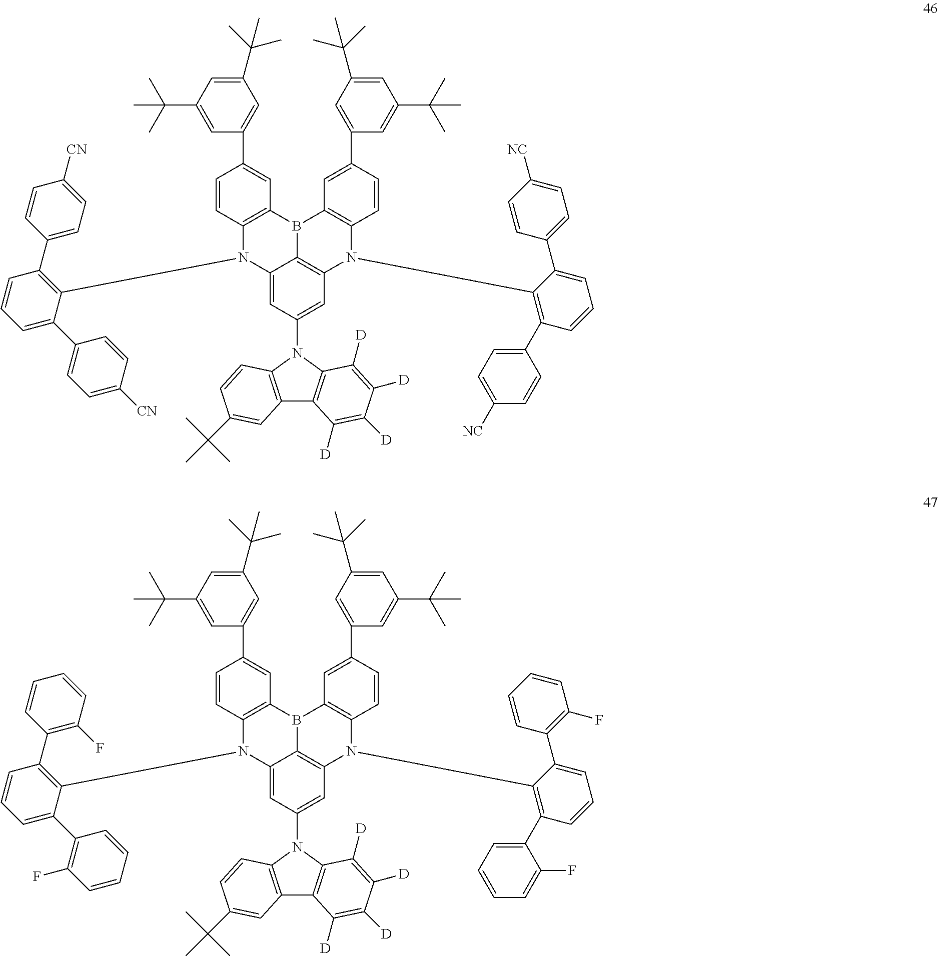 [SMILES: [2H]c1c([2H])c([2H])c2c(c1[2H])c1cc(C(C)(C)C)ccc1n2-c1cc2c3c(c1)N(c1c(-c4ccc(C#N)cc4)cccc1-c1ccc(C#N)cc1)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccc(C#N)cc2)cccc1-c1ccc(C#N)cc1 ; [2H]c1c([2H])c([2H])c2c(c1[2H])c1cc(C(C)(C)C)ccc1n2-c1cc2c3c(c1)N(c1c(-c4ccccc4F)cccc1-c1ccccc1F)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccccc2F)cccc1-c1ccccc1F] 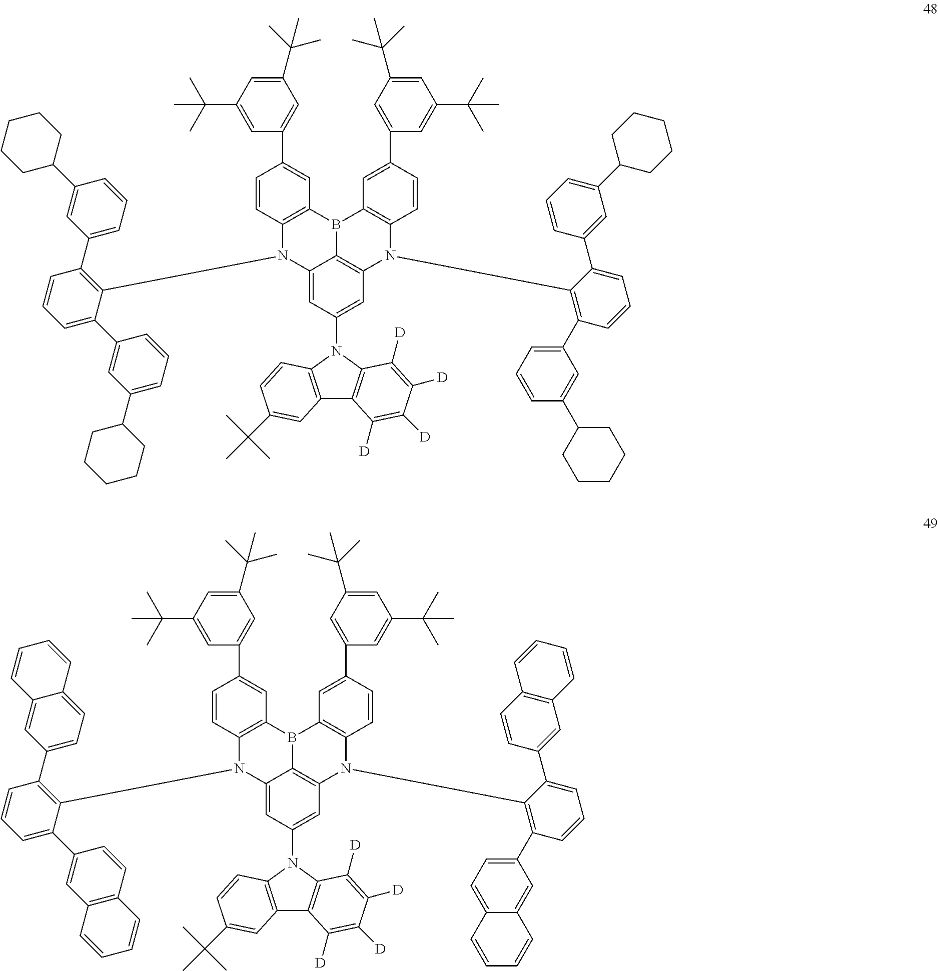 [SMILES: [2H]c1c([2H])c([2H])c2c(c1[2H])c1cc(C(C)(C)C)ccc1n2-c1cc2c3c(c1)N(c1c(-c4cccc(C5CCCCC5)c4)cccc1-c1cccc(C4CCCCC4)c1)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2cccc(C3CCCCC3)c2)cccc1-c1cccc(C2CCCCC2)c1 ; [2H]c1c([2H])c([2H])c2c(c1[2H])c1cc(C(C)(C)C)ccc1n2-c1cc2c3c(c1)N(c1c(-c4ccc5ccccc5c4)cccc1-c1ccc4ccccc4c1)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccc3ccccc3c2)cccc1-c1ccc2ccccc2c1] 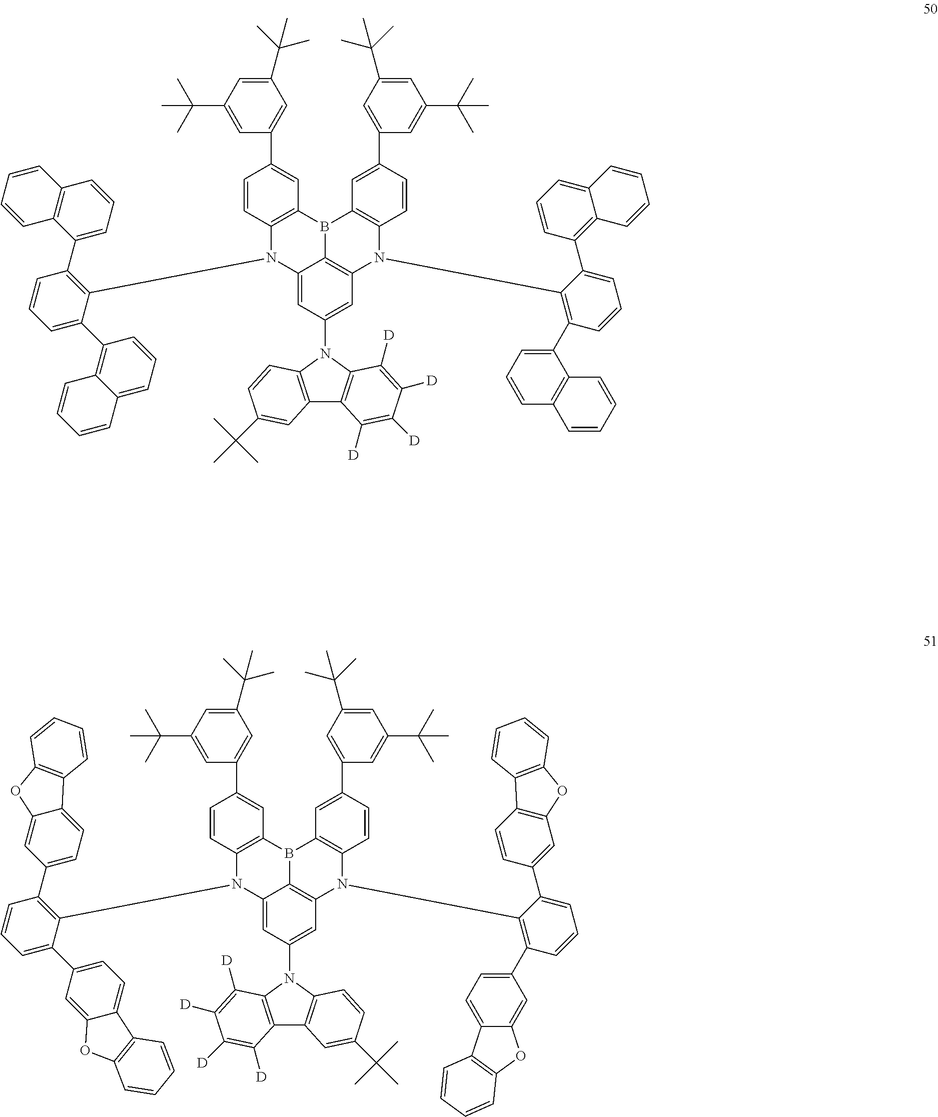 [SMILES: [2H]c1c([2H])c([2H])c2c(c1[2H])c1cc(C(C)(C)C)ccc1n2-c1cc2c3c(c1)N(c1c(-c4cccc5ccccc45)cccc1-c1cccc4ccccc14)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2cccc3ccccc23)cccc1-c1cccc2ccccc12 ; [2H]c1c([2H])c([2H])c2c(c1[2H])c1cc(C(C)(C)C)ccc1n2-c1cc2c3c(c1)N(c1c(-c4ccc5c(c4)oc4ccccc45)cccc1-c1ccc4c(c1)oc1ccccc14)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccc3c(c2)oc2ccccc23)cccc1-c1ccc2c(c1)oc1ccccc12] 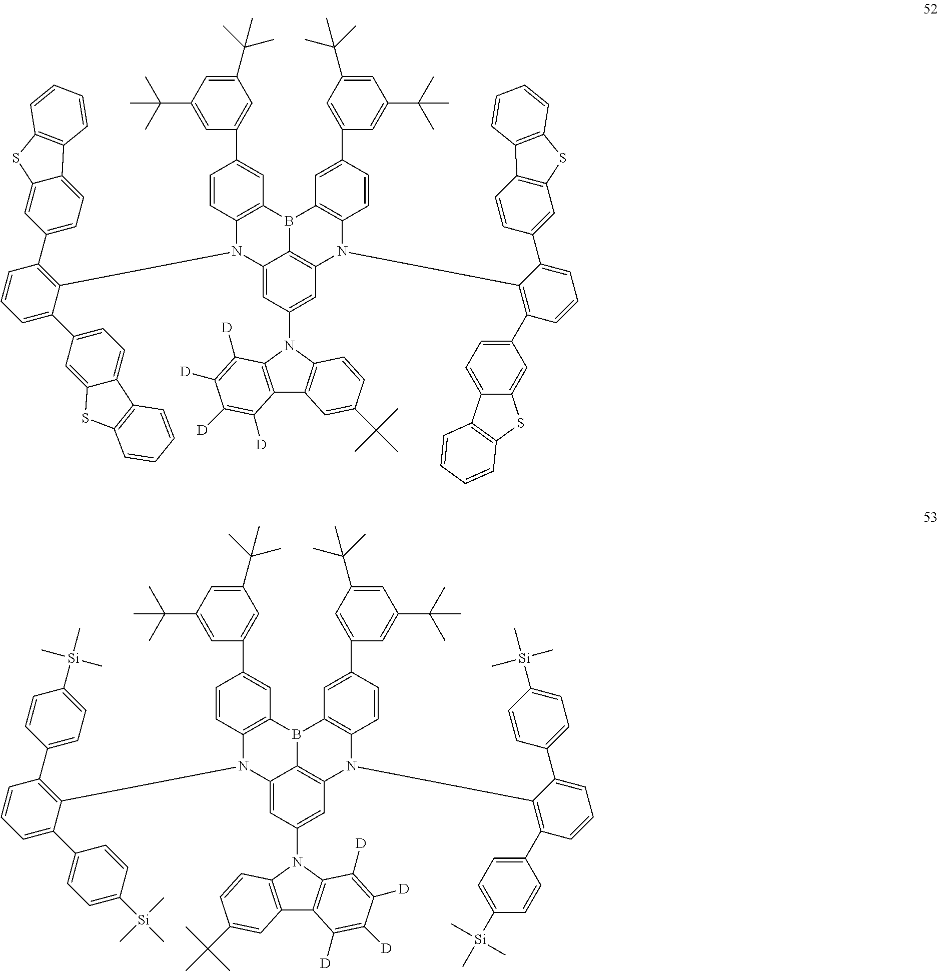 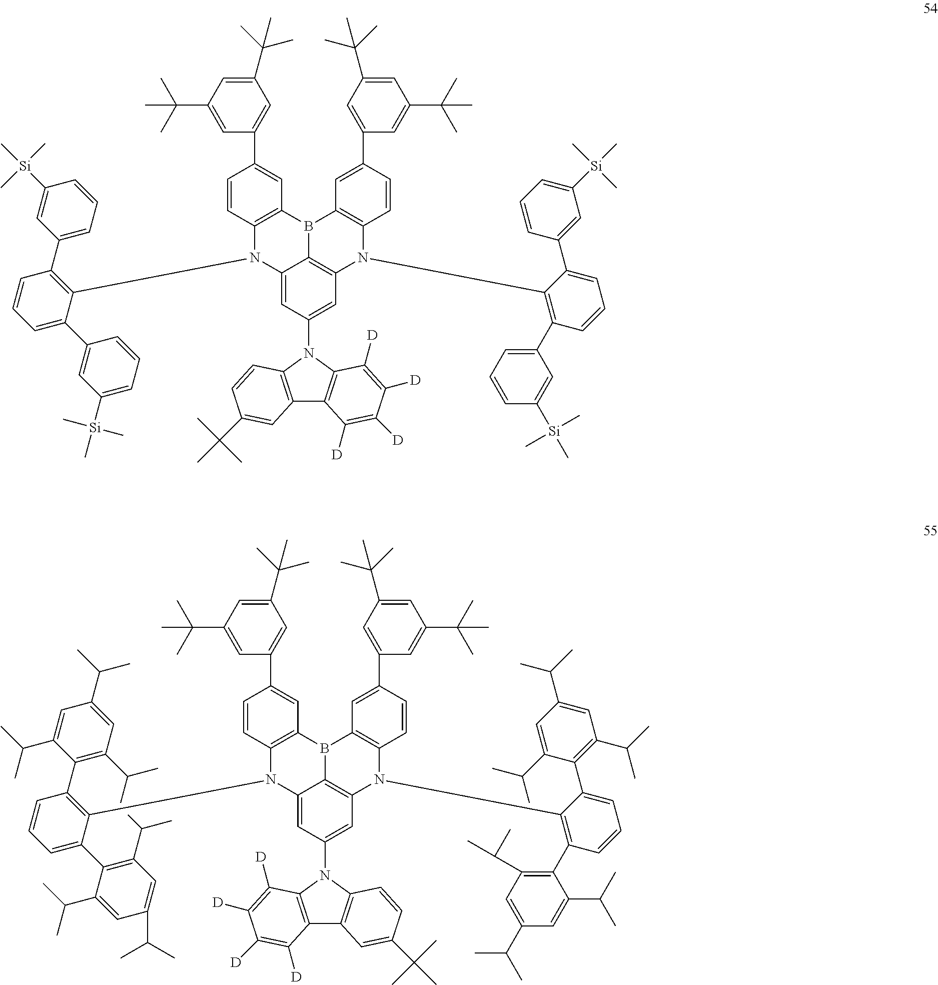 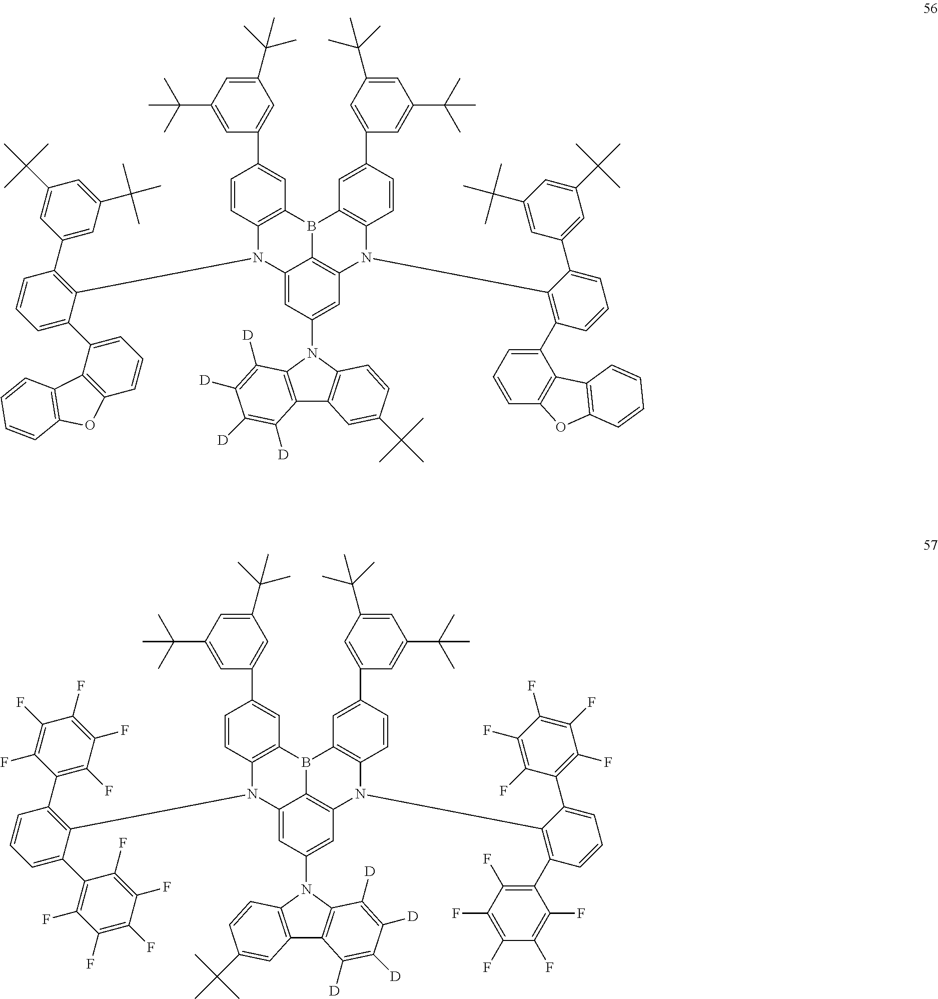 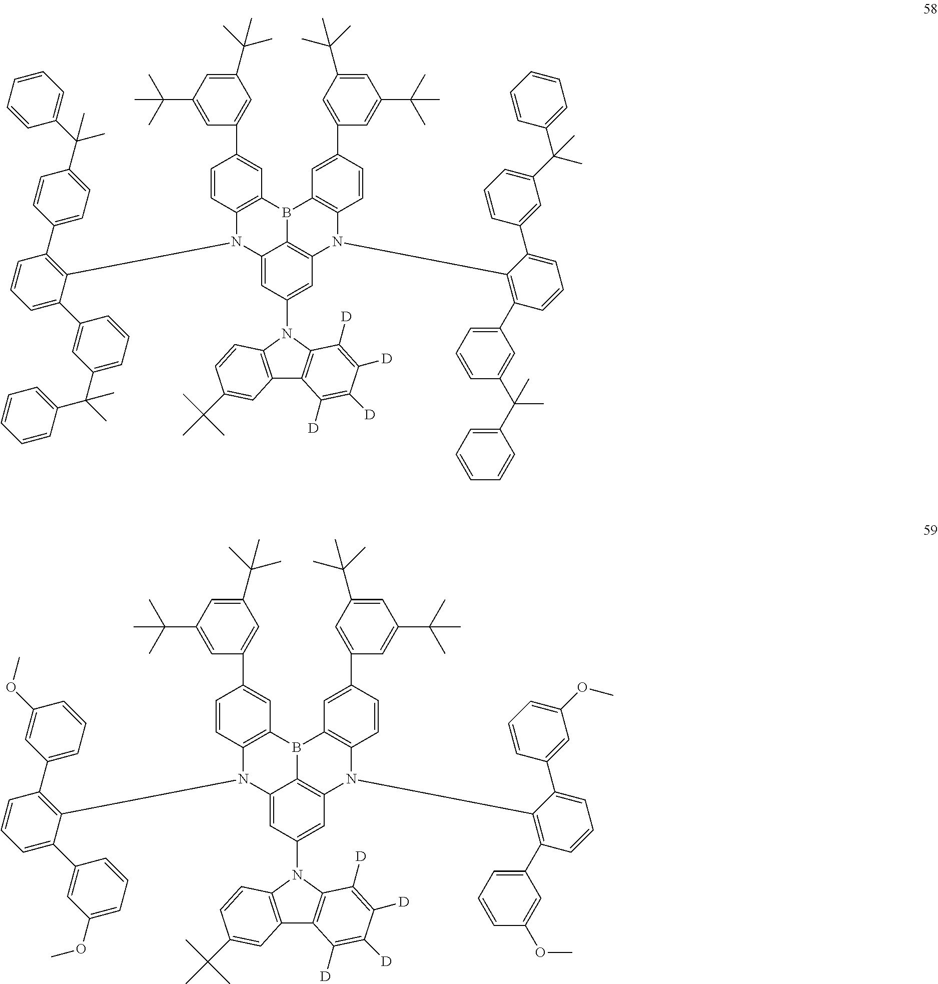 [SMILES: [2H]c1c([2H])c([2H])c2c(c1[2H])c1cc(C(C)(C)C)ccc1n2-c1cc2c3c(c1)N(c1c(-c4cccc(C(C)(C)c5ccccc5)c4)cccc1-c1cccc(C(C)(C)c4ccccc4)c1)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2ccc(C(C)(C)c3ccccc3)cc2)cccc1-c1cccc(C(C)(C)c2ccccc2)c1 ; [2H]c1c([2H])c([2H])c2c(c1[2H])c1cc(C(C)(C)C)ccc1n2-c1cc2c3c(c1)N(c1c(-c4cccc(OC)c4)cccc1-c1cccc(OC)c1)c1ccc(-c4cc(C(C)(C)C)cc(C(C)(C)C)c4)cc1B3c1cc(-c3cc(C(C)(C)C)cc(C(C)(C)C)c3)ccc1N2c1c(-c2cccc(OC)c2)cccc1-c1cccc(OC)c1] 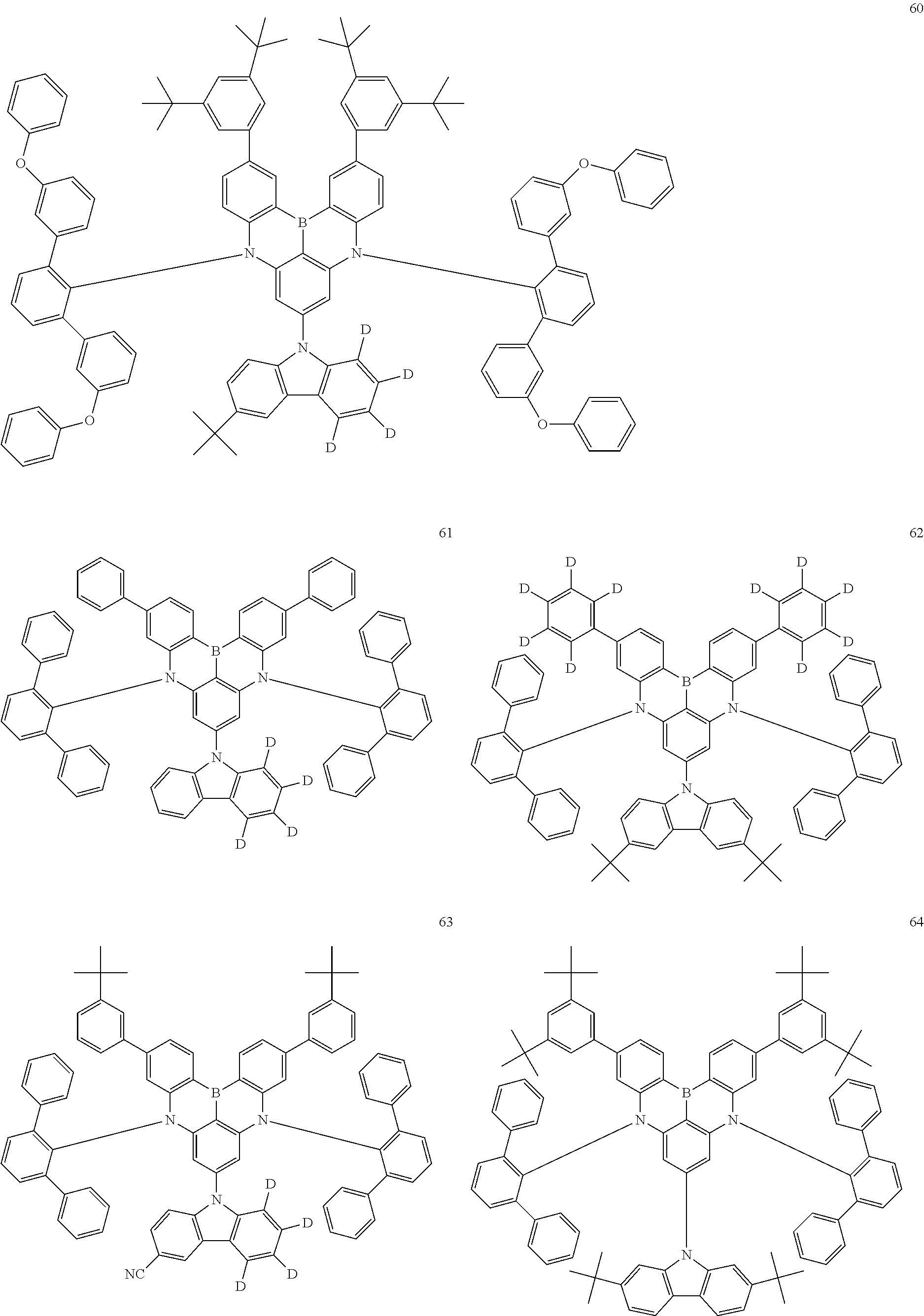 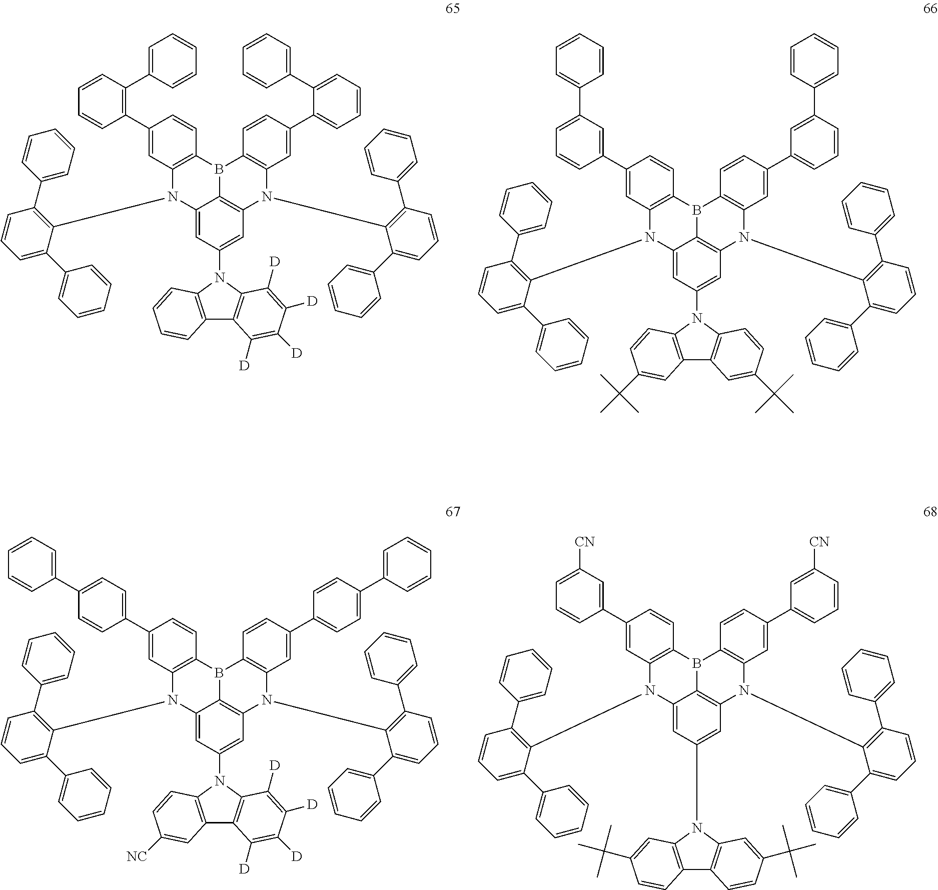 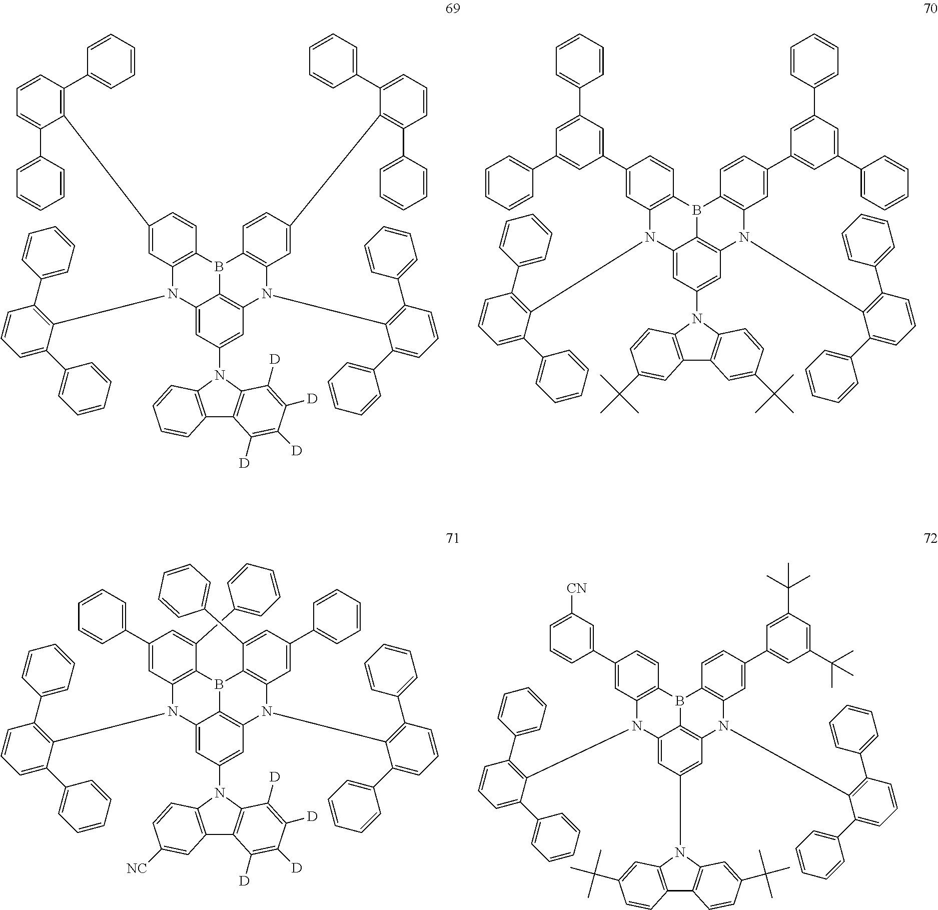 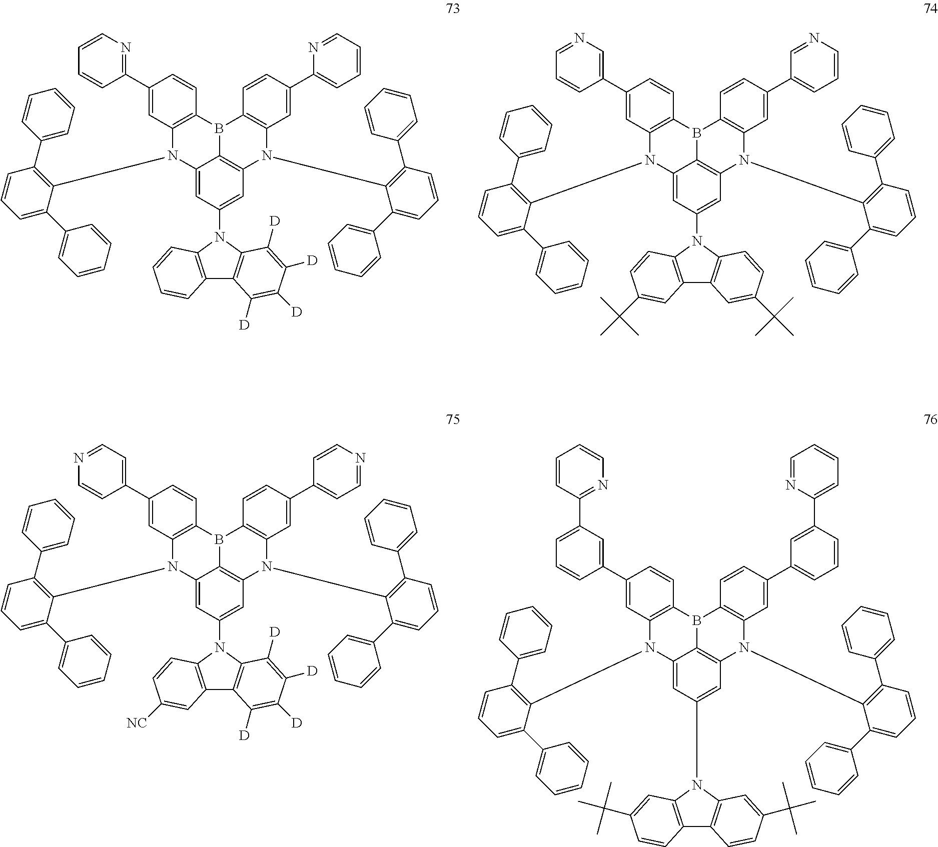 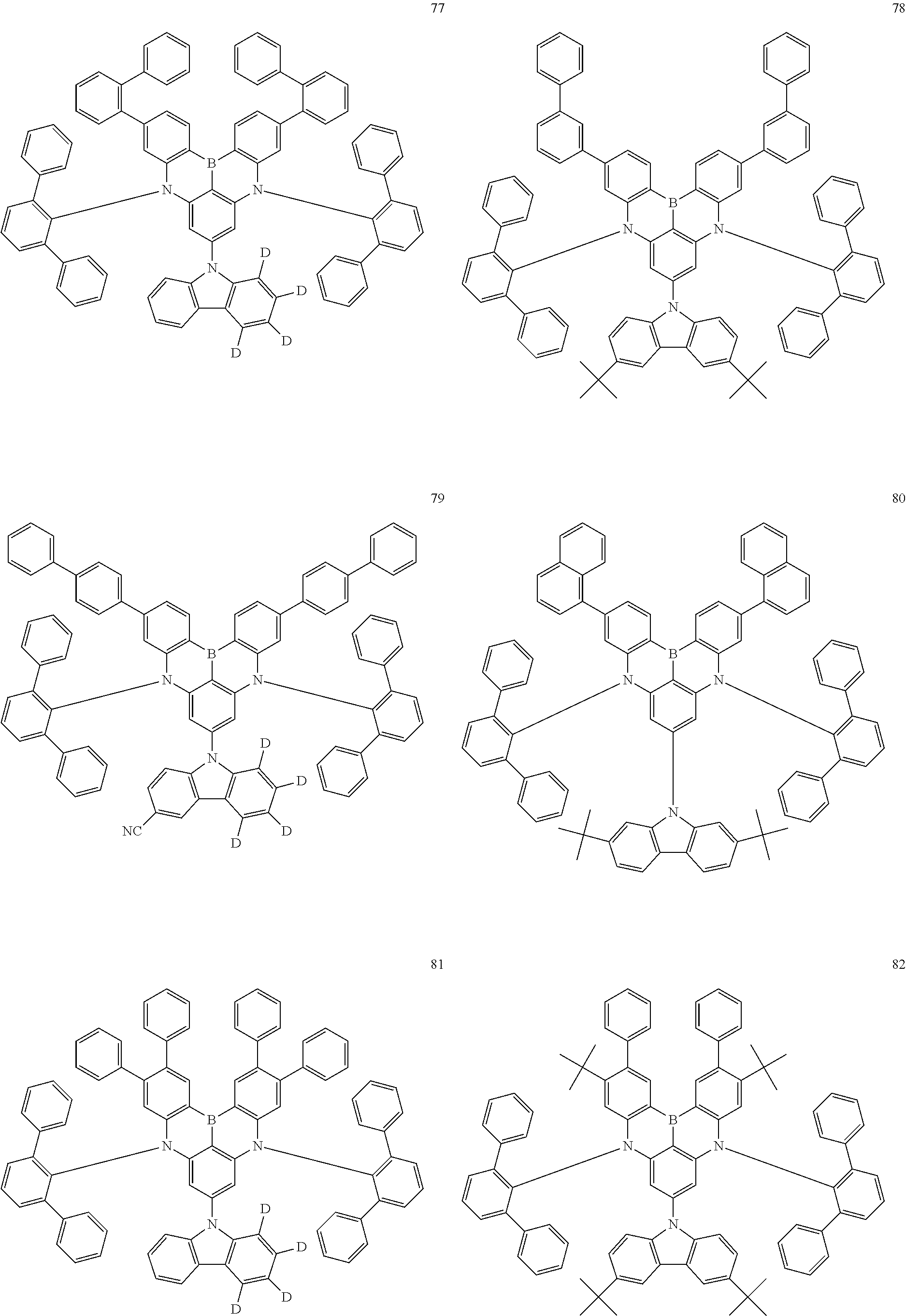 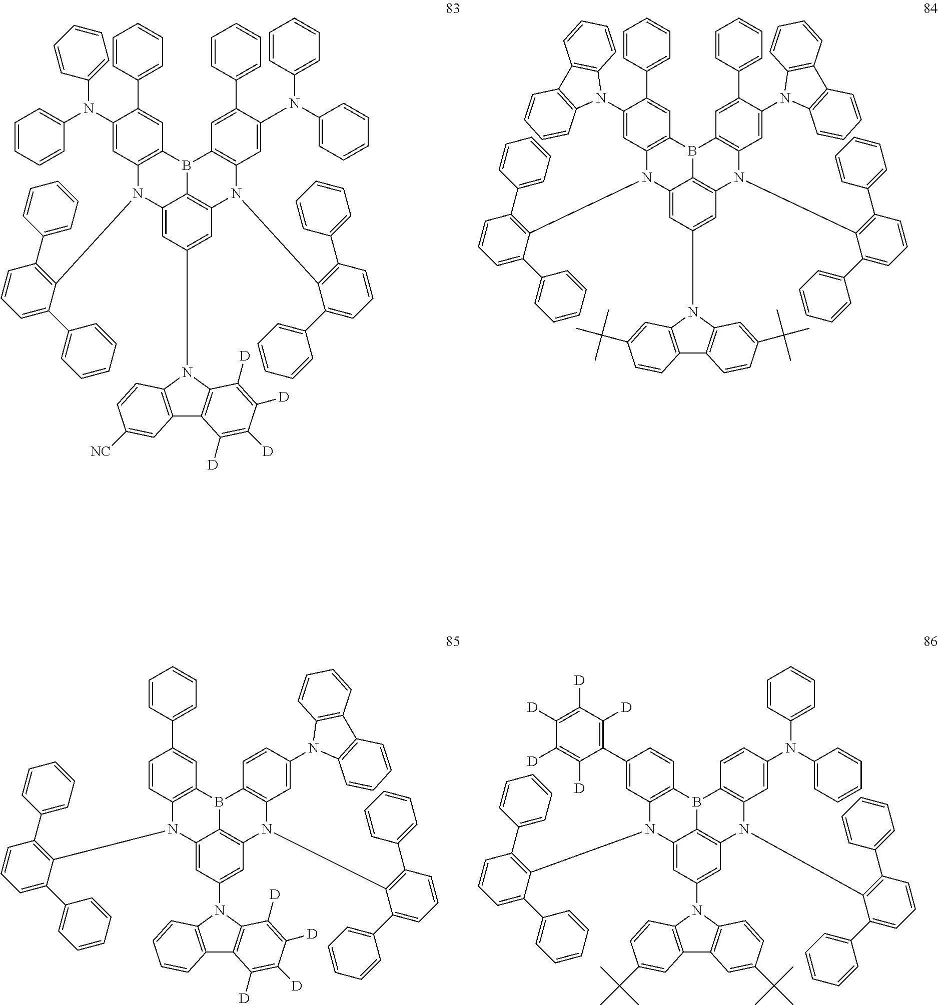 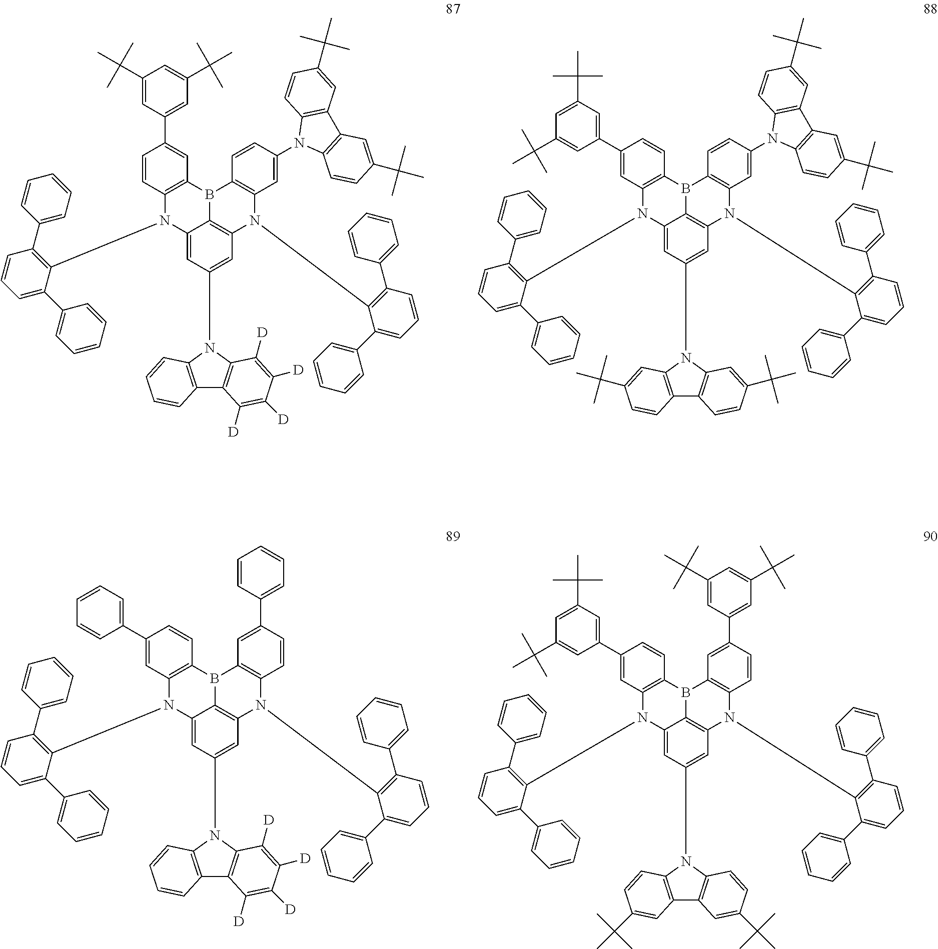 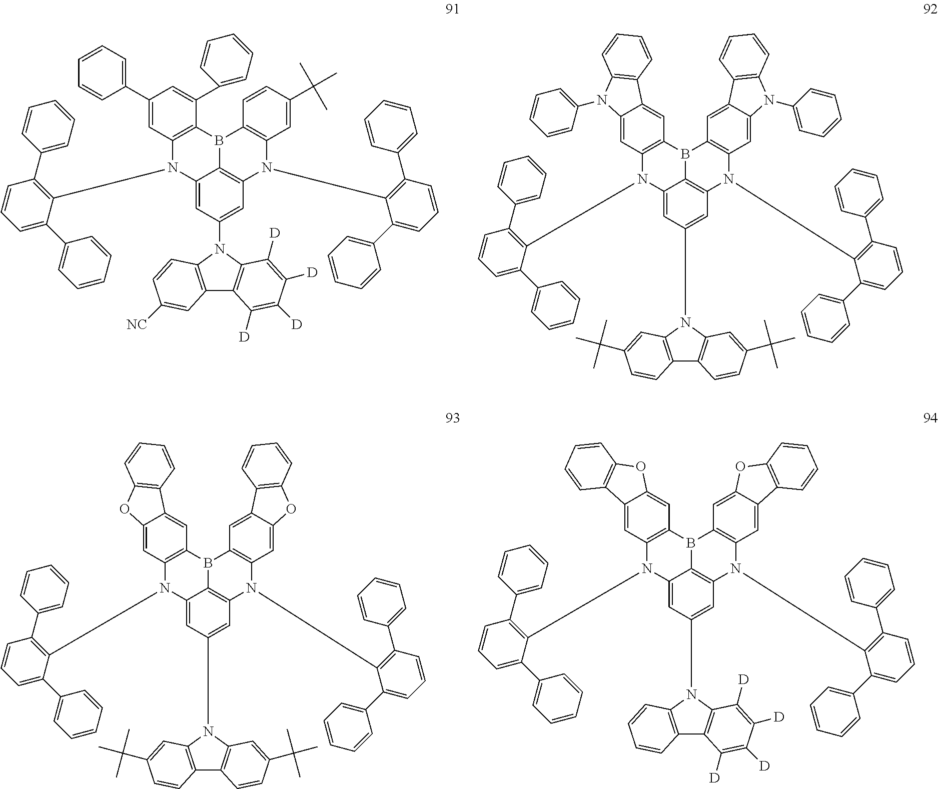 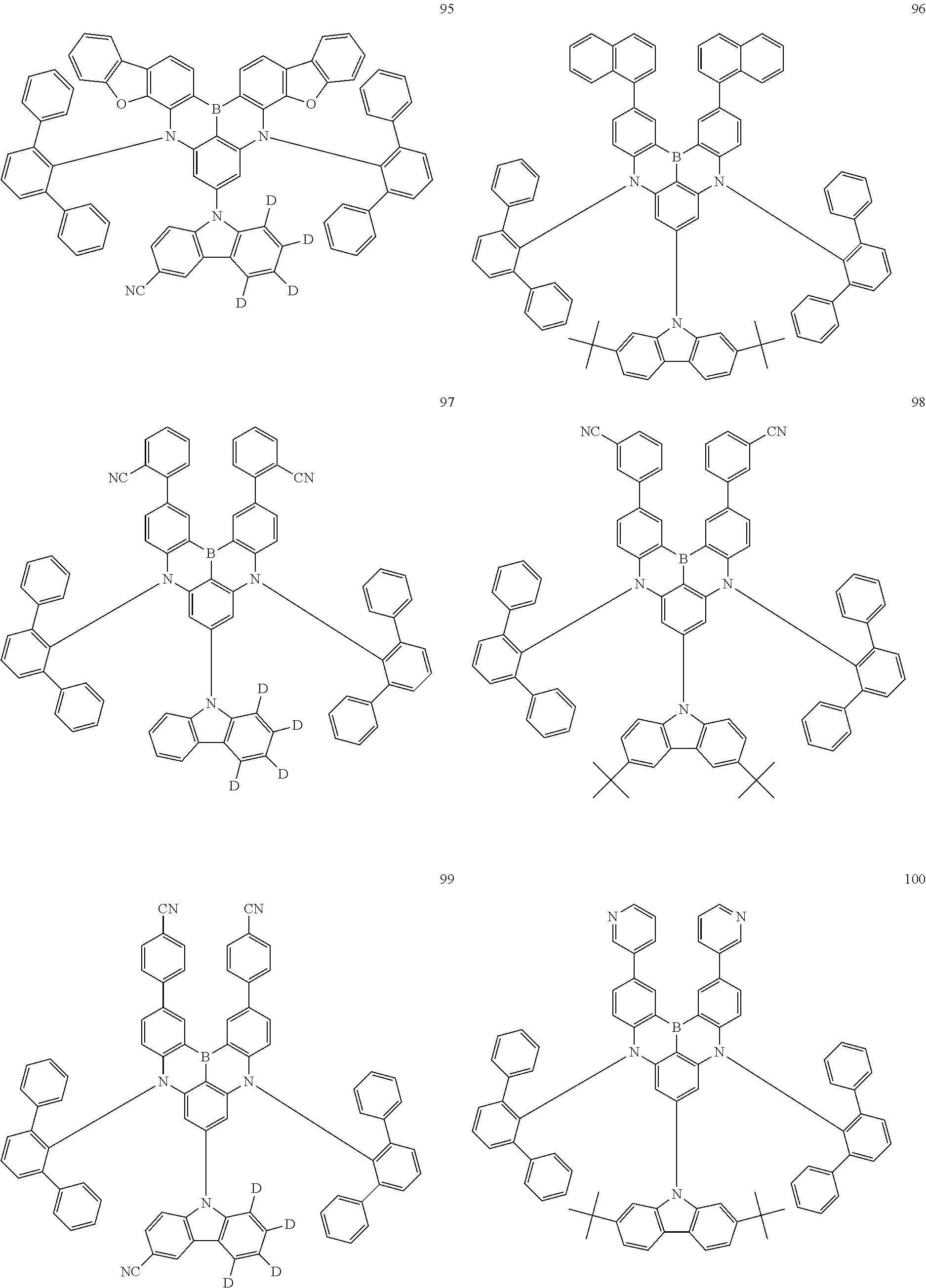
wherein in Compound Group 1,
D represents a deuterium atom.
